(19) United States
(12) Patent Application Publication
(10) Pub. No.: US 2023/0216476 A1
(43) Pub. Date: Jul. 6, 2023

(54) BULK ACOUSTIC WAVE (BAW) RESONATOR, PATTERNED LAYER STRUCTURES, DEVICES AND SYSTEMS

(71) Applicant: QXONIX INC., Irvine, CA (US)

(72) Inventors: DARIUSZ BURAK, FORT COLLINS, CO (US); KEVIN J. GRANNEN, Selma, TX (US); JACK LENELL, FORT COLLINS, CO (US)

(21) Appl. No.: 18/094,383

(22) Filed: Jan. 8, 2023

Related U.S. Application Data
(63) Continuation-in-part of application No. 17/564,797, filed on Dec. 29, 2021.
Application No. 17/564,797 is a continuation of application No. PCT/US2020/043746, filed on Jul. 27, 2020.
Application No. 17/564,797 is a continuation of application No. 17/380,011, filed on Jul. 20, 2021.
Application No. 17/380,011 is a continuation of application No. 16/940,172, filed on Jul. 27, 2020, now Pat. No. 11,101,783.
Application No. 16/940,172 is a continuation-in-part of application No. 17/380,011, filed on Jul. 20, 2021.
Application No. 17/380,011 is a continuation of application No. 16/940,172, filed on Jul. 27, 2020, now Pat. No. 11,101,783.
(60) Provisional application No. 63/302,067, filed on Jan. 22, 2022.
(60) Provisional application No. 63/302,068, filed on Jan. 22, 2022.
(60) Provisional application No. 62/881,061, filed on Jul. 31, 2019.
(60) Provisional application No. 62/881,074, filed on Jul. 31, 2019.
(60) Provisional application No. 62/881,077, filed on Jul. 31, 2019.
(60) Provisional application No. 62/881,085, filed on Jul. 31, 2019.
(60) Provisional application No. 62/881,087, filed on Jul. 31, 2019.
(60) Provisional application No. 63/302,070, filed on Jan. 22, 2022.
(60) Provisional application No. 62/881,091, filed on Jul. 31, 2019.
(60) Provisional application No. 62/881,094, filed on Jul. 31, 2019.
(60) Provisional application No. 62/881,061, filed on Jul. 31, 2019.
(60) Provisional application No. 62/881,074, filed on Jul. 31, 2019.
(60) Provisional application No. 62/881,077, filed on Jul. 31, 2019.
(60) Provisional application No. 62/881,085, filed on Jul. 31, 2019.
(60) Provisional application No. 62/881,087, filed on Jul. 31, 2019.
(60) Provisional application No. 62/881,091, filed on Jul. 31, 2019.
(60) Provisional application No. 63/306,299, filed on Feb. 3, 2022.
(60) Provisional application No. 62/881,094, filed on Jul. 31, 2019.
(60) Provisional application No. 62/881,061, filed on Jul. 31, 2019.
(60) Provisional application No. 62/881,074, filed on Jul. 31, 2019.
(60) Provisional application No. 62/881,077, filed on Jul. 31, 2019.
(60) Provisional application No. 62/881,085, filed on Jul. 31, 2019.

(51) Int. Cl. H03H 9/17; H03B 5/32; H03H 9/56; H03H 9/02; H03H 9/135

(52) U.S. Cl. CPC H03H 9/17; H03B 5/326; H03H 9/568; H03H 9/0211; H03H 9/135

(57) ABSTRACT

Techniques for improving Bulk Acoustic Wave (BAW) reflector and resonator structures are disclosed, including filters, oscillators and systems that may include such devices. A Bulk Acoustic Wave (BAW) resonator of this disclosure may comprise a substrate and an active piezoelectric resonant volume. The active piezoelectric resonant volume of the Bulk Acoustic Wave (BAW) resonator may have a main resonant frequency. The active piezoelectric resonant volume of the Bulk Acoustic Wave (BAW) resonator may comprise first and second piezoelectric layers having respective piezoelectric axis that substantially oppose one another. A first patterned layer may be disposed within the active piezoelectric volume. This may, but need not facilitate suppression of spurious modes. The main resonant frequency of the Bulk Acoustic Wave (BAW) resonator may be in a super high frequency (SHF) band. The main resonant frequency of the Bulk Acoustic Wave (BAW) resonator may be in an extremely high frequency (EHF) band.

### PRIORITY CLAIM

This application claims the benefit of priority to the following provisional patent applications:

(1) U.S. Provisional Patent Application Ser. No. 63/302,067 entitled “LAYERS, STRUCTURES, ACOUSTIC WAVE RESONATORS, DEVICES AND SYSTEMS” and filed on Jan. 22, 2022;

(2) U.S. Provisional Patent Application Ser. No. 63/302,068 entitled “BULK ACOUSTIC WAVE (BAW) RESONATOR, PATTERNED LAYER STRUCTURES, DEVICES AND SYSTEMS” and filed on Jan. 22, 2022;

(3) U.S. Provisional Patent Application Ser. No. 63/302,070 entitled “STRUCTURES, ACOUSTIC WAVE RESONATORS, LAYERS, DEVICES AND SYSTEMS” and filed on Jan. 22, 2022; and

(4) U.S. Provisional Patent Application Ser. No. 63/306,299 entitled “LAYERS, STRUCTURES, ACOUSTIC WAVE RESONATORS, DEVICES, CIRCUITS AND SYSTEMS” and filed on Feb. 3, 2022.

Each of the provisional patent applications identified above is incorporated herein by reference in its entirety.

This application is also a continuation in part of U.S. patent application Ser. No. 17/380,011 filed Jul. 20, 2021, entitled “STRUCTURES, ACOUSTIC WAVE RESONATORS, DEVICES AND SYSTEMS TO SENSE A TARGET VARIABLE”, which in turn is a continuation of U.S. patent application Ser. No. 16/940,172 filed Jul. 27, 2020 (issued as U.S. Pat. No. 11,101,783), entitled “STRUCTURES, ACOUSTIC WAVE RESONATORS, DEVICES AND SYSTEMS TO SENSE A TARGET VARIABLE, INCLUDING AS A NON-LIMITING EXAMPLE CORONAVIRUSES”, which in turn claims priority to the U.S. Provisional Patent Applications:

(1) U.S. Provisional Patent Application Ser. No. 62/881,061, entitled “BULK ACOUSTIC WAVE (BAW) RESONATOR STRUCTURES, DEVICES AND SYSTEMS” and filed on Jul. 31, 2019;

(2) U.S. Provisional Patent Application Ser. No. 62/881,074, entitled “ACOUSTIC DEVICE STRUCTURES, DEVICES AND SYSTEMS” and filed on Jul. 31, 2019;

(3) U.S. Provisional Patent Application Ser. No. 62/881,077, entitled “DOPED BULK ACOUSTIC WAVE (BAW) RESONATOR STRUCTURES, DEVICES AND SYSTEMS” and filed on Jul. 31, 2019;

(4) U.S. Provisional Patent Application Ser. No. 62/881,085, entitled “BULK ACOUSTIC WAVE (BAW) RESONATOR WITH PATTERNED LAYER STRUCTURES, DEVICES AND SYSTEMS” and filed on Jul. 31, 2019;

(5) U.S. Provisional Patent Application Ser. No. 62/881,087, entitled “BULK ACOUSTIC WAVE (BAW) REFLECTOR AND RESONATOR STRUCTURES, DEVICES AND SYSTEMS” and filed on Jul. 31, 2019;

(6) U.S. Provisional Patent Application Ser. No. 62/881,091, entitled “MASS LOADED BULK ACOUSTIC WAVE (BAW) RESONATOR STRUCTURES, DEVICES AND SYSTEMS” and filed on Jul. 31, 2019; and

(7) U.S. Provisional Patent Application Ser. No. 62/881,094, entitled “TEMPERATURE COMPENSATING BULK ACOUSTIC WAVE (BAW) RESONATOR STRUCTURES, DEVICES AND SYSTEMS” and filed on Jul. 31, 2019.

Each of the applications identified above are hereby incorporated by reference in their entirety.

This application is also a continuation in part of U.S. patent application Ser. No. 17/564,797 titled “MASS LOADED BULK ACOUSTIC WAVE (BAW) RESONATOR STRUCTURES, DEVICES, AND SYSTEMS”, filed Dec. 29, 2021, which in turn is a continuation of PCT Application No. PCTUS2020043746 filed Jul. 27, 2020, titled “MASS LOADED BULK ACOUSTIC WAVE (BAW) RESONATOR STRUCTURES, DEVICES AND SYSTEMS”, which claims priority to the following provisional patent applications:

(1) U.S. Provisional Patent Application Ser. No. 62/881,061, entitled “BULK ACOUSTIC WAVE (BAW) RESONATOR STRUCTURES, DEVICES AND SYSTEMS” and filed on Jul. 31, 2019;

(2) U.S. Provisional Patent Application Ser. No. 62/881,074, entitled “ACOUSTIC DEVICE STRUCTURES, DEVICES AND SYSTEMS” and filed on Jul. 31, 2019;

(3) U.S. Provisional Patent Application Ser. No. 62/881,077, entitled “DOPED BULK ACOUSTIC WAVE (BAW) RESONATOR STRUCTURES, DEVICES AND SYSTEMS” and filed on Jul. 31, 2019;

(4) U.S. Provisional Patent Application Ser. No. 62/881,085, entitled “BULK ACOUSTIC WAVE (BAW) RESONATOR WITH PATTERNED LAYER STRUCTURES, DEVICES AND SYSTEMS” and filed on Jul. 31, 2019;

(5) U.S. Provisional Patent Application Ser. No. 62/881,087, entitled “BULK ACOUSTIC WAVE (BAW) REFLECTOR AND RESONATOR STRUCTURES, DEVICES AND SYSTEMS” and filed on Jul. 31, 2019;

(6) U.S. Provisional Patent Application Ser. No. 62/881,091, entitled “MASS LOADED BULK ACOUSTIC WAVE (BAW) RESONATOR STRUCTURES, DEVICES AND SYSTEMS” and filed on Jul. 31, 2019; and

(7) U.S. Provisional Patent Application Ser. No. 62/881,094, entitled “TEMPERATURE COMPENSATING BULK ACOUSTIC WAVE (BAW) RESONATOR STRUCTURES, DEVICES AND SYSTEMS” and filed on Jul. 31, 2019.

Each of the applications identified above are hereby incorporated by reference in their entirety.

U.S. patent application Ser. No. 17/564,797 is also a continuation of U.S. patent application Ser. No. 17/380,011 filed Jul. 20, 2021, entitled “STRUCTURES, ACOUSTIC WAVE RESONATORS, DEVICES AND SYSTEMS TO SENSE A TARGET VARIABLE”, which in turn is a continuation of U.S. patent application Ser. No. 16/940,172 filed Jul. 27, 2020 (issued as U.S. Pat. No. 11,101,783), entitled “STRUCTURES, ACOUSTIC WAVE RESONATORS, DEVICES AND SYSTEMS TO SENSE A TARGET VARIABLE, INCLUDING AS A NON-LIMITING EXAMPLE CORONAVIRUSES”, which in turn claims priority to the U.S. Provisional Patent Applications:

(1) U.S. Provisional Patent Application Ser. No. 62/881,061, entitled “BULK ACOUSTIC WAVE (BAW) RESONATOR STRUCTURES, DEVICES AND SYSTEMS” and filed on Jul. 31, 2019;

(2) U.S. Provisional Patent Application Ser. No. 62/881,074, entitled “ACOUSTIC DEVICE STRUCTURES, DEVICES AND SYSTEMS” and filed on Jul. 31, 2019;

(3) U.S. Provisional Patent Application Ser. No. 62/881,077, entitled “DOPED BULK ACOUSTIC WAVE (BAW) RESONATOR STRUCTURES, DEVICES AND SYSTEMS” and filed on Jul. 31, 2019;

(4) U.S. Provisional Patent Application Ser. No. 62/881,085, entitled “BULK ACOUSTIC WAVE (BAW) RESONATOR WITH PATTERNED LAYER STRUCTURES, DEVICES AND SYSTEMS” and filed on Jul. 31, 2019;

(5) U.S. Provisional Patent Application Ser. No. 62/881,087, entitled “BULK ACOUSTIC WAVE (BAW) REFLECTOR AND RESONATOR STRUCTURES, DEVICES AND SYSTEMS” and filed on Jul. 31, 2019;

(6) U.S. Provisional Patent Application Ser. No. 62/881,091, entitled “MASS LOADED BULK ACOUSTIC WAVE (BAW) RESONATOR STRUCTURES, DEVICES AND SYSTEMS” and filed on Jul. 31, 2019; and

(7) U.S. Provisional Patent Application Ser. No. 62/881,094, entitled “TEMPERATURE COMPENSATING BULK ACOUSTIC WAVE (BAW) RESONATOR STRUCTURES, DEVICES AND SYSTEMS” and filed on Jul. 31, 2019.

Each of the applications identified above are hereby incorporated by reference in their entirety.

### TECHNICAL FIELD

The present disclosure relates to acoustic resonators and to devices and to systems comprising acoustic resonators.

### BACKGROUND

Bulk Acoustic Wave (BAW) resonators have enjoyed commercial success in filter applications. For example, 4G cellular phones that operate on fourth generation broadband cellular networks typically include a large number of BAW filters for various different frequency bands of the 4G network. In addition to BAW resonators and filters, also included in 4G phones are filters using Surface Acoustic Wave (SAW) resonators, typically for lower frequency band filters. SAW based resonators and filters are generally easier to fabricate than BAW based filters and resonators. However, performance of SAW based resonators and filters may decline if attempts are made to use them for higher 4G frequency bands. Accordingly, even though BAW based filters and resonators are relatively more difficult to fabricate than SAW based filters and resonators, they can be included in 4G cellular phones to provide better performance in higher 4G frequency bands what is provided by SAW based filters and resonators.

5G cellular phones can operate on newer, fifth generation broadband cellular networks. 5G frequencies include some frequencies that are much higher frequency than 4G frequencies. Such relatively higher 5G frequencies can transport data at relatively faster speeds than what can be provided over relatively lower 4G frequencies. However, previously known SAW and BAW based resonators and filters have encountered performance problems when attempts were made to use them at relatively higher 5G frequencies. Many learned engineering scholars have studied these problems, but have not found solutions. For example, performance problems cited for previously known SAW and BAW based resonators and filters include scaling issues and significant increases in acoustic losses at high frequencies.

From the above, it is seen that techniques for improving Bulk Acoustic Wave (BAW) resonator structures are highly desirable, for example for operation over frequencies higher than 4G frequencies, in particular for filters, oscillators and systems that can include such devices.

### BRIEF DESCRIPTION OF THE DRAWINGS

FIG. 1AA shows simplified diagrams of two bulk acoustic wave resonator structures of this disclosure.

FIG. 1AB shows simplified diagrams of six multilayer metal acoustic reflector electrodes comprising current spreading layers (CSLs) for use in the bulk acoustic wave resonator structures of this disclosure, and a corresponding chart showing sheet resistance versus number of additional quarter wavelength current spreading layers, with results as expected from simulation.

FIG. 1AC shows three simplified diagrams of multilayer metal acoustic reflector electrodes comprising current spreading layers (CSLs) for use in the bulk acoustic wave resonator structures of this disclosure, and two corresponding charts showing acoustic reflectivity versus acoustic frequency, with results as expected from simulation.

FIG. 1A is a diagram that illustrates an example bulk acoustic wave resonator structure.

FIG. 1B is a simplified view of FIG. 1A that illustrates acoustic stress profile during electrical operation of the bulk acoustic wave resonator structure shown in FIG. 1A.

FIG. 1C shows a simplified top plan view of a bulk acoustic wave resonator structure corresponding to the cross sectional view of FIG. 1A, and also shows another simplified top plan view of an alternative bulk acoustic wave resonator structure.

FIG. 1D is a perspective view of an illustrative model of a crystal structure of AlN in piezoelectric material of layers in FIG. 1A having reverse axis orientation of negative polarization.

FIG. 1E is a perspective view of an illustrative model of a crystal structure of AlN in piezoelectric material of layers in FIG. 1A having normal axis orientation of positive polarization.

FIG. 2A shows further simplified views of four additional bulk acoustic wave resonators.

FIG. 2B shows a first two diagrams for different mass load materials and different mass load layer placement shown with bulk acoustic wave resonator interposer layer sensitivity versus number of alternating axis half wavelength thickness piezoelectric layers, as predicted by simulation.

FIG. 2C shows an additional two diagrams for different mass load materials and different mass load layer placement shown with bulk acoustic wave resonator interposer layer sensitivity versus number of alternating axis half wavelength thickness piezoelectric layers, as predicted by simulation.

FIG. 2D shows further simplified views of another additional four bulk acoustic wave resonators.

FIG. 2E shows a first two diagrams for different patterned mass load materials and different patterned layer placement shown with bulk acoustic wave resonator patterned layer sensitivity versus number of alternating axis half wavelength thickness piezoelectric layers, as predicted by simulation.

FIG. 2F shows an additional two diagrams for different patterned mass load materials and different patterned layer placement shown with bulk acoustic wave resonator patterned layer sensitivity versus number of alternating axis half wavelength thickness piezoelectric layers, as predicted by simulation.

FIG. 2G shows further simplified views of an additional five bulk acoustic wave resonators.

FIG. 2H shows further simplified views of another additional five bulk acoustic wave resonators.

FIGS. 3A through 3D illustrate example integrated circuit structures used to form the example bulk acoustic wave resonator structure of FIG. 1A. Note that although AlN is used as an example piezoelectric layer material, the present disclosure is not intended to be so limited. For example, in some embodiments, the piezoelectric layer material may include other group III material-nitride (III-N) compounds (e.g., any combination of one or more of gallium, indium, and aluminum with nitrogen), and further, any of the foregoing may include dopants, e.g., Scandium, e.g., Magnesium, e.g., Oxygen, e.g., Silicon.

FIGS. 4A through 4G show alternative example bulk acoustic wave resonators to the example bulk acoustic wave resonator structures shown in FIG. 1A.

FIG. 5 shows a schematic of an example ladder filter using three series resonators of the bulk acoustic wave resonator structure of FIG. 1A, and two mass loaded shunt resonators of the bulk acoustic wave resonator structure of FIG. 1A, along with a simplified view of the three series resonators.

FIG. 6A shows a schematic of an example ladder filter using five series resonators of the bulk acoustic wave resonator structure of FIG. 1A, and five mass loaded shunt resonators of the bulk acoustic wave resonator structure of FIG. 1A, along with a simplified top view of the ten resonators interconnected in the example ladder filter, along with input and output coupled integrated inductors, and lateral dimensions of the example ladder filter.

FIG. 6B shows four charts with results as expected from simulation along with corresponding simplified example cascade arrangements of resonators similar to the bulk acoustic wave resonator structure of FIG. 1A.

FIG. 6C shows four alternative example integrated inductors along with three corresponding inductance charts showing versus number of turns, showing versus inner diameter and showing versus outer diameter, with results as expected from simulation.

FIG. 7A shows an example millimeter acoustic wave transversal filter using bulk acoustic millimeter wave resonator structures similar to those shown in FIG. 1A.

FIG. 7B shows an example oscillator using bulk acoustic wave resonator similar to the bulk acoustic wave resonator structure of FIG. 1A.

FIG. 8A shows simplified views of an additional six bulk acoustic wave resonators.

FIG. 8B shows simplified views of another additional six bulk acoustic wave resonators.

FIG. 8C shows simplified views of an additional pair of bulk acoustic wave resonators, and along with Smith charts corresponding to respective members of the pair of bulk acoustic wave resonators showing Scattering-parameters (S-parameters) at various operating frequencies.

FIG. 8D shows simplified views of another additional pair of bulk acoustic wave resonators, and along with Smith charts corresponding to respective members of the pair of bulk acoustic wave resonators showing Scattering-parameters (S-parameters) at various operating frequencies.

FIG. 8E shows simplified views of yet another additional pair of bulk acoustic wave resonators, and along with Smith charts corresponding to respective members of the pair of bulk acoustic wave resonators showing Scattering-parameters (S-parameters) at various operating frequencies.

FIG. 8F shows an additional pair of bulk acoustic wave resonators, along with charts corresponding to respective members of the pair of bulk acoustic wave resonators showing quality factor averaged over two alternative frequency ranges versus ratio of peripheral feature overlap width to full active width, as expected from simulation.

FIG. 8G shows another additional pair of bulk acoustic wave resonators, along with charts corresponding to respective members of the pair of bulk acoustic wave resonators showing quality factor averaged over two alternative frequency ranges versus ratio of peripheral feature overlap width to full active width, as expected from simulation.

FIGS. 9A and 9B are simplified diagrams of a frequency spectrum illustrating application frequencies and application frequency bands of the example bulk acoustic wave resonators shown in FIG. 1A and FIGS. 4A through 4G, and the example filters shown in FIGS. 5 and 6A and 7A, and the example oscillator shown in FIG. 7B.

FIG. 10 illustrates a computing system implemented with integrated circuit structures or devices formed using the techniques disclosed herein, in accordance with an embodiment of the present disclosure.

FIG. 11A shows a top view of an antenna device of the present disclosure.

FIG. 11B shows a cross sectional view of the antenna device shown in FIG. 11A.

FIG. 11C shows a schematic of a millimeter wave transceiver employing millimeter wave filters and a millimeter wave oscillator respectively employing millimeter wave resonators of this disclosure.

### DETAILED DESCRIPTION

Non-limiting embodiments will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment shown where illustration is not necessary to allow understanding by those of ordinary skill in the art. In the specification, as well as in the claims, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively. Further, relative terms, such as “above,” “below,” “top,” “bottom,” “upper” and “lower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element. The term “compensating” is to be understood as including “substantially compensating”. The terms “oppose”, “opposes” and “opposing” are to be understood as including “substantially oppose”, “substantially opposes” and “substantially opposing” respectively. Further, as used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” or “about” means to within an acceptable limit or amount to one of ordinary skill in the art. For example, “approximately the same” means that one of ordinary skill in the art would consider the items being compared to be the same. As used in the specification and appended claims, the terms “a”, “an” and “the” include both singular and plural referents, unless the context clearly dictates otherwise. Thus, for example, “a device” includes one device and plural devices. As used herein, the International Telecommunication Union (ITU) defines Super High Frequency (SHF) as extending between three Gigahertz (3 GHz) and thirty Gigahertz (30 GHz). The ITU defines Extremely High Frequency (EHF) as extending between thirty Gigahertz (30 GHz) and three hundred Gigahertz (300 GHz). As defined herein, millimeter wave means a wave having a frequency within a range extending from eight Gigahertz (8 GHz) to three hundred Gigahertz (300 GHz), and millimeter wave band means a frequency band spanning this millimeter wave frequency range from eight Gigahertz (8 GHz) to three hundred Gigahertz (300 GHz). Similarly, as defined herein, bulk acoustic millimeter wave resonator (or more generally, an acoustic millimeter wave device) means a bulk acoustic wave resonator (or more generally, an acoustic wave device) having a main resonant frequency (e.g., main series resonant frequency) within a range extending from eight Gigahertz (8 GHz) to three hundred Gigahertz (300 GHz). As defined herein, millimeter acoustic wave filter means a filter comprising a bulk acoustic wave resonator (or more generally, comprising an acoustic wave device) having a main resonant frequency (e.g., main series resonant frequency) within a range extending from eight Gigahertz (8 GHz) to three hundred Gigahertz (300 GHz).

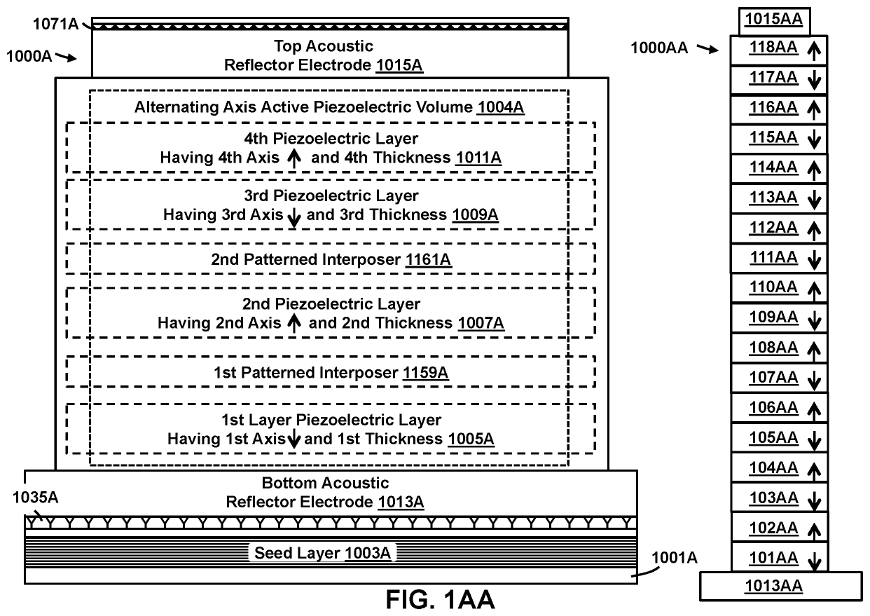

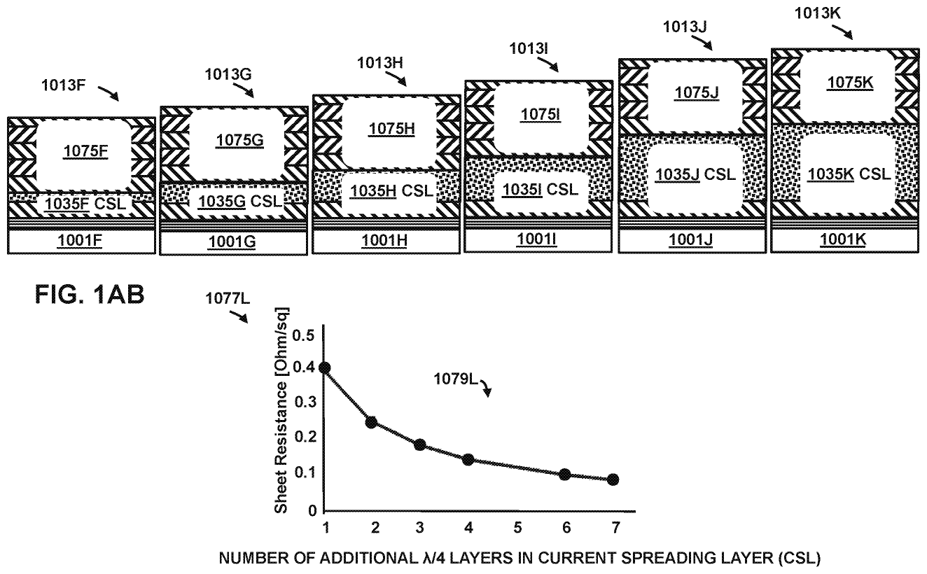

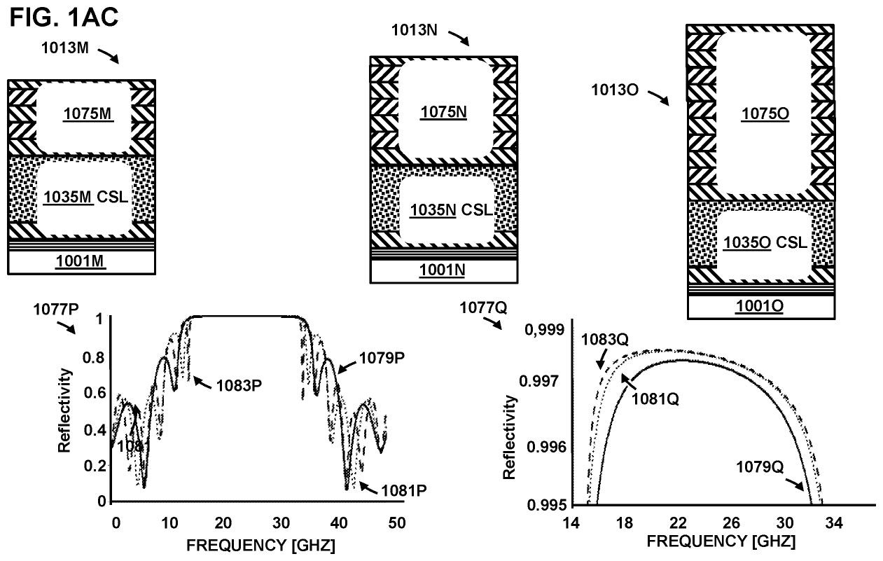

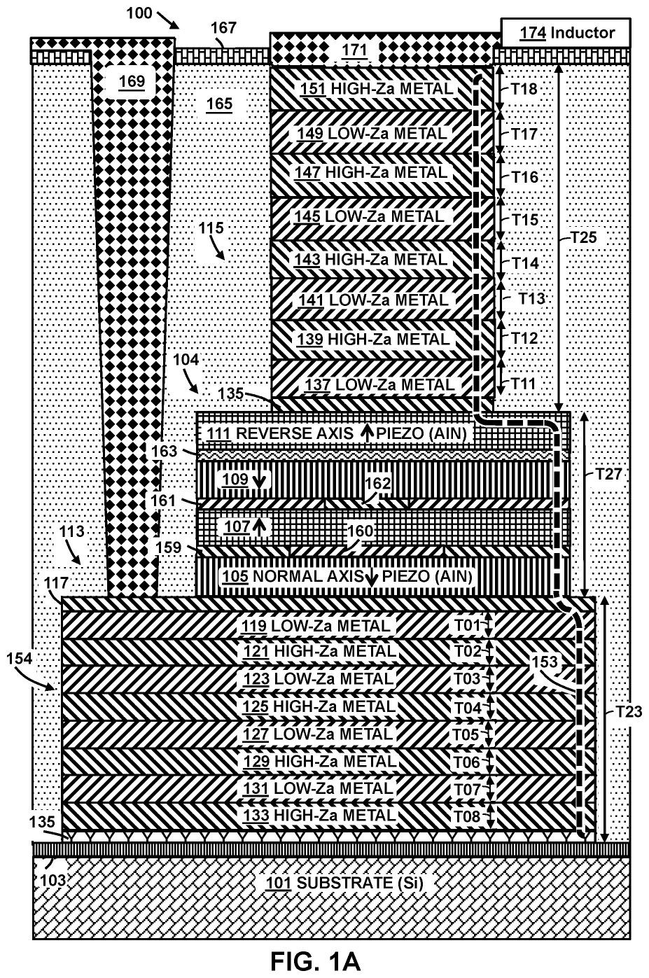

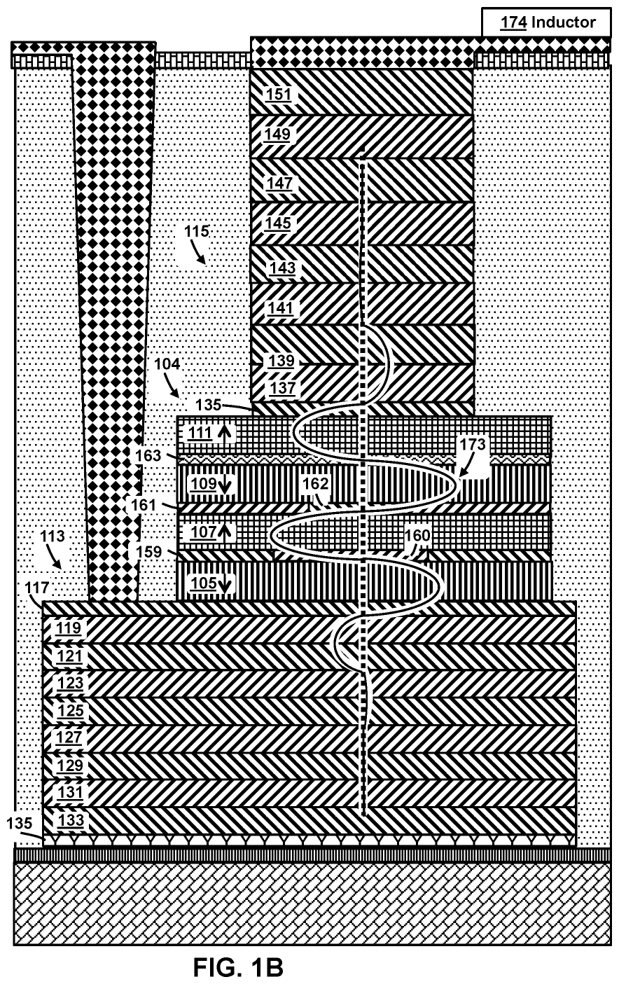

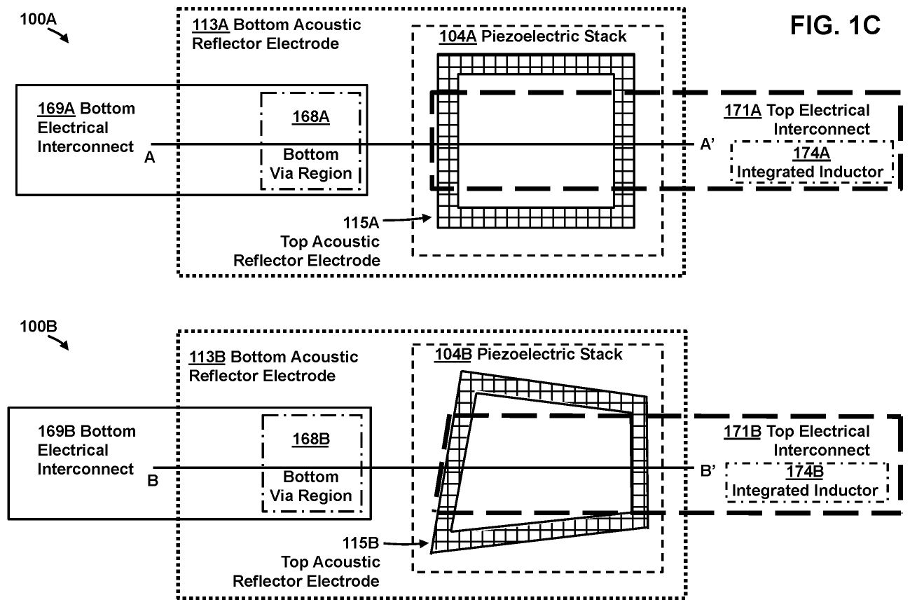

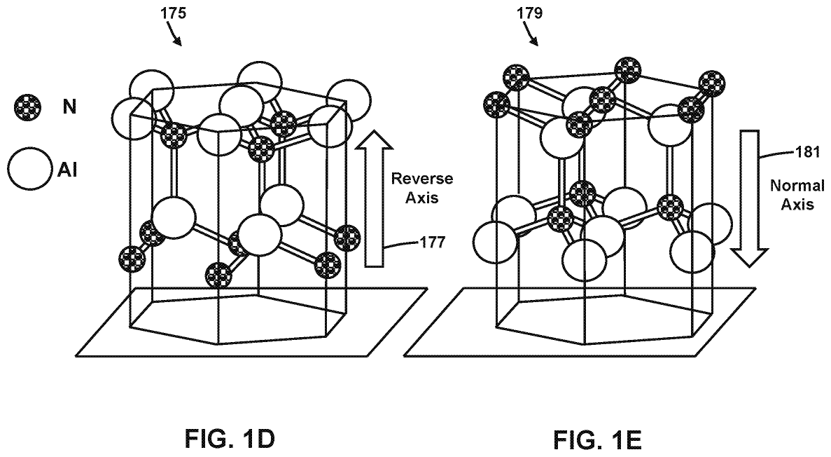

FIG. 1AA shows simplified diagrams of two bulk acoustic wave resonator structures 1000A, 1000AA of this disclosure. A first bulk acoustic wave resonator structure 1000A may comprise a piezoelectric resonant volume, e.g., having a plurality of piezoelectric layers, e.g., in which the plurality of piezoelectric layers have respective piezoelectric axes, e.g., in which piezoelectric resonant volumes have respective alternating piezoelectric axes arrangements.

For example, bulk acoustic wave resonator structure 1000A may comprise a piezoelectric resonant volume of an example four layers of piezoelectric material, for example, four layers comprising Aluminum Nitride (AlN) having a wurtzite structure. For example, the piezoelectric resonant volumes may comprise a first piezoelectric layer 1005A (e.g., bottom piezoelectric layer 1005A), a second piezoelectric layer 1007A (e.g., first middle piezoelectric layer 1007A), a third piezoelectric layer 1009A (e.g., second middle piezoelectric layer 1009A), and fourth piezoelectric layer 1011A (e.g. top piezoelectric layer 1011A). The example piezoelectric layers, e.g., example four piezoelectric layers, may be acoustically coupled with one another, for example, in a piezoelectrically excitable resonant mode.

The example four piezoelectric layers of the piezoelectric resonant volumes may have an alternating axis arrangement piezoelectric resonant volume. For example the first piezoelectric layer 1005A (e.g., bottom piezoelectric layer 1005A) may have a first piezoelectric axis orientation (e.g., a normal piezoelectric axis orientation, e.g., representatively illustrated using a downward pointing arrow), as discussed in greater detail subsequently herein. Next in the alternating axis arrangement of the piezoelectric resonant volume, the second piezoelectric layer 1007A (e.g., first middle piezoelectric layer 1007A) may have a second piezoelectric axis orientation (e.g., reverse piezoelectric axis orientation, e.g., representatively illustrated using an upward pointing arrow). Next in the alternating axis arrangement of the piezoelectric resonant volumes, the third piezoelectric layer 1009A (e.g., second middle piezoelectric layer 1009A) may have a third piezoelectric axis orientation (e.g., normal piezoelectric axis orientation, e.g., representatively illustrated using the downward pointing arrow). Next in the alternating axis arrangement of the piezoelectric resonant volume, the fourth piezoelectric layer 1011A (e.g. top piezoelectric layer 1011A) may have a fourth piezoelectric axis orientation (e.g., reverse piezoelectric axis orientation, e.g., representatively illustrated using the upward pointing arrow).

In the alternating axis arrangement in the piezoelectric resonant volumes, respective piezoelectric axes of adjacent piezoelectric layers may substantially oppose one another (e.g., may be antiparallel, e.g., may be substantially antiparallel).

For example, first piezoelectric axis orientation (e.g., a normal piezoelectric axis orientation) of the first piezoelectric layer 1005A (e.g., bottom piezoelectric layer 1005A) may substantially oppose the second piezoelectric axis orientation (e.g., reverse piezoelectric axis orientation) of the second piezoelectric layer 1007A (e.g., first middle piezoelectric layer 1007A). For example, first piezoelectric axis orientation (e.g., a normal piezoelectric axis orientation) of the first piezoelectric layer 1005A (e.g., bottom piezoelectric layer 1005A) may substantially oppose the fourth piezoelectric axis orientation (e.g., reverse piezoelectric axis orientation) of the fourth piezoelectric layer 1011A (e.g., top piezoelectric layer 1011A). For example, the second piezoelectric axis orientation (e.g., reverse piezoelectric axis orientation) of the second piezoelectric layer 1007A (e.g., first middle piezoelectric layer 1007A) may substantially oppose the third piezoelectric axis orientation (e.g., a normal piezoelectric axis orientation) of the third piezoelectric layer 1005A (e.g., second middle piezoelectric layer 1005A). For example, the third piezoelectric axis orientation (e.g., a normal piezoelectric axis orientation) of the third piezoelectric layer 1005A (e.g., second middle piezoelectric layer 1005A may substantially oppose the fourth piezoelectric axis orientation (e.g., reverse piezoelectric axis orientation) of the fourth piezoelectric layer 1011A (e.g., top piezoelectric layer 1011A).

The piezoelectric layers of the example piezoelectric resonant volume may have respective layer thicknesses, e.g., the first piezoelectric layer 1005A (e.g., bottom piezoelectric layer 1005A) may have a first piezoelectric layer thickness have (e.g., bottom piezoelectric layer thickness), e.g., second piezoelectric layer 1007A (e.g., first middle piezoelectric layer 1007A) may have a second layer thickness (e.g., first middle piezoelectric layer thickness), e.g., third piezoelectric layer 1009A (e.g., second middle piezoelectric layer 1009A) may have a third layer thickness (e.g., second middle piezoelectric layer thickness), e.g., fourth piezoelectric layer 1011A (e.g. top piezoelectric layer 1011A) may have a fourth layer thickness (e.g., top piezoelectric layer thickness). The piezoelectric resonant volume may have a main resonant frequency. Respective first, second, third and fourth layer thicknesses (e.g., respective bottom piezoelectric layer thickness, first middle piezoelectric layer thickness, second middle piezoelectric layer thickness and top piezoelectric layer thickness) may be about a half acoustic wavelength of the main resonant frequency of the piezoelectric resonant volume. More generally, respective first, second, third and fourth layer thicknesses (e.g., respective bottom piezoelectric layer thickness, first middle piezoelectric layer thickness, second middle piezoelectric layer thickness and top piezoelectric layer thickness) may be about an integral multiple of the half acoustic wavelength of the main resonant frequency of the he piezoelectric resonant volume.

For the bulk acoustic wave resonator 1000A, respective first, second, third and fourth piezoelectric layer thicknesses (e.g., respective bottom piezoelectric layer thickness, first middle piezoelectric layer thickness, second middle piezoelectric layer thickness and top piezoelectric layer thickness) may facilitate the main resonant frequency (e.g., the main resonant frequency of the resonant piezoelectric volume, e.g., the main resonant frequency of the alternating axis active piezoelectric volume 1004A, e.g., the main resonant frequency of the bulk acoustic wave resonator 1000A). An example twenty-four GigaHertz (24 GHz) design comprising four piezoelectric layers is discussed in greater detail subsequently herein. However, bulk acoustic wave resonators of this disclosure are not limited to the example twenty-four GigaHertz (24 GHz) design. In the examples of this disclosure, piezoelectric layer thickness may be scaled up or down to facilitate (e.g., determine) main resonant frequency.

Further, for the bulk acoustic wave resonator 1000A having the alternating axis stack of four piezoelectric layers, simulation of the 24 GHz design predicts an average passband quality factor of approximately 1600. Scaling this 24 GHz, four piezoelectric layer design to a 37 GHz, four piezoelectric layer design, may have an average passband quality factor of approximately 1200 as predicted by simulation. Scaling this 24 GHz, four piezoelectric layer design to a 77 GHz, four piezoelectric layer design, may have an average passband quality factor of approximately 700 as predicted by simulation.

The piezoelectric resonant volume comprising the example four layers of piezoelectric material 1005A, 1007A, 1009A, 1011A may be sandwiched between bottom acoustic reflector electrode 1013A and top acoustic reflector electrode 1015A. For example, the bottom acoustic reflector electrode 1013A may be electrically and acoustically coupled with the piezoelectric resonant volume (e.g., with the four layers of piezoelectric material 1005A, 1007A, 1009A, 1011A) to excite the piezoelectrically excitable main resonant mode at the main resonant frequency of the bulk acoustic wave resonator 1000A. For example, the top acoustic reflector electrode 1015A may be electrically and acoustically coupled with the piezoelectric resonant volume (e.g., with the four layers of piezoelectric material 1005A, 1007A, 1009A, 1011A) to excite the piezoelectrically excitable main resonant mode at the main resonant frequency of the bulk acoustic wave resonator 1000A. Bottom acoustic reflector electrode 1013A may be arranged over respective seed layers 1003A. Seed layer 1003A (e.g. Aluminum Nitride seed layer) may be interposed between bottom acoustic reflector electrode 1013A and a substrate 1001A (e.g., silicon substrate 1001A). Top acoustic reflector electrode 1015A may comprise a plurality of top metal acoustic reflector electrode layers. This may approximate a top distributed Bragg acoustic reflector. Accordingly the plurality of top metal acoustic reflector electrode layers may have respective thicknesses of approximately a quarter wavelength of the main resonant frequency of the resonant piezoelectric volume. The plurality of top metal acoustic reflector electrode layers may comprise an alternating acoustic impedance arrangement of high acoustic impedance metal layers (e.g., Tungsten (W) layers) and low acoustic impedance metal layers (e.g., Titanium (Ti) layers).

Similarly, bottom acoustic reflector electrode 1013A may comprise a plurality of bottom metal acoustic reflector electrode layers. This may approximate a bottom distributed Bragg acoustic reflector. Accordingly the plurality of bottom metal acoustic reflector electrode layers may have respective thicknesses of approximately the quarter wavelength of the main resonant frequency of the resonant piezoelectric volume. The plurality of bottom metal acoustic reflector electrode layers may comprise the alternating acoustic impedance arrangement of high acoustic impedance metal layers (e.g., Tungsten (W) layers) and low acoustic impedance metal layers (e.g., Titanium (Ti) layers).

Bottom acoustic reflector electrode 1013A may comprise a bottom current spreading layer 1035A. Top acoustic reflector electrode 1015A may comprise a top current spreading layers 1071A. Current spreading layer(s) of this disclosure may comprise aluminum. Current spreading layer(s) of this disclosure may comprise tungsten. Current spreading layers of this disclosure may comprise molybdenum. Current spreading layer(s) of this disclosure may comprise gold. Current spreading layer(s) of this disclosure may comprise silver. Current spreading layer(s) of this disclosure may comprise copper. Current spreading layer(s) of this disclosure may comprise a Back End Of Line (BEOL) metal. Current spreading layer(s) of this disclosure may comprise a Front End Of Line (FEOL) metal.

It is the teaching of this disclosure that acoustic absorption in current spreading layers may be significantly higher than in materials that may be used in metal acoustic reflector electrode layers (e.g., Molybdenum (Mo), e.g., Tungsten (W), e.g., Ruthenium (Ru), e.g., Titanium (Ti)), which may be arranged proximate to the alternating axis piezoelectric volume. Accordingly, metal acoustic reflector electrode layers (e.g., top metal acoustic reflector electrode layers, e.g., bottom metal acoustic reflector electrode layers) may be interposed between current spreading layers (e.g., bottom currently spreading layer 1035A, e.g., top current spreading layer 1071A) and the alternating axis piezoelectric volume. This may facilitate substantial acoustic isolation of the current spreading layers (e.g., bottom currently spreading layer 1035A, e.g., top current spreading layer 1071A) from the alternating axis piezoelectric volume.

As already mentioned previously herein, the piezoelectric resonant volume of bulk acoustic wave resonator 1000A may comprise the example four layers of piezoelectric material 1005A, 1007A, 1009A, 1011A. Bottom acoustic reflector electrode 1013A and top acoustic reflector electrode 1015A may have respective lateral extents. For example, as shown in FIG. 1AA, the lateral extent of bottom acoustic reflector electrode 1013A may be greater than the lateral extent of top acoustic reflector electrode 1015A. The piezoelectric resonant volume of bulk acoustic wave resonator 1000A may be sandwiched between the lateral extent of bottom acoustic reflector electrode 1013A and top acoustic reflector electrode 1015A.

The stack of four piezoelectric material layers 1005A, 1007A, 1009A, 1011A may have an active region 1004A (e.g., alternating axis active piezoelectric volume 1004A) where the lateral extent of the top acoustic reflector electrode may overlap the lateral extent of the bottom acoustic reflector electrode. For example, in operation of bulk acoustic wave resonator 1000A, an oscillating electric field may be applied via top acoustic reflector electrode 1015A and bottom acoustic reflector electrodes 1013A so as to activate responsive piezoelectric acoustic oscillations (e.g., a main resonant mode) in the active region 1004A (e.g., alternating axis active piezoelectric volume 1004A) of the stack of four piezoelectric material layers 1005A, 1007A, 1009A, 1011A, where the lateral extent of the top acoustic reflector electrode may overlap the lateral extent of the bottom acoustic reflector electrode. In other words, where the lateral extent of the top acoustic reflector electrode 1015A overlaps the lateral extent of the bottom acoustic reflector 1013A may define the alternating axis active piezoelectric volume 1004A (e.g., active region 1004A).

A first patterned interposer 1159A (e.g., a first patterned layer 1159A, e.g., a first patterned interposer layer 1159A) may be disposed within the active piezoelectric volume 1004A (e.g., may be disposed with the alternating axis active piezoelectric volume 1004A). This may, but need not facilitate suppression of spurious modes. The first patterned layer 1159A (e.g., first patterned interposer 1159A) may comprise a step mass feature. The active piezoelectric volume 1004A (e.g., the alternating axis active piezoelectric volume 1004A) may have a lateral perimeter. The step mass feature of the first patterned layer 1159A (e.g., of first patterned interposer 1159A) may be proximate to the lateral perimeter of the active piezoelectric volume. For example, a first mesa structure having a lateral perimeter may comprise the four piezoelectric layers 1005A, 1007A, 1009A, 1011A having respective piezoelectric axis that substantially oppose one another. The step mass feature of the first patterned layer 1159A (e.g., first patterned interposer 1159A) may be proximate to the lateral perimeter of the first mesa structure. The active piezoelectric volume 1004A (e.g., the alternating axis active piezoelectric volume 1004A) may be interposed between the top and bottom acoustic reflector electrodes 1015A, 1013A. A second mesa structure may comprise the bottom acoustic reflector electrode 1013A. A third mesa structure may comprise the top acoustic reflector electrode 1015A.

The first patterned layer 1159A (e.g., the first patterned interposer 1159A, e.g., the first patterned interposer layer 1159A) may comprise a first step mass feature having a first acoustic impedance. The first patterned layer 1159A (e.g., the first patterned interposer 1159A, e.g., the first patterned interposer layer 1159A) may further comprise a second step mass feature having a second acoustic impedance. The first acoustic impedance may be different than the second acoustic impedance. More generally, the first patterned layer 1159A (e.g., the first patterned interposer 1159A, e.g., the first patterned interposer layer 1159A) may comprise first and second materials that may be different from one another (e.g., first and second materials having respective acoustic impedances that may be different from one another). For example, the first patterned layer 1159A (e.g., the first patterned interposer 1159A, e.g., the first patterned interposer layer 1159A) may comprise dielectric. For example, the first patterned layer 1159A (e.g., the first patterned interposer 1159A, e.g., the first patterned interposer layer 1159A) may comprise first and second dielectrics that may be different from one another (e.g., first and second dielectrics having respective acoustic impedances that may be different from one another). The first patterned layer 1159A (e.g., the first patterned interposer 1159A, e.g., the first patterned interposer layer 1159A) may comprise semiconductor. For example, the first patterned layer 1159A (e.g., the first patterned interposer 1159A, e.g., the first patterned interposer layer 1159A) may comprise first and second semiconductors that may be different from one another (e.g., first and second semiconductors having respective acoustic impedances that may be different from one another). The first patterned layer 1159A (e.g., the first patterned interposer 1159A, e.g., the first patterned interposer layer 1159A) may comprise metal. For example, the first patterned layer 1159A (e.g., the first patterned interposer 1159A, e.g., the first patterned interposer layer 1159A) may comprise first and second metals that may be different from one another (e.g., first and second metals having respective acoustic impedances that may be different from one another).

The first patterned layer 1159A (e.g., the first patterned interposer 1159A, e.g., the first patterned interposer layer 1159A) may comprise combinations of the foregoing. The first patterned layer 1159A (e.g., the first patterned interposer 1159A, e.g., the first patterned interposer layer 1159A) may comprise a first metal and a first dielectric. The first patterned layer 1159A (e.g., the first patterned interposer 1159A, e.g., the first patterned interposer layer 1159A) may comprise a first metal and a first semiconductor. The first patterned layer 1159A (e.g., the first patterned interposer 1159A, e.g., the first patterned interposer layer 1159A) may comprise a first semiconductor and a first dielectric.

The first patterned layer 1159A (e.g., the first patterned interposer 1159A, e.g., the first patterned interposer layer 1159A) may comprise a first central feature having a first central acoustic impedance. The first patterned layer 1159A (e.g., the first patterned interposer 1159A, e.g., the first patterned interposer layer 1159A) may further comprise a first peripheral feature having a first peripheral acoustic impedance that is greater than first central acoustic impedance. The first peripheral feature having the first peripheral acoustic impedance that is greater than first central acoustic impedance of the first central feature may, but need not facilitate a quality factor enhancement of the bulk acoustic wave resonator 1000A.

The first patterned layer 1159A (e.g., the first patterned interposer 1159A, e.g., the first patterned interposer layer 1159A) may comprise a first peripheral feature having a first peripheral acoustic impedance. The first patterned layer 1159A (e.g., the first patterned interposer 1159A, e.g., the first patterned interposer layer 1159A) may further comprise a first central feature having a first central acoustic impedance that is greater than first peripheral acoustic impedance. The first central feature having the first central acoustic impedance that is greater than first peripheral acoustic impedance of the first peripheral feature may, but need not facilitate a quality factor enhancement of the bulk acoustic wave resonator 1000A.

The first patterned layer 1159A (e.g., the first patterned interposer 1159A, e.g., the first patterned interposer layer 1159A) may comprise a first central feature, and may further comprise a first peripheral feature having a first width dimension. The first width dimension of the first peripheral feature may be within a range from approximately a tenth of a percent of a width of the active piezoelectric volume to approximately ten percent of a width of the active piezoelectric volume. The first width dimension of the first peripheral feature being within a range from approximately a tenth of a percent of a width of the active piezoelectric volume to approximately ten percent of a width of the active piezoelectric volume may, but need not facilitate a quality factor enhancement of the bulk acoustic wave resonator 1000A

The first patterned layer 1159A (e.g., the first patterned interposer 1159A, e.g., the first patterned interposer layer 1159A) may comprise a first peripheral feature, and may further comprise a first central feature having a first width dimension. The first width dimension of the first central feature may be within a range from approximately ninety percent of a width of the active piezoelectric volume to approximately ninety-nine and nine tenths percent of a width of the active piezoelectric volume. The first width dimension of the first central feature being within a range from approximately ninety percent of a width of the active piezoelectric volume to approximately ninety-nine and nine tenths percent of a width of the active piezoelectric volume may, but need not facilitate a quality factor enhancement of the bulk acoustic wave resonator 1000A.

The first patterned layer 1159A (e.g., the first patterned interposer 1159A, e.g., the first patterned interposer layer 1159A) may be substantially planar. The bulk acoustic wave resonator 1000A may further comprise a second patterned layer 1161A (e.g., second patterned interposer 1161A, e.g., second patterned interposer layer 1161A). The second patterned layer 1161A (e.g., second patterned interposer 1161A, e.g., second patterned interposer layer 1161A) may be substantially planar. The second patterned layer 1161A (e.g., second patterned interposer 1161A, e.g., second patterned interposer layer 1161A) may be disposed within the active piezoelectric volume. This may, but need not facilitate the suppression of spurious modes.

As shown in FIG. 1AA, the first patterned layer 1159A (e.g., the first patterned interposer 1159A, e.g., the first patterned interposer layer 1159A) may be interposed between the first piezoelectric layer 1005A (e.g., bottom piezoelectric layer 1005A, e.g., having the normal piezoelectric axis orientation) and the second piezoelectric layer 1007A (e.g., first middle piezoelectric layer 1007A, e.g., having reverse piezoelectric axis orientation). Similarly, the second patterned layer 1161A (e.g., second patterned interposer 1161A, e.g., second patterned interposer layer 1161A) may be interposed between the second piezoelectric layer 1007A (e.g., first middle piezoelectric layer 1007A, e.g., having reverse piezoelectric axis orientation) and the third piezoelectric layer 1009A (e.g., second middle piezoelectric layer 1009A, e.g., having the normal piezoelectric axis orientation).

The second patterned layer 1161A (e.g., second patterned interposer 1161A, e.g., second patterned interposer layer 1161A) may comprise a third step mass feature having a third acoustic impedance. The second patterned layer 1161A (e.g., second patterned interposer 1161A, e.g., second patterned interposer layer 1161A) may further comprise a fourth step mass feature having a fourth acoustic impedance. The third acoustic impedance may be different than the fourth acoustic impedance. More generally, the second patterned layer 1161A (e.g., second patterned interposer 1161A, e.g., second patterned interposer layer 1161A) may comprise third and fourth materials that may be different from one another (e.g., third and fourth materials having respective acoustic impedances that may be different from one another). For example, the second patterned layer 1161A (e.g., second patterned interposer 1161A, e.g., second patterned interposer layer 1161A) may comprise dielectric. For example, the second patterned layer 1161A (e.g., second patterned interposer 1161A, e.g., second patterned interposer layer 1161A) may comprise third and fourth dielectrics that may be different from one another (e.g., third and fourth dielectrics having respective acoustic impedances that may be different from one another). The second patterned layer 1161A (e.g., second patterned interposer 1161A, e.g., second patterned interposer layer 1161A) may comprise semiconductor. For example, the second patterned layer 1161A (e.g., second patterned interposer 1161A, e.g., second patterned interposer layer 1161A) may comprise third and fourth semiconductors that may be different from one another (e.g., third and fourth semiconductors having respective acoustic impedances that may be different from one another). The second patterned layer 1161A (e.g., second patterned interposer 1161A, e.g., second patterned interposer layer 1161A) may comprise metal. For example, the second patterned layer 1161A (e.g., second patterned interposer 1161A, e.g., second patterned interposer layer 1161A) may comprise third and fourth metals that may be different from one another (e.g., third and fourth metals having respective acoustic impedances that may be different from one another).

The second patterned layer 1161A (e.g., second patterned interposer 1161A, e.g., second patterned interposer layer 1161A) may comprise combinations of the foregoing. The second patterned layer 1161A (e.g., second patterned interposer 1161A, e.g., second patterned interposer layer 1161A) may comprise a second metal and a second dielectric. The second patterned layer 1161A (e.g., second patterned interposer 1161A, e.g., second patterned interposer layer 1161A) may comprise a second metal and a second semiconductor. The second patterned layer 1161A (e.g., second patterned interposer 1161A, e.g., second patterned interposer layer 1161A) may comprise a second semiconductor and a second dielectric.

The second patterned layer 1161A (e.g., second patterned interposer 1161A, e.g., second patterned interposer layer 1161A) may comprise a second central feature having a second central acoustic impedance. The second patterned layer 1161A (e.g., second patterned interposer 1161A, e.g., second patterned interposer layer 1161A) may further comprise a second peripheral feature having a second peripheral acoustic impedance that is greater than second central acoustic impedance.

The second peripheral feature having the second peripheral acoustic impedance that is greater than second central acoustic impedance of the second central feature may, but need not facilitate a quality factor enhancement of the bulk acoustic wave resonator 1000A.

The second patterned layer 1161A (e.g., second patterned interposer 1161A, e.g., second patterned interposer layer 1161A) may comprise a second peripheral feature having a second peripheral acoustic impedance. The second patterned layer 1161A (e.g., second patterned interposer 1161A, e.g., second patterned interposer layer 1161A) may further comprise a second central feature having a second central acoustic impedance that is greater than second peripheral acoustic impedance. The second central feature having the second central acoustic impedance that is greater than second peripheral acoustic impedance of the second peripheral feature may, but need not facilitate a quality factor enhancement of the bulk acoustic wave resonator 1000A.

The second patterned layer 1161A (e.g., second patterned interposer 1161A, e.g., second patterned interposer layer 1161A) may comprise a second central feature, and may further comprise a second peripheral feature having a second width dimension. The second width dimension of the second peripheral feature may be within a range from approximately a tenth of a percent of a second width of the active piezoelectric volume to approximately ten percent of a width of the active piezoelectric volume. The second width dimension of the second peripheral feature being within a range from approximately a tenth of a percent of a width of the active piezoelectric volume to approximately ten percent of a width of the active piezoelectric volume may, but need not facilitate a quality factor enhancement of the bulk acoustic wave resonator 1000A

The second patterned layer 1161A (e.g., second patterned interposer 1161A, e.g., second patterned interposer layer 1161A) may comprise a second peripheral feature, and may further comprise a second central feature having a second width dimension. The second width dimension of the second central feature may be within a range from approximately ninety percent of a width of the active piezoelectric volume to approximately ninety-nine and nine tenths percent of a width of the active piezoelectric volume. The second width dimension of the second central feature being within a range from approximately ninety percent of a width of the active piezoelectric volume to approximately ninety-nine and nine tenths percent of a width of the active piezoelectric volume may, but need not facilitate a quality factor enhancement of the bulk acoustic wave resonator 1000A.

FIG. 1AA also shows a greatly simplified view of bulk acoustic wave resonator structure 1000AA. Bulk acoustic wave resonator structure 1000AA of FIG. 1AA may be similar in many ways to bulk acoustic wave resonator structure 1000A of FIG. 1AA, just discussed. However, bulk acoustic wave resonator structure 1000AA of FIG. 1AA may have many more layers than what is explicitly shown bulk acoustic wave resonator structure 1000A of FIG. 1AA. For example, bulk acoustic wave resonator structure 1000A may comprise four piezoelectric layers 1005A, 1007A, 1009A, 1011A having respective piezoelectric axes orientations in an alternating arrangement sandwiched between bottom acoustic reflector electrode 1013A and top acoustic reflector electrode 1015A. In contrast, bulk acoustic wave resonator structure 1000A may comprise eighteen piezoelectric layers (e.g., nine normal axis piezoelectric layers 101AA, 103AA, 105AA, 107AA, 109AA, 111AA, 113AA, 115AA, 117AA, e.g., nine reverse axis piezoelectric layers 102AA, 104AA, 106AA, 108AA, 110AA, 112AA, 114AA, 116AA, 118AA) having respective piezoelectric axes orientations in an alternating arrangement sandwiched between bottom acoustic reflector electrode 1013AA and top acoustic reflector electrode 1015AA.

Although bottom acoustic reflector electrode 1013AA and top acoustic reflector electrode 1015AA may be similarly structured to bottom acoustic reflector electrode 1013A and top acoustic reflector electrode 1015A discussed in detail previously herein, specific details of bottom acoustic reflector electrode 1013AA and top acoustic reflector electrode 1015AA are not shown in detail in the greatly simplified view of bulk acoustic wave resonator 1000AA shown in FIG. 1AA. For example, bottom acoustic reflector electrode 1013AA may comprise a bottom current spreading layer (not shown) arranged between bottom acoustic reflector electrode layers and a seed layer (not shown) and arranged over substrate (e.g., silicon substrate, not shown). For example, top acoustic reflector electrode 1015AA may comprise a top current spreading layer (not shown).

As already mentioned, bulk acoustic wave resonator structure 1000AA of FIG. 1AA may have many more layers than what is shown bulk acoustic wave resonator structure 1000A of FIG. 1A. For example, bulk acoustic wave resonator structure 1000A may comprise first patterned layer 1159A (e.g., the first patterned interposer 1159A, e.g., the first patterned interposer layer 1159A) may be interposed between the first piezoelectric layer 1005A (e.g., bottom piezoelectric layer 1005A, e.g., having the normal piezoelectric axis orientation) and the second piezoelectric layer 1007A (e.g., first middle piezoelectric layer 1007A, e.g., having reverse piezoelectric axis orientation). Similarly, the second patterned layer 1161A (e.g., second patterned interposer 1161A, e.g., second patterned interposer layer 1161A) may be interposed between the second piezoelectric layer 1007A (e.g., first middle piezoelectric layer 1007A, e.g., having reverse piezoelectric axis orientation) and the third piezoelectric layer 1009A (e.g., second middle piezoelectric layer 1009A, e.g., having the normal piezoelectric axis orientation).

In contrast, bulk acoustic wave resonator structure 1000AA may have seventeen patterned layers (not shown) e.g. seventeen patterned interposers, e.g., seventeen patterned interposer layers. First patterned layer (not shown) e.g., first patterned interposer, e.g., first patterned interposer layer, may be interposed between the first piezoelectric layer 101AA (e.g., having the normal piezoelectric axis orientation) and the second piezoelectric layer 102AA (e.g., having reverse piezoelectric axis orientation). Second patterned layer (not shown) e.g., second patterned interposer, e.g., second patterned interposer layer may be interposed between the second piezoelectric layer 102AA (e.g., having reverse piezoelectric axis orientation) and third piezoelectric layer 103AA (e.g., having the normal piezoelectric axis orientation). Third patterned layer (not shown) e.g., third patterned interposer, e.g., third patterned interposer layer, may be interposed between the third piezoelectric layer 103AA (e.g., having the normal piezoelectric axis orientation) and the fourth piezoelectric layer 104AA (e.g., having reverse piezoelectric axis orientation). Fourth patterned layer (not shown) e.g., fourth patterned interposer, e.g., fourth patterned interposer layer may be interposed between the fourth piezoelectric layer 104AA (e.g., having reverse piezoelectric axis orientation) and fifth piezoelectric layer 105AA (e.g., having the normal piezoelectric axis orientation). Fifth patterned layer (not shown) e.g., fifth patterned interposer, e.g., fifth patterned interposer layer, may be interposed between the fifth piezoelectric layer 105AA (e.g., having the normal piezoelectric axis orientation) and the sixth piezoelectric layer 106AA (e.g., having reverse piezoelectric axis orientation). Sixth patterned layer (not shown) e.g., sixth patterned interposer, e.g., sixth patterned interposer layer may be interposed between the sixth piezoelectric layer 106AA (e.g., having reverse piezoelectric axis orientation) and seventh piezoelectric layer 105AA (e.g., having the normal piezoelectric axis orientation). Seventh patterned layer (not shown) e.g., seventh patterned interposer, e.g., seventh patterned interposer layer, may be interposed between the seventh piezoelectric layer 107AA (e.g., having the normal piezoelectric axis orientation) and the eighth piezoelectric layer 108AA (e.g., having reverse piezoelectric axis orientation). Eighth patterned layer (not shown) e.g., eighth patterned interposer, e.g., eighth patterned interposer layer may be interposed between the eighth piezoelectric layer 108AA (e.g., having reverse piezoelectric axis orientation) and ninth piezoelectric layer 109AA (e.g., having the normal piezoelectric axis orientation). Ninth patterned layer (not shown) e.g., ninth patterned interposer, e.g., ninth patterned interposer layer, may be interposed between the ninth piezoelectric layer 109AA (e.g., having the normal piezoelectric axis orientation) and the tenth piezoelectric layer 110AA (e.g., having reverse piezoelectric axis orientation). Tenth patterned layer (not shown) e.g., tenth patterned interposer, e.g., tenth patterned interposer layer may be interposed between the tenth piezoelectric layer 110AA (e.g., having reverse piezoelectric axis orientation) and eleventh piezoelectric layer 111AA (e.g., having the normal piezoelectric axis orientation). Eleventh patterned layer (not shown) e.g., eleventh patterned interposer, e.g., eleventh patterned interposer layer, may be interposed between the eleventh piezoelectric layer 111AA (e.g., having the normal piezoelectric axis orientation) and the twelfth piezoelectric layer 112AA (e.g., having reverse piezoelectric axis orientation). Twelfth patterned layer (not shown) e.g., twelfth patterned interposer, e.g., twelfth patterned interposer layer may be interposed between the twelfth piezoelectric layer 112AA (e.g., having reverse piezoelectric axis orientation) and thirteenth piezoelectric layer 113AA (e.g., having the normal piezoelectric axis orientation). Thirteenth patterned layer (not shown) e.g., thirteenth patterned interposer, e.g., thirteenth patterned interposer layer, may be interposed between the thirteenth piezoelectric layer 113AA (e.g., having the normal piezoelectric axis orientation) and the fourteenth piezoelectric layer 112AA (e.g., having reverse piezoelectric axis orientation). Fourteenth patterned layer (not shown) e.g., fourteenth patterned interposer, e.g., fourteenth patterned interposer layer may be interposed between the fourteenth piezoelectric layer 114AA (e.g., having reverse piezoelectric axis orientation) and fifteenth piezoelectric layer 115AA (e.g., having the normal piezoelectric axis orientation). Fifteenth patterned layer (not shown) e.g., fifteenth patterned interposer, e.g., fifteenth patterned interposer layer, may be interposed between the fifteenth piezoelectric layer 115AA (e.g., having the normal piezoelectric axis orientation) and the sixteenth piezoelectric layer 116AA (e.g., having reverse piezoelectric axis orientation). Sixteenth patterned layer (not shown) e.g., sixteenth patterned interposer, e.g., sixteenth patterned interposer layer may be interposed between the sixteenth piezoelectric layer 116AA (e.g., having reverse piezoelectric axis orientation) and seventeenth piezoelectric layer 117AA (e.g., having the normal piezoelectric axis orientation). Seventeenth patterned layer (not shown) e.g., seventeenth patterned interposer, e.g., seventeenth patterned interposer layer, may be interposed between the seventeenth piezoelectric layer 117AA (e.g., having the normal piezoelectric axis orientation) and the eighteenth piezoelectric layer 118AA (e.g., having reverse piezoelectric axis orientation). In other examples, fewer than seventeen patterned layers, e.g., a subset of seventeen patterned layers may be present e.g., based on performance goals, e.g., based on tradeoffs with processing costs.

The seventeen patterned layers (not shown, but just discussed) e.g. seventeen patterned interposers, e.g., seventeen patterned interposer layers of bulk acoustic wave resonator structure 1000AA may be similarly structured, for example, as first patterned layer 1159A, for example, as second patterned layer 1161A, already discussed in detail previously herein, specific details of the seventeen patterned layers are not discussed in detail again here. For brevity and clarity, such discussions are referenced and incorporated rather than repeated in full.

For the bulk acoustic wave resonator 1000AA having the alternating axis stack of eighteen piezoelectric layers, simulation of the 24 GHz design predicts an average passband quality factor of approximately 2,700. Scaling this 24 GHz, eighteen piezoelectric layer design to a 37 GHz, eighteen piezoelectric layer design, may have an average passband quality factor of approximately 2000 as predicted by simulation. Scaling this 24 GHz, eighteen piezoelectric layer design to a 77 GHz, eighteen piezoelectric layer design, may have an average passband quality factor of approximately 1,130 as predicted by simulation.

FIG. 1AB shows six simplified diagrams of multilayer metal acoustic reflector electrodes 1013F through 1013K comprising five metal electrode layers in an alternating acoustic impedance arrangement 1075F through 1075K (e.g, three Tungsten metal electrode layers alternating with two Titanium layers) over current spreading layers (CSLs) 1035F through 1035K. Respective seed layers may be interposed between substrates 1001F through 1001K (e.g., silicon substrates 1001F through 1001K) and current spreading layers (CSLs) 1035F through 1035K. As discussed in detail subsequently herein, current spreading layers (CSLs) 1035F through 1035K may comprise a varying number of additional quarter wavelength current spreading layers for use in bulk acoustic wave resonator structures of this disclosure. FIG. 1AB also includes a chart 1077L showing sheet resistance corresponding to the varying number of additional quarter wavelength current spreading layers for the multilayer metal acoustic reflector electrodes 1013F through 1013K, with results as expected from simulation. The multilayer metal acoustic reflector electrodes 1013F through 1013K shown in FIG. 1AB may be employed in example millimeter acoustic wave resonators (e.g., 24 GigaHertz bulk acoustic wave resonators) of this disclosure, e.g., bulk acoustic wave resonators having main resonant frequencies in a millimeter wave band, e.g., bulk acoustic wave resonators having main resonant frequencies of about 24 GigaHertz. As a general matter, quarter wavelength layer thickness for layers may be understood as corresponding to quarter acoustic wavelength for the main resonant frequency of a given bulk acoustic wave resonator.

For example, a first bottom multilayer metal acoustic reflector electrode 1013F may comprise a first additional quarter wavelength current spreading layer in a first bottom current spreading layer 1035F. First bottom current spreading layer 1035F may be bilayer, for example, comprising a quarter wavelength thick layer of Aluminum (Al) over a quarter wavelength thick layer of Tungsten (W). For example, a second bottom multilayer metal acoustic reflector electrode 1013G may comprise two additional quarter wavelength current spreading layer in a second bottom current spreading layer 1035G. Second bottom current spreading layer 1035G may be bilayer, for example, comprising two quarter wavelength thick layer of Aluminum (Al) over a quarter wavelength thick layer of Tungsten (W). For example, a third bottom multilayer metal acoustic reflector electrode 1013H may comprise three additional quarter wavelength current spreading layer in a third bottom current spreading layer 1035H. Third bottom current spreading layer 1035H may be bilayer, for example, comprising three quarter wavelength thick layer of Aluminum (Al) over a quarter wavelength thick layer of Tungsten (W).

For example, a fourth bottom multilayer metal acoustic reflector electrode 1013I may comprise a fourth additional quarter wavelength current spreading layer in a fourth bottom current spreading layer 1035I. Fourth bottom current spreading layer 1035I may be bilayer, for example, comprising four-quarter wavelength thick layer of Aluminum (Al) over a quarter wavelength thick layer of Tungsten (W). For example, a fifth bottom multilayer metal acoustic reflector electrode 1013J may comprise a sixth additional quarter wavelength current spreading layer in a fifth bottom current spreading layer 1035J. Fifth bottom current spreading layer 1035G may be bilayer, for example, comprising six quarter wavelength thick layer of Aluminum (Al) over a quarter wavelength thick layer of Tungsten (W). For example, a sixth bottom multilayer metal acoustic reflector electrode 1013K may comprise a seventh additional quarter wavelength current spreading layer in a sixth bottom current spreading layer 1035K. Sixth bottom current spreading layer 1035K may be bilayer, for example, comprising seven quarter wavelength thick layer of Aluminum (Al) over a quarter wavelength thick layer of Tungsten (W). Incrementally increasing current spreading layer thickness from the first bottom current spreading layer 1035F to the sixth bottom current spreading layer 1035K may increase thickness, for example may increase current spreading layer thickness of one additional quarter wavelength thickness (e.g., in first bottom current spreading layer 1035F) to seven additional quarter wavelength thickness (e.g., sixth bottom current spreading layer 1035K). This increase in current spreading thickness may increase electrical conductivity, as reflected in decreasing sheet resistance as shown in chart 1077L.

Chart 1077L shows sheet resistance versus varying number of additional quarter wavelength current spreading layers 1079L for the multilayer metal acoustic reflector electrodes 1013F through 1013K, with results as expected from simulation. For example, as shown in chart 1077L, simulation predicts sheet resistance of approximately forty-two hundredths of an Ohm per square corresponding to the multilayer metal acoustic reflector electrode 1013F comprising one additional quarter wavelength (Lambda/4) layer in current spreading layer 1035F. For example, as shown in chart 1077L, simulation predicts sheet resistance of approximately twenty-seven hundredths of an Ohm per square corresponding to the multilayer metal acoustic reflector electrode 1013G comprising two additional quarter wavelength (Lambda/4) layers in current spreading layer 1035G. For example, as shown in chart 1077L, simulation predicts sheet resistance of approximately twenty hundredths of an Ohm per square corresponding to the multilayer metal acoustic reflector electrode 1013H comprising three additional quarter wavelength (Lambda/4) layers in current spreading layer 1035H. For example, as shown in chart 1077L, simulation predicts sheet resistance of approximately fifteen hundredths of an Ohm per square corresponding to the multilayer metal acoustic reflector electrode 1013I comprising four additional quarter wavelength (Lambda/4) layers in current spreading layer 1035I. For example, as shown in chart 1077L, simulation predicts sheet resistance of approximately eleven hundredths of an Ohm per square corresponding to the multilayer metal acoustic reflector electrode 1013J comprising six additional quarter wavelength (Lambda/4) layers in current spreading layer 1035J. For example, as shown in chart 1077L, simulation predicts sheet resistance of approximately nine hundredths of an Ohm per square corresponding to the multilayer metal acoustic reflector electrode 1013K comprising seven additional quarter wavelength (Lambda/4) layers in current spreading layer 1035K.

FIG. 1AC shows three simplified diagrams of multilayer metal acoustic reflector electrodes 1013M through 1013O comprising varying number of metal electrode layers in alternating acoustic impedance arrangements 1075M through 1075O. For example, multilayer metal acoustic reflector electrode 1013M comprises a first arrangement 1075M of a Tungsten metal electrode layer over two alternating pairs of Titanium and Tungsten layers. For example, multilayer metal acoustic reflector electrode 1013N comprises a second arrangement 1075N of a Tungsten metal electrode layer over three alternating pairs of Titanium and Tungsten layers. For example, multilayer metal acoustic reflector electrode 1013O comprises a third arrangement 1075O of a Tungsten metal electrode layer over five alternating pairs of Titanium and Tungsten layers. For example, current spreading layers (CSLs) 1035M through 1035O may be bilayer, for example, comprising six quarter wavelength thick layer of Aluminum (Al) over a quarter wavelength thick layer of Tungsten (W). Respective seed layers may be interposed between substrates 1001M through 1001O (e.g., silicon substrates 1001M through 1001O) and current spreading layers (CSLs) 1035M through 1035O.

Two corresponding charts 1077P, 1077Q show acoustic reflectivity versus acoustic frequency, with results as expected from simulation. Chart 1077P shows wideband acoustic reflectivity in a wideband scale ranging from zero to fifty GigaHertz. Chart 1077Q shows acoustic reflectivity in a scale ranging from fourteen to thirty-four GigaHertz. For example, as depicted in solid line and shown in traces 1079P, 1079Q, simulation predicts a peak reflectivity of about 0.99825 at a frequency of about 22.3 GigaHertz for multilayer metal acoustic reflector electrode 1013M comprising the first arrangement 1075M of the Tungsten metal electrode layer over two alternating pairs of Titanium and Tungsten layers, in which the first arrangement 1075M is over current spreading layer (CSL) 1035M. For example, as depicted in dotted line and shown in traces 1081P, 1081Q, simulation predicts a peak reflectivity of about 0.99846 at a frequency of about 22.1 GigaHertz for multilayer metal acoustic reflector electrode 1013N comprising the second arrangement 1075N of the Tungsten metal electrode layer over three alternating pairs of Titanium and Tungsten layers, in which the second arrangement 1075N is over current spreading layer (CSL) 1035N. For example, as depicted in dashed line and shown in traces 1083P, 1083Q simulation predicts a peak reflectivity of about 0.99848 at a frequency of about 20.7 GigaHertz for multilayer metal acoustic reflector electrode 1013O comprising the third arrangement 1075O of the Tungsten metal electrode layer over five alternating pairs of Titanium and Tungsten layers, in which the third arrangement 1075O is over current spreading layer (CSL) 1035O. As shown in charts 1077P, 1077Q, acoustic reflectivity may increase with increasing number of pairs of alternating acoustic impedance metal layers.

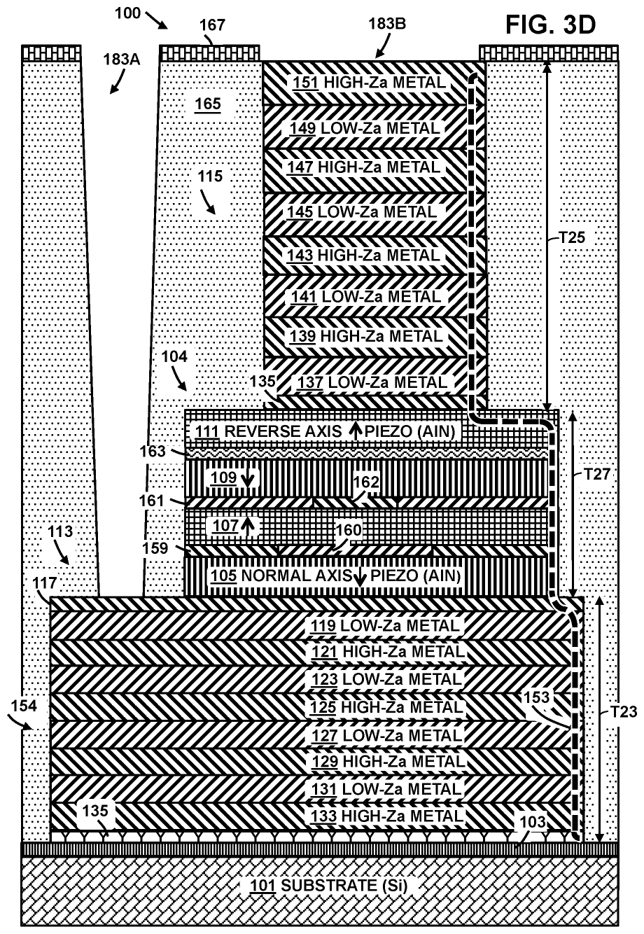

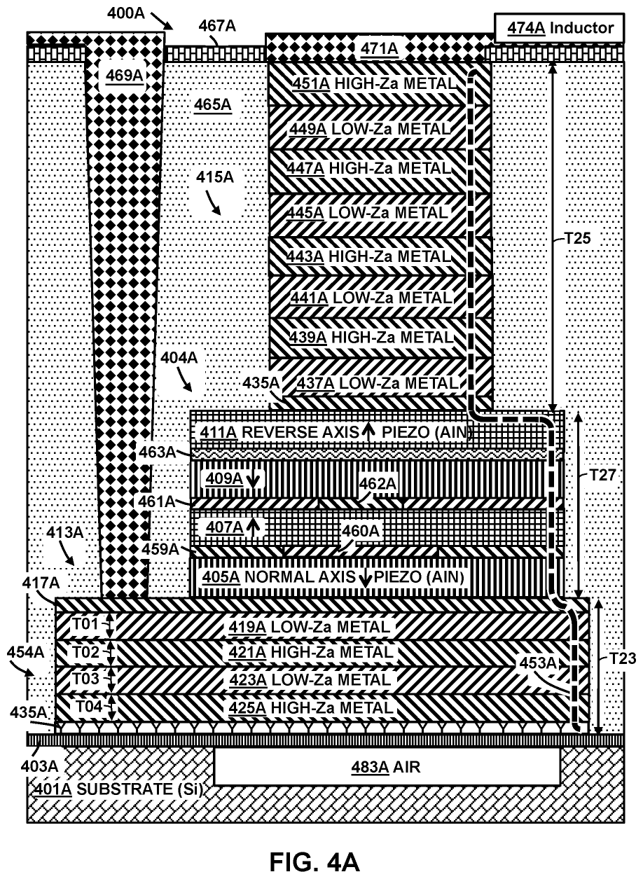

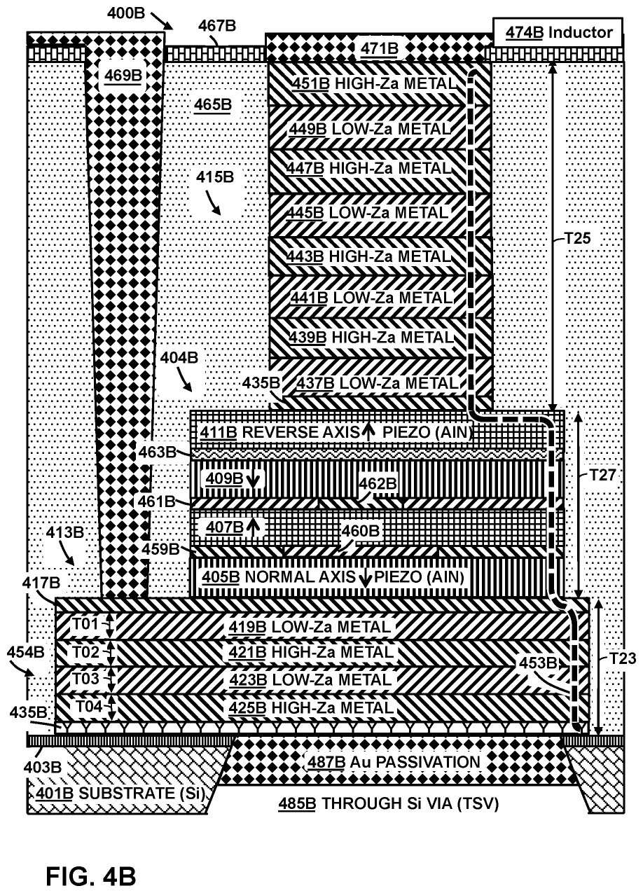

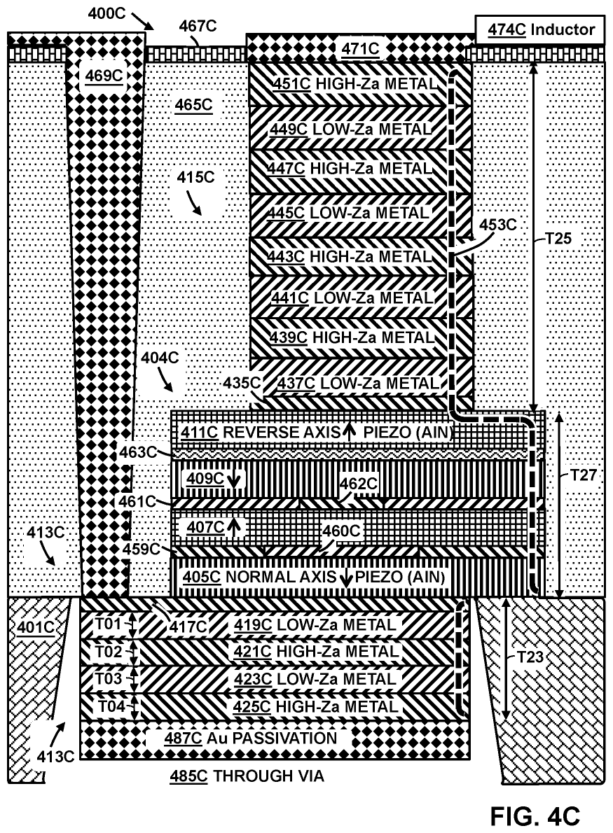

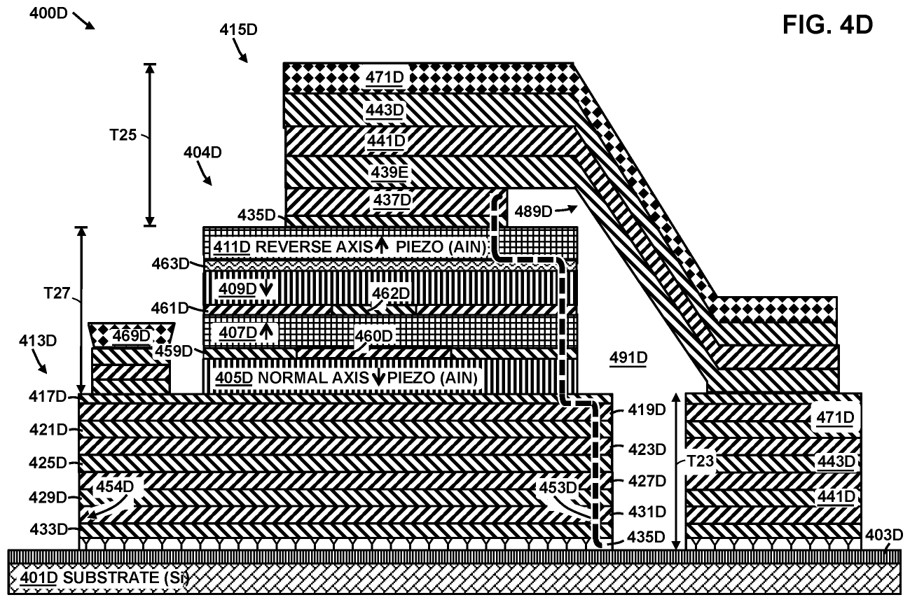

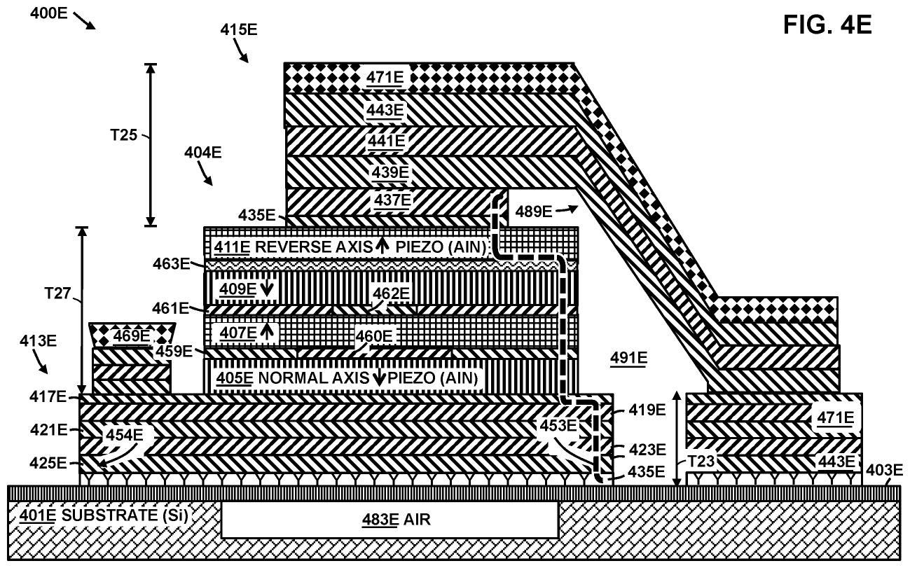

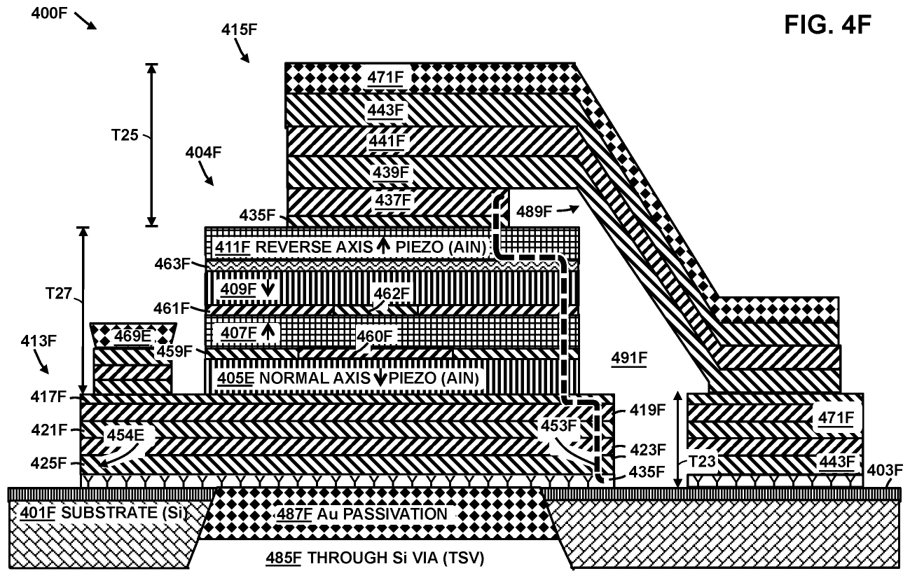

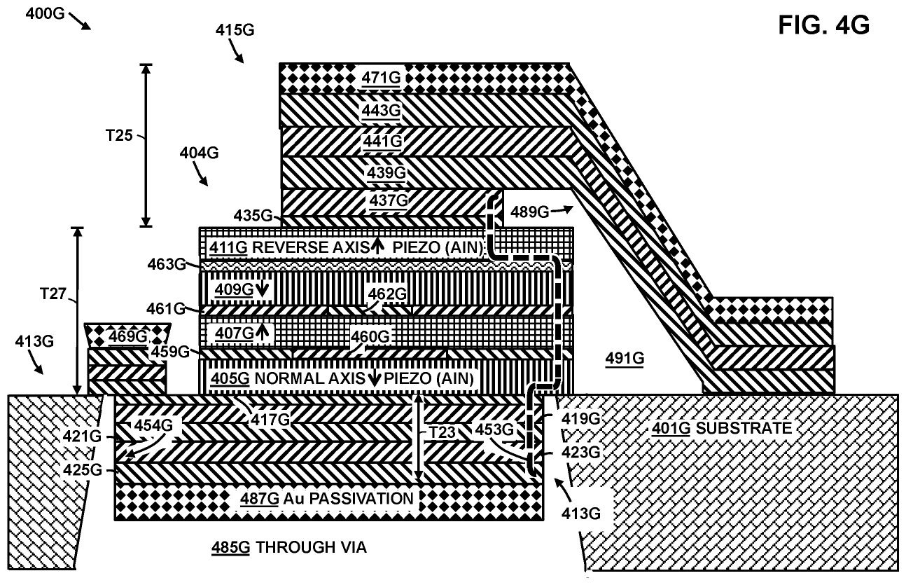

FIG. 1A is a diagram that illustrates an example bulk acoustic wave resonator structure 100. FIGS. 4A through 4G show alternative example bulk acoustic wave resonators, 400A through 400G, to the example bulk acoustic wave resonator structure 100 shown in FIG. 1A. The foregoing are shown in simplified cross sectional views. The resonator structures are formed over a substrate 101, 401A through 401G (e.g., silicon substrate 101, 401A, 401B, 401D through 401F, e.g., silicon carbide substrate 401C. In some examples, the substrate may further comprise a seed layer 103, 403A, 403B, 403D through 403F, formed of, for example, aluminum nitride (AlN), or another suitable material (e.g., silicon dioxide (SiO₂), aluminum oxide (Al₂O₃), silicon nitride (Si₃N₄), amorphous silicon (a-Si), silicon carbide (SiC)), having an example thickness in a range from approximately 100 A to approximately 1 um on the silicon substrate. Bottom current spreading layers 135, 435A through 435G may be interposed between the seed layers 135, 435A through 435G and bottom electrode layer pairs of the bottom acoustic reflector electrodes 113, 413A through 413G. Bottom current spreading layers have already been discussed in detail herein. Accordingly, these discussions are referenced and incorporated, rather than repeated here.

The example resonators 100, 400A through 400G, include a respective stack 104, 404A through 404G, of an example four layers of piezoelectric material, for example, four layers of Aluminum Nitride (AlN) having a wurtzite structure. For example, FIG. 1A and FIGS. 4A through 4G show a bottom piezoelectric layer 105, 405A through 405G, a first middle piezoelectric layer 107, 407A through 407G, a second middle piezoelectric layer 109, 409A through 409G, and a top piezoelectric layer 111, 411A through 411G. A mesa structure 104, 404A through 404G (e.g., first mesa structure 104, 404A through 404G) may comprise the respective stack 104, 404A through 404G, of the example four layers of piezoelectric material. The mesa structure 104, 404A through 404G (e.g., first mesa structure 104, 404A through 404G) may comprise bottom piezoelectric layer 105, 405A through 405G. The mesa structure 104, 404A through 404G (e.g., first mesa structure 104, 404A through 404G) may comprise first middle piezoelectric layer 107, 407A through 407G. The mesa structure 104, 404A through 404G (e.g., first mesa structure 104, 404A through 404G) may comprise second middle piezoelectric layer 109, 409A through 409G. The mesa structure 104, 404A through 404G (e.g., first mesa structure 104, 404A through 404G) may comprise top piezoelectric layer 111, 411A through 411G.

The four layers of piezoelectric material in the respective stack 104, 404A through 404G of FIG. 1A and FIGS. 4A through 4G may have an alternating axis arrangement in the respective stack 104, 404A through 404G. For example the bottom piezoelectric layer 105, 405A through 405G may have a normal axis orientation, which is depicted in the figures using a downward directed arrow. Next in the alternating axis arrangement of the respective stack 104, 404A through 404G, the first middle piezoelectric layer 107, 407A through 407G may have a reverse axis orientation, which is depicted in the figures using an upward directed arrow. Next in the alternating axis arrangement of the respective stack 104, 404A through 404G, the second middle piezoelectric layer 109, 409A through 409G may have the normal axis orientation, which is depicted in the figures using the downward directed arrow. Next in the alternating axis arrangement of the respective stack 104, 404A through 404G, the top piezoelectric layer 111, 411A through 411G may have the reverse axis orientation, which is depicted in the figures using the upward directed arrow.

For example, polycrystalline thin film MN may be grown in a crystallographic c-axis negative polarization, or normal axis orientation perpendicular relative to the substrate surface using reactive magnetron sputtering of an Aluminum target in a nitrogen atmosphere. However, as will be discussed in greater detail subsequently herein, changing sputtering conditions, for example by adding oxygen, may reverse the axis to a crystallographic c-axis positive polarization, or reverse axis, orientation perpendicular relative to the substrate surface.

In the example resonators 100, 400A through 400G, of FIG. 1A and FIGS. 4A through 4G, the bottom piezoelectric layer 105, 405A through 405G, may have a piezoelectrically excitable resonance mode (e.g., main resonance mode) at a resonant frequency (e.g., main resonant frequency) of the example resonators. Similarly, the first middle piezoelectric layer 107, 407A through 407G, may have its piezoelectrically excitable resonance mode (e.g., main resonance mode) at the resonant frequency (e.g., main resonant frequency) of the example resonators. Similarly, the second middle piezoelectric layer 109, 409A through 409G, may have its piezoelectrically excitable resonance mode (e.g., main resonance mode) at the resonant frequency (e.g., main resonant frequency) of the example resonators. Similarly, the top piezoelectric layer 111, 411A through 411G, may have its piezoelectrically excitable main resonance mode (e.g., main resonance mode) at the resonant frequency (e.g., main resonant frequency) of the example resonators. Accordingly, the top piezoelectric layer 111, 411A through 411G, may have its piezoelectrically excitable main resonance mode (e.g., main resonance mode) at the resonant frequency (e.g., main resonant frequency) with the bottom piezoelectric layer 105, 405A through 405G, the first middle piezoelectric layer 107, 407A through 407G, and the second middle piezoelectric layer 109, 409A through 409G.

The bottom piezoelectric layer 105, 405A through 405G, may be acoustically coupled with the first middle piezoelectric layer 107, 407A through 407G, in the piezoelectrically excitable resonance mode (e.g., main resonance mode) at the resonant frequency (e.g., main resonant frequency) of the example resonators 100, 400A through 400G. The normal axis of bottom piezoelectric layer 105, 405A through 405G, in opposing the reverse axis of the first middle piezoelectric layer 107, 407A through 407G, may cooperate for the piezoelectrically excitable resonance mode (e.g., main resonance mode) at the resonant frequency (e.g., main resonant frequency) of the example resonators. The first middle piezoelectric layer 107, 407A through 407G, may be sandwiched between the bottom piezoelectric layer 105, 405A through 405G, and the second middle piezoelectric layer 109, 409A through 409G, for example, in the alternating axis arrangement in the respective stack 104, 404A through 404G. For example, the reverse axis of the first middle piezoelectric layer 107, 407A through 407G, may oppose the normal axis of the bottom piezoelectric layer 105, 405A through 405G, and the normal axis of the second middle piezoelectric layer 109, 409A-409G. In opposing the normal axis of the bottom piezoelectric layer 105, 405A through 405G, and the normal axis of the second middle piezoelectric layer 109, 409A through 409G, the reverse axis of the first middle piezoelectric layer 107, 407A through 407G, may cooperate for the piezoelectrically excitable resonance mode (e.g., main resonance mode) at the resonant frequency (e.g., main resonant frequency) of the example resonators.

The second middle piezoelectric layer 109, 409A through 409G, may be sandwiched between the first middle piezoelectric layer 107, 407A through 407G, and the top piezoelectric layer 111, 411A through 411G, for example, in the alternating axis arrangement in the respective stack 104, 404A through 404G. For example, the normal axis of the second middle piezoelectric layer 109, 409A through 409G, may oppose the reverse axis of the first middle piezoelectric layer 107, 407A through 407G, and the reverse axis of the top piezoelectric layer 111, 411A through 411G. In opposing the reverse axis of the first middle piezoelectric layer 107, 407A through 407G, and the reverse axis of the top piezoelectric layer 111, 411A through 411G, the normal axis of the second middle piezoelectric layer 109, 409A through 409G, may cooperate for the piezoelectrically excitable resonance mode (e.g., main resonance mode) at the resonant frequency (e.g., main resonant frequency) of the example resonators. Similarly, the alternating axis arrangement of the bottom piezoelectric layer 105, 405A through 405G, and the first middle piezoelectric layer 107, 407A through 407G, and the second middle piezoelectric layer 109, 409A through 409G, and the top piezoelectric layer 111, 411A-411G, in the respective stack 104, 404A through 404G may cooperate for the piezoelectrically excitable resonance mode (e.g., main resonance mode) at the resonant frequency (e.g., main resonant frequency) of the example resonators. Despite differing in their alternating axis arrangement in the respective stack 104, 404A through 404G, the bottom piezoelectric layer 105, 405A through 405G and the first middle piezoelectric layer 107, 407A through 407G, and the second middle piezoelectric layer 109, 409A through 409G, and the top piezoelectric layer 111, 411A through 411G, may all be made of the same piezoelectric material, e.g., Aluminum Nitride (AlN).

Respective layers of piezoelectric material in the stack 104, 404A through 404G, of FIG. 1A and FIGS. 4A through 4G may have respective layer thicknesses of about one half wavelength (e.g., one half acoustic wavelength) of the main resonant frequency of the example resonators. For example, respective layers of piezoelectric material in the stack 104, 404A through 404G, of FIG. 1A and FIGS. 4A through 4G may have respective layer thicknesses so that (e.g., selected so that) the respective bulk acoustic wave resonators 100, 400A through 400G may have respective resonant frequencies that are in a Super High Frequency (SHF) band or an Extremely High Frequency (EHF) band (e.g., respective resonant frequencies that are in a Super High Frequency (SHF) band, e.g., respective resonant frequencies that are in an Extremely High Frequency (EHF) band. For example, respective layers of piezoelectric material in the stack 104, 404A through 404G, of FIG. 1A and FIGS. 4A through 4G may have respective layer thicknesses so that (e.g., selected so that) the respective bulk acoustic wave resonators 100, 400A through 400G may have respective resonant frequencies that are in a millimeter wave band. For example, for a twenty-four gigahertz (e.g., 24 GHz) main resonant frequency of the example resonators, the bottom piezoelectric layer 105, 405A through 405G, may have a layer thickness corresponding to about one half of a wavelength (e.g., one half of an acoustic wavelength) of the main resonant frequency, and may be about two thousand Angstroms (2000 A). Similarly, the first middle piezoelectric layer 107, 407A through 407G, may have a layer thickness corresponding the one half of the wavelength (e.g., one half of the acoustic wavelength) of the main resonant frequency; the second middle piezoelectric layer 109, 409A through 409G, may have a layer thickness corresponding the one half of the wavelength (e.g., one half of the acoustic wavelength) of the main resonant frequency; and the top piezoelectric layer 111, 411A through 411G, may have a layer thickness corresponding the one half of the wavelength (e.g., one half of the acoustic wavelength) of the main resonant frequency. Piezoelectric layer thickness may be scaled up or down to determine main resonant frequency.

The example resonators 100, 400A through 400G, of FIG. 1A and FIGS. 4A through 4G may comprise: a bottom acoustic reflector 113, 413A through 413G, including an acoustically reflective bottom electrode stack of a plurality of bottom metal electrode layers; and a top acoustic reflector 115, 415A through 415G, including an acoustically reflective bottom electrode stack of a plurality of top metal electrode layers. Accordingly, the bottom acoustic reflector 113, 413A through 413G, may be a bottom multilayer acoustic reflector, and the top acoustic reflector 115, 415A through 415G, may be a top multilayer acoustic reflector. The piezoelectric layer stack 104, 404A through 404G, may be sandwiched between the plurality of bottom metal electrode layers of the bottom acoustic reflector 113, 413A through 413G, and the plurality of top metal electrode layers of the top acoustic reflector 115, 415A through 415G. For example, top acoustic reflector electrode 115, 415A through 415G and bottom acoustic reflector electrode 113, 413A through 413G may abut opposite sides of a resonant volume 104, 404A through 404G (e.g., piezoelectric layer stack 104, 404A through 404G) free of any interposing electrode. The piezoelectric layer stack 104, 404A through 404G, may be electrically and acoustically coupled with the plurality of bottom metal electrode layers of the bottom acoustic reflector 113, 413A through 413G and the plurality of top metal electrode layers of the top acoustic reflector 115, 415A through 415G, to excite the piezoelectrically excitable resonance mode (e.g., main resonance mode) at the resonant frequency (e.g., main resonant frequency). For example, such excitation may be done by using the plurality of bottom metal electrode layers of the bottom acoustic reflector 113, 413A through 413G and the plurality of top metal electrode layers of the top acoustic reflector 115, 415A through 415G to apply an oscillating electric field having a frequency corresponding to the resonant frequency (e.g., main resonant frequency) of the piezoelectric layer stack 104, 404A through 404G, and of the example resonators 100, 400A through 400G.

For example, the bottom piezoelectric layer 105, 405A through 405G, may be electrically and acoustically coupled with the plurality of bottom metal electrode layers of the bottom acoustic reflector 113, 413A through 413G and the plurality of top metal electrode layers of the top acoustic reflector 115, 415A through 415G, to excite the piezoelectrically excitable resonance mode (e.g., main resonance mode) at the resonant frequency (e.g., main resonant frequency) of the bottom piezoelectric layer 105, 405A through 405G. Further, the bottom piezoelectric layer 105, 405A through 405G and the first middle piezoelectric layer 107, 407A through 407G, may be electrically and acoustically coupled with the plurality of bottom metal electrode layers of the bottom acoustic reflector 113, 413A through 413G, and the plurality of top metal electrode layers of the top acoustic reflector 115, 415A through 415G, to excite the piezoelectrically excitable resonance mode (e.g., main resonance mode) at the resonant frequency (e.g., main resonant frequency) of the bottom piezoelectric layer 105, 405A through 405G, acoustically coupled with the first middle piezoelectric layer 107, 407A through 407G. Additionally, the first middle piezoelectric layer 107, 407A-407G, may be sandwiched between the bottom piezoelectric layer 105, 405A through 405G and the second middle piezoelectric layer 109, 409A through 409G, and may be electrically and acoustically coupled with the plurality of bottom metal electrode layers of the bottom acoustic reflector 113, 413A through 413G, and the plurality of top metal electrode layers of the top acoustic reflector 115, 415A through 415G, to excite the piezoelectrically excitable resonance mode (e.g., main resonance mode) at the resonant frequency (e.g., main resonant frequency) of the first middle piezoelectric layer 107, 407A through 407G, sandwiched between the bottom piezoelectric layer 105, 405A through 405G, and the second middle piezoelectric layer 109, 409A through 409G.

The acoustically reflective bottom electrode stack of the plurality of bottom metal electrode layers of the bottom acoustic reflector 113, 413A through 413G, may have an alternating arrangement of low acoustic impedance metal layer and high acoustic impedance metal layer. For example, an initial bottom metal electrode layer 117, 417A through 417G, may comprise a relatively high acoustic impedance metal, for example, Tungsten having an acoustic impedance of about 100 MegaRayls, or for example, Molybdenum having an acoustic impedance of about 65 MegaRayls. The acoustically reflective bottom electrode stack of the plurality of bottom metal electrode layers of the bottom acoustic reflector 113, 413A through 413G may approximate a metal distributed Bragg acoustic reflector. The plurality of metal bottom electrode layers of the bottom acoustic reflector may be electrically coupled (e.g., electrically interconnected) with one another. The acoustically reflective bottom electrode stack of the plurality of bottom metal electrode layers may operate together as a multilayer (e.g., bilayer, e.g., multiple layer) bottom electrode for the bottom acoustic reflector 113, 413A through 413G.

Next in the alternating arrangement of low acoustic impedance metal layer and high acoustic impedance metal layer of the acoustically reflective bottom electrode stack, may be a first pair of bottom metal electrode layers 119, 419A through 419G and 121, 421A through 421G. A first member 119, 419A through 419G, of the first pair of bottom metal electrode layers may comprise a relatively low acoustic impedance metal, for example, Titanium having an acoustic impedance of about 27 MegaRayls, or for example, Aluminum having an acoustic impedance of about 18 MegaRayls. A second member 121, 421A through 421G, of the first pair of bottom metal electrode layers may comprise the relatively high acoustic impedance metal, for example, Tungsten or Molybdenum. Accordingly, the first pair of bottom metal electrode layers 119, 419A through 419G, and 121, 421A through 421G, of the bottom acoustic reflector 113, 413A through 413G, may be different metals, and may have respective acoustic impedances that are different from one another so as to provide a reflective acoustic impedance mismatch at the resonant frequency (e.g., main resonant frequency). Similarly, the initial bottom metal electrode layer 117, 417A through 417G, and the first member of the first pair of bottom metal electrode layers 119, 419A through 419G, of the bottom acoustic reflector 113, 413A through 413G, may be different metals, and may have respective acoustic impedances that are different from one another so as to provide a reflective acoustic impedance mismatch at the resonant frequency (e.g., main resonant frequency).

Next in the alternating arrangement of low acoustic impedance metal layer and high acoustic impedance metal layer of the acoustically reflective bottom electrode stack, a second pair of bottom metal electrode layers 123, 423A through 423G, and 125, 425A through 425G, may respectively comprise the relatively low acoustic impedance metal and the relatively high acoustic impedance metal. Accordingly, the initial bottom metal electrode layer 117, 417A through 417G, and members of the first and second pairs of bottom metal electrode layers 119, 419A through 419G, 121, 421A through 421G, 123, 423A through 423G, 125, 425A through 425G, may have respective acoustic impedances in the alternating arrangement to provide a corresponding plurality of reflective acoustic impedance mismatches.

Next in the alternating arrangement of low acoustic impedance metal layer and high acoustic impedance metal layer of the acoustically reflective bottom electrode stack, a third pair of bottom metal electrode layers 127, 427D, 129, 429D may respectively comprise the relatively low acoustic impedance metal and the relatively high acoustic impedance metal. Next in the alternating arrangement of low acoustic impedance metal layer and high acoustic impedance metal layer of the acoustically reflective bottom electrode stack, a fourth pair of bottom metal electrode layers 131, 431D and 133, 433D may respectively comprise the relatively low acoustic impedance metal and the relatively high acoustic impedance metal.

Respective thicknesses of the bottom metal electrode layers may be related to wavelength (e.g., acoustic wavelength) for the main resonant frequency of the example bulk acoustic wave resonators, 100, 400A through 400G. Further, various embodiments for resonators having relatively higher resonant frequency (higher main resonant frequency) may have relatively thinner bottom metal electrode thicknesses, e.g., scaled thinner with relatively higher resonant frequency (e.g., higher main resonant frequency). Similarly, various alternative embodiments for resonators having relatively lower resonant frequency (e.g., lower main resonant frequency) may have relatively thicker bottom metal electrode layer thicknesses, e.g., scaled thicker with relatively lower resonant frequency (e.g., lower main resonant frequency). For example, a layer thickness of the initial bottom metal electrode layer 117, 417A through 417G, may be about one eighth of a wavelength (e.g., one eighth of an acoustic wavelength) at the main resonant frequency of the example resonator. For example, if molybdenum is used as the high acoustic impedance metal and the main resonant frequency of the resonator is twenty-four gigahertz (e.g., 24 GHz), then using the one eighth of the wavelength (e.g., one eighth of the acoustic wavelength) provides the layer thickness of the initial bottom metal electrode layer 117, 417A through 417G, as about three hundred and thirty Angstroms (330 A). In the foregoing example, the one eighth of the wavelength (e.g., the one eighth of the acoustic wavelength) at the main resonant frequency was used for determining the layer thickness of the initial bottom metal electrode layer 117, 417A-417G, but it should be understood that this layer thickness may be varied to be thicker or thinner in various other alternative example embodiments.

Respective layer thicknesses, T01 through T08, shown in FIG. 1A for members of the pairs of bottom metal electrode layers may be about an odd multiple (e.g., 1×, 3×, etc). of a quarter of a wavelength (e.g., one quarter of the acoustic wavelength) at the main resonant frequency of the example resonator. However, the foregoing may be varied. For example, members of the pairs of bottom metal electrode layers of the bottom acoustic reflector may have respective layer thickness that correspond to from about one eighth to about one half wavelength at the resonant frequency, or an odd multiple (e.g., 1×, 3×, etc). thereof.

In an example, if Tungsten is used as the high acoustic impedance metal, and the main resonant frequency of the resonator is twenty-four gigahertz (e.g., 24 GHz), then using the one quarter of the wavelength (e.g., one quarter of the acoustic wavelength) provides the layer thickness of the high impedance metal electrode layer members of the pairs as about five hundred and forty Angstroms (540 A). For example, if Titanium is used as the low acoustic impedance metal, and the main resonant frequency of the resonator is twenty-four gigahertz (e.g., 24 GHz), then using the one quarter of the wavelength (e.g., one quarter of the acoustic wavelength) provides the layer thickness of the low impedance metal electrode layer members of the pairs as about six hundred and thirty Angstroms (630 A). Similarly, respective layer thicknesses for members of the pairs of bottom metal electrode layers shown in FIGS. 4A through 4G may likewise be about one quarter of the wavelength (e.g., one quarter of the acoustic wavelength) of the main resonant frequency of the example resonator, and these respective layer thicknesses may likewise be determined for members of the pairs of bottom metal electrode layers for the high and low acoustic impedance metals employed.

For example, the bottom piezoelectric layer 105, 405A through 405G, may be electrically and acoustically coupled with the initial bottom metal electrode layer 117, 417A through 417G, and pair(s) of bottom metal electrode layers (e.g., first pair of bottom metal electrode layers 119, 419A through 419G, 121, 421A through 421G, e.g., second pair of bottom metal electrode layers 123, 423A through 423G, 125, 425A through 425G, e.g., third pair of bottom metal electrode layers 127, 427D, 129, 429D, fourth pair of bottom metal electrode layers 131, 431D, 133, 433D), to excite the piezoelectrically excitable resonance mode (e.g., main resonance mode) at the resonant frequency (e.g., main resonant frequency) of the bottom piezoelectric layer 105, 405A through 405G. Further, the bottom piezoelectric layer 105, 405A through 405G and the first middle piezoelectric layer 107, 407A through 407G may be electrically and acoustically coupled with the initial bottom metal electrode layer 117, 417A through 417G and pair(s) of bottom metal electrode layers (e.g., first pair of bottom metal electrode layers 119, 419A through 419G, 121, 421A through 421G, e.g., second pair of bottom metal electrode layers 123, 423A through 423G, 125, 425A through 425G, e.g., third pair of bottom metal electrode layers 127, 427D, 129, 429D), to excite the piezoelectrically excitable resonance mode (e.g., main resonance mode) at the resonant frequency (e.g., main resonant frequency) of the bottom piezoelectric layer 105, 405A through 405G acoustically coupled with the first middle piezoelectric layer 107, 407A through 407G. Additionally, the first middle piezoelectric layer 107, 407A through 407G, may be sandwiched between the bottom piezoelectric layer 105, 405A through 405G, and the second middle piezoelectric layer 109, 409A through 409G, and may be electrically and acoustically coupled with initial bottom metal electrode layer 117, 417A through 417G, and pair(s) of bottom metal electrode layers (e.g., first pair of bottom metal electrode layers 119, 419A through 419G, 121, 421A through 421G, e.g., second pair of bottom metal electrode layers 123, 423A through 423G, 125, 425A through 425G, e.g., third pair of bottom metal electrode layers 127, 427D, 129, 429D), to excite the piezoelectrically excitable resonance mode (e.g., main resonance mode) at the resonant frequency (e.g., main resonant frequency) of the first middle piezoelectric layer 107, 407A through 407G, sandwiched between the bottom piezoelectric layer 105, 405A through 405G, and the second middle piezoelectric layer 109, 409A through 409G.

Another mesa structure 113, 413A through 413G, (e.g., second mesa structure 113, 413A through 413G), may comprise the bottom acoustic reflector 113, 413A through 413G. The another mesa structure 113, 413A through 413G, (e.g., second mesa structure 113, 413A through 413G), may comprise initial bottom metal electrode layer 117, 417A through 417G. The another mesa structure 113, 413A through 413G, (e.g., second mesa structure 113, 413A through 413G), may comprise one or more pair(s) of bottom metal electrode layers (e.g., first pair of bottom metal electrode layers 119, 419A through 419G, 121, 421A through 421G, e.g., second pair of bottom metal electrode layers 123, 423A through 423G, 125, 425A through 425G, e.g., third pair of bottom metal electrode layers 127, 427A, 427D, 129, 429D, e.g., fourth pair of bottom metal electrode layers 131, 431D, 133, 433D).

Similar to what has been discussed for the bottom electrode stack, likewise the top electrode stack of the plurality of top metal electrode layers of the top acoustic reflector 115, 415A through 415G, may have the alternating arrangement of low acoustic impedance metal layer and high acoustic impedance metal layer. For example, an initial top metal electrode layer 135, 435A through 435G, may comprise the relatively high acoustic impedance metal, for example, Tungsten or Molybdenum. The top electrode stack of the plurality of top metal electrode layers of the top acoustic reflector 115, 415A through 415G, may approximate a metal distributed Bragg acoustic reflector. The plurality of top metal electrode layers of the top acoustic reflector may be electrically coupled (e.g., electrically interconnected) with one another. The acoustically reflective top electrode stack of the plurality of top metal electrode layers may operate together as a multilayer (e.g., bilayer, e.g., multiple layer) top electrode for the top acoustic reflector 115, 415A through 415G. Next in the alternating arrangement of low acoustic impedance metal layer and high acoustic impedance metal layer of the acoustically reflective top electrode stack, may be a first pair of top metal electrode layers 137, 437A through 437G, and 139, 439A through 439G. A first member 137, 437A through 437G, of the first pair of top metal electrode layers may comprise the relatively low acoustic impedance metal, for example, Titanium or Aluminum. A second member 139, 439A through 439G, of the first pair of top metal electrode layers may comprise the relatively high acoustic impedance metal, for example, Tungsten or Molybdenum. Accordingly, the first pair of top metal electrode layers 137, 437A through 437G, 139, 439A through 439G, of the top acoustic reflector 115, 415A through 415G, may be different metals, and may have respective acoustic impedances that are different from one another so as to provide a reflective acoustic impedance mismatch at the resonant frequency (e.g., main resonant frequency). Similarly, the initial top metal electrode layer 135, 435A through 435G, and the first member of the first pair of top metal electrode layers 137, 437A through 437G, of the top acoustic reflector 115, 415A through 415G, may be different metals, and may have respective acoustic impedances that are different from one another so as to provide a reflective acoustic impedance mismatch at the resonant frequency (e.g., main resonant frequency).

Next in the alternating arrangement of low acoustic impedance metal layer and high acoustic impedance metal layer of the acoustically reflective top electrode stack, a second pair of top metal electrode layers 141, 441A through 441G, and 143, 443A through 443G, may respectively comprise the relatively low acoustic impedance metal and the relatively high acoustic impedance metal. Accordingly, the initial top metal electrode layer 135, 435A through 435G, and members of the first and second pairs of top metal electrode layers 137, 437A through 437G, 139, 439A through 439G, 141, 441A through 441G, 143, 443A through 443G, may have respective acoustic impedances in the alternating arrangement to provide a corresponding plurality of reflective acoustic impedance mismatches.

Next in the alternating arrangement of low acoustic impedance metal layer and high acoustic impedance metal layer of the acoustically reflective top electrode stack, a third pair of top metal electrode layers 145, 445A through 445C, and 147, 447A through 447C, may respectively comprise the relatively low acoustic impedance metal and the relatively high acoustic impedance metal. Next in the alternating arrangement of low acoustic impedance metal layer and high acoustic impedance metal layer of the acoustically reflective top electrode stack, a fourth pair of top metal electrode layers 149, 449A through 449C, 151, 451A through 451C, may respectively comprise the relatively low acoustic impedance metal and the relatively high acoustic impedance metal.

For example, the bottom piezoelectric layer 105, 405A through 405G, may be electrically and acoustically coupled with the initial top metal electrode layer 135, 435A through 435G, and the pair(s) of top metal electrode layers (e.g., first pair of top metal electrode layers 137, 437A through 437G, 139, 439A through 439G, e.g., second pair of top metal electrode layers 141, 441A through 441G, 143, 443A through 443G, e.g., third pair of top metal electrode layers 145, 445A through 445C, 147, 447A through 447C), to excite the piezoelectrically excitable resonance mode (e.g., main resonance mode) at the resonant frequency (e.g., main resonant frequency) of the bottom piezoelectric layer 105, 405A through 405G. Further, the bottom piezoelectric layer 105, 405A through 405G and the first middle piezoelectric layer 107, 407A through 407G may be electrically and acoustically coupled with the initial top metal electrode layer 135, 435A through 435G and pair(s) of top metal electrode layers (e.g., first pair of top metal electrode layers 137, 437A through 437G, 139, 439A through 439G, e.g., second pair of top metal electrode layers 141, 441A through 441G, 143, 443A through 443G, e.g., third pair of top metal electrode layers 145, 445A through 445C, 147, 447A through 447C), to excite the piezoelectrically excitable resonance mode (e.g., main resonance mode) at the resonant frequency (e.g., main resonant frequency) of the bottom piezoelectric layer 105, 405A through 405G acoustically coupled with the first middle piezoelectric layer 107, 407A through 407G. Additionally, the first middle piezoelectric layer 107, 407A through 407G, may be sandwiched between the bottom piezoelectric layer 105, 405A through 405G, and the second middle piezoelectric layer 109, 409A through 409G, and may be electrically and acoustically coupled with the initial top metal electrode layer 135, 435A through 435G, and the pair(s) of top metal electrode layers (e.g., first pair of top metal electrode layers 137, 437A through 437G, 139, 439A through 439G, e.g., second pair of top metal electrode layers 141, 441A through 441G, 143, 443A through 443G, e.g., third pair of top metal electrode layers 145, 445A through 445C, 147, 447A through 447C), to excite the piezoelectrically excitable resonance mode (e.g., main resonance mode) at the resonant frequency (e.g., main resonant frequency) of the first middle piezoelectric layer 107, 407A through 407G, sandwiched between the bottom piezoelectric layer 105, 405A through 405G, and the second middle piezoelectric layer 109, 409A through 409G.

Yet another mesa structure 115, 415A through 415G, (e.g., third mesa structure 115, 415A through 415G), may comprise the top acoustic reflector 115, 415A through 415G, or a portion of the top acoustic reflector 115, 415A through 415G. The yet another mesa structure 115, 415A through 415G, (e.g., third mesa structure 115, 415A through 415G), may comprise initial top metal electrode layer 135, 435A through 435G. The yet another mesa structure 115, 415A through 415C, (e.g., third mesa structure 115, 415A through 415C), may comprise one or more pair(s) of top metal electrode layers (e.g., first pair of top metal electrode layers 137, 437A through 437C, 139, 439A through 439C, e.g., second pair of top metal electrode layers 141, 441A through 441C, 143, 443A through 443C, e.g., third pair of top metal electrode layers 145, 445A through 445C, 147, 447A through 447C, e.g., fourth pair of top metal electrode layers 149, 449A through 449C, 151, 451A through 451C).

Like the respective layer thicknesses of the bottom metal electrode layers, respective thicknesses of the top metal electrode layers may likewise be related to wavelength (e.g., acoustic wavelength) for the main resonant frequency of the example bulk acoustic wave resonators, 100, 400A through 400G. Further, various embodiments for resonators having relatively higher main resonant frequency may have relatively thinner top metal electrode thicknesses, e.g., scaled thinner with relatively higher main resonant frequency. Similarly, various alternative embodiments for resonators having relatively lower main resonant frequency may have relatively thicker top metal electrode layer thicknesses, e.g., scaled thicker with relatively lower main resonant frequency. Like the layer thickness of the initial bottom metal, a layer thickness of the initial top metal electrode layer 135, 435A through 435G, may likewise be about one eighth of the wavelength (e.g., one eighth of the acoustic wavelength) of the main resonant frequency of the example resonator. For example, if molybdenum is used as the high acoustic impedance metal and the main resonant frequency of the resonator is twenty-four gigahertz (e.g., 24 GHz), then using the one eighth of the wavelength (e.g., one eighth of the acoustic wavelength) provides the layer thickness of the initial top metal electrode layer 135, 435A through 435G, as about three hundred and thirty Angstroms (330 A). In the foregoing example, the one eighth of the wavelength (e.g., one eighth of the acoustic wavelength) at the main resonant frequency was used for determining the layer thickness of the initial top metal electrode layer 135, 435A-435G, but it should be understood that this layer thickness may be varied to be thicker or thinner in various other alternative example embodiments. Respective layer thicknesses, T11 through T18, shown in FIG. 1A for members of the pairs of top metal electrode layers may be about an odd multiple (e.g., 1×, 3×, etc). of a quarter of a wavelength (e.g., one quarter of an acoustic wavelength) of the main resonant frequency of the example resonator. Similarly, respective layer thicknesses for members of the pairs of top metal electrode layers shown in FIGS. 4A through 4G may likewise be about one quarter of a wavelength (e.g., one quarter of an acoustic wavelength) at the main resonant frequency of the example resonator multiplied by an odd multiplier (e.g., 1×, 3×, etc), and these respective layer thicknesses may likewise be determined for members of the pairs of top metal electrode layers for the high and low acoustic impedance metals employed. However, the foregoing may be varied. For example, members of the pairs of top metal electrode layers of the top acoustic reflector may have respective layer thickness that correspond to from an odd multiple (e.g., 1×, 3×, etc). of about one eighth to an odd multiple (e.g., 1×, 3×, etc). of about one half wavelength at the resonant frequency.

The bottom acoustic reflector 113, 413A through 413G, may have a thickness dimension T23 extending along the stack of bottom electrode layers. For the example of the 24 GHz resonator, the thickness dimension T23 of the bottom acoustic reflector may be about five thousand Angstroms (5,000 A). The top acoustic reflector 115, 415A through 415G, may have a thickness dimension T25 extending along the stack of top electrode layers. For the example of the 24 GHz resonator, the thickness dimension T25 of the top acoustic reflector may be about five thousand Angstroms (5,000 A). The piezoelectric layer stack 104, 404A through 404G, may have a thickness dimension T27 extending along the piezoelectric layer stack 104, 404A through 404G. For the example of the 24 GHz resonator, the thickness dimension T27 of the piezoelectric layer stack may be about eight thousand Angstroms (8,000 A).

In the example resonators 100, 400A through 400G, of FIG. 1A and FIGS. 4A through 4G, a notional heavy dashed line is used in depicting an etched edge region 153, 453A through 453G, associated with the example resonators 100, 400A through 400G. Similarly, a laterally opposing etched edge region 154, 454A through 454G is arranged laterally opposing or opposite from the notional heavy dashed line depicting the etched edge region 153, 453A through 453G. The etched edge region may, but need not, assist with acoustic isolation of the resonators. The etched edge region may, but need not, help with avoiding acoustic losses for the resonators. The etched edge region 153, 453A through 453G, (and the laterally opposing etched edge region 154, 454A through 454G) may extend along the thickness dimension T27 of the piezoelectric layer stack 104, 404A through 404G. The etched edge region 153, 453A through 453G, may extend through (e.g., entirely through or partially through) the piezoelectric layer stack 104, 404A through 404G. Similarly, the laterally opposing etched edge region 154, 454A through 454G may extend through (e.g., entirely through or partially through) the piezoelectric layer stack 104, 404A through 404G. The etched edge region 153, 453A through 453G, (and the laterally opposing etched edge region 154, 454A through 454G) may extend through (e.g., entirely through or partially through) the bottom piezoelectric layer 105, 405A through 405G. The etched edge region 153, 453A through 453G, (and the laterally opposing etched edge region 154, 454A through 454G) may extend through (e.g., entirely through or partially through) the first middle piezoelectric layer 107, 407A through 407G. The etched edge region 153, 453A through 453G, (and the laterally opposing etched edge region 154, 454A through 454G) may extend through (e.g., entirely through or partially through) the second middle piezoelectric layer 109, 409A through 409G. The etched edge region 153, 453A through 453G, (and the laterally opposing etched edge region 154, 454A through 454G) may extend through (e.g., entirely through or partially through) the top piezoelectric layer 111, 411A through 411G.

The etched edge region 153, 453A through 453G, (and the laterally opposing etched edge region 154, 454A through 454G) may extend along the thickness dimension T23 of the bottom acoustic reflector 113, 413A through 413G. The etched edge region 153, 453A through 453G, (and the laterally opposing etched edge region 154, 454A through 454G) may extend through (e.g., entirely through or partially through) the bottom acoustic reflector 113, 413A through 413G. The etched edge region 153, 453A through 453G, (and the laterally opposing etched edge region 154, 454A through 454G) may extend through (e.g., entirely through or partially through) the initial bottom metal electrode layer 117, 417A through 417G. The etched edge region 153, 453A through 453G, (and the laterally opposing etched edge region 154, 454A through 454G) may extend through (e.g., entirely through or partially through) the first pair of bottom metal electrode layers, 119, 419A through 419G, 121, 421A through 421G. The etched edge region 153, 453A through 453G (and the laterally opposing etched edge region 154, 454A through 454G) may extend through (e.g., entirely through or partially through) the second pair of bottom metal electrode layers, 123, 423A through 423G, 125, 425A through 425G. The etched edge region 153, 453A through 453G (and the laterally opposing etched edge region 154, 454A through 454G) may extend through (e.g., entirely through or partially through) the third pair of bottom metal electrode layers, 127, 427D, 129, 429D. The etched edge region 153, 453A through 453G (and the laterally opposing etched edge region 154, 454A through 454G) may extend through (e.g., entirely through or partially through) the fourth pair of bottom metal electrode layers, 131, 431D, 133, 433D.

The etched edge region 153, 453A through 453G (and the laterally opposing etched edge region 154, 454A through 454G) may extend along the thickness dimension T25 of the top acoustic reflector 115, 415A through 415G. The etched edge region 153, 453A through 453G (and the laterally opposing etched edge region 154, 454A through 454G) may extend through (e.g., entirely through or partially through) the top acoustic reflector 115, 415A through 415G. The etched edge region 153, 453A through 453G (and the laterally opposing etched edge region 154, 454A through 454G) may extend through (e.g., entirely through or partially through) the initial top metal electrode layer 135, 435A through 435G. The etched edge region 153, 453A through 453G (and the laterally opposing etched edge region 154, 454A through 454G) may extend through (e.g., entirely through or partially through) the first pair of top metal electrode layers, 137, 437A through 437G, 139, 439A through 49G. The etched edge region 153, 453A through 453C (and the laterally opposing etched edge region 154, 454A through 454C) may extend through (e.g., entirely through or partially through) the second pair of top metal electrode layers, 141, 441A through 441C, 143, 443A through 443C. The etched edge region 153, 453A through 453C (and the laterally opposing etched edge region 154, 454A through 454C) may extend through (e.g., entirely through or partially through) the third pair of top metal electrode layers, 145, 445A through 445C, 147, 447A through 447C. The etched edge region 153, 453A through 453C (and the laterally opposing etched edge region 154, 454A through 454C) may extend through (e.g., entirely through or partially through) the fourth pair of top metal electrode layers, 149, 449A through 449C, 151, 451A through 451C.

As mentioned previously, mesa structure 104, 404A through 404G (e.g., first mesa structure 104, 404A through 404G) may comprise the respective stack 104, 404A through 404G, of the example four layers of piezoelectric material. The mesa structure 104, 404A through 404G (e.g., first mesa structure 104, 404A through 404G) may extend laterally between (e.g., may be formed between) etched edge region 153, 453A through 453G and laterally opposing etched edge region 154, 454A through 454G. As mentioned previously, another mesa structure 113, 413A through 413G, (e.g., second mesa structure 113, 413A through 413G), may comprise the bottom acoustic reflector 113, 413A through 413G. The another mesa structure 113, 413A through 413G, (e.g., second mesa structure 113, 413A through 413G) may extend laterally between (e.g., may be formed between) etched edge region 153, 453A through 453G and laterally opposing etched edge region 154, 454A through 454G. As mentioned previously, yet another mesa structure 115, 415A through 415G, (e.g., third mesa structure 115, 415A through 415G), may comprise the top acoustic reflector 115, 415A through 415G or a portion of the top acoustic reflector 115, 415A through 415G. The yet another mesa structure 115, 415A through 415G, (e.g., third mesa structure 115, 415A through 415G) may extend laterally between (e.g., may be formed between) etched edge region 153, 453A through 453G and laterally opposing etched edge region 154, 454A through 454G. In some example resonators 100, 400A, 400B, 400D through 400F, the second mesa structure corresponding to the bottom acoustic reflector 113, 413A, 413B, 413D through 413F may be laterally wider than the first mesa structure corresponding to the stack 104, 404A, 404B, 404D through 404F, of the example four layers of piezoelectric material. In some example resonators 100, 400A through 400C, the first mesa structure corresponding to the stack 104, 404A through 404C, of the example four layers of piezoelectric material may be laterally wider than the third mesa structure corresponding to the top acoustic reflector 115, 415A through 415C. In some example resonators 400D through 400G, the first mesa structure corresponding to the stack 404D through 404G, of the example four layers of piezoelectric material may be laterally wider than a portion of the third mesa structure corresponding to the top acoustic reflector 415D through 415G.

The example resonators 100, 400A through 400G, of FIG. 1A and FIGS. 4A through 4G may include one or more (e.g., one or a plurality of) interposer layers sandwiched between piezoelectric layers of the stack 104, 404A through 404G. For example, a first interposer layer 159, 459A through 459G may be sandwiched between the bottom piezoelectric layer 105, 405A through 405G, and the first middle piezoelectric layer 107, 407A through 407G. For example, a second interposer layer 161, 461A through 461G, may be sandwiched between the first middle piezoelectric layer 107, 407A through 407G, and the second middle piezoelectric layer 109, 409A through 409G. For example, a third interposer layer 163, 463A through 463G, may be sandwiched between the second middle piezoelectric layer 109, 409A through 409G, and the top piezoelectric layer 111, 411A through 411G.

One or more (e.g., one or a plurality of) interposer layers may be metal interposer layers. The metal interposer layers may be relatively high acoustic impedance metal interposer layers (e.g., using relatively high acoustic impedance metals such as Tungsten (W) or Molybdenum (Mo)). Such metal interposer layers may (but need not) flatten stress distribution across adjacent piezoelectric layers, and may (but need not) raise effective electromechanical coupling coefficient (Kt2) of adjacent piezoelectric layers.

Alternatively or additionally, one or more (e.g., one or a plurality of) interposer layers may be dielectric interposer layers. The dielectric of the dielectric interposer layers may be a dielectric that has a positive acoustic velocity temperature coefficient, so acoustic velocity increases with increasing temperature of the dielectric. The dielectric of the dielectric interposer layers may be, for example, silicon dioxide. Dielectric interposer layers may, but need not, facilitate compensating for frequency response shifts with increasing temperature. Most materials (e.g., metals, e.g., dielectrics) generally have a negative acoustic velocity temperature coefficient, so acoustic velocity decreases with increasing temperature of such materials. Accordingly, increasing device temperature generally causes response of resonators and filters to shift downward in frequency. Including dielectric (e.g., silicon dioxide) that instead has a positive acoustic velocity temperature coefficient may facilitate countering or compensating (e.g., temperature compensating) this downward shift in frequency with increasing temperature. Alternatively or additionally, one or more (e.g., one or a plurality of) interposer layers may comprise metal and dielectric for respective interposer layers.

In addition to the foregoing application of metal interposer layers to raise effective electromechanical coupling coefficient (Kt2) of adjacent piezoelectric layers, and the application of dielectric interposer layers to facilitate compensating for frequency response shifts with increasing temperature, interposer layers may, but need not, increase quality factor (Q-factor) and/or suppress irregular spectral response patterns characterized by sharp reductions in Q-factor known as “rattles”. Q-factor of a resonator is a figure of merit in which increased Q-factor indicates a lower rate of energy loss per cycle relative to the stored energy of the resonator. Increased Q-factor in resonators used in filters results in lower insertion loss and sharper roll-off in filters. The irregular spectral response patterns characterized by sharp reductions in Q-factor known as “rattles” may cause ripples in filter pass bands.

Metal and/or dielectric interposer layer of suitable thicknesses and acoustic material properties (e.g., velocity, density) may be placed at appropriate places in the stack 104, 404A through 404G, of piezoelectric layers, for example, proximate to the nulls of acoustic energy distribution in the stacks (e.g., between interfaces of piezoelectric layers of opposing axis orientation). Finite Element Modeling (FEM) simulations and varying parameters in fabrication prior to subsequent testing may help to optimize interposer layer designs for the stack. Thickness of interposer layers may, but need not, be adjusted to influence increased Q-factor and/or rattle suppression. It is theorized that if the interposer layer is too thin there is no substantial effect. Thus minimum thickness for the interposer layer may be about one mono-layer, or about five Angstroms (5 A). Alternatively, if the interposer layer is too thick, rattle strength may increase rather than being suppressed. Accordingly, an upper limit of interposer thickness may be about five-hundred Angstroms (500 A) for a twenty-four Gigahertz (24 GHz) resonator design, with limiting thickness scaling inversely with frequency for alternative resonator designs. It is theorized that below a series resonant frequency of resonators, Fs, Q-factor may not be systematically and significantly affected by including a single interposer layer. However, it is theorized that there may, but need not, be significant increases in Q-factor, for example from about two-thousand (2000) to about three-thousand (3000), for inclusion of two or more interposer layers. Alternatively or additionally, thickness of interposer layers may, but need not, be adjusted to provide mass loading, for example, mass loading of shunt resonators in ladder filters. For example, filters may include series connected resonator designs and shunt connected resonator designs that may include mass load layers. For example, for ladder filter designs, the shunt resonator may include a sufficient mass load layer so that the parallel resonant frequency (Fp) of the shunt resonator approximately matches the series resonant frequency (Fs) of the series resonator design. Thus the series resonator design (without the mass load layer) may be used for the shunt resonator design, but with the addition of the mass load layer 155, 455A through 455G, for the shunt resonator design. By including the mass load layer, the design of the shunt resonator may be approximately downshifted, or reduced, in frequency relative to the series resonator by a relative amount approximately corresponding to the electromechanical coupling coefficient (Kt2) of the shunt resonator.

In the example resonators 100, 400A through 400G, of FIG. 1A and FIGS. 4A through 4G, the first interposer layer 159, 459A through 459G may be a first patterned interposer 159, 459A through 459G (e.g., a first patterned layer 159, 459A through 459G, e.g., a first patterned interposer layer 159, 459A through 459G) may be disposed within the active piezoelectric volume (e.g., may be disposed with the alternating axis active piezoelectric volume). This may, but need not facilitate suppression of spurious modes. The first patterned layer 159, 459A through 459G (e.g., first patterned interposer 159, 459A through 459G) may comprise a respective step mass feature (and may comprise a respective plurality of step mass features) as shown in FIG. 1A and FIGS. 4A through 4G. The active piezoelectric volume (e.g., the alternating axis active piezoelectric volume) may have a lateral perimeter. The step mass feature of the first patterned layer 159, 459A through 459G (e.g., of first patterned interposer 159, 459A through 459G) may be proximate to the lateral perimeter of the active piezoelectric volume. For example, a first mesa structure having a lateral perimeter may comprise the four piezoelectric layers 105, 107, 109, 111, 405A through 405G, 407A through 407G, 409A through 409G, 411A through 411G having respective piezoelectric axis that substantially oppose one another. The step mass feature of the first patterned layer 159, 459A through 459G (e.g., first patterned interposer 159, 459A through 459G) may be proximate to the lateral perimeter of the first mesa structure. The active piezoelectric volume (e.g., the alternating axis active piezoelectric volume) may be interposed between the top and bottom acoustic reflector electrodes 115, 113, 415A through 415G, 413A through 413G. A second mesa structure may comprise the bottom acoustic reflector electrode 113, 413A through 413G. A third mesa structure may comprise the top acoustic reflector electrode 115, 415A through 415G.

The first patterned layer 159, 459A through 459G (e.g., the first patterned interposer 159, 459A through 459G, e.g., the first patterned interposer layer 159, 459A through 459G) may comprise a first step mass feature having a first acoustic impedance. The first patterned layer 159, 459A through 459G (e.g., the first patterned interposer 159, 459A through 459G, e.g., the first patterned interposer layer 159, 459A through 459G) may further comprise a second step mass feature having a second acoustic impedance. The first acoustic impedance may be different than the second acoustic impedance. More generally, the first patterned layer 159, 459A through 459G (e.g., the first patterned interposer 159, 459A through 459G, e.g., the first patterned interposer layer 159, 459A through 459G) may comprise first and second materials that may be different from one another (e.g., first and second materials having respective acoustic impedances that may be different from one another). For example, the first patterned layer 159, 459A through 459G (e.g., the first patterned interposer 159, 459A through 459G, e.g., the first patterned interposer layer 159, 459A through 459G) may comprise dielectric. For example, the first patterned layer 159, 459A through 459G (e.g., the first patterned interposer 159, 459A through 459G, e.g., the first patterned interposer layer 159, 459A through 459G) may comprise first and second dielectrics that may be different from one another (e.g., first and second dielectrics having respective acoustic impedances that may be different from one another). The first patterned layer 159, 459A through 459G (e.g., the first patterned interposer 159, 459A through 459G, e.g., the first patterned interposer layer 159, 459A through 459G) may comprise semiconductor. For example, the first patterned layer 159, 459A through 459G (e.g., the first patterned interposer 159, 459A through 459G, e.g., the first patterned interposer layer 159, 459A through 459G) may comprise first and second semiconductors that may be different from one another (e.g., first and second semiconductors having respective acoustic impedances that may be different from one another). The first patterned layer 159, 459A through 459G (e.g., the first patterned interposer 159, 459A through 459G, e.g., the first patterned interposer layer 159, 459A through 459G) may comprise metal. For example, the first patterned layer 159, 459A through 459G (e.g., the first patterned interposer 159, 459A through 459G, e.g., the first patterned interposer layer 159, 459A through 459G) may comprise first and second metals that may be different from one another (e.g., first and second metals having respective acoustic impedances that may be different from one another).

The first patterned layer 159, 459A through 459G (e.g., the first patterned interposer 159, 459A through 459G, e.g., the first patterned interposer layer 159, 459A through 459G) may comprise combinations of the foregoing. The first patterned layer 159, 459A through 459G (e.g., the first patterned interposer 159, 459A through 459G, e.g., the first patterned interposer layer 159, 459A through 459G) may comprise a first metal and a first dielectric. The first patterned layer 159, 459A through 459G (e.g., the first patterned interposer 159, 459A through 459G, e.g., the first patterned interposer layer 159, 459A through 459G) may comprise a first metal and a first semiconductor. The first patterned layer 159, 459A through 459G (e.g., the first patterned interposer 159, 459A through 459G, e.g., the first patterned interposer layer 159, 459A through 459G) may comprise a first semiconductor and a first dielectric.

The first patterned layer 159, 459A through 459G (e.g., the first patterned interposer 159, 459A through 459G, e.g., the first patterned interposer layer 159, 459A through 459G) may comprise a first central feature 160, 160A trough 160G having a first central acoustic impedance. The first patterned layer 159, 459A through 459G (e.g., the first patterned interposer 159, 459A through 459G, e.g., the first patterned interposer layer 159, 459A through 459G) may further comprise a first peripheral feature having a first peripheral acoustic impedance that is greater than first central acoustic impedance. The first peripheral feature having the first peripheral acoustic impedance that is greater than first central acoustic impedance of the first central feature 160, 160A trough 160G may, but need not facilitate a quality factor enhancement of the bulk acoustic wave resonators 100, 400A through 400G. The first patterned layer 159, 459A through 459G (e.g., the first patterned interposer 159, 459A through 459G, e.g., the first patterned interposer layer 159, 459A through 459G) may comprise a first peripheral feature having a first peripheral acoustic impedance. The first patterned layer 159, 459A through 459G (e.g., the first patterned interposer 159, 459A through 459G, e.g., the first patterned interposer layer 159, 459A through 459G) may further comprise a first central feature 160, 160A trough 160G having a first central acoustic impedance that is greater than first peripheral acoustic impedance. The first central feature 160, 160A trough 160G having the first central acoustic impedance that is greater than first peripheral acoustic impedance of the first peripheral feature may, but need not facilitate a quality factor enhancement of the bulk acoustic wave resonator 100, 400A through 400G.

The first patterned layer 159, 459A through 459G (e.g., the first patterned interposer 159, 459A through 459G, e.g., the first patterned interposer layer 159, 459A through 459G) may comprise a first central feature 160, 160A trough 160G, and may further comprise a first peripheral feature having a first width dimension. The first width dimension of the first peripheral feature may be within a range from approximately a tenth of a percent of a width of the active piezoelectric volume to approximately ten percent of a width of the active piezoelectric volume. The first width dimension of the first peripheral feature being within a range from approximately a tenth of a percent of a width of the active piezoelectric volume to approximately ten percent of a width of the active piezoelectric volume may, but need not facilitate a quality factor enhancement of the bulk acoustic wave resonator 100, 400A through 400G.

The first patterned layer 159, 459A through 459G (e.g., the first patterned interposer 159, 459A through 459G, e.g., the first patterned interposer layer 159, 459A through 459G) may comprise a first peripheral feature, and may further comprise a first central feature 160, 160A trough 160G having a first width dimension. The first width dimension of the first central feature 160, 160A trough 160G may be within a range from approximately ninety percent of a width of the active piezoelectric volume to approximately ninety-nine and nine tenths percent of a width of the active piezoelectric volume. The first width dimension of the first central feature 160, 160A trough 160G being within a range from approximately ninety percent of a width of the active piezoelectric volume to approximately ninety-nine and nine tenths percent of a width of the active piezoelectric volume may, but need not facilitate a quality factor enhancement of the bulk acoustic wave resonator 100, 400A through 400G. The first patterned layer 159, 459A through 459G (e.g., the first patterned interposer 159, 459A through 459G, e.g., the first patterned interposer layer 159, 459A through 459G) may be substantially planar.

In the example resonators 100, 400A through 400G, of FIG. 1A and FIGS. 4A through 4G, the second interposer layer 161, 461A through 461G may be a second patterned interposer 161, 461A through 461G (e.g., a second patterned layer 161, 461A through 461G, e.g., a second patterned interposer layer 161, 461A through 461G) may be disposed within the active piezoelectric volume (e.g., may be disposed with the alternating axis active piezoelectric volume).

The second patterned interposer 161, 461A through 461G (e.g., a second patterned layer 161, 461A through 461G, e.g., a second patterned interposer layer 161, 461A through 461G) may be substantially planar. The second patterned interposer 161, 461A through 461G (e.g., a second patterned layer 161, 461A through 461G, e.g., a second patterned interposer layer 161, 461A through 461G) may be disposed within the active piezoelectric volume. This may, but need not facilitate the suppression of spurious modes.

Second patterned interposer 161, 461A through 461G (e.g., a second patterned layer 161, 461A through 461G, e.g., a second patterned interposer layer 161, 461A through 461G) may be interposed between the second piezoelectric layer 107, 407A through 407G (e.g., first middle piezoelectric layer 107, 407A through 407G, e.g., having reverse piezoelectric axis orientation) and the third piezoelectric layer 109, 409A through 409G (e.g., second middle piezoelectric layer 109, 409A through 409G, e.g., having the normal piezoelectric axis orientation).

Second patterned interposer 161, 461A through 461G (e.g., a second patterned layer 161, 461A through 461G, e.g., a second patterned interposer layer 161, 461A through 461G) may comprise a third step mass feature having a third acoustic impedance. Second patterned interposer 161, 461A through 461G (e.g., a second patterned layer 161, 461A through 461G, e.g., a second patterned interposer layer 161, 461A through 461G) may further comprise a fourth step mass feature having a fourth acoustic impedance. The third acoustic impedance may be different than the fourth acoustic impedance. More generally, second patterned interposer 161, 461A through 461G (e.g., a second patterned layer 161, 461A through 461G, e.g., a second patterned interposer layer 161, 461A through 461G) may comprise third and fourth materials that may be different from one another (e.g., third and fourth materials having respective acoustic impedances that may be different from one another). For example, second patterned interposer 161, 461A through 461G (e.g., a second patterned layer 161, 461A through 461G, e.g., second patterned interposer layer 161, 461A through 461G) may comprise dielectric. For example, second patterned interposer 161, 461A through 461G (e.g., a second patterned layer 161, 461A through 461G, e.g., a second patterned interposer layer 161, 461A through 461G) may comprise third and fourth dielectrics that may be different from one another (e.g., third and fourth dielectrics having respective acoustic impedances that may be different from one another). Second patterned interposer 161, 461A through 461G (e.g., a second patterned layer 161, 461A through 461G, e.g., a second patterned interposer layer 161, 461A through 461G) may comprise semiconductor. For example, second patterned interposer 161, 461A through 461G (e.g., a second patterned layer 161, 461A through 461G, e.g., a second patterned interposer layer 161, 461A through 461G) may comprise third and fourth semiconductors that may be different from one another (e.g., third and fourth semiconductors having respective acoustic impedances that may be different from one another). Second patterned interposer 161, 461A through 461G (e.g., a second patterned layer 161, 461A through 461G, e.g., a second patterned interposer layer 161, 461A through 461G) may comprise metal. For example, second patterned interposer 161, 461A through 461G (e.g., a second patterned layer 161, 461A through 461G, e.g., a second patterned interposer layer 161, 461A through 461G) may comprise third and fourth metals that may be different from one another (e.g., third and fourth metals having respective acoustic impedances that may be different from one another).

Second patterned interposer 161, 461A through 461G (e.g., second patterned layer 161, 461A through 461G, e.g., second patterned interposer layer 161, 461A through 461G) may comprise combinations of the foregoing. Second patterned interposer 161, 461A through 461G (e.g., a second patterned layer 161, 461A through 461G, e.g., a second patterned interposer layer 161, 461A through 461G) may comprise a second metal and a second dielectric. Second patterned interposer 161, 461A through 461G (e.g., a second patterned layer 161, 461A through 461G, e.g., a second patterned interposer layer 161, 461A through 461G) may comprise a second metal and a second semiconductor. Second patterned interposer 161, 461A through 461G (e.g., a second patterned layer 161, 461A through 461G, e.g., a second patterned interposer layer 161, 461A through 461G) may comprise a second semiconductor and a second dielectric.

Second patterned interposer 161, 461A through 461G (e.g., a second patterned layer 161, 461A through 461G, e.g., a second patterned interposer layer 161, 461A through 461G) may comprise a second central feature 162, 162A through 162D having a second central acoustic impedance. Second patterned interposer 161, 461A through 461G (e.g., a second patterned layer 161, 461A through 461G, e.g., a second patterned interposer layer 161, 461A through 461G) may further comprise a second peripheral feature having a second peripheral acoustic impedance that is greater than second central acoustic impedance. The second peripheral feature having the second peripheral acoustic impedance that is greater than second central acoustic impedance of the second central feature 162, 162A through 162D may, but need not facilitate a quality factor enhancement of the bulk acoustic wave resonators 100, 400A through 400G.

Second patterned interposer 161, 461A through 461G (e.g., a second patterned layer 161, 461A through 461G, e.g., a second patterned interposer layer 161, 461A through 461G) may comprise a second peripheral feature having a second peripheral acoustic impedance. Second patterned interposer 161, 461A through 461G (e.g., a second patterned layer 161, 461A through 461G, e.g., a second patterned interposer layer 161, 461A through 461G) may further comprise a second central feature 162, 162A through 162D having a second central acoustic impedance that is greater than second peripheral acoustic impedance. The second central feature 162, 162A through 162D having the second central acoustic impedance that is greater than second peripheral acoustic impedance of the second peripheral feature may, but need not facilitate a quality factor enhancement of the bulk acoustic wave resonators 100, 400A through 400G.

Second patterned interposer 161, 461A through 461G (e.g., a second patterned layer 161, 461A through 461G, e.g., a second patterned interposer layer 161, 461A through 461G) may comprise a second central feature 162, 162A through 162D, and may further comprise a second peripheral feature having a second width dimension. The second width dimension of the second peripheral feature may be within a range from approximately a tenth of a percent of a second width of the active piezoelectric volume to approximately ten percent of a width of the active piezoelectric volume. The second width dimension of the second peripheral feature being within a range from approximately a tenth of a percent of a width of the active piezoelectric volume to approximately ten percent of a width of the active piezoelectric volume may, but need not facilitate a quality factor enhancement of the bulk acoustic wave resonators 100, 400A through 400G

Second patterned interposer 161, 461A through 461G (e.g., a second patterned layer 161, 461A through 461G, e.g., a second patterned interposer layer 161, 461A through 461G) may comprise a second peripheral feature, and may further comprise a second central feature 162, 162A through 162D having a second width dimension. The second width dimension of the second central feature 162, 162A through 162D may be within a range from approximately ninety percent of a width of the active piezoelectric volume to approximately ninety-nine and nine tenths percent of a width of the active piezoelectric volume. The second width dimension of the second central feature 162, 162A through 162D being within a range from approximately ninety percent of a width of the active piezoelectric volume to approximately ninety-nine and nine tenths percent of a width of the active piezoelectric volume may, but need not facilitate a quality factor enhancement of the bulk acoustic wave resonator 100, 400A through 400G.

In the example resonators 100, 400A through 400C, of FIG. 1A and FIGS. 4A through 4C, a planarization layer 165, 465A through 465C may be included. A suitable material may be used for planarization layer 165, 465A through 465C, for example Silicon Dioxide (SiO2), Hafnium Dioxide (HfO2), polyimide, or BenzoCyclobutene (BCB). An isolation layer 167, 467A through 467C, may also be included and arranged over the planarization layer 165, 465A-465C. A suitable low dielectric constant (low-k), low acoustic impedance (low-Za) material may be used for the isolation layer 167, 467A through 467C, for example polyimide, or BenzoCyclobutene (BCB).

In the example resonators 100, 400A through 400G, of FIG. 1A and FIGS. 4A through 4G, a bottom electrical interconnect 169, 469A through 469G, may be included to interconnect electrically with (e.g., electrically contact with) the bottom acoustic reflector 113, 413A through 413G, stack of the plurality of bottom metal electrode layers. A top electrical interconnect 171, 471A through 471G, may be included to interconnect electrically with the top acoustic reflector 115, 415A through 415G, stack of the plurality of top metal electrode layers. A suitable material may be used for the bottom electrical interconnect 169, 469A through 469G, and the top electrical interconnect 171, 471A through 471G, for example, gold (Au). At least a portion of top electrical interconnect 171, 471A through 471G, may comprise a top current spreading layer (as already discussed in detail previously herein), electrically coupled with the top electrode layers of the top acoustic reflector electrode 115, 415A through 415G over the piezoelectric stack 104, 404A through 404G. Top electrical interconnect 171, 471A through 471G (and integral top current spreading layer) may be substantially acoustically isolated from the stack 104, 404A through 404G of the example four layers of piezoelectric material by the top multilayer metal acoustic reflector electrode 115, 415A through 415G. Top electrical interconnect 171, 471A through 471G may have dimensions selected so that the top electrical interconnect 171, 471A through 471G approximates a fifty ohm electrical transmission line at the main resonant frequency of the bulk acoustic wave resonator 100, 400A through 400G. Top electrical interconnect 171, 471A through 471G may have a thickness that is substantially thicker than a thickness of a pair of top metal electrode layers of the top multilayer metal acoustic reflector electrode 115, 415A through 415G (e.g., thicker than thickness of the first pair of top metal electrode layers 137, 437A through 437G, 139, 439A through 439G). Top electrical interconnect 171, 471A through 471G may have a thickness within a range from about one hundred Angstroms (100 A) to about five micrometers (5 um). For example, top electrical interconnect 171, 471A through 471G may have a thickness of about two thousand Angstroms (2000 A). As shown for example in FIG. 1A and FIGS. 4A through 4C, an integrated inductor 174, 474A through 474C may be electrically coupled with top electrical interconnect 171, 471A through 471G.

FIG. 1B is a simplified view of FIG. 1A that illustrates an example of acoustic stress distribution during electrical operation of the bulk acoustic wave resonator structure shown in FIG. 1A. A notional curved line schematically depicts vertical (Tzz) stress distribution 173 through stack 104 of the example four piezoelectric layers, 105, 107, 109, 111. The stress 173 is excited by the oscillating electric field applied via the top acoustic reflector 115 stack of the plurality of top metal electrode layers 135, 137, 139, 141, 143, 145, 147, 149, 151, and the bottom acoustic reflector 113 stack of the plurality of bottom metal electrode layers 117, 119, 121, 123, 125, 127, 129, 131, 133. The stress 173 has maximum values inside the stack 104 of piezoelectric layers, while exponentially tapering off within the top acoustic reflector 115 and the bottom acoustic reflector 113. Notably, acoustic energy confined in the resonator structure 100 is proportional to stress magnitude.

As discussed previously herein, the example four piezoelectric layers, 105, 107, 109, 111 in the stack 104 may have an alternating axis arrangement in the stack 104. For example the bottom piezoelectric layer 105 may have the normal axis orientation, which is depicted in FIG. 1B using the downward directed arrow. Next in the alternating axis arrangement of the stack 104, the first middle piezoelectric layer 107 may have the reverse axis orientation, which is depicted in FIG. 1B using the upward directed arrow. Next in the alternating axis arrangement of the stack 104, the second middle piezoelectric layer 109 may have the normal axis orientation, which is depicted in FIG. 1B using the downward directed arrow. Next in the alternating axis arrangement of the stack 104, the top piezoelectric layer 111 may have the reverse axis orientation, which is depicted in FIG. 1B using the upward directed arrow. For the alternating axis arrangement of the stack 104, stress 173 excited by the applied oscillating electric field causes normal axis piezoelectric layers (e.g., bottom and second middle piezoelectric layers 105, 109) to be in compression, while reverse axis piezoelectric layers (e.g., first middle and top piezoelectric layers 107, 111) to be in extension. Accordingly, FIG. 1B shows peaks of stress 173 on the right side of the heavy dashed line to depict compression in normal axis piezoelectric layers (e.g., bottom and second middle piezoelectric layers 105, 109), while peaks of stress 173 are shown on the left side of the heavy dashed line to depict extension in reverse axis piezoelectric layers (e.g., first middle and top piezoelectric layers 107, 111).

FIG. 1C shows a simplified top plan view of a bulk acoustic wave resonator structure 100A corresponding to the cross sectional view of FIG. 1A, and also shows another simplified top plan view of an alternative bulk acoustic wave resonator structure 100B. The bulk acoustic wave resonator structure 100A includes the stack 104A of four layers of piezoelectric material e.g., having the alternating piezoelectric axis arrangement of the four layers of piezoelectric material. The stack 104A of piezoelectric layers may be sandwiched between the bottom acoustic reflector electrode 113A and the top acoustic reflector electrode 115A. The bottom acoustic reflector electrode may comprise the stack of the plurality of bottom metal electrode layers of the bottom acoustic reflector electrode 113A, e.g., having the alternating arrangement of low acoustic impedance bottom metal electrode layers and high acoustic impedance bottom metal layers. Similarly, the top acoustic reflector electrode 115A may comprise the stack of the plurality of top metal electrode layers of the top acoustic reflector electrode 115A, e.g., having the alternating arrangement of low acoustic impedance top metal electrode layers and high acoustic impedance top metal electrode layers.

Top electrical interconnect 171A extends over (e.g., electrically contacts) top acoustic reflector electrode 115A. Integrated inductor 174A may be made integral with top electrical interconnect 171A. Bottom electrical interconnect 169A extends over (e.g., electrically contacts) bottom acoustic reflector electrode 113A through bottom via region 168A.

FIG. 1C also shows another simplified top plan view of an alternative bulk acoustic wave resonator structure 100B. Similarly, the bulk acoustic wave resonator structure 100B includes the stack 104B of four layers of piezoelectric material e.g., having the alternating piezoelectric axis arrangement of the four layers of piezoelectric material. The stack 104B of piezoelectric layers may be sandwiched between the bottom acoustic reflector electrode 113B and the top acoustic reflector electrode 115B. The bottom acoustic reflector electrode may comprise the stack of the plurality of bottom metal electrode layers of the bottom acoustic reflector electrode 113B, e.g., having the alternating arrangement of low acoustic impedance bottom metal electrode layers and high acoustic impedance bottom metal layers. Similarly, the top acoustic reflector electrode 115B may comprise the stack of the plurality of top metal electrode layers of the top acoustic reflector electrode 115B, e.g., having the alternating arrangement of low acoustic impedance top metal electrode layers and high acoustic impedance top metal electrode layers. Top electrical interconnect 171B extends over (e.g., electrically contacts) top acoustic reflector electrode 115B. Integrated inductor 174B may be made integral with top electrical interconnect 171B. Bottom electrical interconnect 169B extends over (e.g., electrically contacts) bottom acoustic reflector electrode 113B through bottom via region 168B.

In FIGS. 1D and 1E, Nitrogen (N) atoms are depicted with a hatching style, while Aluminum (Al) atoms are depicted without a hatching style. FIG. 1D is a perspective view of an illustrative model of a reverse axis crystal structure 175 of Aluminum Nitride, AlN, in piezoelectric material of layers in FIG. 1A, e.g., having reverse axis orientation of negative polarization. For example, first middle and top piezoelectric layers 107, 111 discussed previously herein with respect to FIGS. 1A and 1B are reverse axis piezoelectric layers. By convention, when the first layer of normal axis crystal structure 175 is a Nitrogen, N, layer and second layer in an upward direction (in the depicted orientation) is an Aluminum, Al, layer, the piezoelectric material including the reverse axis crystal structure 175 is said to have crystallographic c-axis negative polarization, or reverse axis orientation as indicated by the upward pointing arrow 177. For example, polycrystalline thin film Aluminum Nitride, AlN, may be grown in the crystallographic c-axis negative polarization, or reverse axis, orientation perpendicular relative to the substrate surface using reactive magnetron sputtering of an aluminum target in a nitrogen atmosphere, and by introducing oxygen into the gas atmosphere of the reaction chamber during fabrication at the position where the flip to the reverse axis is desired. An inert gas, for example, Argon may also be included in a sputtering gas atmosphere, along with the nitrogen and oxygen.

For example, a predetermined amount of oxygen containing gas may be added to the gas atmosphere over a short predetermined period of time or for the entire time the reverse axis layer is being deposited. The oxygen containing gas may be diatomic oxygen containing gas, such as oxygen (O2). Proportionate amounts of the Nitrogen gas (N2) and the inert gas may flow, while the predetermined amount of oxygen containing gas flows into the gas atmosphere over the predetermined period of time. For example, N2 and Ar gas may flow into the reaction chamber in approximately a 3:1 ratio of N2 to Ar, as oxygen gas also flows into the reaction chamber. For example, the predetermined amount of oxygen containing gas added to the gas atmosphere may be in a range from about a thousandth of a percent (0.001%) to about ten percent (10%), of the entire gas flow. The entire gas flow may be a sum of the gas flows of argon, nitrogen and oxygen, and the predetermined period of time during which the predetermined amount of oxygen containing gas is added to the gas atmosphere may be in a range from about a quarter (0.25) second to a length of time needed to create an entire layer, for example. For example, based on mass-flows, the oxygen composition of the gas atmosphere may be about 2 percent when the oxygen is briefly injected. This results in an aluminum oxynitride (ALON) portion of the final monolithic piezoelectric layer, integrated in the Aluminum Nitride, AlN, material, having a thickness in a range of about 5 nm to about 20 nm, which is relatively oxygen rich and very thin. Alternatively, the entire reverse axis piezoelectric layer may be aluminum oxynitride.

FIG. 1E is a perspective view of an illustrative model of a normal axis crystal structure 179 of Aluminum Nitride, AlN, in piezoelectric material of layers in FIG. 1A, e.g., having normal axis orientation of positive polarization. For example, bottom and second middle piezoelectric layers 105, 109 discussed previously herein with respect to FIGS. 1A and 1B are normal axis piezoelectric layers. By convention, when the first layer of the reverse axis crystal structure 179 is an Al layer and second layer in an upward direction (in the depicted orientation) is an N layer, the piezoelectric material including the reverse axis crystal structure 179 is said to have a c-axis positive polarization, or normal axis orientation as indicated by the downward pointing arrow 181. For example, polycrystalline thin film MN may be grown in the crystallographic c-axis positive polarization, or normal axis, orientation perpendicular relative to the substrate surface by using reactive magnetron sputtering of an Aluminum target in a nitrogen atmosphere.

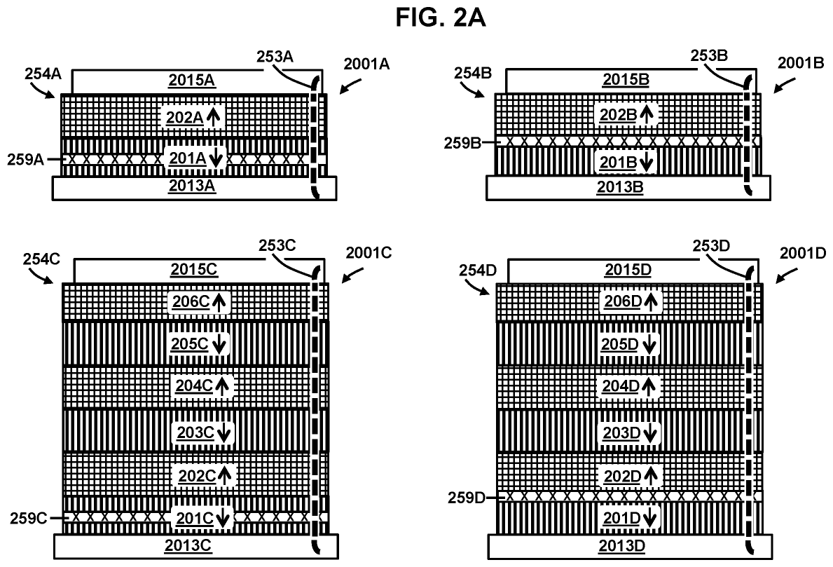

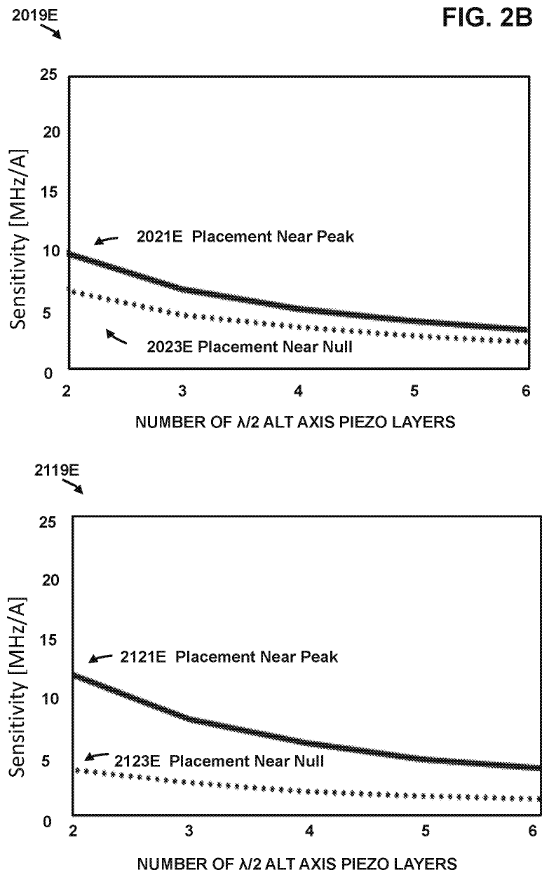

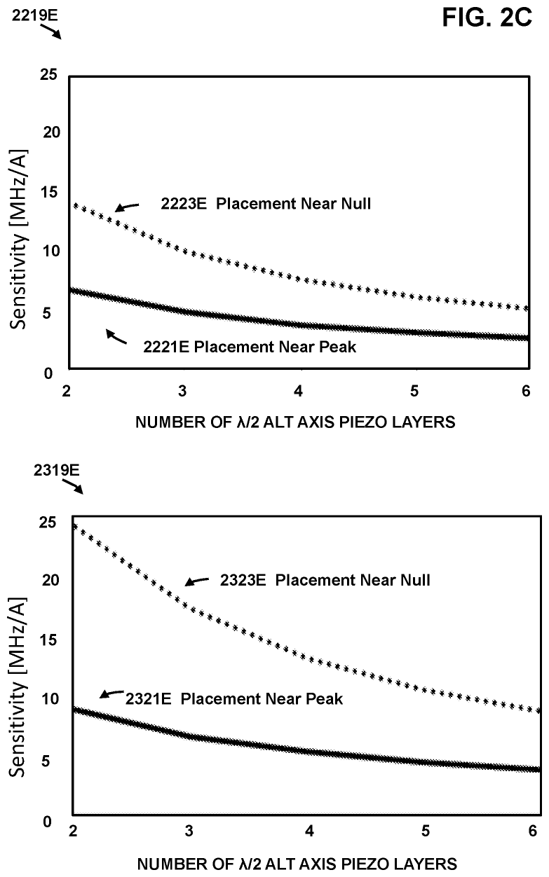

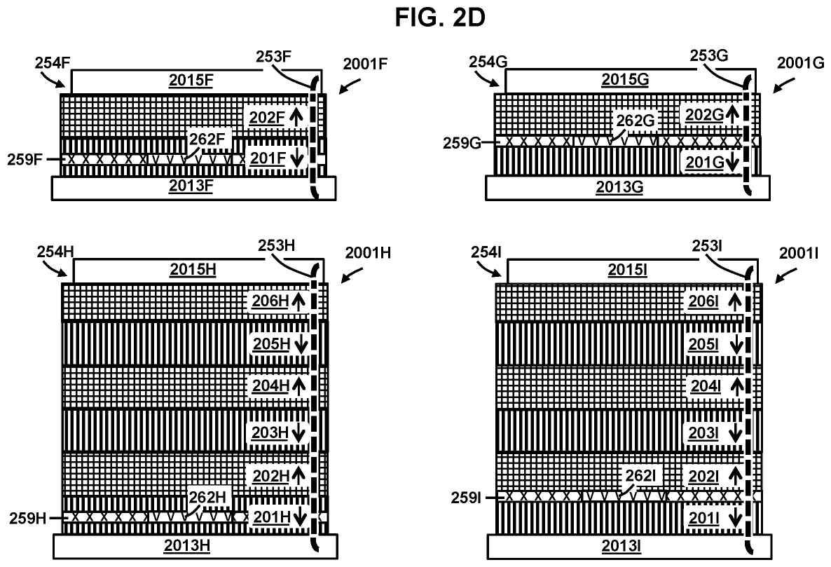

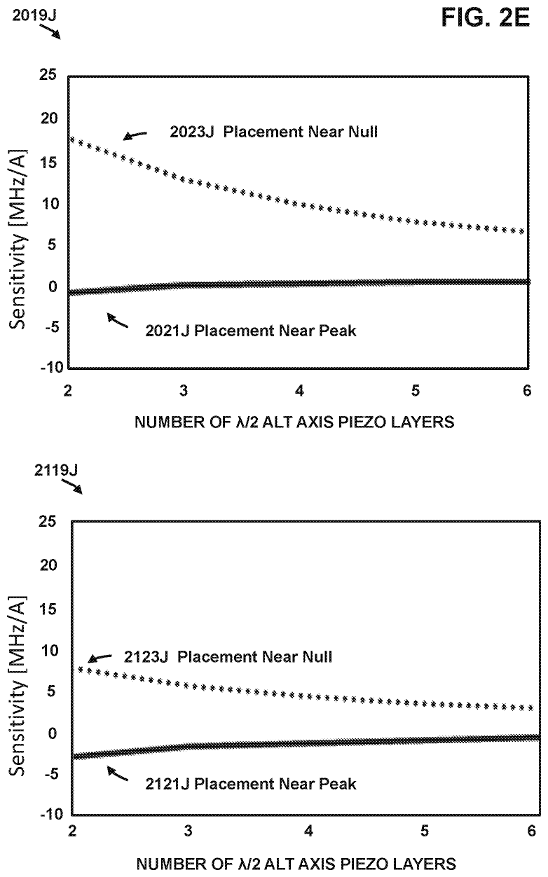

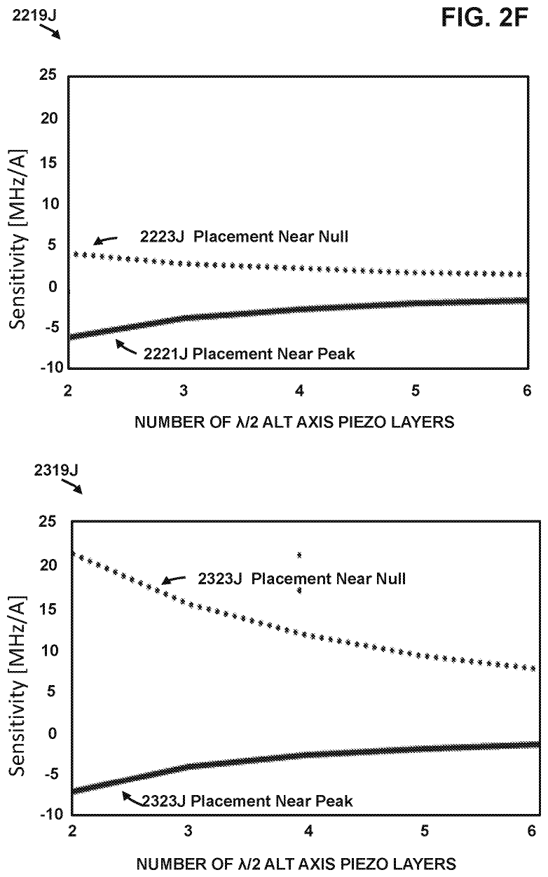

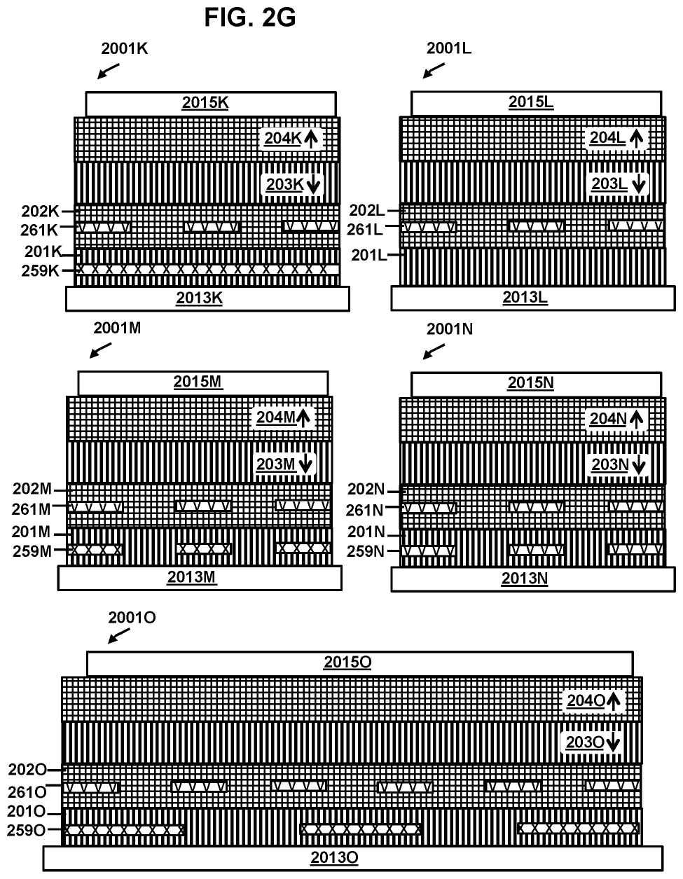

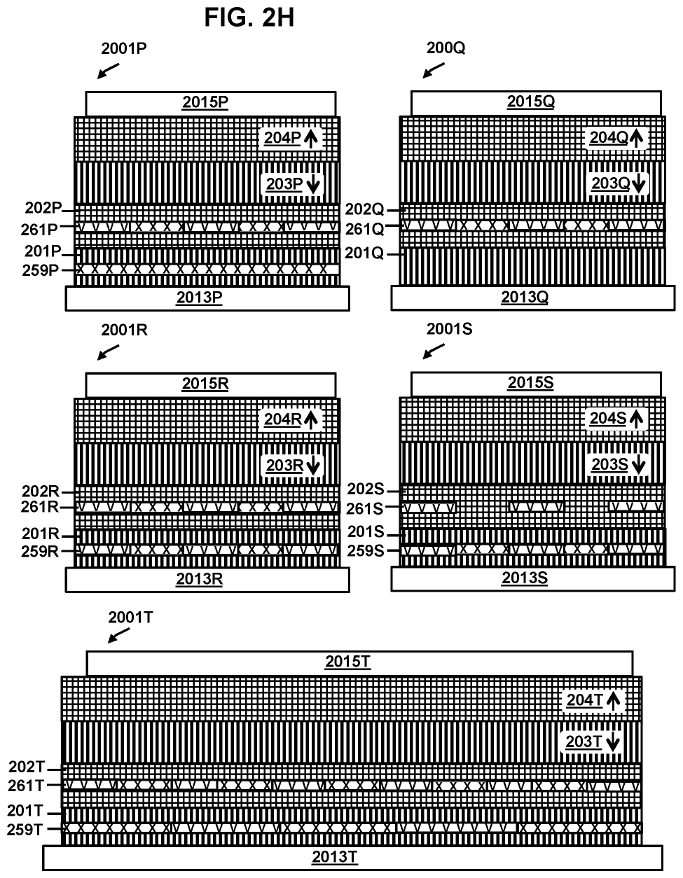

FIG. 2A shows further simplified views of four additional bulk acoustic wave resonators 2001A, 2001B, 2001C, 2001D. As shown, the four additional bulk acoustic wave resonators 2001A, 2001B, 2001C, 2001D comprise piezoelectric stacks of piezoelectric layers in alternating piezoelectric axis orientation arrangements, sandwiched between top acoustic reflector electrodes 2015A, 2015B, 2015C, 2015D and bottom acoustic reflector electrodes 2013A, 2013B, 2013C, 2013D. As shown, respective etched edges 253A, 253B, 253C, 253C (depicted in FIG. 2A using heavy dashed lines) may extend through the bottom acoustic reflector electrodes 2013A, 2013B, 2013C, 2013D, through the piezoelectric stacks and through the top acoustic reflector electrodes 2015A, 2015B, 2015C, 2015D. Respective opposing etched edges 254A, 254B, 254C, 254D (e.g., arranged opposing respective etched edges 253A, 253B, 253C, 253C) likewise may extend through the bottom acoustic reflector electrodes 2013A, 2013B, 2013C, 2013D, through the piezoelectric stacks and through the top acoustic reflector electrodes 2015A, 2015B, 2015C, 2015D.

Bulk acoustic wave resonators 2001A, 2001B, 2001C, 2001D may comprise first piezoelectric layers 201A, 201B, 201C, 201D having respective normal piezoelectric axis orientations, as depicted in FIG. 2A using the downward pointed arrow. Bulk acoustic wave resonators 2001A, 2001B, 2001C, 2001D may comprise second piezoelectric layers 202A, 202B, 202C, 202D having respective reverse piezoelectric axis orientations, as depicted in FIG. 2A using the upward pointed arrow.

As shown in FIG. 2A, bulk acoustic wave resonators 2001C, 2001D may further comprise third piezoelectric layers 203C, 203D having respective normal piezoelectric axis orientations, as depicted in FIG. 2A using the downward pointed arrow. Bulk acoustic wave resonators 2001C, 2001D may further comprise fourth piezoelectric layers 204C, 204D having respective reverse piezoelectric axis orientations, as depicted in FIG. 2A using the upward pointed arrow. Bulk acoustic wave resonators 2001C, 2001D may further comprise fifth piezoelectric layers 205C, 205D having respective normal piezoelectric axis orientations, as depicted in FIG. 2A using the downward pointed arrow. Bulk acoustic wave resonators 2001C, 2001D may further comprise sixth piezoelectric layers 206C, 206D having respective reverse piezoelectric axis orientations, as depicted in FIG. 2A using the upward pointed arrow.

Accordingly, bulk acoustic wave resonators 2001A, 2001B may comprise respective alternating axis pairs of piezoelectric layers 201A, 202A, 201B, 202B, in which members of the pairs of piezoelectric layers 201A, 202A, 201B, 202B have respective thicknesses of approximately half acoustic wavelength of the main resonant frequencies of the bulk acoustic wave resonators 2001A, 2001B. Bulk acoustic wave resonators 2001C, 2001D may comprise respective six piezoelectric layers 201C, 202C, 203C, 204C, 205C, 206C, 201D, 202D, 203D, 204D, 205D, 206D in which the piezoelectric layers may have respective thicknesses of approximately half acoustic wavelength of the main resonant frequencies of the bulk acoustic wave resonators 2001C, 2001D.

In bulk acoustic wave resonator 2001A, a first interposer layer 259A may split the middle of first piezoelectric layer 201A. For example, first interposer layer 259A may split the half acoustic wavelength thickness of first piezoelectric layer 201A into two quarter acoustic wavelength thick sub-layers. In other words, first interposer layer 259A may be arranged along a central portion of the first half acoustic wavelength thick piezoelectric layer 201A. It is theorized that an acoustic energy peak may be placed at the location of the first interposer layer 259A, at the central portion of the first half acoustic wavelength thick piezoelectric layer 201A, during operation of the bulk acoustic wave resonator 2001A. It is theorized that relatively more acoustic energy may be present at the central portion of the first half acoustic wavelength thick piezoelectric layer 201A, during operation of the bulk acoustic wave resonator 2001A. It is theorized, that the first interposer layer 259A may have relatively more interaction with the relatively more acoustic energy present at the central portion of the first half acoustic wavelength thick piezoelectric layer 201A. It is theorized that this location arrangement of the first interposer layer 259A may produce relatively more mass loading effect from the first interposer layer 259A, for example, when the first interposer layer 259A comprises relatively low acoustic impedance material, e.g., Titanium (Ti), e.g., Silicon Dioxide (SiO2). It is theorized that this location arrangement of the first interposer layer 259A may produce relatively less mass loading effect from the first interposer layer 259A, for example, when the first interposer layer 259A comprises relatively high acoustic impedance material, e.g., Tungsten (W), e.g., Molybdenum (Mo).

In contrast, in bulk acoustic wave resonator 2001B, a first interposer layer 259B may be arranged between the half acoustic wave thickness of the first piezoelectric layer 201B and the half acoustic wave thickness of second piezoelectric layer 202B. It is theorized that an acoustic energy null may be placed at the location of the first interposer layer 259B, between the half acoustic wave thickness of the first piezoelectric layer 201B and the half acoustic wave thickness of second piezoelectric layer 202B, during operation of the bulk acoustic wave resonator 2001B. It is theorized that relatively less acoustic energy may be present at the location of the first interposer layer 259B, between the half acoustic wave thickness of the first piezoelectric layer 201B and the half acoustic wave thickness of second piezoelectric layer 202B, during operation of the bulk acoustic wave resonator 2001B. It is theorized, that the first interposer layer 259B may have relatively less interaction with the relatively less acoustic energy present at the location between the half acoustic wave thickness of the first piezoelectric layer 201B and the half acoustic wave thickness of second piezoelectric layer 202B. It is theorized that this location arrangement of the first interposer layer 259B may produce relatively less mass loading effect from the first interposer layer 259B, for example, when the first interposer layer 259B comprises relatively low acoustic impedance material, e.g., Titanium (Ti), e.g., Silicon Dioxide (SiO2). It is theorized that this location arrangement of the first interposer layer 259B may produce relatively more mass loading effect from the first interposer layer 259B, for example, when the first interposer layer 259B comprises relatively high acoustic impedance material, e.g., Tungsten (W), e.g., Molybdenum (Mo).

In bulk acoustic wave resonator 2001C, a first interposer layer 259C may split the middle of first piezoelectric layer 201C. For example, first interposer layer 259C may split the half acoustic wavelength thickness of first piezoelectric layer 201C into two quarter acoustic wavelength thick sub-layers. In other words, first interposer layer 259C may be arranged along a central portion of the first half acoustic wavelength thick piezoelectric layer 201C. It is theorized that an acoustic energy peak may be placed at the location of the first interposer layer 259C, at the central portion of the first half acoustic wavelength thick piezoelectric layer 201C, during operation of the bulk acoustic wave resonator 2001C. It is theorized that relatively more acoustic energy may be present at the central portion of the first half acoustic wavelength thick piezoelectric layer 201C, during operation of the bulk acoustic wave resonator 2001C. It is theorized, that the first interposer layer 259C may have relatively more interaction with the relatively more acoustic energy present at the central portion of the first half acoustic wavelength thick piezoelectric layer 201C. It is theorized that this location arrangement of the first interposer layer 259C may produce relatively more mass loading effect from the first interposer layer 259C, for example, when the first interposer layer 259C comprises relatively low acoustic impedance material, e.g., Titanium (Ti), e.g., Silicon Dioxide (SiO2). It is theorized that this location arrangement of the first interposer layer 259C may produce relatively less mass loading effect from the first interposer layer 259C, for example, when the first interposer layer 259C comprises relatively high acoustic impedance material, e.g., Tungsten (W), e.g., Molybdenum (Mo).

However, comparing bulk acoustic wave resonator 2001C to bulk acoustic wave resonator 2001A shows that bulk acoustic wave resonator 2001C has a greater number of piezoelectric layers than bulk acoustic wave resonator 2001A (e.g., six piezoelectric layers for bulk acoustic wave resonator 2001C versus just two piezoelectric layers for bulk acoustic wave resonator 2001A). It is theorized that the mass loading effect of first interposer layer 259C may be relatively less, due to the increased number of piezoelectric layers bulk acoustic wave resonator 2001C (e.g., six piezoelectric layers for bulk acoustic wave resonator 2001C versus just two piezoelectric layers for bulk acoustic wave resonator 2001A).

In bulk acoustic wave resonator 2001D, a first interposer layer 259D may be arranged between the half acoustic wave thickness of the first piezoelectric layer 201D and the half acoustic wave thickness of second piezoelectric layer 202D. It is theorized that an acoustic energy null may be placed at the location of the first interposer layer 259D, between the half acoustic wave thickness of the first piezoelectric layer 201D and the half acoustic wave thickness of second piezoelectric layer 202D, during operation of the bulk acoustic wave resonator 2001D. It is theorized that relatively less acoustic energy may be present at the location of the first interposer layer 259D, between the half acoustic wave thickness of the first piezoelectric layer 201D and the half acoustic wave thickness of second piezoelectric layer 202D, during operation of the bulk acoustic wave resonator 2001D. It is theorized, that the first interposer layer 259D may have relatively less interaction with the relatively less acoustic energy present at the location between the half acoustic wave thickness of the first piezoelectric layer 201D and the half acoustic wave thickness of second piezoelectric layer 202D. It is theorized that this location arrangement of the first interposer layer 259D may produce relatively less mass loading effect from the first interposer layer 259D, for example, when the first interposer layer 259D may comprise relatively low acoustic impedance material, e.g., Titanium (Ti), e.g., Silicon Dioxide (SiO2). It is theorized that this location arrangement of the first interposer layer 259D may produce relatively more mass loading effect from the first interposer layer 259D, for example, when the first interposer layer 259D may comprise relatively high acoustic impedance material, e.g., Tungsten (W), e.g., Molybdenum (Mo).

Further, comparing bulk acoustic wave resonator 2001D to bulk acoustic wave resonator 2001B shows that bulk acoustic wave resonator 2001B has a greater number of piezoelectric layers than bulk acoustic wave resonator 2001B (e.g., six piezoelectric layers for bulk acoustic wave resonator 2001D versus just two piezoelectric layers for bulk acoustic wave resonator 2001B). It is theorized that the mass loading effect of first interposer layer 259D may be relatively less, due to the increased number of piezoelectric layers bulk acoustic wave resonator 2001D (e.g., six piezoelectric layers for bulk acoustic wave resonator 2001D versus just two piezoelectric layers for bulk acoustic wave resonator 2001B).

FIG. 2B shows a first two diagrams 2019E, 2119E for different mass load materials and different mass load layer placement shown with bulk acoustic wave resonator interposer layer sensitivity versus number of alternating axis half wavelength thickness piezoelectric layers, as predicted by simulation. Diagram 2019E corresponds to the bulk acoustic wave resonators of this disclosure in which the interposer layer may comprise Titanium (Ti). For example trace 2021E depicted in solid line shows sensitivity for an interposer layer comprising Titanium (Ti) placed near an acoustic energy peak, e.g., the location of the first interposer layer 259A, at the central portion of the first half acoustic wavelength thick piezoelectric layer 201A, during operation of the bulk acoustic wave resonator 2001A as discussed previously herein with respect to FIG. 2A, e.g., the location of the first interposer layer 259C, at the central portion of the first half acoustic wavelength thick piezoelectric layer 201C, during operation of the bulk acoustic wave resonator 2001C as discussed previously herein with respect to FIG. 2A. As shown in example trace 2021E, mass load sensitivity to the interposer layer comprising Titanium (Ti) and arranged near the acoustic energy peak may range and decrease from about 10 Mhz of main resonant frequency downshift per Angstrom thickness of the interposer layer to about 4 Mhz of main resonant frequency downshift per Angstrom thickness of the interposer layer, as number of piezoelectric layers may range and increase from two (2) piezoelectric layers to six (6) piezoelectric layers.

For example trace 2023E depicted in dotted line shows sensitivity for an interposer layer comprising Titanium (Ti) placed near an acoustic energy null, e.g., the location of the first interposer layer 259B, between the first half acoustic wavelength thick piezoelectric layer 201B and the second half acoustic wavelength thick piezoelectric layer 202B, during operation of the bulk acoustic wave resonator 2001B as discussed previously herein with respect to FIG. 2A, e.g., the location of the first interposer layer 259D, between the first half acoustic wavelength thick piezoelectric layer 201D and the second half acoustic wavelength thick piezoelectric layer 202D, during operation of the bulk acoustic wave resonator 2001D as discussed previously herein with respect to FIG. 2A. As shown in trace 2023E, mass load sensitivity to the interposer layer comprising Titanium (Ti) and arranged near the acoustic energy null may range and decrease from about 7 Mhz of main resonant frequency downshift per Angstrom thickness of the interposer layer to about 2 Mhz of main resonant frequency downshift per Angstrom thickness of the interposer layer, as number of piezoelectric layers may range and increase from two (2) piezoelectric layers to six (6) piezoelectric layers.

Diagram 2119E corresponds to the bulk acoustic wave resonators of this disclosure in which the interposer layer may comprise Silicon Dioxide (SiO2). For example trace 2121E depicted in solid line shows sensitivity for an interposer layer comprising Silicon Dioxide (SiO2) placed near an acoustic energy peak, e.g., the location of the first interposer layer 259A, at the central portion of the first half acoustic wavelength thick piezoelectric layer 201A, during operation of the bulk acoustic wave resonator 2001A as discussed previously herein with respect to FIG. 2A, e.g., the location of the first interposer layer 259C, at the central portion of the first half acoustic wavelength thick piezoelectric layer 201C, during operation of the bulk acoustic wave resonator 2001C as discussed previously herein with respect to FIG. 2A. As shown in trace 2121E, mass load sensitivity to the interposer layer comprising Silicon Dioxide (SiO2) and arranged near the acoustic energy peak may range and decrease from about 12 Mhz of main resonant frequency downshift per Angstrom thickness of the interposer layer to about 4 Mhz of main resonant frequency downshift per Angstrom thickness of the interposer layer, as number of piezoelectric layers range and increase from two (2) piezoelectric layers to six (6) piezoelectric layers.

For example trace 2123E depicted in dotted line shows sensitivity for an interposer layer comprising Silicon Dioxide (SiO2) placed near an acoustic energy null, e.g., the location of the first interposer layer 259B, between the first half acoustic wavelength thick piezoelectric layer 201B and the second half acoustic wavelength thick piezoelectric layer 202B, during operation of the bulk acoustic wave resonator 2001B as discussed previously herein with respect to FIG. 2A, e.g., the location of the first interposer layer 259D, between the first half acoustic wavelength thick piezoelectric layer 201D and the second half acoustic wavelength thick piezoelectric layer 202D, during operation of the bulk acoustic wave resonator 2001D as discussed previously herein with respect to FIG. 2A. As shown in trace 2123E, mass load sensitivity to the interposer layer comprising Silicon Dioxide (SiO2) and arranged near the acoustic energy null may range and decrease from about 4 Mhz of main resonant frequency downshift per Angstrom thickness of the interposer layer to about 2 Mhz of main resonant frequency downshift per Angstrom thickness of the interposer layer, as number of piezoelectric layers range and increase from two (2) piezoelectric layers to six (6) piezoelectric layers.

FIG. 2C shows two diagrams 2219E, 2319E for different mass load materials and different mass load layer placement shown with bulk acoustic wave resonator interposer layer sensitivity versus number of alternating axis half wavelength thickness piezoelectric layers, as predicted by simulation. Diagram 2219E corresponds to the bulk acoustic wave resonators of this disclosure in which the interposer layer may comprise Molybdenum (Mo). For example trace 2221E depicted in solid line shows sensitivity for an interposer layer comprising Molybdenum (Mo) placed near an acoustic energy peak, e.g., the location of the first interposer layer 259A, at the central portion of the first half acoustic wavelength thick piezoelectric layer 201A, during operation of the bulk acoustic wave resonator 2001A as discussed previously herein with respect to FIG. 2A, e.g., the location of the first interposer layer 259C, at the central portion of the first half acoustic wavelength thick piezoelectric layer 201C, during operation of the bulk acoustic wave resonator 2001C as discussed previously herein with respect to FIG. 2A. As shown in example trace 2221E, mass load sensitivity to the interposer layer comprising Molybdenum (Mo) and arranged near the acoustic energy peak may range and decrease from about 7 Mhz of main resonant frequency downshift per Angstrom thickness of the interposer layer to about 4 Mhz of main resonant frequency downshift per Angstrom thickness of the interposer layer, as number of piezoelectric layers may range and increase from two (2) piezoelectric layers to six (6) piezoelectric layers.

For example trace 2223E depicted in dotted line shows sensitivity for an interposer layer comprising Molybdenum (Mo) placed near an acoustic energy null, e.g., the location of the first interposer layer 259B, between the first half acoustic wavelength thick piezoelectric layer 201B and the second half acoustic wavelength thick piezoelectric layer 202B, during operation of the bulk acoustic wave resonator 2001B as discussed previously herein with respect to FIG. 2A, e.g., the location of the first interposer layer 259D, between the first half acoustic wavelength thick piezoelectric layer 201D and the second half acoustic wavelength thick piezoelectric layer 202D, during operation of the bulk acoustic wave resonator 2001D as discussed previously herein with respect to FIG. 2A. As shown in trace 2223E, mass load sensitivity to the interposer layer comprising Molybdenum (Mo) and arranged near the acoustic energy null may range and decrease from about 15 Mhz of main resonant frequency downshift per Angstrom thickness of the interposer layer to about 5 Mhz of main resonant frequency downshift per Angstrom thickness of the interposer layer, as number of piezoelectric layers range and increase from two (2) piezoelectric layers to six (6) piezoelectric layers.

Diagram 2319E corresponds to the bulk acoustic wave resonators of this disclosure in which the interposer layer may comprise Tungsten (W). For example trace 2321E depicted in solid line shows sensitivity for an interposer layer comprising Tungsten (W) placed near an acoustic energy peak, e.g., the location of the first interposer layer 259A, at the central portion of the first half acoustic wavelength thick piezoelectric layer 201A, during operation of the bulk acoustic wave resonator 2001A as discussed previously herein with respect to FIG. 2A, e.g., the location of the first interposer layer 259C, at the central portion of the first half acoustic wavelength thick piezoelectric layer 201C, during operation of the bulk acoustic wave resonator 2001C as discussed previously herein with respect to FIG. 2A. As shown in example trace 2021E, mass load sensitivity to the interposer layer comprising Tungsten (W) and arranged near the acoustic energy peak may range and decrease from about 10 Mhz of main resonant frequency downshift per Angstrom thickness of the interposer layer to about 5 Mhz of main resonant frequency downshift per Angstrom thickness of the interposer layer, as number of piezoelectric layers may range and increase from two (2) piezoelectric layers to six (6) piezoelectric layers.

For example trace 2323E depicted in dotted line shows sensitivity for an interposer layer comprising Tungsten (W) placed near an acoustic energy null, e.g., the location of the first interposer layer 259B, between the first half acoustic wavelength thick piezoelectric layer 201B and the second half acoustic wavelength thick piezoelectric layer 202B, during operation of the bulk acoustic wave resonator 2001B as discussed previously herein with respect to FIG. 2A, e.g., the location of the first interposer layer 259D, between the first half acoustic wavelength thick piezoelectric layer 201D and the second half acoustic wavelength thick piezoelectric layer 202D, during operation of the bulk acoustic wave resonator 2001D as discussed previously herein with respect to FIG. 2A. As shown in trace 2323E, mass load sensitivity to the interposer layer comprising Tungsten (W) and arranged near the acoustic energy null may range and decrease from about 25 Mhz of main resonant frequency downshift per Angstrom thickness of the interposer layer to about 10 Mhz of main resonant frequency downshift per Angstrom thickness of the interposer layer, as number of piezoelectric layers range and increase from two (2) piezoelectric layers to six (6) piezoelectric layers.

Accordingly, it has been shown in simulation results of FIGS. 2B and 2C that interposer layer placement near an acoustic energy peak may produce relatively more mass loading effect from the first interposer layer, for example, when the first interposer layer comprises relatively low acoustic impedance material, e.g., Titanium (Ti), e.g., Silicon Dioxide (SiO2). However, it has been shown in simulation results that this location arrangement of the first interposer layer may produce relatively less mass loading effect from the first interposer layer, for example, when the first interposer layer comprises relatively high acoustic impedance material, e.g., Tungsten (W), e.g., Molybdenum (Mo).

Further, it has been shown in simulation results of FIGS. 2B and 2C that interposer layer placement near an acoustic energy null may produce relatively less mass loading effect from the first interposer layer, for example, when the first interposer layer comprises relatively low acoustic impedance material, e.g., Titanium (Ti), e.g., Silicon Dioxide (SiO2). However, it has been shown in simulation results that this location arrangement of the first interposer layer may produce relatively more mass loading effect from the first interposer layer, for example, when the first interposer layer comprises relatively high acoustic impedance material, e.g., Tungsten (W), e.g., Molybdenum (Mo).

It is theorized that there may be observed sensitivity effects in interposer location e.g., with respect to the peak or null of acoustic energy. This may be related to sound velocity e.g., average sound velocity of the stacks comprising AlN (with longitudinal wave sound velocity over 10 km/s) and e.g., W, Mo, Ti or SiO2 interposers (with longitudinal wave sound velocities in range from about 5 km/s to about 7 km/s). It is theorized that relatively low acoustic impedance interposer (e.g., Ti, e.g., SiO2) placed at the peak of acoustic energy may trap relatively more acoustic energy in the interposer region. This may effectively lower the average sound velocity in a composite stack comprising AlN and the relatively low acoustic impedance interposer (e.g., as less acoustic energy may be effectively confined in the relatively high acoustic velocity AlN). One the other hand, it is theorized that relatively high acoustic impedance interposer (e.g., W, e.g., Mo) placed at the peak of acoustic energy may anti-trap acoustic energy in the interposer region. This may increase the average sound velocity in the composite stack comprising AlN and the relatively high acoustic impedance interposer (e.g., as more acoustic energy may be effectively confined in the high acoustic velocity AlN). It is therefore theorized that the interposer layer formed of relatively low acoustic impedance (e.g., with respect to AlN) material (e.g., Ti, e.g., SiO2) placed at the peak of acoustic energy may have relatively more impact on frequency shift than the same layer placed at the null of the acoustic energy where the velocity averaging effect is weaker. It is therefore theorized that the interposer layer formed of relatively high acoustic impedance (e.g., with respect to AlN) material (e.g., W, e.g., Mo) placed at the peak of acoustic energy may have relatively less impact on frequency shift than the same layer placed at the null of the acoustic energy, e.g., where the velocity averaging effect is weaker.

Moreover, it has been shown in simulation results of FIGS. 2B and 2C that mass loading effect of the interposer layer may decrease, as number of piezoelectric layers may increase.

FIG. 2D shows further simplified views of four additional bulk acoustic wave resonators 2001F, 2001G, 2001H, 2001I. As shown, the four additional bulk acoustic wave resonators 2001F, 2001G, 2001H, 2001I comprise piezoelectric stacks of piezoelectric layers in alternating piezoelectric axis orientation arrangements, sandwiched between top acoustic reflector electrodes 2015F, 2015G, 2015H, 2015I and bottom acoustic reflector electrodes 2013F, 2013G, 2013H, 2013I. As shown, respective etched edges 253F, 253G, 253H, 253I (depicted in FIG. 2D using heavy dashed lines) may extend through the bottom acoustic reflector electrodes 2013F, 2013G, 2013H, 2013I, through the piezoelectric stacks and through the top acoustic reflector electrodes 2015F, 2015G, 2015H, 2015I. Respective opposing etched edges 254F, 254G, 254H, 254I (e.g., arranged opposing respective etched edges 253F, 253G, 253H, 253I) likewise may extend through the bottom acoustic reflector electrodes 2013F, 2013G, 2013H, 2013I, through the piezoelectric stacks and through the top acoustic reflector electrodes 2015F, 2015G, 2015H, 2015I.

Bulk acoustic wave resonators 2001F, 2001G, 2001H, 2001I may comprise first piezoelectric layers 201F, 201G, 201H, 201I having respective normal piezoelectric axis orientations, as depicted in FIG. 2D using the downward pointed arrow. Bulk acoustic wave resonators 2001F, 2001G, 2001H, 2001I may comprise second piezoelectric layers 202F, 202G, 202H, 202I having respective reverse piezoelectric axis orientations, as depicted in FIG. 2D using the upward pointed arrow.

As shown in FIG. 2D, bulk acoustic wave resonators 2001H, 2001I may further comprise third piezoelectric layers 203H, 203I having respective normal piezoelectric axis orientations, as depicted in FIG. 2D using the downward pointed arrow. Bulk acoustic wave resonators 2001H, 2001I may further comprise fourth piezoelectric layers 204H, 204I having respective reverse piezoelectric axis orientations, as depicted in FIG. 2D using the upward pointed arrow. Bulk acoustic wave resonators 2001H, 2001I may further comprise fifth piezoelectric layers 205H, 205I having respective normal piezoelectric axis orientations, as depicted in FIG. 2D using the downward pointed arrow. Bulk acoustic wave resonators 2001H, 2001I may further comprise sixth piezoelectric layers 206H, 206I having respective reverse piezoelectric axis orientations, as depicted in FIG. 2D using the upward pointed arrow.

Accordingly, bulk acoustic wave resonators 2001F, 2001G may comprise respective alternating axis pairs of piezoelectric layers 201F, 202F, 201G, 202G, in which members of the pairs of piezoelectric layers 201F, 202F, 201G, 202G have respective thicknesses of approximately half acoustic wavelength of the main resonant frequencies of the bulk acoustic wave resonators 2001F, 2001G. Bulk acoustic wave resonators 2001H, 2001I may comprise respective six piezoelectric layers 201H, 202H, 203H, 204H, 205H, 206H, 201I, 202I, 203I, 204I, 205I, 206I in which the piezoelectric layers may have respective thicknesses of approximately half acoustic wavelength of the main resonant frequencies of the bulk acoustic wave resonators 2001H, 2001I.

In bulk acoustic wave resonator 2001F, a first patterned interposer layer 259F may split the middle of first piezoelectric layer 201F. For example, first patterned interposer layer 259F may split the half acoustic wavelength thickness of first piezoelectric layer 201F into two quarter acoustic wavelength thick sub-layers. In other words, first patterned interposer layer 259F may be arranged along a central portion of the first half acoustic wavelength thick piezoelectric layer 201F. It is theorized that an acoustic energy peak may be placed at the location of the first patterned interposer layer 259F, at the central portion of the first half acoustic wavelength thick piezoelectric layer 201F, during operation of the bulk acoustic wave resonator 2001F. It is theorized that relatively more acoustic energy may be present at the central portion of the first half acoustic wavelength thick piezoelectric layer 201F, during operation of the bulk acoustic wave resonator 2001F. It is theorized, that the first patterned interposer layer 259F may have relatively more interaction with the relatively more acoustic energy present at the central portion of the first half acoustic wavelength thick piezoelectric layer 201F.

In contrast, in bulk acoustic wave resonator 2001G, a first patterned interposer layer 259G may be arranged between the half acoustic wave thickness of the first piezoelectric layer 201G and the half acoustic wave thickness of second piezoelectric layer 202G. It is theorized that an acoustic energy null may be placed at the location of the first patterned interposer layer 259G, between the half acoustic wave thickness of the first piezoelectric layer 201G and the half acoustic wave thickness of second piezoelectric layer 202G, during operation of the bulk acoustic wave resonator 2001G. It is theorized that relatively less acoustic energy may be present at the location of the first patterned interposer layer 259G, between the half acoustic wave thickness of the first piezoelectric layer 201G and the half acoustic wave thickness of second piezoelectric layer 202G, during operation of the bulk acoustic wave resonator 2001G. It is theorized, that the first patterned interposer layer 259G may have relatively less interaction with the relatively less acoustic energy present at the location between the half acoustic wave thickness of the first piezoelectric layer 201G and the half acoustic wave thickness of second piezoelectric layer 202G.

In bulk acoustic wave resonator 2001H, a first patterned interposer layer 259H may split the middle of first piezoelectric layer 201H. For example, first patterned interposer layer 259H may split the half acoustic wavelength thickness of first piezoelectric layer 201H into two quarter acoustic wavelength thick sub-layers. In other words, first patterned interposer layer 259H may be arranged along a central portion of the first half acoustic wavelength thick piezoelectric layer 201H. It is theorized that an acoustic energy peak may be placed at the location of the first patterned interposer layer 259H, at the central portion of the first half acoustic wavelength thick piezoelectric layer 201H, during operation of the bulk acoustic wave resonator 2001H. It is theorized that relatively more acoustic energy may be present at the central portion of the first half acoustic wavelength thick piezoelectric layer 201H, during operation of the bulk acoustic wave resonator 2001H. It is theorized, that the first patterned interposer layer 259H may have relatively more interaction with the relatively more acoustic energy present at the central portion of the first half acoustic wavelength thick piezoelectric layer 201H.

Comparing bulk acoustic wave resonator 2001H to bulk acoustic wave resonator 2001F shows that bulk acoustic wave resonator 2001H has a greater number of piezoelectric layers than bulk acoustic wave resonator 2001F (e.g., six piezoelectric layers for bulk acoustic wave resonator 2001H versus just two piezoelectric layers for bulk acoustic wave resonator 2001F). It is theorized that the mass loading effect of first patterned interposer layer 259H may be relatively less, due to the increased number of piezoelectric layers bulk acoustic wave resonator 2001H (e.g., six piezoelectric layers for bulk acoustic wave resonator 2001H versus just two piezoelectric layers for bulk acoustic wave resonator 2001F).

In bulk acoustic wave resonator 2001I, a first patterned interposer layer 259I may be arranged between the half acoustic wave thickness of the first piezoelectric layer 201I and the half acoustic wave thickness of second piezoelectric layer 202I. It is theorized that an acoustic energy null may be placed at the location of the first patterned interposer layer 259I, between the half acoustic wave thickness of the first piezoelectric layer 201I and the half acoustic wave thickness of second piezoelectric layer 202I, during operation of the bulk acoustic wave resonator 2001I. It is theorized that relatively less acoustic energy may be present at the location of the first patterned interposer layer 259I, between the half acoustic wave thickness of the first piezoelectric layer 201I and the half acoustic wave thickness of second piezoelectric layer 202I, during operation of the bulk acoustic wave resonator 2001I. It is theorized, that the first patterned interposer layer 259I may have relatively less interaction with the relatively less acoustic energy present at the location between the half acoustic wave thickness of the first piezoelectric layer 201I and the half acoustic wave thickness of second piezoelectric layer 202I.

Comparing bulk acoustic wave resonator 2001I to bulk acoustic wave resonator 2001G shows that bulk acoustic wave resonator 2001G has a greater number of piezoelectric layers than bulk acoustic wave resonator 2001G (e.g., six piezoelectric layers for bulk acoustic wave resonator 2001I versus just two piezoelectric layers for bulk acoustic wave resonator 2001G). It is theorized that the mass loading effect of first patterned interposer layer 259I may be relatively less, due to the increased number of piezoelectric layers bulk acoustic wave resonator 2001I (e.g., six piezoelectric layers for bulk acoustic wave resonator 2001I versus just two piezoelectric layers for bulk acoustic wave resonator 2001G).

The respective first patterned interposer layers 259F, 259G, 259H, 259I of bulk acoustic wave resonators 2001F, 2001G, 2001H, 2001I may comprise a first step mass feature having a first acoustic impedance. The respective first patterned interposer layers 259F, 259G, 259H, 259I of bulk acoustic wave resonators 2001F, 2001G, 2001H, 2001I may further comprise a second step mass feature having a second acoustic impedance. The first acoustic impedance may be different than the second acoustic impedance. More generally, the respective first patterned interposer layers 259F, 259G, 259H, 259I of bulk acoustic wave resonators 2001F, 2001G, 2001H, 2001I may comprise first and second materials that may be different from one another (e.g., first and second materials having respective acoustic impedances that may be different from one another). For example, the respective first patterned interposer layers 259F, 259G, 259H, 259I of bulk acoustic wave resonators 2001F, 2001G, 2001H, 2001I may comprise dielectric. For example, the respective first patterned interposer layers 259F, 259G, 259H, 259I of bulk acoustic wave resonators 2001F, 2001G, 2001H, 2001I may comprise first and second dielectrics that may be different from one another (e.g., first and second dielectrics having respective acoustic impedances that may be different from one another). The respective first patterned interposer layers 259F, 259G, 259H, 259I of bulk acoustic wave resonators 2001F, 2001G, 2001H, 2001I may comprise semiconductor. For example, the respective first patterned interposer layers 259F, 259G, 259H, 259I of bulk acoustic wave resonators 2001F, 2001G, 2001H, 2001I may comprise first and second semiconductors that may be different from one another (e.g., first and second semiconductors having respective acoustic impedances that may be different from one another). The respective first patterned interposer layers 259F, 259G, 259H, 259I of bulk acoustic wave resonators 2001F, 2001G, 2001H, 2001I may comprise metal. For example, the respective first patterned interposer layers 259F, 259G, 259H, 259I of bulk acoustic wave resonators 2001F, 2001G, 2001H, 2001I may comprise first and second metals that may be different from one another (e.g., first and second metals having respective acoustic impedances that may be different from one another).

The respective first patterned interposer layers 259F, 259G, 259H, 259I of bulk acoustic wave resonators 2001F, 2001G, 2001H, 2001I may comprise combinations of the foregoing. The respective first patterned interposer layers 259F, 259G, 259H, 259I of bulk acoustic wave resonators 2001F, 2001G, 2001H, 2001I may comprise a first metal and a first dielectric. The respective first patterned interposer layers 259F, 259G, 259H, 259I of bulk acoustic wave resonators 2001F, 2001G, 2001H, 2001I may comprise a first metal and a first semiconductor. The respective first patterned interposer layers 259F, 259G, 259H, 259I of bulk acoustic wave resonators 2001F, 2001G, 2001H, 2001I may comprise a first semiconductor and a first dielectric.

The respective first patterned interposer layers 259F, 259G, 259H, 259I of bulk acoustic wave resonators 2001F, 2001G, 2001H, 2001I may comprise respective first central features 262F, 262G, 262H, 262I having respective first central acoustic impedances (e.g. relatively low respective first central acoustic impedances). The respective first patterned interposer layers 259F, 259G, 259H, 259I of bulk acoustic wave resonators 2001F, 2001G, 2001H, 2001I may further comprise a respective first peripheral features having respective first peripheral acoustic impedances (e.g., relatively high first peripheral acoustic impedances) that are greater than the respective first central acoustic impedances (e.g., greater than the relatively low first central acoustic impedances).

For example, respective first central features 262F, 262G, 262H, 262I may comprise Titanium (Ti) having relatively low respective first central acoustic impedance, with respective first peripheral features comprising Tungsten (W) having relatively high first peripheral acoustic impedance. As another example, respective first central features 262F, 262G, 262H, 262I may comprise Titanium (Ti) having relatively low respective first central acoustic impedance, with respective first peripheral features comprising Molybdenum (Mo) having relatively high first peripheral acoustic impedance. Since Silicon Dioxide (SiO2) has relatively lower acoustic impedance than Titanium (Ti), in another example, respective first central features 262F, 262G, 262H, 262I may comprise Silicon Dioxide (SiO2) having relatively lower respective first central acoustic impedance, with respective first peripheral features comprising Titanium (Ti) having relatively higher first peripheral acoustic impedance. In another example, respective first central features 262F, 262G, 262H, 262I may comprise Silicon Dioxide (SiO2) having relatively low respective first central acoustic impedance, with respective first peripheral features comprising Tungsten (W) having relatively high first peripheral acoustic impedance. The respective first peripheral features having the respective first peripheral acoustic impedance that is greater than first central acoustic impedance of the respective first central features 262F, 262G, 262H, 262I may, but need not facilitate a quality factor enhancement of the bulk acoustic wave resonators 2001F, 2001G, 2001H, 2001I shown in FIG. 2D.

As just discussed, the respective first patterned interposer layers 259F, 259G, 259H, 259I of bulk acoustic wave resonators 2001F, 2001G, 2001H, 2001I may comprise a respective first peripheral features having respective first peripheral acoustic impedance. In alternative examples to those just discussed, the respective first patterned interposer layers 259F, 259G, 259H, 259I of bulk acoustic wave resonators 2001F, 2001G, 2001H, 2001I may further comprise respective first central features 262F, 262G, 262H, 262I having respective first central acoustic impedance that is greater than the respective first peripheral acoustic impedance. The respective first central features 262F, 262G, 262H, 262I having the respective first central acoustic impedance that is greater than respective first peripheral acoustic impedance of the respective first peripheral features may, but need not facilitate a quality factor enhancement of the bulk acoustic wave resonators 2001F, 2001G, 2001H, 2001I shown in FIG. 2D.

The respective first patterned interposer layers 259F, 259G, 259H, 259I of bulk acoustic wave resonators 2001F, 2001G, 2001H, 2001I may comprise respective first central features 262F, 262G, 262H, 262I, and may further comprise a first peripheral feature having a first width dimension. The first width dimension of the first peripheral feature may be within a range from approximately a tenth of a percent of a width of the active piezoelectric volume to approximately ten percent of a width of the active piezoelectric volume. The first width dimension of the first peripheral feature being within a range from approximately a tenth of a percent of a width of the active piezoelectric volume to approximately ten percent of a width of the active piezoelectric volume may, but need not facilitate a quality factor enhancement of the bulk acoustic wave resonators 2001F, 2001G, 2001H, 2001I shown in FIG. 2D.

The respective first patterned interposer layers 259F, 259G, 259H, 259I of bulk acoustic wave resonators 2001F, 2001G, 2001H, 2001I may comprise respective first peripheral features, and may further comprise a respective first central features 262F, 262G, 262H, 262I having respective first width dimensions. The respective first width dimensions of the respective first central features 262F, 262G, 262H, 262I may be within a range from approximately ninety percent of a width of the active piezoelectric volume to approximately ninety-nine and nine tenths percent of a width of the active piezoelectric volume. The respective first width dimensions of the respective first central features 262F, 262G, 262H, 262I being within the range from approximately ninety percent of the width of the active piezoelectric volume to approximately ninety-nine and nine tenths percent of a width of the active piezoelectric volume may, but need not facilitate a quality factor enhancement of the bulk acoustic wave resonators 2001F, 2001G, 2001H, 2001I shown in FIG. 2D.

FIG. 2E shows a first two diagrams 2019J, 2119J for different patterned interposer layer materials and patterned interposer layer placement shown with bulk acoustic wave resonator patterned interposer layer sensitivity versus number of alternating axis half wavelength thickness piezoelectric layers, as predicted by simulation. For example, FIG. 2E may show a subtracted difference between mass sensitivity of the peripheral feature and the mass sensitivity of the central feature, e.g., the mass sensitivity in the peripheral feature less (e.g., minus) the mass sensitivity in the central feature. Diagram 2019J corresponds to example bulk acoustic wave resonators of this disclosure comprising patterned interposer layers that include central features that may comprise Titanium (Ti) and peripheral features that may comprise Tungsten (W). For example, as discussed previously herein with respect to FIG. 2D, respective first patterned interposer layers 259F, 259G, 259H, 259I may include respective first central features 262F, 262G, 262H, 262I that may comprise Titanium (Ti) having relatively low respective first central acoustic impedance, with respective first peripheral features that may comprise Tungsten (W) having relatively high respective first peripheral acoustic impedance.

For example trace 2021J depicted in solid line shows sensitivity for a patterned interposer layer comprising central feature (e.g., Titanium (Ti)) and peripheral feature (e.g., Tungsten (W)) placed near an acoustic energy peak, e.g., the location of the first patterned interposer layer 259F, at the central portion of the first half acoustic wavelength thick piezoelectric layer 201F, during operation of the bulk acoustic wave resonator 2001F as discussed previously herein with respect to FIG. 2D, e.g., the location of the first patterned interposer layer 259H, at the central portion of the first half acoustic wavelength thick piezoelectric layer 201H, during operation of the bulk acoustic wave resonator 2001H as discussed previously herein with respect to FIG. 2D. As shown in example trace 2021J, mass load sensitivity to the patterned interposer layer comprising central feature (e.g., Titanium (Ti)) and peripheral feature (e.g., Tungsten (W)) and arranged near the acoustic energy peak may range and from about −1 Mhz of main resonant frequency upshift per Angstrom thickness of the patterned interposer layer to about 0 Mhz of main resonant frequency shift per Angstrom thickness of the patterned interposer layer, as number of piezoelectric layers may range and increase from two (2) piezoelectric layers to six (6) piezoelectric layers.

For example trace 2023J depicted in dotted line shows sensitivity for a patterned interposer layer comprising central feature (e.g., Titanium (Ti)) and peripheral feature (e.g., Tungsten (W)) placed near an acoustic energy null, e.g., the location of the first patterned interposer layer 259G, between the first half acoustic wavelength thick piezoelectric layer 201G and the second half acoustic wavelength thick piezoelectric layer 202G, during operation of the bulk acoustic wave resonator 2001G as discussed previously herein with respect to FIG. 2D, e.g., the location of the first patterned interposer layer 259I, between the first half acoustic wavelength thick piezoelectric layer 201I and the second half acoustic wavelength thick piezoelectric layer 202I, during operation of the bulk acoustic wave resonator 2001I as discussed previously herein with respect to FIG. 2D. As shown in trace 2023J, mass load sensitivity to the patterned interposer layer comprising central feature (e.g., Titanium (Ti)) and peripheral feature (e.g., Tungsten (W)), and arranged near the acoustic energy null may range and decrease from about 23 Mhz of main resonant frequency downshift per Angstrom thickness of the patterned interposer layer to about 6 Mhz of main resonant frequency downshift per Angstrom thickness of the patterned interposer layer, as number of piezoelectric layers may range and increase from two (2) piezoelectric layers to six (6) piezoelectric layers.

Diagram 2119J corresponds to example bulk acoustic wave resonators of this disclosure comprising patterned interposer layers that include central features that may comprise Titanium (Ti) and peripheral features that may comprise Molybdenum (Mo). For example, as discussed previously herein with respect to FIG. 2D, respective first patterned interposer layers 259F, 259G, 259H, 259I may include respective first central features 262F, 262G, 262H, 262I that may comprise Titanium (Ti) having relatively low respective first central acoustic impedance, with respective first peripheral features that may comprise Molybdenum (Mo) having relatively high respective first peripheral acoustic impedance. For example trace 2121J depicted in solid line shows sensitivity for a patterned interposer layer comprising central feature (e.g., Titanium (Ti)) and peripheral feature (e.g., Tungsten (W)) placed near an acoustic energy peak, e.g., the location of the first patterned interposer layer 259F, at the central portion of the first half acoustic wavelength thick piezoelectric layer 201F, during operation of the bulk acoustic wave resonator 2001F as discussed previously herein with respect to FIG. 2D, e.g., the location of the first patterned interposer layer 259H, at the central portion of the first half acoustic wavelength thick piezoelectric layer 201H, during operation of the bulk acoustic wave resonator 2001H as discussed previously herein with respect to FIG. 2D. As shown in trace 2121J, mass load sensitivity to the patterned interposer layer comprising central feature (e.g., Titanium (Ti)) and peripheral feature (e.g., Tungsten (W)), and arranged near the acoustic energy peak may range and from about −4 Mhz of main resonant frequency upshift per Angstrom thickness of the patterned interposer layer to about 0 Mhz of main resonant frequency shift per Angstrom thickness of the patterned interposer layer, as number of piezoelectric layers range and increase from two (2) piezoelectric layers to six (6) piezoelectric layers.

For example trace 2123J depicted in dotted line shows sensitivity for a patterned interposer layer comprising central feature (e.g., Titanium (Ti)) and peripheral feature (e.g., Tungsten (W)) placed near an acoustic energy null, e.g., the location of the first patterned interposer layer 259G, between the first half acoustic wavelength thick piezoelectric layer 201G and the second half acoustic wavelength thick piezoelectric layer 202G, during operation of the bulk acoustic wave resonator 2001G as discussed previously herein with respect to FIG. 2D, e.g., the location of the first patterned interposer layer 259I, between the first half acoustic wavelength thick piezoelectric layer 201I and the second half acoustic wavelength thick piezoelectric layer 202I, during operation of the bulk acoustic wave resonator 2001I as discussed previously herein with respect to FIG. 2D. As shown in trace 2123J, mass load sensitivity to the patterned interposer layer comprising central feature (e.g., Titanium (Ti)) and peripheral feature (e.g., Tungsten (W)) and arranged near the acoustic energy null may range and decrease from about 7 Mhz of main resonant frequency downshift per Angstrom thickness of the patterned interposer layer to about 4 Mhz of main resonant frequency downshift per Angstrom thickness of the patterned interposer layer, as number of piezoelectric layers range and increase from two (2) piezoelectric layers to six (6) piezoelectric layers.

FIG. 2F shows two diagrams 2219J, 2319J for different patterned interposer layer materials and patterned interposer layer placement shown with bulk acoustic wave resonator patterned interposer layer sensitivity versus number of alternating axis half wavelength thickness piezoelectric layers, as predicted by simulation. For example, FIG. 2F may show a subtracted difference between mass sensitivity of the peripheral feature and the mass sensitivity of the central feature, e.g., the mass sensitivity in the peripheral feature less (e.g., minus) the mass sensitivity in the central feature. Diagram 2219J corresponds to example bulk acoustic wave resonators of this disclosure comprising patterned interposer layers that include central features that may comprise Silicon Dioxide (SiO2) and peripheral features that may comprise Titanium (Ti). For example, as discussed previously herein with respect to FIG. 2D, respective first patterned interposer layers 259F, 259G, 259H, 259I may include respective first central features 262F, 262G, 262H, 262I that may comprise Silicon Dioxide (SiO2) having relatively low respective first central acoustic impedance, with respective first peripheral features that may comprise Titanium (Ti) having relatively higher respective first peripheral acoustic impedance.

For example trace 2221J depicted in solid line shows sensitivity for a patterned interposer layer comprising central feature (e.g., Silicon Dioxide (SiO2)) and peripheral feature (e.g., Titanium (Ti)) placed near an acoustic energy peak, e.g., the location of the first patterned interposer layer 259F, at the central portion of the first half acoustic wavelength thick piezoelectric layer 201F, during operation of the bulk acoustic wave resonator 2001F as discussed previously herein with respect to FIG. 2D, e.g., the location of the first patterned interposer layer 259H, at the central portion of the first half acoustic wavelength thick piezoelectric layer 201H, during operation of the bulk acoustic wave resonator 2001H as discussed previously herein with respect to FIG. 2D. As shown in example trace 2221J, mass load sensitivity to the patterned interposer layer comprising central feature (e.g., Silicon Dioxide (SiO2)) and peripheral feature (e.g., Titanium (Ti)), and arranged near the acoustic energy peak may range from about −7 Mhz of main resonant frequency upshift per Angstrom thickness of the patterned interposer layer to about −2 Mhz of main resonant frequency upshift per Angstrom thickness of the patterned interposer layer, as number of piezoelectric layers may range and increase from two (2) piezoelectric layers to six (6) piezoelectric layers.

For example trace 2223J depicted in dotted line shows sensitivity for the patterned interposer layer comprising central feature (e.g., Silicon Dioxide (SiO2)) and peripheral feature (e.g., Titanium (Ti)) placed near an acoustic energy null, e.g., the location of the first patterned interposer layer 259G, between the first half acoustic wavelength thick piezoelectric layer 201G and the second half acoustic wavelength thick piezoelectric layer 202G, during operation of the bulk acoustic wave resonator 2001G as discussed previously herein with respect to FIG. 2D, e.g., the location of the first patterned interposer layer 259I, between the first half acoustic wavelength thick piezoelectric layer 201I and the second half acoustic wavelength thick piezoelectric layer 202I, during operation of the bulk acoustic wave resonator 2001I as discussed previously herein with respect to FIG. 2D. As shown in trace 2223J, mass load sensitivity to the patterned interposer layer comprising central feature (e.g., Silicon Dioxide (SiO2)) and peripheral feature (e.g., Titanium (Ti)), and arranged near the acoustic energy null may range and decrease from about 4 Mhz of main resonant frequency downshift per Angstrom thickness of the patterned interposer layer to about 1 Mhz of main resonant frequency downshift per Angstrom thickness of the patterned interposer layer, as number of piezoelectric layers range and increase from two (2) piezoelectric layers to six (6) piezoelectric layers.

Diagram 2319J corresponds to example bulk acoustic wave resonators of this disclosure comprising patterned interposer layers that include central features that may comprise Silicon Dioxide (SiO2) and peripheral features that may comprise Tungsten (W). For example, as discussed previously herein with respect to FIG. 2D, respective first patterned interposer layers 259F, 259G, 259H, 259I may include respective first central features 262F, 262G, 262H, 262I that may comprise Silicon Dioxide (SiO2) having relatively low respective first central acoustic impedance, with respective first peripheral features that may comprise Tungsten (W) having relatively high respective first peripheral acoustic impedance.

For example trace 2321J depicted in solid line shows sensitivity for a patterned interposer layer comprising central feature (e.g., Silicon Dioxide (SiO2)) and peripheral feature (e.g., Tungsten (W)) placed near an acoustic energy peak, e.g., the location of the first patterned interposer layer 259F, at the central portion of the first half acoustic wavelength thick piezoelectric layer 201F, during operation of the bulk acoustic wave resonator 2001F as discussed previously herein with respect to FIG. 2D, e.g., the location of the first patterned interposer layer 259H, at the central portion of the first half acoustic wavelength thick piezoelectric layer 201H, during operation of the bulk acoustic wave resonator 2001H as discussed previously herein with respect to FIG. 2D. As shown in example trace 2021J, mass load sensitivity to the patterned interposer layer comprising central feature (e.g., Silicon Dioxide (SiO2)) and peripheral feature (e.g., Tungsten (W)), and arranged near the acoustic energy peak may range from about −7 Mhz of main resonant frequency upshift per Angstrom thickness of the patterned interposer layer to about −1 Mhz of main resonant frequency upshift per Angstrom thickness of the patterned interposer layer, as number of piezoelectric layers may range and increase from two (2) piezoelectric layers to six (6) piezoelectric layers.

For example trace 2323J depicted in dotted line shows sensitivity for a patterned interposer layer comprising central feature (e.g., Silicon Dioxide (SiO2)) and peripheral feature (e.g., Tungsten (W)) placed near an acoustic energy null, e.g., the location of the first patterned interposer layer 259G, between the first half acoustic wavelength thick piezoelectric layer 201G and the second half acoustic wavelength thick piezoelectric layer 202G, during operation of the bulk acoustic wave resonator 2001G as discussed previously herein with respect to FIG. 2D, e.g., the location of the first patterned interposer layer 259I, between the first half acoustic wavelength thick piezoelectric layer 201I and the second half acoustic wavelength thick piezoelectric layer 202I, during operation of the bulk acoustic wave resonator 2001I as discussed previously herein with respect to FIG. 2D. As shown in trace 2323J, mass load sensitivity to the patterned interposer layer comprising central feature (e.g., Silicon Dioxide (SiO2)) and peripheral feature (e.g., Tungsten (W)), and arranged near the acoustic energy null may range and decrease from about 22 Mhz of main resonant frequency downshift per Angstrom thickness of the patterned interposer layer to about 8 Mhz of main resonant frequency downshift per Angstrom thickness of the patterned interposer layer, as number of piezoelectric layers range and increase from two (2) piezoelectric layers to six (6) piezoelectric layers.

It should be pointed out that for simplicity of notation, the sensitivity values presented in FIGS. 2B and 2C may correspond to negative shifts of main resonant frequency (e.g., series main resonant frequency) when an interposer layer is added. Thus, for example, sensitivity of 1 MHz/A corresponds to lowering of series main resonant frequency of the bulk acoustic wave resonator by one MegaHertz (1 MHz) when a one angstrom (1 A) thick interposer layer may be added to the stack. It should also be pointed out that for simplicity of notation, the sensitivity values presented in FIGS. 2E and 2F may correspond to negative shifts of main resonant frequency, e.g., when the interposer layer having the central feature and having the perimeter feature is added. Thus, for example, sensitivity of 1 MHz/A corresponds to lowering of series main resonant frequency in the perimeter feature region of the bulk acoustic wave resonator with respect to the central feature region of the bulk acoustic wave resonator by one MegaHertz (1 MHz), e.g., when a one angstrom (1 A) thick interposer layer may be added to the stack.

It should be understood that differing combinations may be employed, e.g., reverse combinations may be employed. For example, materials of central features just discussed and materials of peripheral features just discussed may be reversed. With materials of central features just discussed and materials of peripheral features just discussed reversed simulation results of FIGS. 2E and 2F may be reversed, relative to the zero sensitivity axes of corresponding charts 2019J, 2119J, 2219J and 2319J.

FIG. 2G shows further simplified views of an additional five bulk acoustic wave resonators 2001K, 2001L, 2001M, 2001N, 2001O.

FIG. 2H shows further simplified views of another additional five bulk acoustic wave resonators 2001P, 2001Q, 2001R, 2001S, 2001T.

As shown, the ten bulk acoustic wave resonators 2001K, 2001L, 2001M, 2001N, 2001O, 2001P, 2001Q, 2001R, 2001S, 2001T comprise respective piezoelectric stacks of piezoelectric layers in alternating piezoelectric axis orientation arrangements, sandwiched between respective top acoustic reflector electrodes 2015K, 2015L, 2015M, 2015N, 2015O, 2015P, 2015Q, 2015S, 2015T and respective bottom acoustic reflector electrodes 2013K, 2013L, 2013M, 2013N, 2013O, 2013P, 2013Q, 2013S, 2013T.

Bulk acoustic wave resonators 2001K, 2001L, 2001M, 2001N, 2001O, 2001P, 2001Q, 2001R, 2001S, 2001T may comprise respective first piezoelectric layers 201K, 201L, 201M, 201N, 201O, 201P, 201R, 201S, 201T having normal piezoelectric axis orientation. Bulk acoustic wave resonators 2001K, 2001L, 2001M, 2001N, 2001O, 2001P, 2001Q, 2001R, 2001S, 2001T may comprise respective second piezoelectric layers 202K, 202L, 202M, 202N, 202O, 202P, 202R, 202S, 202T having respective reverse piezoelectric axis orientations. Bulk acoustic wave resonators 2001K, 2001L, 2001M, 2001N, 2001O, 2001P, 2001Q, 2001R, 2001S, 2001T may comprise respective third piezoelectric layers 203K, 203L, 203M, 203N, 203O, 203P, 203R, 203S, 203T having respective normal piezoelectric axis orientation. Bulk acoustic wave resonators 2001K, 2001L, 2001M, 2001N, 2001O, 2001P, 2001Q, 2001R, 2001S, 2001T may comprise respective fourth piezoelectric layers 204K, 204L, 204M, 204N, 204O, 204P, 204R, 204S, 204T having respective reverse piezoelectric axis orientations. Bulk acoustic wave resonators 2001K, 2001L, 2001M, 2001N, 2001O, 2001P, 2001Q, 2001R, 2001S, 2001T may comprise respective four piezoelectric layers in which the piezoelectric layers may have respective thicknesses of approximately half acoustic wavelength of the main resonant frequencies of the bulk acoustic wave resonators 2001K, 2001L, 2001M, 2001N, 2001O, 2001P, 2001Q, 2001R, 2001S, 2001T.

Bulk acoustic wave resonators 2001K, 2001M, 2001N, 2001O, 2001P, 2001R, 2001S, 2001T may further comprise respective first interposer layers 259K, 259M, 259N, 259O, 259P, 259R, 259S, 259T of a respective first material having respective first acoustic impedances. Respective first interposer layers 259K, 259M, 259N, 259O, 259P, 259R, 259S, 259T may be respectively arranged at respective central regions of respective first piezoelectric layers 201K, 201M, 201N, 201O, 201P, 201R, 201S, 201T, e.g., having respective first piezoelectric axes orientations, e.g., respective normal piezoelectric axes orientations. For example, respective first interposer layers 259K, 259M, 259N, 259O, 259P, 259R, 259S, 259T may be respectively arranged near peaks of acoustic energy of respective first piezoelectric layers 201K, 201M, 201N, 201O, 201P, 201R, 201S, 201T, in operation of bulk acoustic wave resonators 2001K, 2001M, 2001N, 2001O, 2001P, 2001R, 2001S, 2001T.

Respective first interposer layers 259M, 259N, 259O, 259R, 259S, 259T may be respective first patterned interposer layers 259M, 259N, 259O, 259R, 259S, 259T. Respective first patterned interposer layers 259M, 259N, 259O, 259R, 259S, 259T may include respective central features. Respective central features of respective first patterned interposer layers 259M, 259N, 259O, 259R, 259S, 259T may respectively comprise the first material. Respective first patterned interposer layers 259M, 259N, 259O, 259R, 259S, 259T may include respective peripheral features. Respective peripheral features of respective first patterned interposer layers 259M, 259N, 259O, 259R, 259S, 259T may respectively comprise the first material.

Respective first patterned interposer layers 259R, 259S, 259T of bulk acoustic wave resonator 2001R, 2001S, 2001T shown in FIG. 2H may further include additional peripheral features. Respective additional peripheral features of respective first patterned interposer layers 259R, 259S, 259T may comprise the second material. For respective first patterned interposer layers 259R, 259S, 259T of bulk acoustic wave resonators 2001R, 2001S, 2001T shown in FIG. 2H, the respective additional peripheral features of respective first patterned interposer layer 259R, 259S, 259T (e.g., comprising the second material) may be interposed between respective central features (e.g., comprising the first material) of respective first patterned interposer layers 259R, 259S, 259T and respective peripheral features (e.g., comprising the first material) of respective first patterned interposer layers 259R, 259S, 259T.

Bulk acoustic wave resonators 2001K, 2001L, 2001M, 2001N, 2001O, 2001P, 2001Q, 2001R, 2001S, 2001T may further comprise respective second patterned interposer layers 261K, 261L, 261M, 261N, 261O, 261P, 261Q, 261R, 261S, 261T of a respective second material having respective second acoustic impedances. First and second materials may be various different materials, as discussed previously herein. First and second acoustic impedances may be different acoustic impedances, as discussed previously herein. Respective second patterned interposer layers 261K, 261L, 261M, 261N, 261O, 261P, 261Q, 261R, 261S, 261T may include respective central features. Respective central features of respective second patterned interposer layers 261K, 261L, 261M, 261N, 261O, 261P, 261Q, 261R, 261S, 261T may respectively comprise the second material. Respective second patterned interposer layers 261K, 261L, 261M, 261N, 261O, 261P, 261Q, 261R, 261S, 261T may include respective peripheral features. Respective peripheral features of respective second patterned interposer layers 261K, 261L, 261M, 261N, 261O, 261P, 261Q, 261R, 261S, 261T may respectively comprise the second material.

Respective second patterned interposer layers 261P, 261Q, 261R, 261T of bulk acoustic wave resonator 2001P, 2001Q, 2001R, 2001T shown in FIG. 2H may further include additional peripheral features. Respective additional peripheral features of respective second patterned interposer layers 261P, 261Q, 261R, 261T may comprise the first material. For respective second patterned interposer layers 261P, 261Q, 261R, 261T of bulk acoustic wave resonators 2001P, 2001Q, 2001R, 2001T shown in FIG. 2H, the respective additional peripheral features of respective second patterned interposer layer 261P, 261Q, 261R, 261T (e.g., comprising the first material) may be interposed between respective central features (e.g., comprising the second material) of respective second patterned interposer layers 261P, 261Q, 261R, 261T and respective peripheral features (e.g., comprising the second material) of respective second patterned interposer layers 261P, 261Q, 261R, 261T.

Respective second patterned interposer layers 261K, 261L, 261M, 261N, 261O, 261P, 261Q, 261R, 261S, 261T of bulk acoustic wave resonators 2001K, 2001L, 2001M, 2001N, 2001O, 2001P, 2001Q, 2001R, 2001S, 2001T may be respectively arranged at respective central regions of respective second piezoelectric layers 202K, 202L, 202M, 202N, 202O, 202P, 202Q, 202R, 202S, 202T, e.g., having respective second piezoelectric axes orientations, e.g., respective reverse piezoelectric axes orientations. For example, respective second patterned interposer layers 261K, 261L, 261M, 261N, 261O, 261P, 261Q, 261R, 261S, 261T may be respectively arranged near peaks of acoustic energy of respective second piezoelectric layers 202K, 202L, 202M, 202N, 202O, 202P, 202Q, 202R, 202S, 202T, in operation of bulk acoustic wave resonators 2001K, 2001L, 2001M, 2001N, 2001O, 2001P, 2001Q, 2001R, 2001S, 2001T.

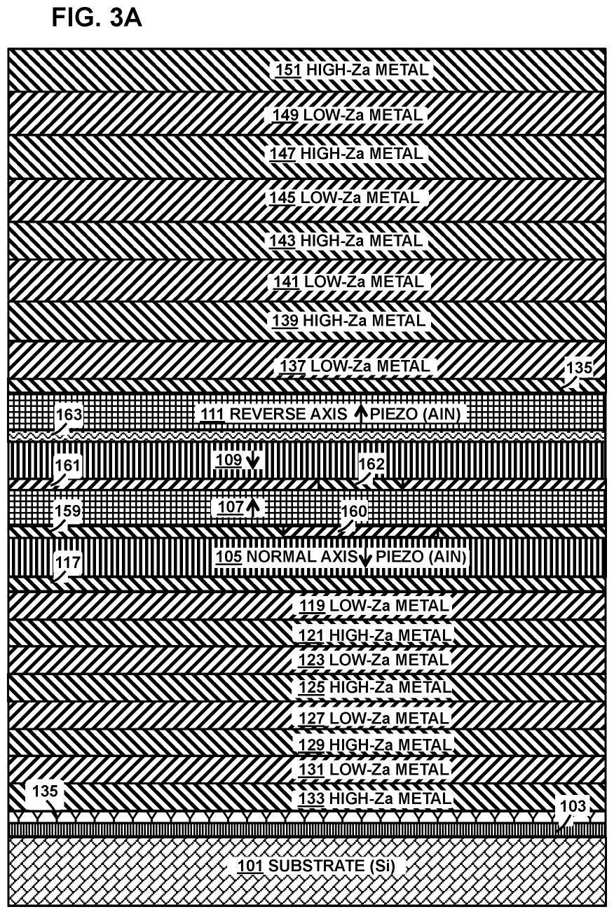

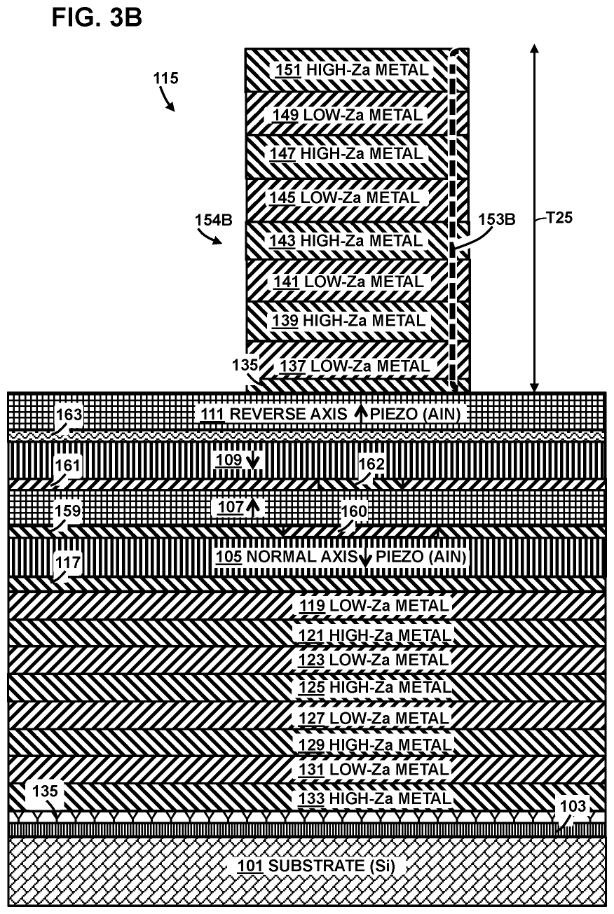

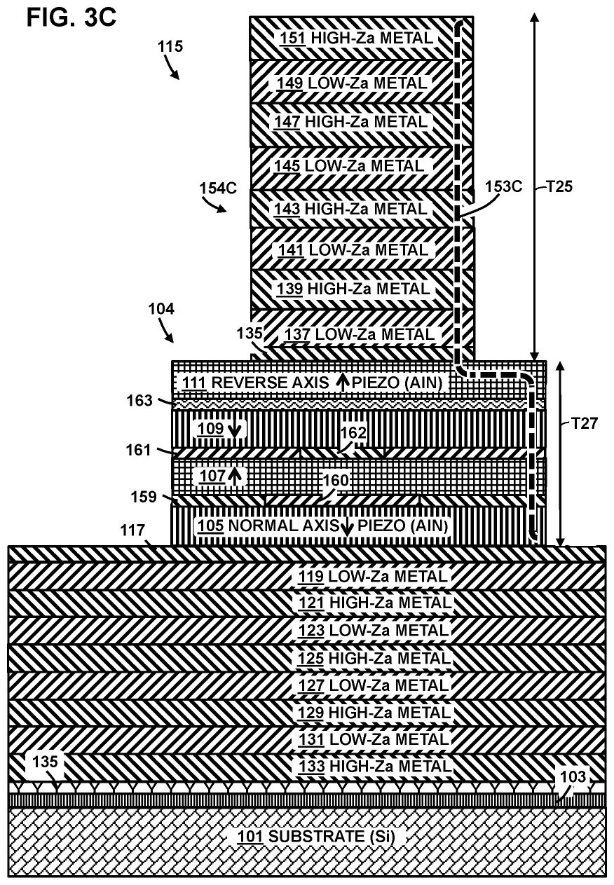

FIGS. 3A through 3D illustrate example integrated circuit structures used to form the example bulk acoustic wave resonator structure of FIG. 1A. As shown in FIG. 3A, magnetron sputtering may sequentially deposit layers on silicon substrate 101. Initially, a seed layer 103 of suitable material (e.g., aluminum nitride (AlN), e.g., silicon dioxide (SiO₂), e.g., aluminum oxide (Al₂O₃), e.g., silicon nitride (Si₃N₄), e.g., amorphous silicon (a-Si), e.g., silicon carbide (SiC)) may be deposited, for example, by sputtering from a respective target (e.g., from an aluminum, silicon, or silicon carbide target). The seed layer may have a layer thickness in a range from approximately one hundred Angstroms (100 A) to approximately one micron (1 um). Next, bottom current spreading layer 135 may be sputter deposited. As bottom current spreading layer teachings e.g., bottom current spreading layer structure, e.g., bottom current spreading layer materials, have already been discussed in detail previously herein, for brevity and clarity, they are referenced and incorporated rather than explicitly repeated herein.

Next, successive pairs of alternating layers of high acoustic impedance metal and low acoustic impedance metal may be deposited by alternating sputtering from targets of high acoustic impedance metal and low acoustic impedance metal. For example, sputtering targets of high acoustic impedance metal such as Molybdenum or Tungsten may be used for sputtering the high acoustic impedance metal layers, and sputtering targets of low acoustic impedance metal such as Aluminum or Titanium may be used for sputtering the low acoustic impedance metal layers. For example, the fourth pair of bottom metal electrode layers, 133, 131, may be deposited by sputtering the high acoustic impedance metal for a first bottom metal electrode layer 133 of the pair on the seed layer 103, and then sputtering the low acoustic impedance metal for a second bottom metal electrode layer 131 of the pair on the first layer 133 of the pair. Similarly, the third pair of bottom metal electrode layers, 129, 127, may then be deposited by sequentially sputtering from the high acoustic impedance metal target and the low acoustic impedance metal target. Similarly, the second pair of bottom metal electrodes 125, 123, may then be deposited by sequentially sputtering from the high acoustic impedance metal target and the low acoustic impedance metal target. Similarly, the first pair of bottom metal electrodes 121, 119, may then be deposited by sequentially sputtering from the high acoustic impedance metal target and the low acoustic impedance metal target. Respective layer thicknesses of bottom metal electrode layers of the first, second, third and fourth pairs 119, 121, 123, 125, 127, 129, 131, 133 may correspond to approximately a quarter wavelength (e.g., a quarter of an acoustic wavelength) of the resonant frequency at the resonator (e.g., respective layer thickness of about six hundred Angstroms (660 A) for the example 24 GHz resonator). Initial bottom electrode layer 119 may then be deposited by sputtering from the high acoustic impedance metal target. Thickness of the initial bottom electrode layer may be, for example, about an eighth wavelength (e.g., an eighth of an acoustic wavelength) of the resonant frequency of the resonator (e.g., layer thickness of about three hundred Angstroms (300 A) for the example 24 GHz resonator).

A stack of four layers of piezoelectric material, for example, four layers of Aluminum Nitride (AlN) having the wurtzite structure may be deposited by sputtering. For example, bottom piezoelectric layer 105, first middle piezoelectric layer 107, second middle piezoelectric layer 109, and top piezoelectric layer 111 may be deposited by sputtering. The four layers of piezoelectric material in the stack 104, may have the alternating axis arrangement in the respective stack 104. For example the bottom piezoelectric layer 105 may be sputter deposited to have the normal axis orientation, which is depicted in FIG. 3A using the downward directed arrow. The first middle piezoelectric layer 107 may be sputter deposited to have the reverse axis orientation, which is depicted in the FIG. 3A using the upward directed arrow. The second middle piezoelectric layer 109 may have the normal axis orientation, which is depicted in the FIG. 3A using the downward directed arrow. The top piezoelectric layer may have the reverse axis orientation, which is depicted in the FIG. 3A using the upward directed arrow. As mentioned previously herein, polycrystalline thin film AlN may be grown in the crystallographic c-axis negative polarization, or normal axis orientation perpendicular relative to the substrate surface using reactive magnetron sputtering of the Aluminum target in the nitrogen atmosphere. As was discussed in greater detail previously herein, changing sputtering conditions, for example by adding oxygen, may reverse the axis to a crystallographic c-axis positive polarization, or reverse axis, orientation perpendicular relative to the substrate surface.

Interposer layers may be sputtered between sputtering of piezoelectric layers, so as to be sandwiched between piezoelectric layers of the stack. For example, first interposer layer 159, may sputtered between sputtering of bottom piezoelectric layer 105, and the first middle piezoelectric layer 107, so as to be sandwiched between the bottom piezoelectric layer 105, and the first middle piezoelectric layer 107. First interposer layer 159 may be a first patterned interposer layer 159. Suitable sequences of sputter deposition (known to those with skill in the art) of various materials in combination with suitable of sequences of photolithographic masking, etching and mask removal (known to those with skill in the art) may be used to form first patterned interposer layer 159. First patterned interposer layer 159 may comprise a first step mass feature having a first acoustic impedance. The first patterned interposer layer 159 may further comprise a second step mass feature having a second acoustic impedance. The first acoustic impedance may be different than the second acoustic impedance. More generally, the first patterned interposer layer 159 may comprise first and second materials that may be different from one another (e.g., first and second materials having respective acoustic impedances that may be different from one another). For example, first patterned interposer layer may comprise dielectric. For example, first patterned interposer layer 159 may comprise first and second dielectrics that may be different from one another (e.g., first and second dielectrics having respective acoustic impedances that may be different from one another). The first patterned interposer layer 159 may comprise semiconductor. For example, the first patterned interposer layer 159 may comprise first and second semiconductors that may be different from one another (e.g., first and second semiconductors having respective acoustic impedances that may be different from one another). The first patterned interposer layer 159 may comprise metal. For example, the first patterned interposer layer 159 may comprise first and second metals that may be different from one another (e.g., first and second metals having respective acoustic impedances that may be different from one another).

The first patterned interposer layer 159 may comprise combinations of the foregoing. The first patterned interposer layer may comprise a first metal and a first dielectric. The first patterned interposer layer 159 may comprise a first metal and a first semiconductor. The first patterned interposer layer 159 may comprise a first semiconductor and a first dielectric.

The first patterned interposer layer 159 may comprise a first central feature having a first central acoustic impedance (e.g. relatively low first central acoustic impedance). The first patterned interposer layer 159 may further comprise a first peripheral feature having a first peripheral acoustic impedance (e.g., relatively high first peripheral acoustic impedance) that may be greater than the first central acoustic impedance (e.g., greater than the relatively low first central acoustic impedance).

For example, the first central feature may comprise sputter deposited and patterned (e.g., photolithographically patterned, e.g., etched) Titanium (Ti), having relatively low respective first central acoustic impedance, with first peripheral features comprising patterned (e.g., photolithographically patterned, e.g., etched) Tungsten (W) having relatively high first peripheral acoustic impedance. As another example, the first central feature may comprise sputter deposited and patterned (e.g., photolithographically patterned, e.g., etched) Titanium (Ti) having relatively low respective first central acoustic impedance, with first peripheral features comprising sputter deposited and patterned (e.g., photolithographically patterned, e.g., etched) Molybdenum (Mo) having relatively high first peripheral acoustic impedance. Since Silicon Dioxide (SiO2) has relatively lower acoustic impedance than Titanium (Ti), in another example, the first central features may comprise sputter deposited and patterned (e.g., photolithographically patterned, e.g., etched) Silicon Dioxide (SiO2) having relatively lower respective first central acoustic impedance, with first peripheral features comprising sputter deposited and patterned (e.g., photolithographically patterned, e.g., etched) Titanium (Ti) having relatively higher first peripheral acoustic impedance. In another example, the first central feature may comprise sputter deposited and patterned (e.g., photolithographically patterned, e.g., etched) Silicon Dioxide (SiO2) having relatively low respective first central acoustic impedance, with first peripheral features comprising sputter deposited and patterned (e.g., photolithographically patterned, e.g., etched) Tungsten (W) having relatively high first peripheral acoustic impedance.

For example, second interposer layer 161 may be sputtered between sputtering first middle piezoelectric layer 107 and the second middle piezoelectric layer 109 so as to be sandwiched between the first middle piezoelectric layer 107, and the second middle piezoelectric layer 109. Second interposer layer 161 may be a second patterned interposer layer 161. Suitable sequences of sputter deposition (known to those with skill in the art) of various materials in combination with suitable of sequences of photolithographic masking, etching and mask removal (known to those with skill in the art) may be used to form second patterned interposer layer 161. Second patterned interposer layer 161 may comprise a first step mass feature having a first acoustic impedance. The second patterned interposer layer 161 may further comprise a second step mass feature having a second acoustic impedance. The first acoustic impedance may be different than the second acoustic impedance. More generally, the second patterned interposer layer 161 may comprise first and second materials that may be different from one another (e.g., first and second materials having respective acoustic impedances that may be different from one another). For example, second patterned interposer layer 161 may comprise dielectric. For example, second patterned interposer layer 161 may comprise first and second dielectrics that may be different from one another (e.g., first and second dielectrics having respective acoustic impedances that may be different from one another). The second patterned interposer layer 161 may comprise semiconductor. For example, the second patterned interposer layer 161 may comprise first and second semiconductors that may be different from one another (e.g., first and second semiconductors having respective acoustic impedances that may be different from one another). The second patterned interposer layer 161 may comprise metal. For example, the second patterned interposer layer 161 may comprise first and second metals that may be different from one another (e.g., first and second metals having respective acoustic impedances that may be different from one another).

The second patterned interposer layer 161 may comprise combinations of the foregoing. The second patterned interposer layer 161 may comprise a first metal and a first dielectric. The second patterned interposer layer 161 may comprise a first metal and a first semiconductor. The second patterned interposer layer 161 may comprise a first semiconductor and a first dielectric.

The second patterned interposer layer 161 may comprise a second central feature having a second central acoustic impedance (e.g. relatively high second central acoustic impedance). The second patterned interposer layer 161 may further comprise a second peripheral feature having a second peripheral acoustic impedance (e.g., relatively low second peripheral acoustic impedance) that may be less than the second central acoustic impedance (e.g., less than the relatively high second central acoustic impedance).

For example, the second central feature may comprise sputter deposited and patterned, (e.g., photolithographically patterned, e.g., etched) Tungsten (W) having relatively high respective second central acoustic impedance, with second peripheral features comprising patterned (e.g., photolithographically patterned, e.g., etched) Titanium (Ti) having relatively low second peripheral acoustic impedance. As another example, the second central feature may comprise sputter deposited and patterned (e.g., photolithographically patterned, e.g., etched) Molybdenum (Mo) having relatively high respective second central acoustic impedance, with second peripheral features comprising sputter deposited and patterned (e.g., photolithographically patterned, e.g., etched) Titanium (Ti) having relatively low second peripheral acoustic impedance. Since Titanium (Ti) has relatively higher acoustic impedance than Silicon Dioxide (SiO2), in another example, the second central features may comprise sputter deposited and patterned (e.g., photolithographically patterned, e.g., etched) Titanium (Ti) having relatively higher respective second central acoustic impedance, with second peripheral features comprising sputter deposited and patterned (e.g., photolithographically patterned, e.g., etched) Silicon Dioxide (SiO2) having relatively lower second peripheral acoustic impedance. In another example, the second central feature may comprise sputter deposited and patterned (e.g., photolithographically patterned, e.g., etched) Tungsten (W) having relatively high respective second central acoustic impedance, with second peripheral features comprising sputter deposited and patterned (e.g., photolithographically patterned, e.g., etched) Silicon Dioxide (SiO2) having relatively low second peripheral acoustic impedance.

For example, third interposer layer 163, may be sputtered between sputtering of second middle piezoelectric layer 109 and the top piezoelectric layer 111 so as to be sandwiched between the second middle piezoelectric layer 109 and the top piezoelectric layer 111.

As discussed previously, one or more of the interposer layers may comprise metal, e.g., high acoustic impedance metal interposer layers, e.g., Molybdenum metal interposer layers. These may be deposited by sputtering from a metal target. As discussed previously, one or more of the interposer layers may comprise dielectric, e.g., silicon dioxide interposer layers. These may be deposited by reactive sputtering from a Silicon target in an oxygen atmosphere. Alternatively or additionally, one or more (e.g., one or a plurality of) interposer layers may comprise metal and dielectric for respective interposer layers. Suitable sputtering thickness for suitable resulting interposer layers may be as discussed previously herein.

Initial top electrode layer 135 may be deposited on the top piezoelectric layer 111 by sputtering from the high acoustic impedance metal target. Thickness of the initial top electrode layer may be, for example, about an eighth wavelength (e.g., an eighth of an acoustic wavelength) of the resonant frequency of the resonator (e.g., layer thickness of about three hundred Angstroms (300 A) for the example 24 GHz resonator). The first pair of top metal electrode layers, 137, 139, may then be deposited by sputtering the low acoustic impedance metal for a first top metal electrode layer 137 of the pair, and then sputtering the high acoustic impedance metal for a second top metal electrode layer 139 of the pair on the first layer 137 of the pair. Layer thicknesses of top metal electrode layers of the first pair 137, 139 may correspond to approximately a quarter wavelength (e.g., a quarter acoustic wavelength) of the resonant frequency of the resonator (e.g., respective layer thickness of about six hundred Angstroms (600 A) for the example 24 GHz resonator).

Sputter deposition of successive additional pairs of alternating layers of high acoustic impedance metal and low acoustic impedance metal may continue as shown in FIG. 3A by alternating sputtering from targets of high acoustic impedance metal and low acoustic impedance metal. For example, sputtering targets of high acoustic impedance metal such as Molybdenum or Tungsten may be used for sputtering the high acoustic impedance metal layers, and sputtering targets of low acoustic impedance metal such as Aluminum or Titanium may be used for sputtering the low acoustic impedance metal layers. For example, the second pair of top metal electrode layers, 141, 143, may be deposited by sputtering the low acoustic impedance metal for a first bottom metal electrode layer 141 of the pair on the plurality of lateral features 157, and then sputtering the high acoustic impedance metal for a second top metal electrode layer 143 of the pair on the first layer 141 of the pair. Similarly, the third pair of top metal electrode layers, 145, 147, may then be deposited by sequentially sputtering from the low acoustic impedance metal target and the high acoustic impedance metal target. Similarly, the fourth pair of top metal electrodes 149, 151, may then be deposited by sequentially sputtering from the low acoustic impedance metal target and the high acoustic impedance metal target. Respective layer thicknesses of top metal electrode layers of the first, second, third and fourth pairs 137, 139, 141, 143, 145, 147, 149, 151 may correspond to approximately a quarter wavelength (e.g., a quarter acoustic wavelength) at the resonant frequency of the resonator (e.g., respective layer thickness of about six hundred Angstroms (600 A) for the example 24 GHz resonator).

After depositing layers of the fourth pair of top metal electrodes 149, 151 as shown in FIG. 3A, suitable photolithographic masking and etching may be used to form a first portion of etched edge region 153 for the top acoustic reflector 115 as shown in FIG. 3B. A notional heavy dashed line is used in FIG. 3B depicting the first portion of etched edge region 153 associated with the top acoustic reflector 115. The first portion of etched edge region 153 may extend along the thickness dimension T25 of the top acoustic reflector 115. The first portion etched edge region 153C may extend through (e.g., entirely through or partially through) the top acoustic reflector 115. The first portion of the etched edge region 153 may extend through (e.g., entirely through or partially through) the initial top metal electrode layer 135. The first portion of the etched edge region 153 may extend through (e.g., entirely through or partially through) the first pair of top metal electrode layers 137, 139. The first portion of etched edge region 153 may extend through (e.g., entirely through or partially through) the second pair of top metal electrode layers, 141,143. The first portion etched edge region 153 may extend through (e.g., entirely through or partially through) the third pair of top metal electrode layers, 145, 147. The first portion of etched edge region 153 may extend through (e.g., entirely through or partially through) the fourth pair of top metal electrode layers, 149, 151. Just as suitable photolithographic masking and etching may be used to form the first portion of etched edge region 153 at a lateral extremity the top acoustic reflector 115 as shown in FIG. 3, such suitable photolithographic masking and etching may likewise be used to form another first portion of a laterally opposing etched edge region 154 at an opposing lateral extremity the top acoustic reflector 115, e.g., arranged laterally opposing or opposite from the first portion of etched edge region 153, as shown in FIG. 3B. The another first portion of the laterally opposing etched edge region 154 may extend through (e.g., entirely through or partially through) the opposing lateral extremity of the top acoustic reflector 115, e.g., arranged laterally opposing or opposite from the first portion of etched edge region 153, as shown in FIG. 3B. The mesa structure (e.g., third mesa structure) corresponding to the top acoustic reflector 115 may extend laterally between (e.g., may be formed between) etched edge region 153 and laterally opposing etched edge region 154. Dry etching may be used, e.g., reactive ion etching may be used to etch the materials of the top acoustic reflector. Chlorine based reactive ion etch may be used to etch Aluminum, in cases where Aluminum is used in the top acoustic reflector. Fluorine based reactive ion etch may be used to etch Tungsten (W), Molybdenum (Mo), Titanium (Ti), Silicon Nitride (SiN), Silicon Dioxide (SiO2) and/or Silicon Carbide (SiC) in cases where these materials are used in the top acoustic reflector.

After etching to form the first portion of etched edge region 153 for top acoustic reflector 115 as shown in FIG. 3B, additional suitable photolithographic masking and etching may be used to form elongated portion of etched edge region 153 for top acoustic reflector 115 and for the stack 104 of four piezoelectric layers 105, 107, 109, 111 as shown in FIG. 3C. A notional heavy dashed line is used in FIG. 3C depicting the elongated portion of etched edge region 153 associated with the stack 104 of four piezoelectric layers 105, 107, 109, 111 and with the top acoustic reflector 115. Accordingly, the elongated portion of etched edge region 153 shown in FIG. 3C may extend through (e.g., entirely through or partially through) the fourth pair of top metal electrode layers, 149, 151, the third pair of top metal electrode layers, 145, 147, the second pair of top metal electrode layers, 141,143, at least one of the lateral features 157 (e.g., patterned layer 157), the first pair of top metal electrode layers 137, 139 and the initial top metal electrode layer 135 of the top acoustic reflector 115. The elongated portion of etched edge region 153 may extend through (e.g., entirely through or partially through) the stack 104 of four piezoelectric layers 105, 107, 109, 111. The elongated portion of etched edge region 153 may extend through (e.g., entirely through or partially through) the first piezoelectric layer, 105, e.g., having the normal axis orientation, first interposer layer 159, first middle piezoelectric layer, 107, e.g., having the reverse axis orientation, second interposer layer 161, second middle interposer layer, 109, e.g., having the normal axis orientation, third interposer layer 163, and top piezoelectric layer 111, e.g., having the reverse axis orientation. The elongated portion of etched edge region 153 may extend along the thickness dimension T25 of the top acoustic reflector 115. The elongated portion of etched edge region 153 may extend along the thickness dimension T27 of the stack 104 of four piezoelectric layers 105, 107, 109, 111. Just as suitable photolithographic masking and etching may be used to form the elongated portion of etched edge region 153 at the lateral extremity the top acoustic reflector 115 and at a lateral extremity of the stack 104 of four piezoelectric layers 105, 107, 109, 111 as shown in FIG. 3C, such suitable photolithographic masking and etching may likewise be used to form another elongated portion of the laterally opposing etched edge region 154 at the opposing lateral extremity the top acoustic reflector 115 and the stack 104 of four piezoelectric layers 105, 107, 109, 111, e.g., arranged laterally opposing or opposite from the elongated portion of etched edge region 153, as shown in FIG. 3C. The another elongated portion of the laterally opposing etched edge region 154 may extend through (e.g., entirely through or partially through) the opposing lateral 5 extremity of the top acoustic reflector 115 and the stack of four piezoelectric layers 105, 107, 109, 111, e.g., arranged laterally opposing or opposite from the elongated portion of etched edge region 153, as shown in FIG. 3C. The mesa structure (e.g., third mesa structure) corresponding to the top acoustic reflector 115 may extend laterally between (e.g., may be formed between) etched edge region 153 and laterally opposing etched edge region 154. The mesa structure (e.g., first mesa structure) corresponding to stack 104 of the example four piezoelectric layers may extend laterally between (e.g., may be formed between) etched edge region 153 and laterally opposing etched edge region 154. Dry etching may be used, e.g., reactive ion etching may be used to etch the materials of the stack 104 of four piezoelectric layers 105, 107, 109, 111 and any interposer layers. For example, Chlorine based reactive ion etch may be used to etch Aluminum Nitride piezoelectric layers. For example, Fluorine based reactive ion etch may be used to etch Tungsten (W), Molybdenum (Mo), Titanium (Ti), Silicon Nitride (SiN), Silicon Dioxide (SiO2) and/or Silicon Carbide (SiC) in cases where these materials are used in interposer layers.

After etching to form the elongated portion of etched edge region 153 for top acoustic reflector 115 and the stack 104 of four piezoelectric layers 105, 107, 109, 111 as shown in FIG. 3C, further additional suitable photolithographic masking and etching may be used to form etched edge region 153 for top acoustic reflector 115 and for the stack 104 of four piezoelectric layers 105, 107, 109, 111 and for bottom acoustic reflector 113 as shown in FIG. 3D. The notional heavy dashed line is used in FIG. 3D depicting the etched edge region 153 associated with the stack 104 of four piezoelectric layers 105, 107, 109, 111 and with the top acoustic reflector 115 and with the bottom acoustic reflector 113. The etched edge region 153 may extend along the thickness dimension T25 of the top acoustic reflector 115. The etched edge region 153 may extend along the thickness dimension T27 of the stack 104 of four piezoelectric layers 105, 107, 109, 111. The etched edge region 153 may extend along the thickness dimension T23 of the bottom acoustic reflector 113. Just as suitable photolithographic masking and etching may be used to form the etched edge region 153 at the lateral extremity the top acoustic reflector 115 and at the lateral extremity of the stack 104 of four piezoelectric layers 105, 107, 109, 111 and at a lateral extremity of the bottom acoustic reflector 113 as shown in FIG. 3C, such suitable photolithographic masking and etching may likewise be used to form another laterally opposing etched edge region 154 at the opposing lateral extremity of the top acoustic reflector 115 and the stack 104 of four piezoelectric layers 105, 107, 109, 111, and the bottom acoustic reflector 113, e.g., arranged laterally opposing or opposite from the etched edge region 153, as shown in FIG. 3D. The laterally opposing etched edge region 154 may extend through (e.g., entirely through or partially through) the opposing lateral extremity of the top acoustic reflector 115 and the stack of four piezoelectric layers 105, 107, 109, 111, and the bottom acoustic reflector 113 e.g., arranged laterally opposing or opposite from the etched edge region 153, as shown in FIG. 3D.

After the foregoing etching to form the etched edge region 153 and the laterally opposing etched edge region 154 of the resonator 100 shown in FIG. 3D, a planarization layer 165 may be deposited. A suitable planarization material (e.g., Silicon Dioxide (SiO2), Hafnium Dioxide (HfO2), Polyimide, or BenzoCyclobutene (BCB)). These materials may be deposited by suitable methods, for example, chemical vapor deposition, standard or reactive magnetron sputtering (e.g., in cases of SiO2 or HfO2) or spin coating (e.g., in cases of Polyimide or BenzoCyclobutene (BCB)). An isolation layer 167 may also be deposited over the planarization layer 165. A suitable low dielectric constant (low-k), low acoustic impedance (low-Za) material may be used for the isolation layer 167, for example polyimide, or BenzoCyclobutene (BCB). These materials may be deposited by suitable methods, for example, chemical vapor deposition, standard or reactive magnetron sputtering or spin coating. After planarization layer 165 and the isolation layer 167 have been deposited, additional procedures of photolithographic masking, layer etching, and mask removal may be done to form a pair of etched acceptance locations 183A, 183B for electrical interconnections. Reactive ion etching or inductively coupled plasma etching with a gas mixture of argon, oxygen and a fluorine containing gas such as tetrafluoromethane (CF4) or Sulfur hexafluoride (SF6) may be used to etch through the isolation layer 167 and the planarization layer 165 to form the pair of etched acceptance locations 183A, 183B for electrical interconnections. Photolithographic masking, sputter deposition, and mask removal may then be used form electrical interconnects in the pair of etched acceptance locations 183A, 183B shown in FIG. 3D, so as to provide for the bottom electrical interconnect 169 and top electrical interconnect 171 that are shown explicitly in FIG. 1A. A suitable material, for example Gold (Au) may be used for the bottom electrical interconnect 169 and top electrical interconnect 171. At least a portion of top electrical interconnect 171 may comprise the top current spreading layer.

FIGS. 4A through 4G show alternative example bulk acoustic wave resonators 400A through 400G to the example bulk acoustic wave resonator 100A shown in FIG. 1A. For example, the bulk acoustic wave resonator 400A, 400E shown in FIG. 4A, 4E may have a cavity 483A, 483E, e.g., an air cavity 483A, 483E, e.g., extending into substrate 401A, 401E, e.g., extending into silicon substrate 401A, 401E, e.g., arranged below bottom acoustic reflector 413A, 413E. The cavity 483A, 483E may be formed using techniques known to those with ordinary skill in the art. For example, the cavity 483A, 483E may be formed by initial photolithographic masking and etching of the substrate 401A, 401E (e.g., silicon substrate 401A, 401E), and deposition of a sacrificial material (e.g., phosphosilicate glass (PSG)). The phosphosilicate glass (PSG) may comprise 8% phosphorous and 92% silicon dioxide. The resonator 400A, 400E may be formed over the sacrificial material (e.g., phosphosilicate glass (PSG)). The sacrificial material may then be selectively etched away beneath the resonator 400A, 400E, leaving cavity 483A, 483E beneath the resonator 400A, 400E. For example phosphosilicate glass (PSG) sacrificial material may be selectively etched away by hydrofluoric acid beneath the resonator 400A, 400E, leaving cavity 483A, 483E beneath the resonator 400A, 400E. The cavity 483A, 483E may, but need not, be arranged to provide acoustic isolation of the structures, e.g., bottom acoustic reflector 413A, 413E, e.g., stack 404A, 404E of piezoelectric layers, e.g., resonator 400A, 400E from the substrate 401A, 401E.

Similarly, in FIGS. 4B, 4C, 4F and 4G, a via 485B, 485C, 485F, 485G (e.g., through silicon via 485B, 485F, e.g., through silicon carbide via 485C, 485G) may, but need not, be arranged to provide acoustic isolation of the structures, e.g., bottom acoustic reflector 413B, 413C, 413F, 413G, e.g., stack 404B, 404C, 404F, 404G, of piezoelectric layers, e.g., resonator 400B, 400C, 400F, 400G from the substrate 401B, 401C, 401F, 401G. The via 485B, 485C, 485F, 485G (e.g., through silicon via 485B, 485F, e.g., through silicon carbide via 485C, 485G) may be formed using techniques (e.g., using photolithographic masking and etching techniques) known to those with ordinary skill in the art. For example, in FIGS. 4B and 4F, backside photolithographic masking and etching techniques may be used to form the through silicon via 485B, 485F, and an additional passivation layer 487B, 487F may be deposited, after the resonator 400B, 400F is formed. For example, in FIGS. 4C and 4G, backside photolithographic masking and etching techniques may be used to form the through silicon carbide via 485C, 485G, after the top acoustic reflector 415C, 415G and stack 404C, 404G of piezoelectric layers are formed. In FIGS. 4C and 4G, after the through silicon carbide via 485C, 485G, is formed, backside photolithographic masking and deposition techniques may be used to form bottom acoustic reflector 413C, 413G, and additional passivation layer 487C, 487G.

In FIGS. 4A, 4B, 4C, 4E, 4F, 4G, bottom acoustic reflector 413A, 413B, 413C, 413E, 413F, 413G, may include the acoustically reflective bottom electrode stack of the plurality of bottom metal electrode layers, in which thicknesses of the bottom metal electrode layers may be related to wavelength (e.g., acoustic wavelength) at the main resonant frequency of the example resonator 400A, 400B, 400C, 400E, 400F, 400G. As mentioned previously herein, the layer thickness of the initial bottom metal electrode layer 417A, 417B, 417C, 417E, 417F, 417G, may be about one eighth of a wavelength (e.g., one eighth acoustic wavelength) at the main resonant frequency of the example resonator 400A. Respective layer thicknesses, (e.g., T01 through T04, explicitly shown in FIGS. 4A, 4B, 4C) for members of the pairs of bottom metal electrode layers may be about one quarter of the wavelength (e.g., one quarter acoustic wavelength) at the main resonant frequency of the example resonators 400A, 400B, 400C, 400E, 400F, 400G. Relatively speaking, in various alternative designs of the example resonators 400A, 400B, 400C, 400E, 400F, 400G, for relatively lower main resonant frequencies (e.g., five Gigahertz (5 GHz)) and having corresponding relatively longer wavelengths (e.g., longer acoustic wavelengths), may have relatively thicker bottom metal electrode layers in comparison to other alternative designs of the example resonators 400A, 400B, 400C, 400E, 400F, 400G, for relatively higher main resonant frequencies (e.g., twenty-four Gigahertz (24 GHz)). There may be corresponding longer etching times to form, e.g., etch through, the relatively thicker bottom metal electrode layers in designs of the example resonator 400A, 400B, 400C, 400E, 400F, 400G, for relatively lower main resonant frequencies (e.g., five Gigahertz (5 GHz)). Accordingly, in designs of the example resonators 400A, 400B, 400C, 400E, 400F, 400G, for relatively lower main resonant frequencies (e.g., five Gigahertz (5 GHz)) having the relatively thicker bottom metal electrode layers, there may (but need not) be an advantage in etching time in having a relatively fewer number (e.g., five (5)) of bottom metal electrode layers, shown in 4A, 4B, 4C, 4E, 4F, 4G, in comparison to a relatively larger number (e.g., nine (9)) of bottom metal electrode layers, shown in FIG. 1A and in FIG. 4D. The relatively larger number (e.g., nine (9)) of bottom metal electrode layers, shown in FIG. 1A and in FIG. 4D may (but need not) provide for relatively greater acoustic isolation than the relatively fewer number (e.g., five (5)) of bottom metal electrode layers. However, in FIGS. 4A and 4E the cavity 483A, 483E, (e.g., air cavity 483A, 483E) may (but need not) be arranged to provide acoustic isolation enhancement relative to some designs without the cavity 483A, 483E. Similarly, in FIGS. 4B, 4C, 4F, 4G, the via 483B, 483C, 483F, 483G, (e.g., through silicon via 485B, 485F, e.g., through silicon carbide via 485C, 485G) may (but need not) be arranged to provide acoustic isolation enhancement relative to some designs without the via 483B, 483C, 483F, 483G.

In FIGS. 4A and 4E, the cavity 483A, 483E may (but need not) be arranged to compensate for relatively lesser acoustic isolation of the relatively fewer number (e.g., five (5)) of bottom metal electrode layers. In FIGS. 4A and 4E, the cavity 483A, 483E may (but need not) be arranged to provide acoustic isolation benefits, while retaining possible electrical conductivity improvements and etching time benefits of the relatively fewer number (e.g., five (5)) of bottom metal electrode layers, e.g., particularly in designs of the example resonator 400A, 400E, for relatively lower main resonant frequencies (e.g., five Gigahertz (5 GHz)). Similarly, in FIGS. 4B, 4C, 4F, 4G, the via 483B, 483C, 483F, 483G, may (but need not) be arranged to compensate for relatively lesser acoustic isolation of the relatively fewer number (e.g., five (5)) of bottom metal electrode layers. In FIGS. 4B, 4C, 4F, 4G, the via 483B, 483C, 483F, 483G, may (but need not) be arranged to provide acoustic isolation benefits, while retaining possible electrical conductivity improvement benefits and etching time benefits of the relatively fewer number (e.g., five (5)) of bottom metal electrode layers, e.g., particularly in designs of the example resonator 400B, 400C, 400F, 400G, for relatively lower main resonant frequencies (e.g., five Gigahertz (5 GHz), e.g., below six Gigahertz (6 GHz), e.g., below five Gigahertz (5 GHz)).

FIGS. 4D through 4G show alternative example bulk acoustic wave resonators 400D through 400G to the example bulk acoustic wave resonator 100A shown in FIG. 1A, in which the top acoustic reflector, 415D through 415G, may comprise a lateral connection portion, 489D through 489G, (e.g., bridge portion, 489D through 489G), of the top acoustic reflector, 415D through 415G. A gap, 491D through 491G, may be formed beneath the lateral connection portion, 489D through 489G, (e.g., bridge portion, 489D through 489G), of the top acoustic reflector 415D through 415G. The gap, 491D through 491G, may be arranged adjacent to the etched edge region, 453D through 453G, of the example resonators 400D through 400G. For example, the gap, 491D through 491G, may be arranged adjacent to where the etched edge region, 453D through 453G, extends through (e.g., extends entirely through or extends partially through) the stack 404D through 404G, of piezoelectric layers, for example along the thickness dimension T27 of the stack 404D through 404G. For example, the gap, 491D through 491G, may be arranged adjacent to where the etched edge region, 453D through 453G, extends through (e.g., extends entirely through or extends partially through) the bottom piezoelectric layer 405D through 405G. For example, the gap, 491D through 491G, may be arranged adjacent to where the etched edge region, 453D through 453G, extends through (e.g., extends entirely through or extends partially through) the bottom piezoelectric layer 405D through 405G. For example, the gap, 491D through 491G, may be arranged adjacent to where the etched edge region, 453D through 453G, extends through (e.g., extends entirely through or extends partially through) the first middle piezoelectric layer 407D through 407G. For example, the gap, 491D through 491G, may be arranged adjacent to where the etched edge region, 453D through 453G, extends through (e.g., extends entirely through or extends partially through) the second middle piezoelectric layer 409D through 409G. For example, the gap, 491D through 491G, may be arranged adjacent to where the etched edge region, 453D through 453G, extends through (e.g., extends entirely through or extends partially through) the top piezoelectric layer 411D through 411G. For example, the gap, 491D through 491G, may be arranged adjacent to where the etched edge region, 453D through 453G, extends through (e.g., extends entirely through or extends partially through) one or more interposer layers (e.g., first interposer layer, 495D through 459G, second interposer layer, 461D through 461G, third interposer layer 411D through 411G).

For example, as shown in FIGS. 4D through 4G, the gap, 491D through 491G, may be arranged adjacent to where the etched edge region, 453D through 453G, extends through (e.g., extends partially through) the top acoustic reflector 415D through 415G, for example partially along the thickness dimension T25 of the top acoustic reflector 415D through 415G. For example, the gap, 491D through 491G, may be arranged adjacent to where the etched edge region, 453D through 453G, extends through (e.g., extends entirely through or extends partially through) the initial top electrode layer 435D through 435G. For example, the gap, 491D through 491G, may be arranged adjacent to where the etched edge region, 453D through 453G, extends through (e.g., extends entirely through or extends partially through) the first member, 437D through 437G, of the first pair of top electrode layers, 437D through 437G, 439D through 439G.

For example, as shown in FIGS. 4D through 4F, the gap, 491D through 491F, may be arranged adjacent to where the etched edge region, 453D through 453F, extends through (e.g., extends entirely through or extends partially through) the bottom acoustic reflector 413D through 413F, for example along the thickness dimension T23 of the bottom acoustic reflector 413D through 413F. For example, the gap, 491D through 491F, may be arranged adjacent to where the etched edge region, 453D through 453F, extends through (e.g., extends entirely through or extends partially through) the initial bottom electrode layer 417D through 417F. For example, the gap, 491D through 491F, may be arranged adjacent to where the etched edge region, 453D through 453F, extends through (e.g., extends entirely through or extends partially through) the first pair of bottom electrode layers, 419D through 419F, 421D through 421F. For example, the gap, 491D through 491F, may be arranged adjacent to where the etched edge region, 453D through 453F, extends through (e.g., extends entirely through or extends partially through) the second pair of bottom electrode layers, 423D through 423F, 425D through 425F. For example, as shown in FIGS. 4D through 4F, the etched edge region, 453D through 453F, may extend through (e.g., entirely through or partially through) the bottom acoustic reflector, 413D through 413F, and through (e.g., entirely through or partially through) one or more of the piezoelectric layers, 405D through 405F, 407D through 407F, 409D through 409F, 411D through 411F, to the lateral connection portion, 489D through 489G, (e.g., to the bridge portion, 489D through 489G), of the top acoustic reflector, 415D through 415F.

As shown in FIGS. 4D-4G, lateral connection portion, 489D through 489G, (e.g., bridge portion, 489D through 489G), of top acoustic reflector, 415D through 415G, may be a multilayer lateral connection portion, 415D through 415G, (e.g., a multilayer metal bridge portion, 415D through 415G, comprising differing metals, e.g., metals having differing acoustic impedances). For example, lateral connection portion, 489D through 489G, (e.g., bridge portion, 489D through 489G), of top acoustic reflector, 415D through 415G, may comprise the second member, 439D through 439G, (e.g., comprising the relatively high acoustic impedance metal) of the first pair of top electrode layers, 437D through 437G, 439D through 439G. For example, lateral connection portion, 489D through 489G, (e.g., bridge portion, 489D through 489G), of top acoustic reflector, 415D through 415G, may comprise the second pair of top electrode layers, 441D through 441G, 443D through 443G.

Gap 491D-491G may be an air gap 491D-491G, or may be filled with a relatively low acoustic impedance material (e.g., BenzoCyclobutene (BCB)), which may be deposited using various techniques known to those with skill in the art. Gap 491D-491G may be formed by depositing a sacrificial material (e.g., phosphosilicate glass (PSG)) after the etched edge region, 453D through 453G, is formed. The lateral connection portion, 489D through 489G, (e.g., bridge portion, 489D through 489G), of top acoustic reflector, 415D through 415G, may then be deposited (e.g., sputtered) over the sacrificial material. The sacrificial material may then be selectively etched away beneath the lateral connection portion, 489D through 489G, (e.g., e.g., beneath the bridge portion, 489D through 489G), of top acoustic reflector, 415D through 415G, leaving gap 491D-491G beneath the lateral connection portion, 489D through 489G, (e.g., beneath the bridge portion, 489D through 489G). For example the phosphosilicate glass (PSG) sacrificial material may be selectively etched away by hydrofluoric acid beneath the lateral connection portion, 489D through 489G, (e.g., beneath the bridge portion, 489D through 489G), of top acoustic reflector, 415D through 415G, leaving gap 491D-491G beneath the lateral connection portion, 489D through 489G, (e.g., beneath the bridge portion, 489D through 489G).

Although in various example resonators, 100A, 400A, 400B, 400D, 400E, 400F, polycrystalline piezoelectric layers (e.g., polycrystalline Aluminum Nitride (AlN)) may be deposited (e.g., by sputtering), in other example resonators 400C, 400G, alternative single crystal or near single crystal piezoelectric layers (e.g., single/near single crystal Aluminum Nitride (AlN)) may be deposited (e.g., by metal organic chemical vapor deposition (MOCVD)). Normal axis piezoelectric layers (e.g., normal axis Aluminum Nitride (AlN) piezoelectric layers) may be deposited by MOCVD using techniques known to those with skill in the art. As discussed previously herein, the interposer layers may be deposited by sputtering, but alternatively may be deposited by MOCVD. Reverse axis piezoelectric layers (e.g., reverse axis Aluminum Nitride (AlN) piezoelectric layers) may likewise be deposited via MOCVD. For the respective example resonators 400C, 400G shown in FIGS. 4C and 4G, the alternating axis piezoelectric stack 404C, 404G comprised of piezoelectric layers 405C, 407C, 409C, 411C, 405G, 407G, 409G, 411G as well as interposer layers 459C, 461C, 463C, 459G, 461G, 453G extending along stack thickness dimension T27 fabricated using MOCVD on a silicon carbide substrate 401C, 401G. For example, aluminum nitride of piezoelectric layers 405C, 407C, 409C, 411C, 405G, 407G, 409G, 411G the may grow nearly epitaxially on silicon carbide (e.g., 4H SiC) by virtue of the small lattice mismatch between the polar axis aluminum nitride wurtzite structure and specific crystal orientations of silicon carbide. Alternative small lattice mismatch substrates may be used (e.g., sapphire, e.g., aluminum oxide). By varying the ratio of the aluminum and nitrogen in the deposition precursors, an aluminum nitride film may be produced with the desired polarity (e.g., normal axis, e.g., reverse axis). For example, normal axis aluminum nitride may be synthesized using MOCVD when a nitrogen to aluminum ratio in precursor gases approximately 1000. For example, reverse axis aluminum nitride may synthesized when the nitrogen to aluminum ratio is approximately 27000. In accordance with the foregoing, FIGS. 4C and 4G show MOCVD synthesized normal axis piezoelectric layer 405C, 405G, MOCVD synthesized reverse axis piezoelectric layer 407C, 407G, MOCVD synthesized normal axis piezoelectric layer 409C, 409G, and MOCVD synthesized reverse axis piezoelectric layer 411C, 411G. For example, normal axis piezoelectric layer 405C, 405G may be synthesized by MOCVD in a deposition environment where the nitrogen to aluminum gas ratio is relatively low, e.g., 1000 or less. Next an oxyaluminum nitride layer, 459C at lower temperature, may be deposited by MOCVD that may reverse axis (e.g., reverse axis polarity) of the growing aluminum nitride under MOCVD growth conditions, and has also been shown to be able to be deposited by itself under MOCVD growth conditions. Increasing the nitrogen to aluminum ratio into the several thousands during the MOCVD synthesis may enable the reverse axis piezoelectric layer 407C, 407G to be synthesized. Interposer layer 461C, 461G may be an oxide layer such as, but not limited to, aluminum oxide or silicon dioxide. This oxide layer may be deposited in in a low temperature physical vapor deposition process such as sputtering or in a higher temperature chemical vapor deposition process. Normal axis piezoelectric layer 409C, 409G may be grown by MOCVD on top of interposer layer 461C, 461G using growth conditions similar to the normal axis layer 405C, 405G, as discussed previously, namely MOCVD in a deposition environment where the nitrogen to aluminum gas ratio is relatively low, e.g., 1000 or less. Next an aluminum oxynitride, interposer layer 463C, 463G may be deposited in a low temperature MOCVD process followed by a reverse axis piezoelectric layer 411C, 411G, synthesized in a high temperature MOCVD process and an atmosphere of nitrogen to aluminum ratio in the several thousand range. Upon conclusion of these depositions, the piezoelectric stack 404C, 404G shown in FIGS. 4C and 4G may be realized

FIG. 5 shows a schematic of an example ladder filter 500A (e.g., SHF or EHF wave ladder filter 500A) using three series resonators of the bulk acoustic wave resonator structure of FIG. 1A (e.g., three bulk acoustic SHF or EHF wave resonators), and two mass loaded shunt resonators of the bulk acoustic wave resonator structure of FIG. 1A (e.g., two mass loaded bulk acoustic SHF or EHF wave resonators), along with a simplified view of the three series resonators. Accordingly, the example ladder filter 500A (e.g., SHF or EHF wave ladder filter 500A) is an electrical filter, comprising a plurality of bulk acoustic wave (BAW) resonators, e.g., on a substrate, in which the plurality of BAW resonators may comprise a respective first layer (e.g., bottom layer) of piezoelectric material having a respective piezoelectrically excitable resonance mode. The plurality of BAW resonators of the filter 500A may comprise a respective top acoustic reflector (e.g., top acoustic reflector electrode) including a respective initial top metal electrode layer and a respective first pair of top metal electrode layers electrically and acoustically coupled with the respective first layer (e.g., bottom layer) of piezoelectric material to excite the respective piezoelectrically excitable resonance mode at a respective resonant frequency. For example, the respective top acoustic reflector (e.g., top acoustic reflector electrode) may include the respective initial top metal electrode layer and the respective first pair of top metal electrode layers, and the foregoing may have a respective peak acoustic reflectivity in the Super High Frequency (SHF) band or the Extremely High Frequency (EHF) band that includes the respective resonant frequency of the respective BAW resonator. The plurality of BAW resonators of the filter 500A may comprise a respective bottom acoustic reflector (e.g., bottom acoustic reflector electrode) including a respective initial bottom metal electrode layer and a respective first pair of bottom metal electrode layers electrically and acoustically coupled with the respective first layer (e.g., bottom layer) of piezoelectric material to excite the respective piezoelectrically excitable resonance mode at the respective resonant frequency. For example, the respective bottom acoustic reflector (e.g., bottom acoustic reflector electrode) may include the respective initial bottom metal electrode layer and the respective first pair of bottom metal electrode layers, and the foregoing may have a respective peak acoustic reflectivity in the super high frequency band or the extremely high frequency band that includes the respective resonant frequency of the respective BAW resonator. The respective first layer (e.g., bottom layer) of piezoelectric material may be sandwiched between the respective top acoustic reflector and the respective bottom acoustic reflector. Further, the plurality of BAW resonators may comprise at least one respective additional layer of piezoelectric material, e.g., first middle piezoelectric layer. The at least one additional layer of piezoelectric material may have the piezoelectrically excitable main resonance mode with the respective first layer (e.g., bottom layer) of piezoelectric material. The respective first layer (e.g., bottom layer) of piezoelectric material may have a respective first piezoelectric axis orientation (e.g., normal axis orientation) and the at least one respective additional layer of piezoelectric material may have a respective piezoelectric axis orientation (e.g., reverse axis orientation) that opposes the first piezoelectric axis orientation of the respective first layer of piezoelectric material. Further discussion of features that may be included in the plurality of BAW resonators of the filter 500A is present previously herein with respect to previous discussion of FIG. 1A

As shown in the schematic appearing at an upper section of FIG. 5, the example ladder filter 500A may include an input port comprising a first node 521A (InA), and may include a first series resonator 501A (Series1A) (e.g., first bulk acoustic SHF or EHF wave resonator 501A) coupled between the first node 521A (InA) associated with the input port and a second node 522A. The example ladder filter 500A may also include a second series resonator 502A (Series2A) (e.g., second bulk acoustic SHF or EHF wave resonator 502A) coupled between the second node 522A and a third node 523A. The example ladder filter 500A may also include a third series resonator 503A (Series3A) (e.g., third bulk acoustic SHF or EHF wave resonator 503A) coupled between the third node 523A and a fourth node 524A (OutA), which may be associated with an output port of the ladder filter 500A. The example ladder filter 500A may also include a first mass loaded shunt resonator 511A (Shunt1A) (e.g., first mass loaded bulk acoustic SHF or EHF wave resonator 511A) coupled between the second node 522A and ground. The example ladder filter 500A may also include a second mass loaded shunt resonator 512A (Shunt2A) (e.g., second mass loaded bulk acoustic SHF or EHF wave resonator 512A) coupled between the third node 523 and ground.

Appearing at a lower section of FIG. 5 is the simplified view of the three series resonators 501B (Series1B), 502B (Series2B), 503B (Series3B) in a serial electrically interconnected arrangement 500B, for example, corresponding to series resonators 501A, 502A, 503A, of the example ladder filter 500A. The three series resonators 501B (Series1B), 502B (Series2B), 503B (Series3B), may be constructed as shown in the arrangement 500B and electrically interconnected in a way compatible with integrated circuit fabrication of the ladder filter. Although the first mass loaded shunt resonator 511A (Shunt1A) and the second mass loaded shunt resonator 512A are not explicitly shown in the arrangement 500B appearing at a lower section of FIG. 5, it should be understood that the first mass loaded shunt resonator 511A (Shunt1A) and the second mass loaded shunt resonator 512A are constructed similarly to what is shown for the series resonators in the lower section of FIG. 5, but that the first and second mass loaded shunt resonators 511A, 512A may include mass layers, in addition to layers corresponding to those shown for the series resonators in the lower section of FIG. 5 (e.g., the first and second mass loaded shunt resonators 511A, 512A may include respective mass layers, in addition to respective top acoustic reflectors of respective top metal electrode layers, may include respective alternating axis stacks of piezoelectric material layers, and may include respective bottom acoustic reflectors of bottom metal electrode layers). For example, all of the resonators of the ladder filter may be co-fabricated using integrated circuit processes (e.g., Complementary Metal Oxide Semiconductor (CMOS) compatible fabrication processes) on the same substrate (e.g., same silicon substrate). The example ladder filter 500A and serial electrically interconnected arrangement 500B of series resonators 501A, 502A, 503A, may respectively be relatively small in size, and may respectively have a lateral dimension (X5) of less than approximately one millimeter.

For example, the serial electrically interconnected arrangement 500B of three series resonators 501B (Series1B), 502B (Series2B), 503B (Series3B), may include an input port comprising a first node 521B (InB) and may include a first series resonator 501B (Series1B) (e.g., first bulk acoustic SHF or EHF wave resonator 501B) coupled between the first node 521B (InB) associated with the input port and a second node 522B. The first node 521B (InB) may include bottom electrical interconnect 569B electrically contacting a first bottom acoustic reflector of first series resonator 501B (Series1B) (e.g., first bottom acoustic reflector electrode of first series resonator 501B (Series1B)). Accordingly, in addition to including bottom electrical interconnect 569, the first node 521B (InB) may also include the first bottom acoustic reflector of first series resonator 501B (Series1B) (e.g., first bottom acoustic reflector electrode of first series resonator 501B (Series1B)). The first bottom acoustic reflector of first series resonator 501B (Series1B) (e.g., first bottom acoustic reflector electrode of first series resonator 501B (Series1B)) may include a stack of the plurality of bottom metal electrode layers 517 through 525 (and this may further comprise bottom current spreading layer 535 arranged over a seed layer). The serial electrically interconnected arrangement 500B of three series resonators 501B (Series1B), 502B (Series2B), 503B (Series3B), may include the second series resonator 502B (Series2B) (e.g., second bulk acoustic SHF or EHF wave resonator 502B) coupled between the second node 522B (e.g. comprising top interconnect 571B) and a third node 523B. The third node 523B may include a second bottom acoustic reflector of second series resonator 502B (Series2B) (e.g., second bottom acoustic reflector electrode of second series resonator 502B (Series2B)). The second bottom acoustic reflector of second series resonator 502B (Series2B) (e.g., second bottom acoustic reflector electrode of second series resonator 502B (Series2B)) may include an additional stack of an additional plurality of bottom metal electrode layers. The serial electrically interconnected arrangement 500B of three series resonators 501B (Series1B), 502B (Series2B), 503B (Series3B), may also include the third series resonator 503B (Series3B) (e.g., third bulk acoustic SHF or EHF wave resonator 503B) coupled between the third node 523B and a fourth node 524B (OutB). The third node 523B, e.g., including the additional plurality of bottom metal electrode layers, may electrically interconnect the second series resonator 502B (Series2B) and the third series resonator 503B (Series3B). The second bottom acoustic reflector (e.g., second bottom acoustic reflector electrode) of second series resonator 502B (Series2B) of the third node 523B, e.g., including the additional plurality of bottom metal electrode layers, may be a mutual bottom acoustic reflector (e.g., mutual bottom acoustic reflector electrode), and may likewise serve as bottom acoustic reflector (e.g., bottom acoustic reflector) of third series resonator 503B (Series3B). The fourth node 524B (OutB) may be associated with an output port of the serial electrically interconnected arrangement 500B of three series resonators 501B (Series1B), 502B (Series2B), 503B (Series3B). The fourth node 524B (OutB) may include electrical interconnect 571C. At lease portions of electrical interconnects 571B, 571C may comprise top current spreading layers.

The stack of the plurality of bottom metal electrode layers 517 through 525 are associated with the first bottom acoustic reflector (e.g., first bottom acoustic reflector electrode) of first series resonator 501B (Series1B). The additional stack of the additional plurality of bottom metal electrode layers (e.g., of the third node 523B) may be associated with the mutual bottom acoustic reflector (e.g., mutual bottom acoustic reflector electrode) of both the second series resonant 502B (Series2B) and the third series resonator 503B (Series3B). Although stacks of respective five bottom metal electrode layers are shown in simplified view in FIG. 5, in should be understood that the stacks may include respective larger numbers of bottom metal electrode layers, e.g., respective nine top metal electrode layers. Further, the first series resonator (Series1B), and the second series resonant 502B (Series2B) and the third series resonator 503B (Series3B) may all have the same, or approximately the same, or different (e.g., achieved by means of additional mass loading layers) resonant frequency (e.g., the same, or approximately the same, or different main resonant frequency). For example, small additional massloads (e.g, a tenth of the main shunt mass-load) of series and shunt resonators may help to reduce pass-band ripples in insertion loss, as may be appreciated by one with skill in the art. The bottom metal electrode layers 517 through 525 and the additional plurality of bottom metal electrode layers (e.g., of the mutual bottom acoustic reflector, e.g., of the third node 523B) may have respective thicknesses that are related to wavelength (e.g., acoustic wavelength) for the resonant frequency (e.g., main resonant frequency) of the series resonators (e.g., first series resonator 501B (Series1B), e.g., second series resonator 502B, e.g., third series resonator (503B)).

Various embodiments for series resonators (e.g., first series resonator 501B (Series1B), e.g., second series resonator 502B, e.g., third series resonator (503B)) having various relatively higher resonant frequency (e.g., higher main resonant frequency) may have relatively thinner bottom metal electrode thicknesses, e.g., scaled thinner with relatively higher resonant frequency (e.g., higher main resonant frequency). Similarly, various embodiments of the series resonators (e.g., first series resonator 501B (Series1B), e.g., second series resonator 502B, e.g., third series resonator (503B)) having various relatively lower resonant frequency (e.g., lower main resonant frequency) may have relatively thicker bottom metal electrode layer thicknesses, e.g., scaled thicker with relatively lower resonant frequency (e.g., lower main resonant frequency). The bottom metal electrode layers 517 through 525 and the additional plurality of bottom metal electrode layers (e.g., of the mutual bottom acoustic reflector, e.g., of the third node 523B) may include members of pairs of bottom metal electrodes having respective thicknesses of one quarter wavelength (e.g., one quarter acoustic wavelength) at the resonant frequency (e.g., main resonant frequency) of the series resonators (e.g., first series resonator 501B (Series1B), e.g., second series resonator 502B, e.g., third series resonator (503B)). The stack of bottom metal electrode layers 517 through 525 and the stack of additional plurality of bottom metal electrode layers (e.g., of the mutual bottom acoustic reflector, e.g., of the third node 523B) may include respective alternating stacks of different metals, e.g., different metals having different acoustic impedances (e.g., alternating relatively high acoustic impedance metals with relatively low acoustic impedance metals). The foregoing may provide acoustic impedance mismatches for facilitating acoustic reflectivity (e.g., SHF or EHF acoustic wave reflectivity) of the first bottom acoustic reflector (e.g., first bottom acoustic reflector electrode) of the first series resonator 501B (Series1B) and the mutual bottom acoustic reflector (e.g., of the third node 523B) of the second series resonator 502B (Series2B) and the third series resonator 503B (Series3B).

A first top acoustic reflector (e.g., first top acoustic reflector electrode) comprises a first stack of a first plurality of top metal electrode layers 535C through 543C of the first series resonator 501B (Series1B). A second top acoustic reflector (e.g., second top acoustic reflector electrode) comprises a second stack of a second plurality of top metal electrode layers 535D through 543D of the second series resonator 502B (Series2B). A third top acoustic reflector (e.g., third top acoustic reflector electrode) comprises a third stack of a third plurality of top metal electrode layers 535E through 543E of the third series resonator 503B (Series3B). Although stacks of respective five top metal electrode layers are shown in simplified view in FIG. 5, it should be understood that the stacks may include respective larger numbers of top metal electrode layers, e.g., respective nine bottom metal electrode layers. Further, the first plurality of top metal electrode layers 535C through 543C, the second plurality of top metal electrode layers 535D through 543D, and the third plurality of top metal electrode layers 535E through 543E may have respective thicknesses that are related to wavelength (e.g., acoustic wavelength) for the resonant frequency (e.g., main resonant frequency) of the series resonators (e.g., first series resonator 501B (Series1B), e.g., second series resonator 502B, e.g., third series resonator (503B)). Various embodiments for series resonators (e.g., first series resonator 501B (Series1B), e.g., second series resonator 502B, e.g., third series resonator (503B)) having various relatively higher resonant frequency (e.g., higher main resonant frequency) may have relatively thinner top metal electrode thicknesses, e.g., scaled thinner with relatively higher resonant frequency (e.g., higher main resonant frequency). Similarly, various embodiments of the series resonators (e.g., first series resonator 501B (Series1B), e.g., second series resonator 502B, e.g., third series resonator (503B)) having various relatively lower resonant frequency (e.g., lower main resonant frequency) may have relatively thicker top metal electrode layer thicknesses, e.g., scaled thicker with relatively lower resonant frequency (e.g., lower main resonant frequency). The first plurality of top metal electrode layers 535C through 543C, the second plurality of top metal electrode layers 535D through 543D, and the third plurality of top metal electrode layers 535E through 543E may include members of pairs of bottom metal electrodes having respective thicknesses of one quarter wavelength (e.g., one quarter acoustic wavelength) of the resonant frequency (e.g., main resonant frequency) of the series resonators (e.g., first series resonator 501B (Series1B), e.g., second series resonator 502B, e.g., third series resonator (503B)). The first stack of the first plurality of top metal electrode layers 535C through 543C, the second stack of the second plurality of top metal electrode layers 535D through 543D, and the third stack of the third plurality of top metal electrode layers 535E through 543E may include respective alternating stacks of different metals, e.g., different metals having different acoustic impedances (e.g., alternating relatively high acoustic impedance metals with relatively low acoustic impedance metals). The foregoing may provide acoustic impedance mismatches for facilitating acoustic reflectivity (e.g., SHF or EHF acoustic wave reflectivity) of the top acoustic reflectors (e.g., the first top acoustic reflector of the first series resonator 501B (Series1B), e.g., the second top acoustic reflector of the second series resonator 502B (Series2B), e.g., the third top acoustic reflector of the third series resonator 503B (Series3B)).

The first series resonator 501B (Series1B) may comprise a first alternating axis stack, e.g., an example first stack of four layers of alternating axis piezoelectric material, 505C through 511C. The second series resonator 502B (Series2B) may comprise a second alternating axis stack, e.g., an example second stack of four layers of alternating axis piezoelectric material, 505D through 511D. The third series resonator 503B (Series3B) may comprise a third alternating axis stack, e.g., an example third stack of four layers of alternating axis piezoelectric material, 505E through 511E. The first, second and third alternating axis piezoelectric stacks may comprise layers of Aluminum Nitride (AlN) having alternating C-axis wurtzite structures. For example, piezoelectric layers 505C, 505D, 505E, 509C, 509D, 509E have normal axis orientation. For example, piezoelectric layers 507C, 507D, 507E, 511C, 511D, 511E have reverse axis orientation. Members of the first stack of four layers of alternating axis piezoelectric material, 505C through 511C, and members of the second stack of four layers of alternating axis piezoelectric material, 505D through 511D, and members of the third stack of four layers of alternating axis piezoelectric material, 505E through 511E, may have respective thicknesses that are related to wavelength (e.g., acoustic wavelength) for the resonant frequency (e.g., main resonant frequency) of the series resonators (e.g., first series resonator 501B (Series1B), e.g., second series resonator 502B, e.g., third series resonator (503B)). Various embodiments for series resonators (e.g., first series resonator 501B (Series1B), e.g., second series resonator 502B, e.g., third series resonator (503B)) having various relatively higher resonant frequency (e.g., higher main resonant frequency) may have relatively thinner piezoelectric layer thicknesses, e.g., scaled thinner with relatively higher resonant frequency (e.g., higher main resonant frequency). Similarly, various embodiments of the series resonators (e.g., first series resonator 501B (Series1B), e.g., second series resonator 502B, e.g., third series resonator (503B)) having various relatively lower resonant frequency (e.g., lower main resonant frequency) may have relatively thicker piezoelectric layer thicknesses, e.g., scaled thicker with relatively lower resonant frequency (e.g., lower main resonant frequency). The example first stack of four layers of alternating axis piezoelectric material, 505C through 511C, the example second stack of four layers of alternating axis piezoelectric material, 505D through 511D and the example third stack of four layers of alternating axis piezoelectric material, 505D through 511D may include stack members of piezoelectric layers having respective thicknesses of approximately one half wavelength (e.g., one half acoustic wavelength) at the resonant frequency (e.g., main resonant frequency) of the series resonators (e.g., first series resonator 501B (Series1B), e.g., second series resonator 502B, e.g., third series resonator (503B)).

The example first stack of four layers of alternating axis piezoelectric material, 505C through 511C, may include a first three members of interposer layers 559C, 561C, 563C respectively sandwiched between the corresponding four layers of alternating axis piezoelectric material, 505C through 511C. First interposer layer 559C may be a first patterned interposer layer, 559C, as first patterned interposer layers are discussed in detail previously herein. Second interposer layer 561C may be a second patterned interposer layer 561C, as second patterned interposer layers are discussed in detail previously herein. For brevity and clarity, such discussions are referenced and incorporated, rather than explicitly repeated in full here.

The example second stack of four layers of alternating axis piezoelectric material, 505D through 511D, may include a second three members of interposer layers 559D, 561D, 563D respectively sandwiched between the corresponding four layers of alternating axis piezoelectric material, 505D through 511D. First interposer layer 559D may be a first patterned interposer layer 559D, as first patterned interposer layers are discussed in detail previously herein. Second interposer layer 561D may be a second patterned interposer layer 561D, as second patterned interposer layers are discussed in detail previously herein. For brevity and clarity, such discussions are referenced and incorporated, rather than explicitly repeated in full here.

The example third stack of four layers of alternating axis piezoelectric material, 505E through 511E, may include a third three members of interposer layers 559E, 561E, 563E respectively sandwiched between the corresponding four layers of alternating axis piezoelectric material, 505E through 511E. First interposer layer 559E may be a first patterned interposer layer 559E, as first patterned interposer layers are discussed in detail previously herein. Second interposer layer 561E may be a second patterned interposer layer 561E, as second patterned interposer layers are discussed in detail previously herein. For brevity and clarity, such discussions are referenced and incorporated, rather than explicitly repeated in full here.

One or more (e.g., one or a plurality of) interposer layers may comprise metal. The metal interposer layers may comprise relatively high acoustic impedance metal interposer (e.g., using relatively high acoustic impedance metals such as Tungsten (W) or Molybdenum (Mo)). Alternatively or additionally, one or more (e.g., one or a plurality of) interposer layers may comprise dielectric. The dielectric may be a dielectric that has a positive acoustic velocity temperature coefficient, so acoustic velocity increases with increasing temperature of the dielectric. The dielectric may comprise, for example, silicon dioxide. Dielectric of interposer layers may, but need not, facilitate compensating for frequency response shifts with increasing temperature. Alternatively or additionally, one or more (e.g., one or a plurality of) interposer layers may comprise metal and dielectric for respective interposer layers.

The first series resonator 501B (Series1B), the second series resonator 502B (Series2B) and the third series resonator 503B (Series3B) may have respective etched edge regions 553C, 553D, 553E, and respective laterally opposing etched edge regions 554C, 554D, 554E. Reference is made to resonator mesa structures as have already been discussed in detail previously herein. Accordingly, they are not discussed again in detail at this point. Briefly, respective first, second and third mesa structures of the respective first series resonator 501B (Series1B), the respective second series resonator 502B (Series2B) and the respective third series resonator 503B (Series3B) may extend between respective etched edge regions 553C, 553D, 553E, and respective laterally opposing etched edge regions 554C, 554D, 554E of the respective first series resonator 501B (Series1B), the respective second series resonator 502B (Series2B) and the respective third series resonator 503B (Series3B). The second bottom acoustic reflector of second series resonator 502B (Series2B) of the third node 523B, e.g., including the additional plurality of bottom metal electrode layers may be a second mesa structure. For example, this may be a mutual second mesa structure bottom acoustic reflector 523B, and may likewise serve as bottom acoustic reflector of third series resonator 503B (Series3B). Accordingly, this mutual second mesa structure bottom acoustic reflector 523B may extend between etched edge region 553E of the third series resonator 503B (Series3B) and the laterally opposing etched edge region 554D of the third series resonator 503B (Series3B).

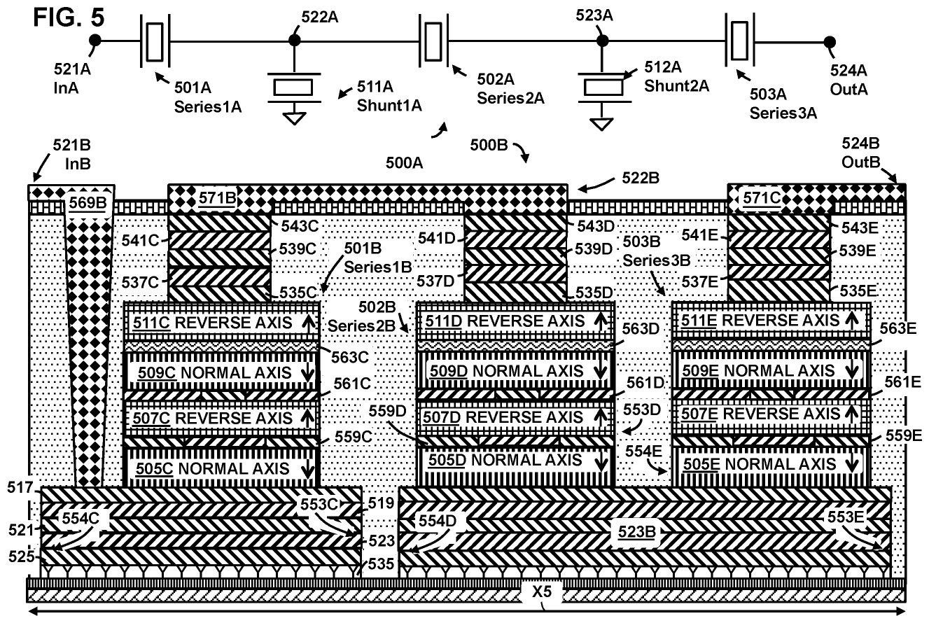

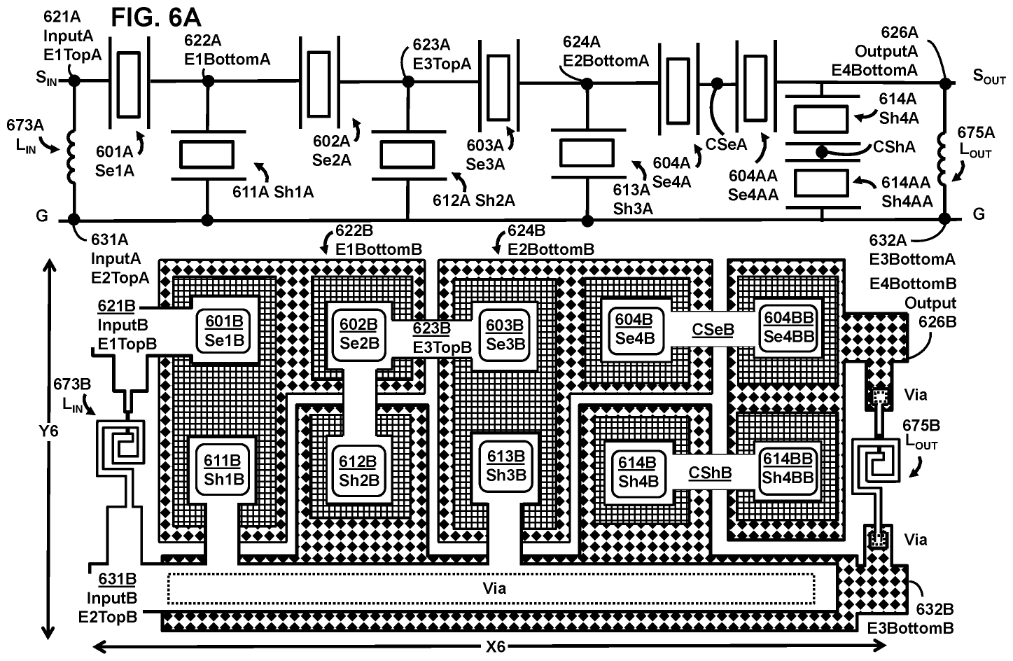

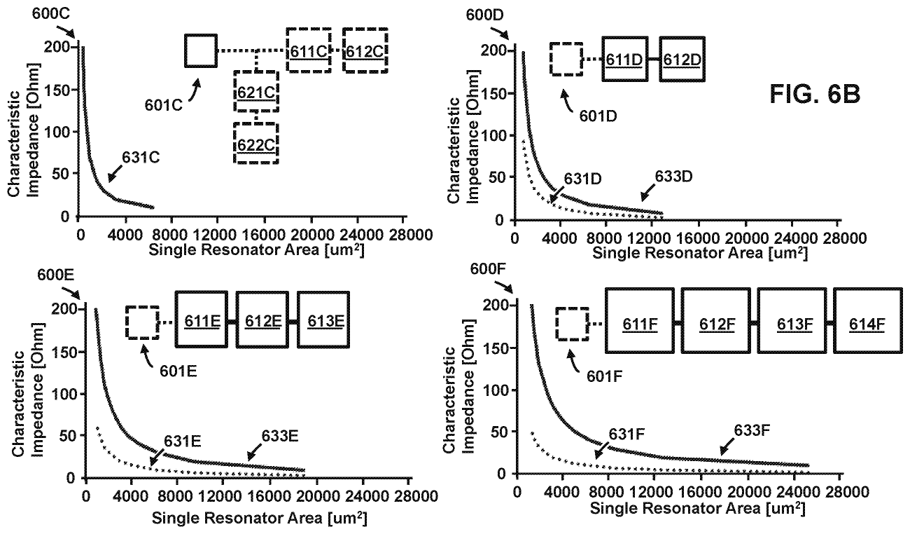

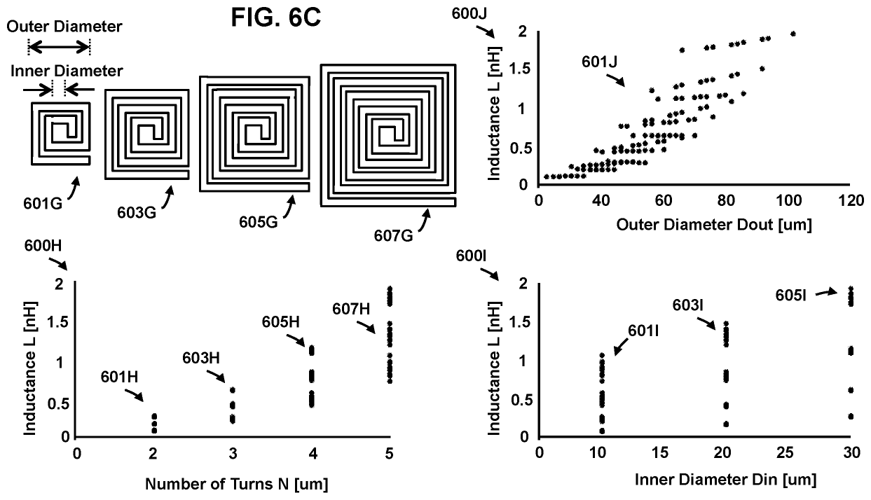

FIG. 6A shows a schematic of an example ladder filter 600A (e.g., SHF or EHF wave ladder filter 600A) using five series resonators of the bulk acoustic wave resonator structure of FIG. 1A (e.g., five bulk acoustic SHF or EHF wave resonators), and five mass loaded shunt resonators of the bulk acoustic wave resonator structure of FIG. 1A (e.g., five mass loaded bulk acoustic SHF or EHF wave resonators), including schematic representations of input coupled integrated inductor 673A and output coupled integrated inductor 675A. Corresponding to the example ladder filter 600A shown in schematic view, FIG. 6B also shows a simplified top view of the ten resonators interconnected in the example ladder filter 600B, along with input and output coupled integrated inductors 673B, 673B, and lateral dimensions of the example ladder filter 600B.

As shown in the schematic appearing at an upper section of FIG. 6A, the example ladder filter 600A may include an input port comprising a first node 621A (InputA ElTopA), and may include a first series resonator 601A (SelA) (e.g., first bulk acoustic SHF or EHF wave resonator 601A) coupled between the first node 621A (InputA ElTopA) associated with the input port and a second node 622A (E1BottomA). Input coupled integrated inductor 673A may be coupled between first node 621A (InputA ElTopA) and a first input grounding node 631A (E2TopA).

The example ladder filter 600A may also include a second series resonator 602A (Se2A) (e.g., second bulk acoustic SHF or EHF wave resonator 602A) coupled between the second node 622A (E1BottomA) and a third node 623A (E3TopA). The example ladder filter 600A may also include a third series resonator 603A (Se3A) (e.g., third bulk acoustic SHF or EHF wave resonator 603A) coupled between the third node 623A (E3TopA) and a fourth node 624A (E2BottomA). The example ladder filter 600A may also include a fourth and fifth cascade node coupled series resonators 604A (Se4A), 604AA (Se4AA) (e.g., fourth and fifth cascade node coupled bulk acoustic SHF or EHF wave resonators 604A, 604AA) coupled between the fourth node 624A (E2BottomA) and a sixth node 626A (OutputA E4BottomA). Fourth and fifth cascade node coupled series resonators 604A (Se4A), 604AA (Se4AA) (e.g., fourth and fifth cascade node coupled bulk acoustic SHF or EHF wave resonators 604A, 604AA) may be coupled to one another at cascade series branch node CSeA.

The example ladder filter 600A may also comprise the sixth node 626A (OutputA E4BottomA) and may further comprise a second grounding node 632A (E3BottomA), which may be associated with an output port of the ladder filter 600A. Output coupled integrated inductor 675A may be coupled between the sixth node 626A (OutputA E4BottomA) and the second grounding node 632A (E3BottomA).

The example ladder filter 600A may also include a first mass loaded shunt resonator 611A (Sh1A) (e.g., first mass loaded bulk acoustic SHF or EHF wave resonator 611A) coupled between the second node 622A (E1BottomA) and first grounding node 631A (E2TopA). The example ladder filter 600A may also include a second mass loaded shunt resonator 612A (Sh2A) (e.g., second mass loaded bulk acoustic SHF or EHF wave resonator 612A) coupled between the third node 623A (E3TopA) and second grounding node (E3BottomA). The example ladder filter 600A may also include a third mass loaded shunt resonator 613A (Sh3A) (e.g., third mass loaded bulk acoustic SHF or EHF wave resonator 613A) coupled between the fourth node 624A (E2BottomA) and the first grounding node 631A (E2TopA). The example ladder filter 600A may also include fourth and fifth cascade node coupled mass loaded shunt resonators 614A (Sh4A), 614A (Sh4A) (e.g., fourth and fifth mass loaded bulk acoustic SHF or EHF wave resonators 614A, 614AA) coupled between the sixth node 626A (OutputA E4BottomA) and the second grounding node 632A (E3BottomA). Fourth and fifth cascade node coupled mass loaded shunt resonators 614A (Sh4A), 614A (Sh4A) (e.g., fourth and fifth mass loaded bulk acoustic SHF or EHF wave resonators 614A, 614AA) may be coupled to one another at cascade shunt branch node CShA. The first grounding node 631A (E2TopA) and the second grounding node 632A (E3BottomA) may be interconnected to each other.

Appearing at a lower section of FIG. 6A is the simplified top view of the ten resonators interconnected in the example ladder filter 600B, and lateral dimensions of the example ladder filter 600B. The example ladder filter 600B may include an input port comprising a first node 621B (InputA E1TopB), and may include a first series resonator 601B (Se1B) (e.g., first bulk acoustic SHF or EHF wave resonator 601B) coupled between (e.g., sandwiched between) the first node 621B (InputA E1TopB) associated with the input port and a second node 622B (E1BottomB). Input integrated inductor 673G may be coupled between the first node 621B (InputA E1TopB) associated with the input port and first input grounding node 631B (E2TopB) associated with the input port.

The example ladder filter 600B may also include a second series resonator 602B (Se2B) (e.g., second bulk acoustic SHF or EHF wave resonator 602B) coupled between (e.g., sandwiched between) the second node 622B (E1BottomB) and a third node 623B (E3TopB). The example ladder filter 600B may also include a third series resonator 603B (Se3B) (e.g., third bulk acoustic SHF or EHF wave resonator 603B) coupled between (e.g., sandwiched between) the third node 623B (E3TopB) and a fourth node 624B (E2BottomB). The example ladder filter 600B may also include fourth and fifth cascade node coupled series resonators 604B (Se4B), 604BB (Se4BB) (e.g., fourth and fifth bulk acoustic SHF or EHF wave resonators 604B, 604BB) coupled between (e.g., sandwiched between) the fourth node 624B (E2BottomB) and a sixth node 626A (OutputB E4BottomB). Fourth and fifth cascade node coupled series resonators 604B (Se4B), 604BB (Se4BB) (e.g., fourth and fifth bulk acoustic SHF or EHF wave resonators 604B, 604BB) may be coupled to one another by cascade series branch node CSeB. The example ladder filter 600B may comprise the sixth node 626B (OutputB E4BottomB) and may further comprise a second grounding node 632B (E3BottomB), which may be associated with an output port of the ladder filter 600B. Output coupled integrated inductor 675B may be coupled between the sixth node 626B (OutputB E4BottomB) and the second grounding node 632B (E3BottomB).

The example ladder filter 600B may also include a first mass loaded shunt resonator 611B (Sh1B) (e.g., first mass loaded bulk acoustic SHF or EHF wave resonator 611B) coupled between (e.g., sandwiched between) the second node 622B (E1BottomB) and a first grounding node 631B (E2TopB). The example ladder filter 600B may also include a second mass loaded shunt resonator 612B (Sh2B) (e.g., second mass loaded bulk acoustic SHF or EHF wave resonator 612B) coupled between (e.g., sandwiched between) the third node 623B (E3TopB) and first grounding node 631B (E2TopB). First grounding node 631B (E2TopB) and the second grounding node 632B (E3BottomB) may be electrically coupled to one another through a via. The example ladder filter 600B may also include a third mass loaded shunt resonator 613B (Sh3B) (e.g., third mass loaded bulk acoustic SHF or EHF wave resonator 613B) coupled between (e.g., sandwiched between) the fourth node 624B (E2BottomB) and the second grounding node 632B (E3BottomB). The example ladder filter 600B may also include fourth and fifth cascade node coupled mass loaded shunt resonators 614B (Sh4B), 614BB (Sh4BB) (e.g., fourth and fifth mass loaded bulk acoustic SHF or EHF wave resonators 614B, 614BB) coupled between (e.g., sandwiched between) the sixth node 626B (OutputB E4BottomB) and the second grounding node 623B (E3BottomB). Fourth and fifth cascade node coupled mass loaded shunt resonators 614B (Sh4B), 614BB (Sh4BB) (e.g., fourth and fifth mass loaded bulk acoustic SHF or EHF wave resonators 614B, 614BB) may be coupled to one another by cascade shunt branch node CShB. Output coupled integrated inductor 675B may be coupled between the sixth node 626B (OutputB E4BottomB) and the second grounding node 632B (E3BottomB). The example ladder filter 600B may respectively be relatively small in size, and may respectively have lateral dimensions (X6 by Y6) of less than approximately one millimeter by one millimeter.

For simplicity and clarity, ten resonators are shown as similarly sized in the example ladder filter 600B. However, it should be understood that despite appearances in FIG. 6A, there may be different (e.g., larger) sizing of four cascaded resonators relative to remaining six non-cascaded resonators shown in FIG. 6A. For example, the four cascaded resonators (e.g., fourth and fifth cascade node coupled series resonators 604B (Se4B), 604BB (Se4BB) (e.g., fourth and fifth bulk acoustic SHF or EHF wave resonators 604B, 604BB), e.g., fourth and fifth cascade node coupled mass loaded shunt resonators 614B (Sh4B), 614BB (Sh4BB)) may be differently sized (e.g., larger sized) than the remaining six non-cascaded resonators shown in FIG. 6A. Along with different (e.g., larger) size, the four cascaded resonators (e.g., fourth and fifth cascade node coupled series resonators 604B (Se4B), 604BB (Se4BB) (e.g., fourth and fifth bulk acoustic SHF or EHF wave resonators 604B, 604BB), e.g., fourth and fifth cascade node coupled mass loaded shunt resonators 614B (Sh4B), 614BB (Sh4BB)) may have greater power handling capability than the remaining six non-cascaded resonators shown in FIG. 6A. These and other attributes for cascaded resonators versus non-cascaded resonators, as well as additional alternative arrangements of cascaded resonators versus non-cascaded resonators are discussed in greater detail next with reference to FIG. 6B.

FIG. 6B shows four charts 600C, 600D, 600E, 600F with results as expected from simulation along with corresponding simplified example cascade arrangements of resonators similar to the bulk acoustic wave resonator structure of FIG. 1A. An upper left hand corner of FIG. 6B shows a simplified view of a non-cascaded resonator 601C in solid line depiction coupled in dotted line to dotted line depictions of a pair of series branch cascade node coupled series resonators 611C, 612C. Non-cascaded resonator 601C in solid line depiction is also coupled in dotted line to dotted line depictions of a pair of shunt branch cascade node coupled shunt resonators 621C, 622C. Lateral size (e.g., lateral area) of respective members of the pair of series branch cascade node coupled series resonators 611C, 612C is depicted as different (e.g., relatively larger, e.g., about twice as large) as non-cascaded resonator 601C. Power handing of respective members of the pair of series branch cascade node coupled series resonators 611C, 612C may be different (e.g., relatively larger, e.g., about twice as large) as power handling of non-cascaded resonator 601C. Lateral size (e.g., lateral area) of respective members of the pair of shunt branch cascade node coupled shunt resonators 621C, 622C is depicted as different (e.g., relatively larger, e.g., about twice as large) as non-cascaded resonator 601C. Power handling of respective members of the pair of shunt branch cascade node coupled shunt resonators 621C, 622C may be different (e.g., relatively larger, e.g., about twice as large) as power handling of non-cascaded resonator 601C.

Electrical characteristic impedance of respective members of the pair of series branch cascade node coupled series resonators 611C, 612C may be different (e.g., relatively smaller, e.g., about half as large) than electrical character impedance of non-cascaded resonator 601C. For example, electrical characteristic impedance of first member 611C of the pair of series branch cascade node coupled series resonators 611C, 612C may be different (e.g., relatively smaller, e.g., about half as large) than electrical character impedance of non-cascaded resonator 601C. For example, electrical characteristic impedance of second member 612C of the pair of series branch cascade node coupled series resonators 611C, 612C may be different (e.g., relatively smaller, e.g., about half as large) than electrical character impedance of non-cascaded resonator 601C. For example, in a case where electrical character impedance of non-cascaded resonator 601C may be about fifty (50) Ohms: electrical characteristic impedance of first member 611C may be about twenty-five (25) Ohms; electrical characteristic impedance of second member 612C may be about twenty-five (25) Ohms. Combined respective electrical characteristic impedance of members of the pair of series branch cascade node coupled series resonators 611C, 612C may approximate (e.g., may substantially match) electrical characteristic impedance of non-cascaded resonator 601C (e.g., 25 Ohms for 611C plus 25 Ohms for 612C may approximate 50 Ohms for 601C). Ladder filters as discussed may have a series branch characteristic impedance e.g., fifty (50) Ohms. Combined respective electrical characteristic impedance of members of the pair of series branch cascade node coupled series resonators 611C, 612C may approximate (e.g., may substantially match) the series branch characteristic impedance (e.g., 25 Ohms for 611C plus 25 Ohms for 612C may approximate 50 Ohms for series branch). More broadly, ladder filters as discussed may have a characteristic impedance e.g., fifty (50) Ohms. Combined respective electrical characteristic impedance of members of the pair of series branch cascade node coupled series resonators 611C, 612C may approximate (e.g., may substantially match) the filter characteristic impedance (e.g., 25 Ohms for 611C plus 25 Ohms for 612C may approximate 50 Ohms for filter).

Similarly, electrical characteristic impedance of respective members of the pair of shunt branch cascade node coupled shunt resonators 621C, 622C may be different (e.g., relatively smaller, e.g., about half as large) than electrical character impedance of non-cascaded resonator 601C. For example, electrical characteristic impedance of first member 621C of the pair of shunt branch cascade node coupled shunt resonators 621C, 622C may be different (e.g., relatively smaller, e.g., about half as large) than electrical character impedance of non-cascaded resonator 601C. For example, electrical characteristic impedance of second member 622C of the pair of shunt branch cascade node coupled shunt resonators 621C, 622C may be different (e.g., relatively smaller, e.g., about half as large) than electrical character impedance of non-cascaded resonator 601C. For example, in a case where electrical character impedance of non-cascaded resonator 601C may be about fifty (50) Ohms: electrical characteristic impedance of first member 621C may be about twenty-five (25) Ohms; electrical characteristic impedance of second member 622C may be about twenty-five (25) Ohms. Combined respective electrical characteristic impedance of members of the pair of shunt branch cascade node coupled shunt resonators 621C, 622C may approximate (e.g., may substantially match) electrical characteristic impedance of non-cascaded resonator 601C (e.g., 25 Ohms for 621C plus 25 Ohms for 622C may approximate 50 Ohms for 601C). Ladder filters as discussed may have a shunt branch characteristic impedance e.g., fifty (50) Ohms. Combined respective electrical characteristic impedance of members of the pair of shunt branch cascade node coupled shunt resonators 621C, 622C may approximate (e.g., may substantially match) the shunt branch characteristic impedance (e.g., 25 Ohms for 621C plus 25 Ohms for 622C may approximate 50 Ohms for shunt branch). More broadly, ladder filters as discussed may have a characteristic impedance e.g., fifty (50) Ohms. Combined respective electrical characteristic impedance of members of the pair of shunt branch cascade node coupled shunt resonators 621C, 622C may approximate (e.g., may substantially match) the filter characteristic impedance (e.g., 25 Ohms for 621C plus 25 Ohms for 622C may approximate 50 Ohms for filter).

In the upper left hand corner of FIG. 6B, corresponding chart 600C shows electrical characteristic impedance of non-cascaded resonator 601C versus single resonator area of non-cascaded resonator 601C. Trace 631C shows electrical characteristic impedance of non-cascaded resonator 601C decreasing and ranging from less than about 200 Ohms to greater than about ten Ohms as single resonator area of non-cascaded resonator 601C increases and ranges from greater than three hundred square microns to less than about six thousand square microns. Cascaded bulk acoustic wave resonators with different than fifty (50) Ohm electrical characteristic impedances in shunt or series branches may facilitate particular acoustic filter design goals, e.g., steeper roll-off, e.g., larger out-of-band rejection. This may be facilitated with resonators having characteristic impedance substantially different than approximately fifty (50) Ohm electrical characteristic impedance. For illustrative but non-limiting purposes, the example area ranges presented corresponds to a bulk acoustic waver resonator similar to what is shown in FIG. 1A and designed to operate at about 24 GHz. However various other area ranges are possible for various alternative bulk acoustic wave resonators of this disclosure and various bulk acoustic wave resonators of this disclosure configured to operate at different frequencies than 24 GHz, as will be appreciated by one skilled in the art upon reading this disclosure.

An upper right hand corner of FIG. 6B shows a simplified view of a non-cascaded resonator 601D in dotted line depiction coupled in dotted line to solid line depictions of a pair of series branch cascade node coupled series resonators 611D, 612D. Lateral size (e.g., lateral area) of respective members of the pair of series branch cascade node coupled series resonators 611D, 612D is depicted as different (e.g., relatively larger, e.g., about one and four tenths times as large) as non-cascaded resonator 601D. Power handing of respective members of the pair of series branch cascade node coupled series resonators 611C, 612C may be different (e.g., relatively larger, e.g., about twice as large) as power handling of non-cascaded resonator 601C.

In the upper right hand corner of FIG. 6B, corresponding chart 600D shows in dotted line trace 631D the electrical characteristic impedance of single cascaded resonator in cascaded pair 611D and 612D versus single resonator area of in cascaded resonator pair 611D and 612D. Trace 631D shows electrical characteristic impedance of a single resonator in cascaded resonator pair 611D and 612D decreasing and ranging from less than about 100 Ohms to greater than about 5 Ohms as single resonator area in cascaded resonator pair 611D and 612D increases and ranges from greater than 600 of square microns to less than about 12000 thousand square microns. In the upper right hand corner of FIG. 6B, corresponding chart 600D also shows in solid line trace 633D the electrical characteristic impedance of cascaded resonator pair 611D and 612D versus single resonator area in cascaded resonator pair 611D and 612D. Trace 633D shows electrical characteristic impedance of cascaded resonator 611D decreasing and ranging from less than about 200 Ohms to greater than about a 10 Ohms as single resonator area in cascaded resonator pair 611D and 612D increases and ranges from greater than 600 of square microns to less than about 12000 thousand square microns. For example, non-cascaded resonator 601D may have an electrical characteristic impedance of about fifty (50) Ohms and a lateral area of about 1260 square microns. For example, cascaded resonator 611D may have an electrical characteristic impedance of about twenty-five (25) Ohms and a lateral area of about 2520 square microns. Similarly cascaded resonator 612D may have an electrical characteristic impedance of about twenty-five (25) Ohms and a lateral area of about 2520 square microns. Cascaded bulk acoustic wave resonators with different than fifty (50) Ohm electrical characteristic impedances in shunt or series branches may facilitate particular acoustic filter design goals, e.g., steeper roll-off, e.g., larger out-of-band rejection. This may be facilitated with resonators having characteristic impedance substantially different than approximately fifty (50) Ohm electrical characteristic impedance. For illustrative but non-limiting purposes, the example area ranges presented corresponds to a bulk acoustic waver resonator similar to what is shown in FIG. 1A and designed to operate at about 24 GHz. However various other area ranges are possible for various alternative bulk acoustic wave resonators of this disclosure and various bulk acoustic wave resonators of this disclosure configured to operate at different frequencies than 24 GHz, as will be appreciated by one skilled in the art upon reading this disclosure.

The lower left hand corner of FIG. 6B shows a simplified view of a non-cascaded resonator 601E in dotted line depiction coupled in dotted line to solid line depictions of a trio of series branch cascade nodes coupled series resonators 611E, 612E, 613E. Lateral size (e.g., lateral area) of respective members of the trio of series branch cascade nodes coupled series resonators 611E, 612E, 613E is depicted as different (e.g., relatively larger, e.g., about one and seven tenths times as large) as non-cascaded resonator 601E. Power handing of respective members of the trio of series branch cascade nodes coupled series resonators 611E, 612E, 613E may be different (e.g., relatively larger, e.g., about three times as large) as power handling of non-cascaded resonator 601E. Electrical characteristic impedance of respective members of the trio of series branch cascade nodes coupled series resonators 611E, 612E, 613E may be different (e.g., relatively smaller, e.g., three times small) than electrical character impedance of non-cascaded resonator 601E. For example, electrical characteristic impedance of first member 611E of the trio of series branch cascade nodes coupled series resonators 611E, 612E, 613E may be different (e.g., relatively smaller, e.g., about three times smaller) than electrical character impedance of non-cascaded resonator 601E. For example, electrical characteristic impedance of second member 612E of the trio of series branch cascade nodes coupled series resonators 611E, 612E, 613E may be different (e.g., relatively smaller, e.g., about three times smaller) than electrical character impedance of non-cascaded resonator 601E. For example, electrical characteristic impedance of third member 613E of the trio of series branch cascade nodes coupled series resonators 611E, 612E, 613E may be different (e.g., relatively smaller, e.g., about a three time smaller) than electrical character impedance of non-cascaded resonator 601E. For example, in a case where electrical character impedance of non-cascaded resonator 601E may be about fifty (50) Ohms: electrical characteristic impedance of first member 611E may be about sixteen and two thirds (16.6) Ohms; electrical characteristic impedance of second member 612E may be about sixteen and two thirds (16.6) Ohms; electrical characteristic impedance of third member 613E may be about sixteen and two thirds (16.6) Ohms. Combined respective electrical characteristic impedance of members of the trio of series branch cascade nodes coupled series resonators 611E, 612E, 613E may approximate (e.g., may substantially match) electrical characteristic impedance of non-cascaded resonator 601E (e.g., 16.6 Ohms for 611E plus 16.6 Ohms for 612E plus 16.6 Ohms for 613E may approximate 50 Ohms for 601E). Ladder filters as discussed may have a series branch characteristic impedance e.g., fifty (50) Ohms. Combined respective electrical characteristic impedance of members of the trio of series branch cascade nodes coupled series resonators 611E, 612E, 613E may approximate (e.g., may substantially match) the series branch characteristic impedance (e.g., 16.6 Ohms for 611E plus 16.6 Ohms for 612E plus 16.6 Ohms for 613E may approximate 50 Ohms for series branch). More broadly, ladder filters as discussed may have a characteristic impedance e.g., fifty (50) Ohms. Combined respective electrical characteristic impedance of members of the trio of series branch cascade nodes coupled series resonators 611E, 612E, 613E may approximate (e.g., may substantially match) the filter characteristic impedance (e.g., 16.6 Ohms for 611E plus 16.6 Ohms for 612E plus 16.6 Ohms for 613E may approximate 50 Ohms for filter). Cascaded bulk acoustic wave resonators with different than fifty (50) Ohm electrical characteristic impedances in shunt or series branches may facilitate particular acoustic filter design goals, e.g., steeper roll-off, e.g., larger out-of-band rejection. This may be facilitated with resonators having characteristic impedance substantially different than approximately fifty (50) Ohm electrical characteristic impedance. For illustrative but non-limiting purposes, the example area ranges presented corresponds to a bulk acoustic waver resonator similar to what is shown in FIG. 1A and designed to operate at about 24 GHz. However various other area ranges are possible for various alternative bulk acoustic wave resonators of this disclosure and various bulk acoustic wave resonators of this disclosure configured to operate at different frequencies than 24 GHz, as will be appreciated by one skilled in the art upon reading this disclosure.

In the lower left hand corner of FIG. 6B, corresponding chart 600E shows in dotted line trace 631E the electrical characteristic impedance of a single cascaded resonator in a resonator trio 611E, 612E and 613E versus single resonator area in a cascaded resonator trio 611E, 612E and 613E. Trace 631E shows electrical characteristic impedance of a single cascaded resonator in a resonator trio 611E, 612E and 613E decreasing and ranging from less than about 67 Ohms to greater than about 3 Ohms as single resonator area of a single cascaded resonator in a resonator trio 611E, 612E and 613E increases and ranges from greater than 940 of square microns to less than about 19000 square microns. In the lower left hand corner of FIG. 6B, corresponding chart 600E also shows in solid line trace 633E the electrical characteristic impedance of cascaded resonator trio 611E, 612E and 613 versus a single cascaded resonator area in a resonator trio 611E, 612E and 613E. Trace 633E shows electrical characteristic impedance of cascaded resonator trio 611E, 612E and 613 decreasing and ranging from less than about 200 Ohms to greater than about a 10 Ohms as single resonator area of cascaded resonator 611E increases and ranges from greater than 940 square microns to less than about 19000 thousand square microns. For example, non-cascaded resonator 601E may have an electrical characteristic impedance of about fifty (50) Ohms and a lateral area of about 1260 square microns. For example, cascaded resonator 611E may have an electrical characteristic impedance of about sixteen and two thirds (16.6) Ohms and a lateral area of about 3780 square microns. Similarly cascaded resonator 612E may have an electrical characteristic impedance of about sixteen and two thirds (16.6) Ohms and a lateral area of about 3780 square microns. Similarly cascaded resonator 613E may have an electrical characteristic impedance of about sixteen and two thirds (16.6) Ohms and a lateral area of about 3780 square microns

The lower right hand corner of FIG. 6B shows a simplified view of a non-cascaded resonator 601F in dotted line depiction coupled in dotted line to solid line depictions of a quad of series branch cascade nodes coupled series resonators 611F, 612F, 613F, 614F. Lateral size (e.g., lateral area) of respective members of the quad of series branch cascade nodes coupled series resonators 611F, 612F, 613F, 614F is depicted as different (e.g., relatively larger, e.g., about twice as large) as non-cascaded resonator 601E. Power handing of respective members of the quad of series branch cascade nodes coupled series resonators 611F, 612F, 613F, 614F may be different (e.g., relatively larger, e.g., about four times as large) as power handling of non-cascaded resonator 601F. Electrical characteristic impedance of respective members of the quad of series branch cascade nodes coupled series resonators 611F, 612F, 613F, 614F may be different (e.g., relatively smaller, e.g., about four times smaller) than electrical character impedance of non-cascaded resonator 601F. For example, electrical characteristic impedance of first member 611E of the quad of series branch cascade nodes coupled series resonators 611F, 612F, 613F, 614F may be different (e.g., relatively smaller, e.g., about a four times smaller) than electrical character impedance of non-cascaded resonator 601F. For example, electrical characteristic impedance of second member 612F of the quad of series branch cascade nodes coupled series resonators 611F, 612F, 613F, 614F may be different (e.g., relatively smaller, e.g., about four times smaller) than electrical character impedance of non-cascaded resonator 601F. For example, electrical characteristic impedance of third member 613F of the quad of series branch cascade nodes coupled series resonators 611F, 612F, 613F, 614F may be different (e.g., relatively smaller, e.g., about four times smaller) than electrical character impedance of non-cascaded resonator 601F. For example, electrical characteristic impedance of fourth member 614F of the quad of series branch cascade nodes coupled series resonators 611F, 612F, 613F, 614F may be different (e.g., relatively smaller, e.g., about four times smaller) than electrical character impedance of non-cascaded resonator 601F. For example, in a case where electrical character impedance of non-cascaded resonator 601F may be about fifty (50) Ohms: electrical characteristic impedance of first member 611F may be about twelve and a half (12.5) Ohms; electrical characteristic impedance of second member 612F may be about twelve and a half (12.5) Ohms; electrical characteristic impedance of third member 613F may be about twelve and a half (12.5) Ohms. Combined respective electrical characteristic impedance of members of the quad of series branch cascade nodes coupled series resonators 611F, 612F, 613F, 614F may approximate (e.g., may substantially match) electrical characteristic impedance of non-cascaded resonator 601F (e.g., 12.5 Ohms for 611F plus 12.5 Ohms for 612F plus 12.5 Ohms for 613F plus 12.5 Ohms for 614F may approximate 50 Ohms for 601F). Ladder filters as discussed may have a series branch characteristic impedance e.g., fifty (50) Ohms. Combined respective electrical characteristic impedance of members of the quad of series branch cascade nodes coupled series resonators 611F, 612F, 613F, 614F may approximate (e.g., may substantially match) the series branch characteristic impedance (e.g., 12.5 Ohms for 611F plus 12.5 Ohms for 612E plus 12.5 Ohms for 613F plus 12.5 Ohms for 614F may approximate 50 Ohms for series branch). More broadly, ladder filters as discussed may have a characteristic impedance e.g., fifty (50) Ohms. Combined respective electrical characteristic impedance of members of the quad of series branch cascade nodes coupled series resonators 611F, 612F, 613F, 614F may approximate (e.g., may substantially match) the filter characteristic impedance (e.g., 12.5 Ohms for 611F plus 12.5 Ohms for 612E plus 12.5 Ohms for 613F plus 12.5 Ohms for 614F may approximate 50 Ohms for filter).

In the lower right hand corner of FIG. 6B, corresponding chart 600F shows in dotted line trace 631E the electrical characteristic impedance of a single resonator in cascaded resonator 611F, 612F, 613F and 614F quad versus single resonator area in cascaded resonator 611F, 612F, 613F and 614F quad. Trace 631F shows electrical characteristic impedance of a single resonator in cascaded resonator 611F, 612F, 613F and 614F quad decreasing and ranging from less than about 50 Ohms to greater than about a 2.5 Ohms as single resonator area in a cascaded resonator 611F, 612F, 613F and 614F quad increases and ranges from greater than 1260 square microns to less than about 25000 square microns. In the lower right hand corner of FIG. 6B, corresponding chart 600F also shows in solid line trace 633F the electrical characteristic impedance of cascaded resonator 611F, 612F, 613F and 614F quad versus single resonator area in a cascaded resonator 611F, 612F, 613F and 614F quad. Trace 633E shows electrical characteristic impedance of cascaded resonator 611F, 612F, 613F and 614F quad decreasing and ranging from less than about 200 Ohms to greater than about a 12.5 Ohms as single resonator area in a cascaded resonator 611F, 612F, 613F and 614F quad increases and ranges from greater than 1260 square microns to less than about 25000 square microns. For example, non-cascaded resonator 601F may have an electrical characteristic impedance of about fifty (50) Ohms and a lateral area of about 1260 square microns. For example, cascaded resonator 611F may have an electrical characteristic impedance of about twelve and a half (12.5) Ohms and a lateral area of about 5040 square microns. Similarly cascaded resonator 612F may have an electrical characteristic impedance of about twelve and a half (12.5) Ohms and a lateral area of about 5040 square microns. Similarly cascaded resonator 613F may have an electrical characteristic impedance of about twelve and a half (12.5) Ohms and a lateral area of about 5040 square microns. Cascaded bulk acoustic wave resonators with different than fifty (50) Ohm electrical characteristic impedances in shunt or series branches may facilitate particular acoustic filter design goals, e.g., steeper roll-off, e.g., larger out-of-band rejection. This may be facilitated with resonators having characteristic impedance substantially different than approximately fifty (50) Ohm electrical characteristic impedance. For illustrative but non-limiting purposes, the example area ranges presented corresponds to a bulk acoustic waver resonator similar to what is shown in FIG. 1A and designed to operate at about 24 GHz. However various other area ranges are possible for various alternative bulk acoustic wave resonators of this disclosure and various bulk acoustic wave resonators of this disclosure configured to operate at different frequencies than 24 GHz, as will be appreciated by one skilled in the art upon reading this disclosure.

FIG. 6C shows four alternative example integrated inductors 601G, 603G, 605G, 607G along with three corresponding inductance charts showing versus number of turns (Chart 600H), showing versus inner diameter (Chart 600I) and showing versus outer diameter (Chart 600J), with results as expected from approximate simulations. Example integrated inductor 601G may comprise two turns. Example integrated inductor 603G may comprise three turns. Example integrated inductor 605G may comprise four turns. Example integrated inductor 607G may comprise five turns. Example integrated inductors 601G, 603G, 605G, 607G may be spiral. Example integrated inductors 601G, 603G, 605G, 607G may be substantially planar. Example integrated inductors 601G, 603G, 605G, 607G may have respective inner diameters. Example integrated inductors 601G, 603G, 605G, 607G may have respective outer diameters.

Chart 600H shows inductance versus number of turns. For two turns, trace 601H shows inductance increasing and ranging from greater than about 0.09 nanoHenries to less than about 0.28 nanoHenries for various metal trace separations increasing and ranging from greater than about 2 microns to less than about 4 microns, metal trace widths increasing and ranging from greater than about 2 microns to less than about 4 microns and inner diameters increasing and ranging from greater than about 10 microns to less than about 30 microns. For three turns, trace 603H shows inductance increasing and ranging from greater than about 0.23 nanoHenries to less than about 0.62 nanoHenries for various metal trace separations increasing and ranging from greater than about 2 microns to less than about 4 microns, metal trace widths increasing and ranging from greater than about 2 microns to less than about 4 microns and inner diameters increasing and ranging from greater than about 10 microns to less than about 30 microns. For four turns, trace 605H shows inductance increasing and ranging from greater than about 0.43 nanoHenries to less than about 1.17 nanoHenries for various metal trace separations increasing and ranging from greater than about 2 microns to less than about 4 microns, metal trace widths increasing and ranging from greater than about 2 microns to less than about 4 microns and inner diameters increasing and ranging from greater than about 10 microns to less than about 30 microns. For five turns, trace 605H shows inductance increasing and ranging from greater than about 0.74 nanoHenries to less than about 2 nanoHenries for various metal trace separations increasing and ranging from greater than about 2 microns to less than about 4 microns, metal trace widths increasing and ranging from greater than about 2 microns to less than about 4 microns and inner diameters increasing and ranging from greater than about 10 microns to less than about 30 microns.

Chart 600I shows inductance versus inner diameter. Inner diameter may range from about ten (10) microns or greater to about thirty (30) microns or less. For inner diameter of approximately ten (10) microns, trace 601I shows inductance increasing and ranging from greater than about 0.09 nanoHenries to less than about 1.07 nanoHenries for various metal trace separations increasing and ranging from greater than about 2 microns to less than about 4 microns, metal trace widths increasing and ranging from greater than about 2 microns to less than about 4 microns and number of turns increasing and ranging from greater than 1 to less than 6. For inner diameter of approximately twenty (20) microns, trace 603I shows inductance increasing and ranging from greater than about 0.19 nanoHenries to less than about 1.5 nanoHenries for various metal trace separations increasing and ranging from greater than about 2 microns to less than about 4 microns, metal trace widths increasing and ranging from greater than about 2 microns to less than about 4 microns and number of turns increasing and ranging from greater than 1 to less than 6. For inner diameter of approximately thirty (30) microns, trace 605I shows inductance increasing and ranging from greater than about 0.28 nanoHenries to less than about 2 nanoHenries for various metal trace separations increasing and ranging from greater than about 2 microns to less than about 4 microns, metal trace widths increasing and ranging from greater than about 2 microns to less than about 4 microns and number of turns increasing and ranging from greater than 1 to less than 6.

Chart 600J shows inductance versus outer diameter. Outer diameter may range from about 22 microns or greater to about a hundred (100) microns or less, for various integrated inductor embodiments. Plot 601J shows various inductances for various integrated inductor embodiments ranging form greater than about 0.09 nanoHenries to less than about two (2) nanoHenries.

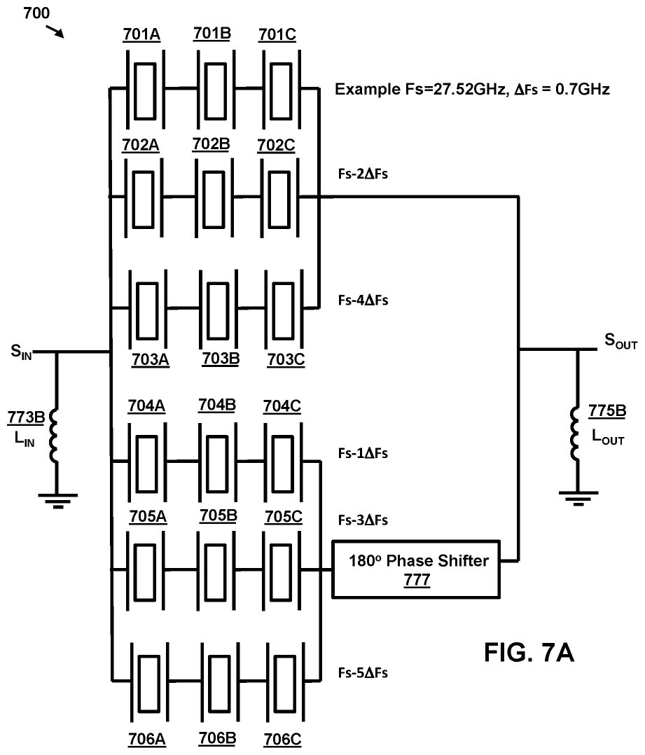

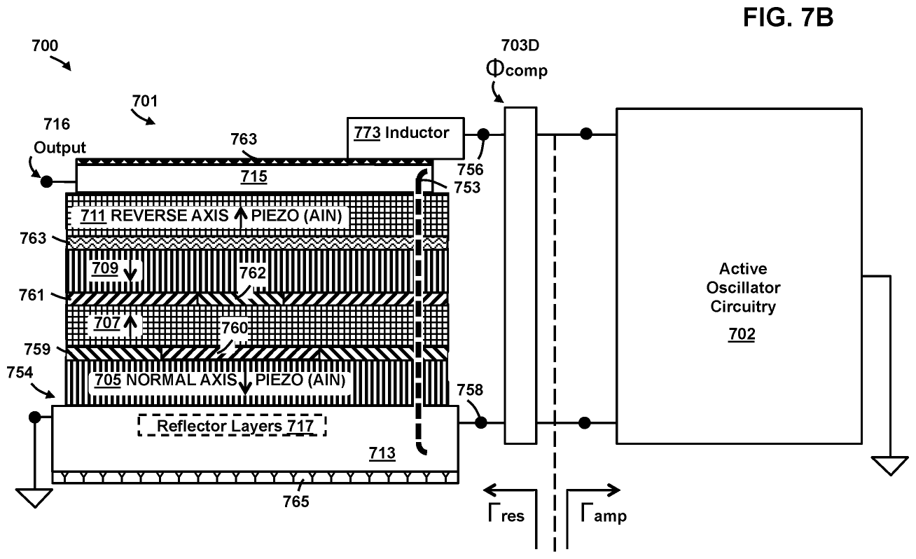

FIG. 7A shows an example millimeter acoustic wave transversal filter 700 using bulk acoustic millimeter wave resonator structures similar to those shown in FIG. 1A. Transversal filter 700 may comprise: a first series branch of three series coupled bulk acoustic millimeter wave resonator 701A, 701B, 701C; a second series branch of three series coupled bulk acoustic millimeter wave resonator 702A, 702B, 702C; a third series branch of three series coupled bulk acoustic millimeter wave resonator 703A, 703B, 703C; a fourth series branch of three series coupled bulk acoustic millimeter wave resonator 704A, 704B, 704C; a fifth series branch of three series coupled bulk acoustic millimeter wave resonator 705A, 705B, 705C; and a sixth series branch of three series coupled bulk acoustic millimeter wave resonator 705A, 705B, 705C. The three series coupled bulk acoustic millimeter wave resonators 701A, 701B, 701C of the first series branch may have respective main series resonant frequencies (Fs) of twenty seven and fifty two hundredths GigaHertz (27.52 GHz). The three series coupled bulk acoustic millimeter wave resonators 702A, 702B, 702C of the second series branch may be mass loaded to shift respective main series resonant frequencies (Fs) down by twice of seven tenths of a GigaHertz (twice delta Fs=twice 0.7 GHz=1.4 GHz) from the respective main series resonant frequencies (Fs) of twenty seven and fifty two hundredths GigaHertz (27.52 GHz) of the three series coupled bulk acoustic millimeter wave resonators 701A, 701B, 701C of the first series branch. The three series coupled bulk acoustic millimeter wave resonators 703A, 703B, 703C of the third series branch may be further mass loaded to shift respective main series resonant frequencies (Fs) down by four times seven tenths of a GigaHertz (four times delta Fs=four times 0.7 GHz=2.8 GHz) from the respective main series resonant frequencies (Fs) of twenty seven and fifty two hundredths GigaHertz (27.52 GHz) of the three series coupled bulk acoustic millimeter wave resonators 701A, 701B, 701C of the first series branch. The three series coupled bulk acoustic millimeter wave resonators 704A, 704B, 704C of the fourth series branch may be further mass loaded to shift respective main series resonant frequencies (Fs) down by seven tenths of a GigaHertz (delta Fs=0.7 GHz=2.1 GHz) from the respective main series resonant frequencies (Fs) of twenty seven and fifty two hundredths GigaHertz (27.52 GHz) of the three series coupled bulk acoustic millimeter wave resonators 701A, 701B, 701C of the first series branch. The three series coupled bulk acoustic millimeter wave resonators 705A, 705B, 705C of the fifth series branch may be further mass loaded to shift respective main series resonant frequencies (Fs) down by three times seven tenths of a GigaHertz (three times delta Fs=three times 0.7 GHz=2.1 GHz) from the respective main series resonant frequencies (Fs) of twenty seven and fifty two hundredths GigaHertz (27.52 GHz) of the three series coupled bulk acoustic millimeter wave resonators 701A, 701B, 701C of the first series branch. The three series coupled bulk acoustic millimeter wave resonators 706A, 706B, 706C of the sixth series branch may be further mass loaded to shift respective main series resonant frequencies (Fs) down by five times seven tenths of a GigaHertz (five times delta Fs=five times 0.7 GHz=3.5 GHz) from the respective main series resonant frequencies (Fs) of twenty seven and fifty two hundredths GigaHertz (27.52 GHz) of the three series coupled bulk acoustic millimeter wave resonators 701A, 701B, 701C of the first series branch.

An input signal Sin may be coupled to a common input node of the first, second, third, fourth, fifth and sixth series branches of transversal filter 700. An input inductor 773B (e.g., input integrated inductor 773B, e.g., fifteen hundredths (0.15) NanoHenry inductor) may be coupled between ground and the common input node of the first, second, third, fourth, fifth and sixth series branches of transversal filter 700. A first common output node of the first, second, and third series branches of transversal filter 700 may be coupled to a summing output node to provide an output signal Sout of transversal filter 700. A one hundred and eighty (180) degree phase shifter 777 may be coupled between a second common output node of the first, second, and third series branches of transversal filter 700 and the summing output node to provide the output signal Sout of transversal filter 700. An output inductor 775B (e.g., output integrated inductor 775B, e.g., fifteen hundredths (0.15) NanoHenry inductor) may be coupled between ground and the summing output node to provide the output signal Sout of transversal filter 700.

In the example transversal filter 700, the eighteen bulk acoustic millimeter wave resonators 701A, 701B, 701C, 702A, 702B, 702C, 703A, 703B, 703C, 704A, 704B, 704C, 705A, 705B, 705C, 706A, 706B, 706C may have respective electrical characteristic impedances of about fifty (50) Ohms. The first, second, third, fourth, fifth and sixth series branches may have respective electrical characteristic impedances of about one hundred and fifty (150) Ohms. Parallel electrical characteristic impedance of a first parallel grouping of first, second, and third series branches may be about fifty (50) Ohms. Parallel electrical characteristic impedance of a second parallel grouping of fourth, fifth and sixth series branches may be about fifty (50) Ohms. The eighteen bulk acoustic millimeter wave resonators 701A, 701B, 701C, 702A, 702B, 702C, 703A, 703B, 703C, 704A, 704B, 704C, 705A, 705B, 705C, 706A, 706B, 706C may have respective electromechanical coupling coefficient (Kt2) of about six and a half percent (6.5%). Various other frequency and electrical characteristic impedance arrangements of eighteen bulk acoustic millimeter wave resonators 701A, 701B, 701C, 702A, 702B, 702C, 703A, 703B, 703C, 704A, 704B, 704C, 705A, 705B, 705C, 706A, 706B, 706C may be possible to achieve specific filter performance goals, as would be appreciated by one with skill in the art upon reading this disclosure. Moreover, fewer than six branches (e.g., four branches, e.g., two branches) or more than 6 branches (e.g., 8 branches, e.g., 10 branches, etc). may be used. In addition, fewer or more than 3 resonators per branch may be used to achieve specific filter performance goals.

FIG. 7B shows an example oscillator 700 (e.g., millimeter wave oscillator 700, e.g., Super High Frequency (SHF) wave oscillator 700, e.g., Extremely High Frequency (EHF) wave oscillator 700) for example, using a bulk acoustic wave resonator 701 similar to the bulk acoustic wave resonator structure of FIG. 1A. For example, FIG. 7B shows a simplified view of bulk acoustic wave resonator 701 electrically coupled via coupling nodes 756, 758 with electrical oscillator circuitry (e.g., active oscillator circuitry 702) through phase compensation circuitry 703 (Φcomp). An integrated inductor 773 may be coupled between coupling node 756 and a top current spreading layer 763 of bulk acoustic wave resonator 701. The example oscillator 700 may be a negative resistance oscillator, e.g., in accordance with a one-port model as shown in FIG. 7B. The electrical oscillator circuitry, e.g., active oscillator circuitry may include one or more suitable active devices (e.g., one or more suitably configured amplifying transistors) to generate a negative resistance commensurate with resistance of the bulk acoustic wave resonator 701. In other words, energy lost in bulk acoustic wave resonator 701 may be replenished by the active oscillator circuitry, thus allowing steady oscillation, e.g., steady SHF or EHF wave oscillation. To ensure oscillation start-up, active gain (e.g., negative resistance) of active oscillator circuitry 702 may be greater than one. As illustrated on opposing sides of a notional dashed line in FIG. 7B, the active oscillator circuitry 702 may have a complex reflection coefficient of the active oscillator circuitry (Γamp), and the bulk acoustic wave resonator 701 together with the phase compensation circuitry 703 (Φcomp) may have a complex reflection coefficient (Γres). To provide for the steady oscillation, e.g., steady SHF or EHF wave oscillation, a magnitude may be greater than one for |Γamp Γres|, e.g., magnitude of a product of the complex reflection coefficient of the active oscillator circuitry (Γamp) and the complex reflection coefficient (Γres) of the resonator to bulk acoustic wave resonator 701 together with the phase compensation circuitry 703 (Φcomp) may be greater than one. Further, to provide for the steady oscillation, e.g., steady SHF or EHF wave oscillation, phase angle may be an integer multiple of three-hundred-sixty degrees for ∠Γamp Γres, e.g., a phase angle of the product of the complex reflection coefficient of the active oscillator circuitry (Γamp) and the complex reflection coefficient (Γres) of the resonator to bulk acoustic wave resonator 701 together with the phase compensation circuitry 703 (Φcomp) may be an integer multiple of three-hundred-sixty degrees. The foregoing may be facilitated by phase selection, e.g., electrical length selection, of the phase compensation circuitry 703 (Φcomp).

In the simplified view of FIG. 7B, the bulk acoustic wave resonator 701 (e.g., bulk acoustic SHF or EHF wave resonator) includes first normal axis piezoelectric layer 705, first reverse axis piezoelectric layer 707, and another normal axis piezoelectric layer 709, and another reverse axis piezoelectric layer 711 arranged in a four piezoelectric layer alternating axis stack arrangement sandwiched between multilayer metal acoustic SHF or EHF wave reflector top electrode 715 and multilayer metal acoustic SHF or EHF wave reflector bottom electrode 713. Multilayer metal acoustic SHF or EHF wave reflector top electrode 715, may include a top current spreading layer 763. Multilayer metal acoustic SHF or EHF wave reflector bottom electrode 713 may include a bottom current spreading layer 765. General structures and applicable teaching of this disclosure for the multilayer metal acoustic SHF or EHF reflector top electrode 715 and the multilayer metal acoustic SHF or EHF reflector bottom electrode 713, as well as bottom current spreading layer 765 and top current spreading layer 763, have already been discussed in detail previously herein, for example, with respect of FIGS. 1A and 4A through 4G. For brevity and clarity, these discussions are referenced and incorporated, rather than explicitly repeated fully here.

As already discussed, these structures are directed to respective pairs of metal electrode layers, in which a first member of the pair has a relatively low acoustic impedance (relative to acoustic impedance of an other member of the pair), in which the other member of the pair has a relatively high acoustic impedance (relative to acoustic impedance of the first member of the pair), and in which the respective pairs of metal electrode layers have layer thicknesses corresponding to approximately one quarter wavelength (e.g., approximately one quarter acoustic wavelength) at a main resonant frequency of the resonator. Accordingly, it should be understood that the bulk acoustic SHF or EHF wave resonator 701 shown in FIG. 7B may include multilayer metal acoustic SHF or EHF wave reflector top electrode 715 and multilayer metal acoustic SHF or EHF wave reflector bottom electrode 715 in which the respective pairs of metal electrode layers may include layer thicknesses corresponding to approximately a quarter wavelength (e.g., approximately one quarter of an acoustic wavelength) at a SHF or EHF wave main resonant frequency of the bulk acoustic SHF or EHF wave resonator 701. Initial top metal electrode layer and initial bottom metal electrode layer may have respective layer thickness of about one eighth of a wavelength (e.g., one eighth of an acoustic wavelength) at the main resonant frequency of the bulk acoustic SHF or EHF wave resonator 701.

The multilayer metal acoustic SHF or EHF wave reflector top electrode 715 may include the initial top metal electrode layer and the first pair of top metal electrode layers electrically and acoustically coupled with the four piezoelectric layer alternating axis stack arrangement (e.g., with the first normal axis piezoelectric layer 705, e.g., with first reverse axis piezoelectric layer 707, e.g., with another normal axis piezoelectric layer 709, e.g., with another reverse axis piezoelectric layer 711) to excite the piezoelectrically excitable resonance mode at the resonant frequency.

For example, the multilayer metal acoustic SHF or EHF wave reflector top electrode 715 may include the initial top metal electrode layer and the first pair of top metal electrode layers, and the foregoing may have a respective peak acoustic reflectivity in the Super High Frequency (SHF) band or the Extremely High Frequency (EHF) band that includes the respective resonant frequency of the respective BAW resonator.

Similarly, the multilayer metal acoustic SHF or EHF wave reflector bottom electrode 713 may include reflector layers 717, e.g., the initial bottom metal electrode layer, and the first pair of bottom metal electrode layers electrically and acoustically coupled with the four piezoelectric layer alternating axis stack arrangement (e.g., with the first normal axis piezoelectric layer 705, e.g, with first reverse axis piezoelectric layer 707, e.g., with another normal axis piezoelectric layer 709, e.g., with another reverse axis piezoelectric layer 711) to excite the piezoelectrically excitable resonance mode at the resonant frequency. For example, the multilayer metal acoustic SHF or EHF wave reflector bottom electrode 715 may include the initial bottom metal electrode layer and the first pair of bottom metal electrode layers, and the foregoing may have a respective peak acoustic reflectivity in the Super High Frequency (SHF) band or the Extremely High Frequency (EHF) band that includes the resonant frequency of the BAW resonator 701.

An output 716 of the oscillator 700 may be coupled to the bulk acoustic wave resonator 701 (e.g., coupled to multilayer metal acoustic SHF or EHF wave reflector top electrode 715). Interposer layers (e.g., first patterned interposer layer 759, e.g., second patterned interposer layer 761, e.g. third interposer layer 763) as discussed previously herein, for example, with respect to FIG. 1A are explicitly shown in the simplified view the example resonator 701 shown in FIG. 7B. Such interposer layers may be included and interposed between adjacent piezoelectric layers. For example, first patterned interposer layer 759 comprising first central feature 760 may be arranged between first normal axis piezoelectric layer 705 and first reverse axis piezoelectric layer 707. For example, second patterned interposer layer 761 comprising second central feature 762 may be arranged between first reverse axis piezoelectric layer 707 and another normal axis piezoelectric layer 709. For example, a third interposer may be arranged between the another normal axis piezoelectric layer 709 and another reverse axis piezoelectric layer 707. As discussed previously herein, such interposer may be metal and/or dielectric, and may, but need not provide various benefits, as discussed previously herein. Alternatively or additionally, one or more (e.g., one or a plurality of) interposer layers may comprise metal and dielectric for respective interposer layers.

A notional heavy dashed line is used in depicting an etched edge region 753 associated with example resonator 701. The example resonator 701 may also include a laterally opposing etched edge region 754 arranged opposite from the etched edge region 753. The etched edge region 753 (and the laterally opposing etch edge region 754) may similarly extend through various members of the example resonator 701 of FIG. 7B. As shown in FIG. 7B, a first mesa structure corresponding to the stack of four piezoelectric material layers 705, 707, 709, 711 may extend laterally between (e.g., may be formed between) etched edge region 753 and laterally opposing etched edge region 754. A second mesa structure corresponding to multilayer metal acoustic SHF or EHF wave reflector bottom electrode 713 may extend laterally between (e.g., may be formed between) etched edge region 753 and laterally opposing etched edge region 754. Third mesa structure corresponding to multilayer metal acoustic SHF or EHF wave reflector top electrode 715 may extend laterally between (e.g., may be formed between) etched edge region 753 and laterally opposing etched edge region 754.

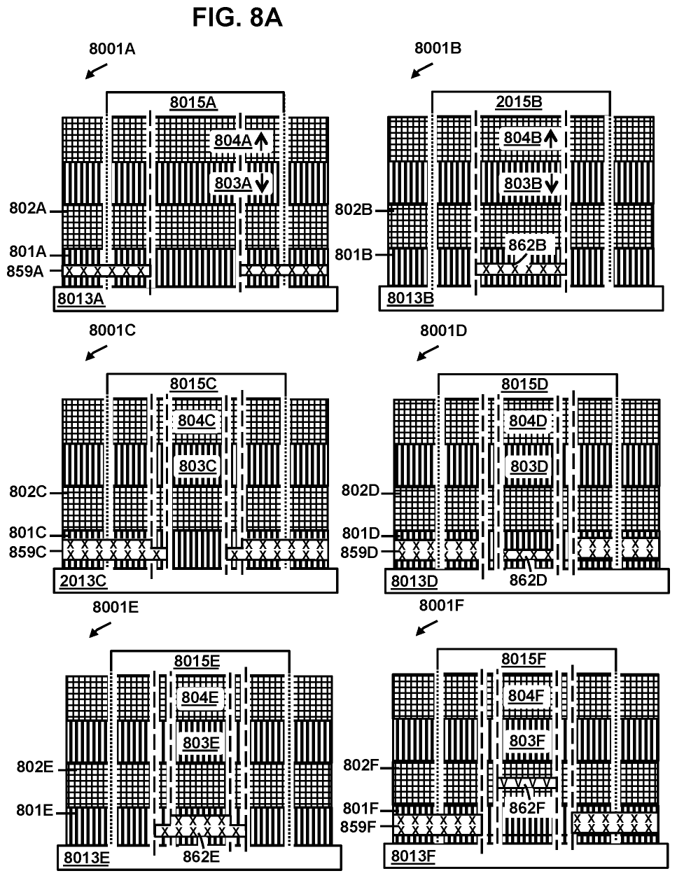

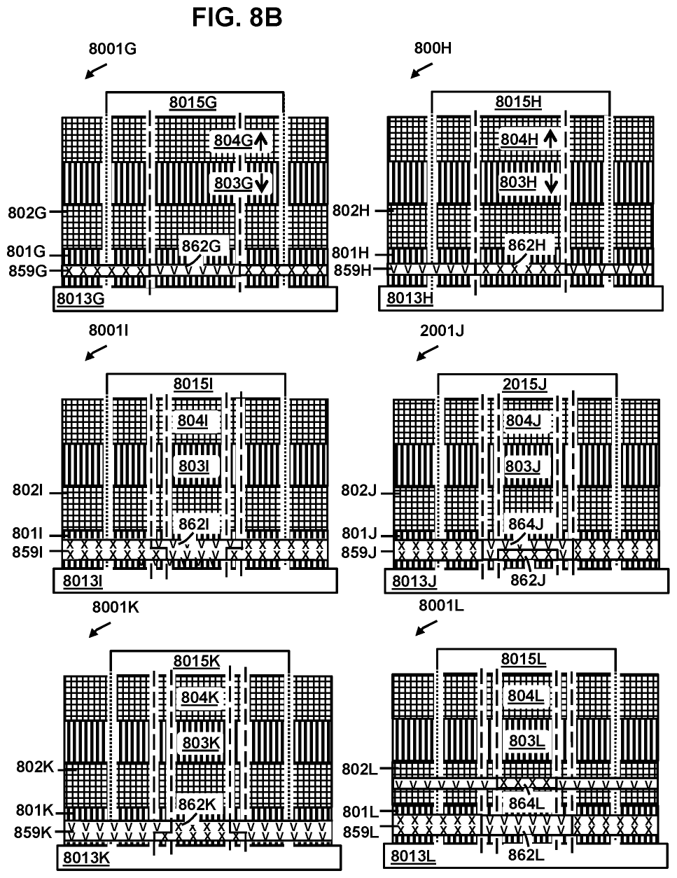

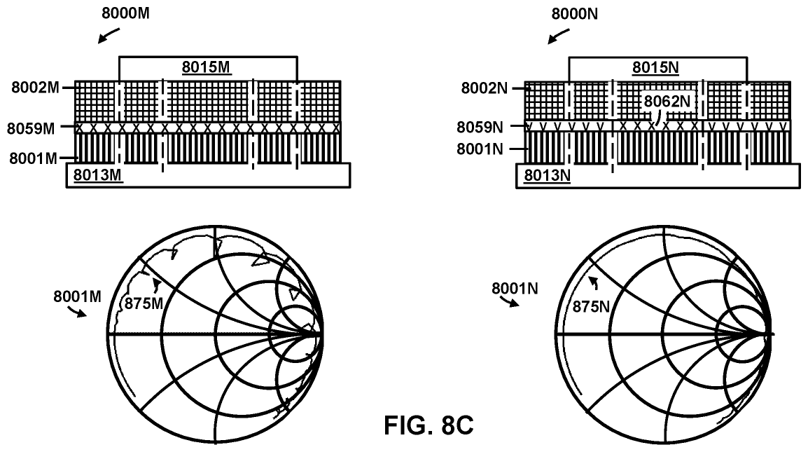

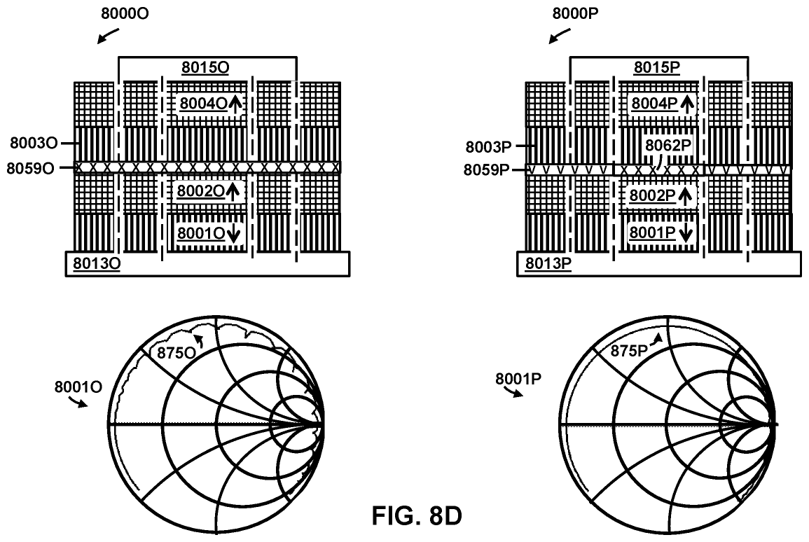

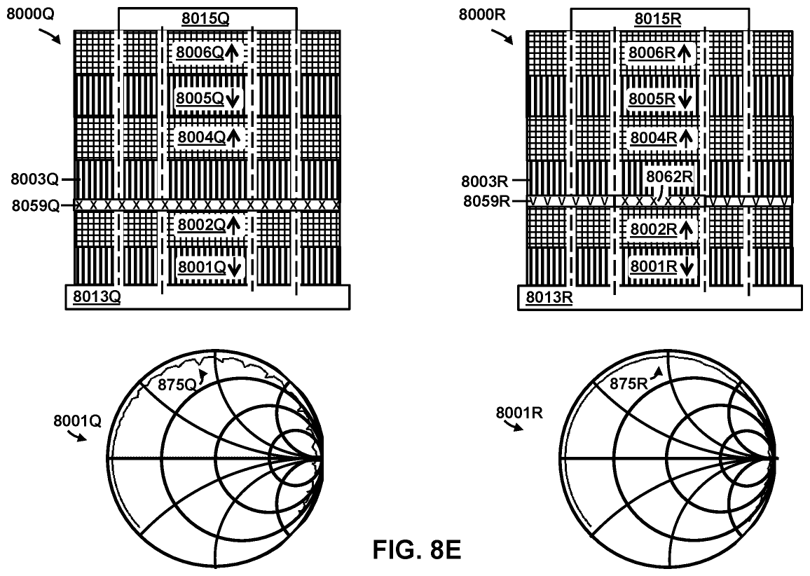

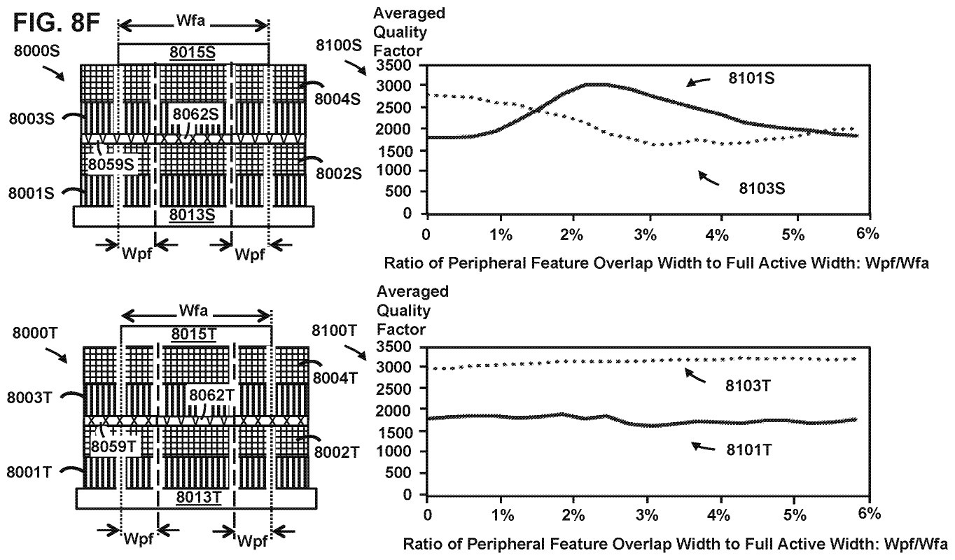

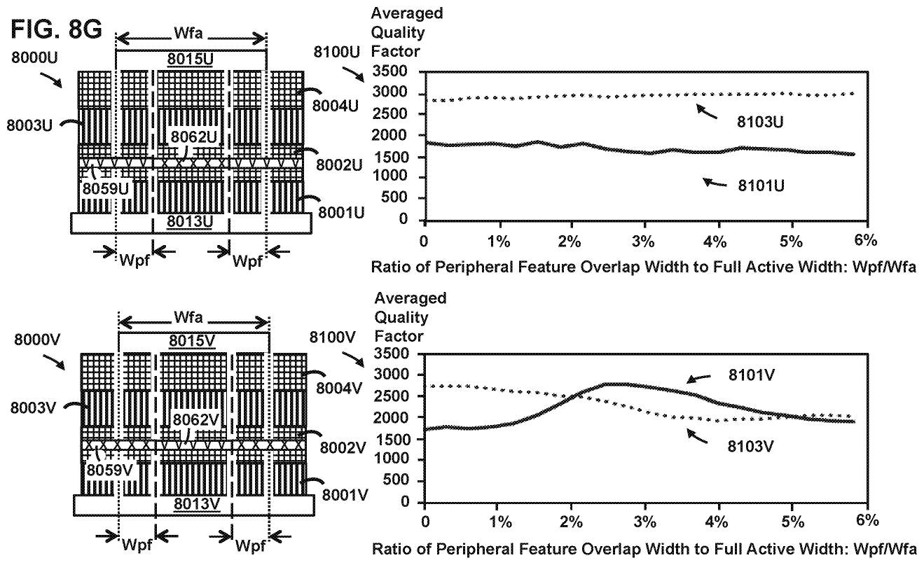

FIG. 8A shows simplified views of an additional six example bulk acoustic wave resonators 8001A, 8001B, 8001C, 8001D, 8001E, 8001F.

FIG. 8B shows simplified views of another additional six exampled bulk acoustic wave resonators 8001G, 8001H, 8001I, 8001J, 8001K, 8001L.

As shown, the twelve bulk acoustic wave resonators 8001A, 8001B, 8001C, 8001D, 8001E, 8001F 8001G, 8001H, 8001I, 8001J, 8001K, 8001L comprise respective piezoelectric stacks of piezoelectric layers in alternating piezoelectric axis orientation arrangements, sandwiched between respective top acoustic reflector electrodes 8015A, 8015B, 8015C, 8015D, 8015E, 8015F, 8015G, 8015H, 8015I, 8015J, 8015K, 8015L and respective bottom acoustic reflector electrodes 8013A, 8013B, 8013C, 8013D, 8013E, 8013F, 8013G, 8013H, 8013I, 8013J, 8013K, 8013L.

Bulk acoustic wave resonators 8001A, 8001B, 8001C, 8001D, 8001E, 8001F 8001G, 8001H, 8001I, 8001J, 8001K, 8001L may comprise respective first piezoelectric layers 801A, 801B, 801C, 801D, 801E, 801F, 801G, 801H, 801I, 801J, 801K, 801L having normal piezoelectric axis orientation. Bulk acoustic wave resonators 8001A, 8001B, 8001C, 8001D, 8001E, 8001F 8001G, 8001H, 8001I, 8001J, 8001K, 8001L may comprise respective second piezoelectric layers 802A, 802B, 802C, 802D, 802E, 802F, 802G, 802H, 802I, 802J, 802K, 802L having respective reverse piezoelectric axis orientations. Bulk acoustic wave resonators 8001A, 8001B, 8001C, 8001D, 8001E, 8001F 8001G, 8001H, 8001I, 8001J, 8001K, 8001L may comprise respective third piezoelectric layers 803A, 803B, 803C, 803D, 803E, 803F, 803G, 803H, 803I, 803J, 803K, 803L having respective normal piezoelectric axis orientation. Bulk acoustic wave resonators 8001A, 8001B, 8001C, 8001D, 8001E, 8001F 8001G, 8001H, 8001I, 8001J, 8001K, 8001L may comprise respective fourth piezoelectric layers 804A, 804B, 804C, 804D, 804E, 804F, 804G, 804H, 804I, 804J, 804K, 804L having respective reverse piezoelectric axis orientations. Bulk acoustic wave resonators 8001A, 8001B, 8001C, 8001D, 8001E, 8001F 8001G, 8001H, 8001I, 8001J, 8001K, 8001L may comprise respective four piezoelectric layers in which the piezoelectric layers may have respective thicknesses of approximately half acoustic wavelength of the main resonant frequencies of the bulk acoustic wave resonators 8001A, 8001B, 8001C, 8001D, 8001E, 8001F 8001G, 8001H, 8001I, 8001J, 8001K, 8001L.

As shown, the twelve bulk acoustic wave resonators 8001A, 8001B, 8001C, 8001D, 8001E, 8001F 8001G, 8001H, 8001I, 8001J, 8001K, 8001L comprise respective piezoelectric stacks of piezoelectric layers in alternating piezoelectric axis orientation arrangements, sandwiched between respective top acoustic reflector electrodes 8015A, 8015B, 8015C, 8015D, 8015E, 8015F, 8015G, 8015H, 8015I, 8015J, 8015K, 8015L and respective bottom acoustic reflector electrodes 8013A, 8013B, 8013C, 8013D, 8013E, 8013F, 8013G, 8013H, 8013I, 8013J, 8013K, 8013L.

Bulk acoustic wave resonators 8001A, 8001B, 8001C, 8001D, 8001E, 8001F 8001G, 8001H, 8001I, 8001J, 8001K, 8001L may comprise respective first piezoelectric layers 801A, 801B, 801C, 801D, 801E, 801F, 801G, 801H, 801I, 801J, 801K, 801L having normal piezoelectric axis orientation. Bulk acoustic wave resonators 8001A, 8001B, 8001C, 8001D, 8001E, 8001F 8001G, 8001H, 8001I, 8001J, 8001K, 8001L may comprise respective second piezoelectric layers 802A, 802B, 802C, 802D, 802E, 802F, 802G, 802H, 802I, 802J, 802K, 802L having respective reverse piezoelectric axis orientations. Bulk acoustic wave resonators 8001A, 8001B, 8001C, 8001D, 8001E, 8001F 8001G, 8001H, 8001I, 8001J, 8001K, 8001L may comprise respective third piezoelectric layers 803A, 803B, 803C, 803D, 803E, 803F, 803G, 803H, 803I, 803J, 803K, 803L having respective normal piezoelectric axis orientation. Bulk acoustic wave resonators 8001A, 8001B, 8001C, 8001D, 8001E, 8001F 8001G, 8001H, 8001I, 8001J, 8001K, 8001L may comprise respective fourth piezoelectric layers 804A, 804B, 804C, 804D, 804E, 804F, 804G, 804H, 804I, 804J, 804K, 804L having respective reverse piezoelectric axis orientations. Bulk acoustic wave resonators 8001A, 8001B, 8001C, 8001D, 8001E, 8001F 8001G, 8001H, 8001I, 8001J, 8001K, 8001L may comprise respective four piezoelectric layers in which the piezoelectric layers may have respective thicknesses of approximately half acoustic wavelength of the main resonant frequencies of the bulk acoustic wave resonators 8001A, 8001B, 8001C, 8001D, 8001E, 8001F 8001G, 8001H, 8001I, 8001J, 8001K, 8001L.

The respective stacks of four piezoelectric material layers of the twelve example bulk acoustic wave resonators 8001A, 8001B, 8001C, 8001D, 8001E, 8001F 8001G, 8001H, 8001I, 8001J, 8001K, 8001L may have respective active regions (e.g., respective alternating axis active piezoelectric volumes) where the lateral extent of the top acoustic reflector electrode may overlap the lateral extent of the bottom acoustic reflector electrode. In the twelve example bulk acoustic wave resonators 8001A, 8001B, 8001C, 8001D, 8001E, 8001F 8001G, 8001H, 8001I, 8001J, 8001K, 8001L of FIGS. 8A and 8B, respective active regions (e.g., respective alternating axis active piezoelectric volumes) where the lateral extent of the top acoustic reflector electrode may overlap the lateral extent of the bottom acoustic reflector electrode are highlighted as extending between notional dotted lines.

For example, in operation of bulk acoustic wave resonators 8001A, 8001B, 8001C, 8001D, 8001E, 8001F 8001G, 8001H, 8001I, 8001J, 8001K, 8001L, a respective oscillating electric field may be applied via respective top acoustic reflector electrodes 8015A, 8015B, 8015C, 8015D, 8015E, 8015F, 8015G, 8015H, 8015I, 8015J, 8015K, 8015L and bottom acoustic reflector electrodes 8013A, 8013B, 8013C, 8013D, 8013E, 8013F, 8013G, 8013H, 8013I, 8013J, 8013K, 8013L, so as to activate responsive piezoelectric acoustic oscillations (e.g., a main resonant mode) in the respective active regions (e.g., respective alternating axis active piezoelectric volumes) of the respective stacks of four piezoelectric material layers, where the lateral extent of the respective top acoustic reflector electrodes may overlap the lateral extent of the respective bottom acoustic reflector electrodes. In other words, where the lateral extent of the respective top acoustic reflector electrodes 8015A, 8015B, 8015C, 8015D, 8015E, 8015F, 8015G, 8015H, 8015I, 8015J, 8015K, 8015L overlaps the lateral extent of the respective bottom acoustic reflector electrodes 8013A, 8013B, 8013C, 8013D, 8013E, 8013F, 8013G, 8013H, 8013I, 8013J, 8013K, 8013L may define the respective alternating axis active piezoelectric volumes (e.g., active regions), as highlighted in FIGS. 8A and 8B as extending between notional dotted lines.

Bulk acoustic wave resonators 8001A, 8001B, 8001C, 8001D, 8001E, 8001F 8001G, 8001H, 8001I, 8001J, 8001K, 8001L may comprise respective first patterned interposer layers 859A, 862B, 859C, 859D, 862E, 859F, 859K, 859H, 859I, 859J, 859K, 859L. Respective first patterned interposer layers 859A, 862B, 859C, 859D, 862E, 859F, 859K, 859H, 859I, 859J, 859K, 859L may be arranged along respective central portions of the respective thickness (e.g., respective half acoustic wavelength thickness) of the respective first piezoelectric layers 801A, 801B, 801C, 801D, 801E, 801F, 801K, 801H, 801I, 801J, 801K, 801L. Respective first patterned interposer layers 859A, 862B, 859C, 859D, 862E, 859F, 859K, 859H, 859I, 859J, 859K, 859L may split the respective middles of first respective first piezoelectric layers 801A, 801B, 801C, 801D, 801E, 801F, 801K, 801H, 801I, 801J, 801K, 801L (e.g., into respective pairs of sublayers). Respective acoustic energy peaks may be placed at respective locations of the respective first patterned interposer layers 859A, 862B, 859C, 859D, 862E, 859F, 859K, 859H, 859I, 859J, 859K, 859L, at the respective central portions of the respective first half acoustic wavelength thick piezoelectric layers 801A, 801B, 801C, 801D, 801E, 801F, 801K, 801H, 801I, 801J, 801K, 801L, during operation of the bulk acoustic wave resonators 8001A, 8001B, 8001C, 8001D, 8001E, 8001F 8001G, 8001H, 8001I, 8001J, 8001K, 8001L.

The respective first patterned interposer layers 859A, 862B, 859C, 859D, 862E, 859F, 859K, 859H, 859I, 859J, 859K, 859L in various examples may comprise a respective first peripheral features. The respective first patterned interposer layers 859A, 862B, 859C, 859D, 862E, 859F, 859K, 859H, 859I, 859J, 859K, 859L in various examples may comprise respective first central features having respective first width dimensions (e.g., respective first width dimensions highlighted between respective pairs of notional dashed lines, for bulk acoustic wave resonators 8001A, 8001B, 8001C, 8001D, 8001E, 8001F 8001G, 8001H, 8001I, 8001J, 8001K, 8001L). The respective first width dimensions of the respective first central features may be within respective ranges from approximately ninety percent of respective widths of the respective active piezoelectric volumes to approximately ninety-nine and nine tenths percent of respective widths of the respective active piezoelectric volumes. The respective first width dimensions of the respective first central features being within respective ranges from approximately ninety percent of the respective widths of the respective active piezoelectric volumes to approximately ninety-nine and nine tenths percent of the respective widths of the respective active piezoelectric volumes may, but need not facilitate respective quality factor enhancements of the bulk acoustic wave resonators.

Example bulk acoustic wave resonators of FIGS. 8A and 8B may comprise respective second patterned interposer layers (e.g., bulk acoustic wave resonator 8001F may comprise second patterned interposer layer 862F, e.g., bulk acoustic wave resonator 8001L may comprise second patterned interposer layer 864L). Respective second patterned interposer layers 859F, 859L may be arranged along respective central portions of the respective thickness (e.g., respective half acoustic wavelength thickness) of the respective second piezoelectric layers 802F, 802L. Respective second patterned interposer layers 859F, 859L may split the respective middles of respective second piezoelectric layers (e.g, or portions thereof, e.g., into respective pairs of sublayers). Respective acoustic energy peaks may be placed at respective locations of the respective second patterned interposer layers 802F, 802L at the respective central portions of the respective second half acoustic wavelength thick piezoelectric layers 802F, 802L, during operation of the bulk acoustic wave resonators 8001F, 8001L.

Respective second patterned interposer layers may comprise respective second central features (e.g., second central feature 862F, e.g., central feature 864L) having respective second width dimensions (e.g., respective second width dimensions highlighted between respective pairs of notional dashed lines). The respective second width dimensions of the respective second central features may be within respective ranges from approximately ninety percent of respective widths of the respective active piezoelectric volumes to approximately ninety-nine and nine tenths percent of respective widths of the respective active piezoelectric volumes. The respective second width dimensions of the respective second central features being within respective ranges from approximately ninety percent of the respective widths of the respective active piezoelectric volumes to approximately ninety-nine and nine tenths percent of the respective widths of the respective active piezoelectric volumes may, but need not facilitate respective quality factor enhancements of the bulk acoustic wave resonators.

In bulk acoustic wave resonator 8001A, a first central feature of first patterned interposer layer 859A may be an absence of additional material. First patterned interposer layer 859A may include first peripheral features comprising a first material.

In bulk acoustic wave resonator 8001B, a first central feature of first patterned interposer layer 862B may comprise a first material. First peripheral features of first patterned interposer layer 859B may comprise an absence of additional material.

In bulk acoustic wave resonator 8001C, a first central feature of first patterned interposer layer 859C may be an absence of additional material. First patterned interposer layer 859C may include first peripheral features comprising initial layer thickness steps of a first material arranged proximate to where additional central material is absent.

In bulk acoustic wave resonator 8001D, a first central feature 862D of first patterned interposer layer 859D may comprise a first material. First patterned interposer layer 859D may include first peripheral features comprising a second material. First peripheral features of first patterned interposer layer 859D need not contact (e.g., may be spaced apart from) first central feature 862D. Thickness of first peripheral features of first patterned interposer layer 859D may be different than (e.g., may be thicker than, e.g., may be twice as thick as) thickness of first central feature 862D.

In bulk acoustic wave resonator 8001E, a first central feature of first patterned interposer layer 862E may comprise a first material. Thickness of a central portion of first central feature of first patterned interposer layer 862E may be different than (e.g., may be thicker than, e.g., may be twice as thick as) extremities of the first central feature of first patterned interposer layer 862E. Step features may be present at extremities of the first central feature of first patterned interposer layer 862E. First peripheral features of first patterned interposer layer 859E may comprise an absence of additional material.

In bulk acoustic wave resonator 8001F, a first central feature of first patterned interposer layer 859F may be an absence of additional material. First patterned interposer layer 859F may include first peripheral features comprising a first material. Bulk acoustic wave resonator 8001F may comprise second patterned interposer 862F arranged in second piezoelectric layer 902F. Second patterned interposer 862F may comprise a second material. A second central feature of second patterned interposer layer 862F may comprise the second material. Second peripheral features of second patterned interposer layer 862F may comprise an absence of additional material. Extremities of second central feature of second patterned interposer layer 862F may be laterally spaced apart from first peripheral features of first patterned interposer layer 859F.

In bulk acoustic wave resonator 8001G, a first central feature 862G of first patterned interposer layer 859G may comprise a first material. First peripheral features of first patterned interposer layer 859G may comprise a second material.

In bulk acoustic wave resonator 8001H, a first central feature 862H of first patterned interposer layer 859H may comprise a second material. First peripheral features of first patterned interposer layer 859H may comprise a first material.

In bulk acoustic wave resonator 8001I, a first central feature 862I of first patterned interposer layer 859I may comprise a first material. Thickness of a central portion of first central feature 862I of first patterned interposer layer 859I may be different than (e.g., may be thicker than, e.g., may be twice as thick as) extremities of the first central feature 862I of first patterned interposer layer 859I. Step features may be present at extremities of the first central feature of first patterned interposer layer 862I. First patterned interposer layer 859I may further comprise first peripheral features comprising initial layer thickness steps of a second material arranged proximate to first central feature 862I.

In bulk acoustic wave resonator 8001J, a first central feature 862J of first patterned interposer layer 859J may comprise a first material. Another first central feature 864J of first patterned interposer layer 859J may comprise a second material and may be arranged over first central feature 862J. First peripheral features of first patterned interposer layer 859J may comprise the first material. Thickness of the first peripheral features of first patterned interposer layer 859J may be different than (e.g., may be thicker than, e.g., may be twice as thick as) thickness of the first central feature 862J. Thickness of the first peripheral features of first patterned interposer layer 859J may be different than (e.g., may be thicker than, e.g., may be twice as thick as) thickness of the another first central feature 864J. Thickness of the first peripheral features of first patterned interposer layer 859J may be about the same as a sum of thickness of the first central feature 862J and thickness of the another first central feature 864J.

In bulk acoustic wave resonator 8001K, a first central feature 862K of first patterned interposer layer 859K may comprise a second material. Thickness of a central portion of first central feature 862K of first patterned interposer layer 859K may be different than (e.g., may be thicker than, e.g., may be twice as thick as) extremities of the first central feature 862K of first patterned interposer layer 859K. Step features may be present at extremities of the first central feature of first patterned interposer layer 862K. First patterned interposer layer 859K may further comprise first peripheral features comprising initial layer thickness steps of a first material arranged proximate to first central feature 862K.

In bulk acoustic wave resonator 8001L, a first central feature 862L of first patterned interposer layer 859L may comprise a second material. First patterned interposer layer 859L may comprise first peripheral features comprising a first material arranged proximate to the first central feature 862L. Bulk acoustic wave resonator 8001L may further comprise second patterned interposer layer having second central feature 864L (e.g., comprising the first material). Width of second central feature 864L may be different than (e.g., may be less than) width of first central feature 862L. Second patterned interposer layer may have peripheral features comprising the second material. Thickness of first patterned interposer layer 859L may be different than (e.g., may be thicker than, e.g., may be twice as thick as) thickness of second patterned interposer layer having second central feature 864L.

FIG. 8C shows simplified views of an additional pair of bulk acoustic wave resonators 8000M, 8000N, and along with Smith charts 8001M, 8001N corresponding to respective members of the pair of bulk acoustic wave resonators 8000M, 8000N, showing Scattering-parameters (S-parameters) at various operating frequencies.

FIG. 8D shows simplified views of another additional pair of bulk acoustic wave resonators 8000O, 8000P, and along with Smith charts 8001O, 8001P corresponding to respective members of the pair of bulk acoustic wave resonators 8000O, 8000P showing Scattering-parameters (S-parameters) at various operating frequencies.

FIG. 8E shows simplified views of yet another additional pair of bulk acoustic wave resonators 8000Q, 8000R, and along with Smith charts 8001Q, 8001R corresponding to respective members of the pair of bulk acoustic wave resonators 8000Q, 8000R, showing Scattering-parameters (S-parameters) at various operating frequencies.

Bulk acoustic wave resonators 8000M, 8000N, 8000O, 8000P, 8000Q, 8000R may comprise respective first piezoelectric layers 8001M, 8001N, 8001O, 8001P, 8001Q, 8001R having respective first piezoelectric axis orientations (e.g., respective normal piezoelectric axis orientations). Bulk acoustic wave resonators 8000M, 8000N, 8000O, 8000P, 8000Q, 8000R may comprise respective second piezoelectric layers 8002M, 8002N, 8002O, 8002P, 8002Q, 8002R having respective second piezoelectric axis orientations (e.g., respective reverse piezoelectric axis orientations). Bulk acoustic wave resonators 8000O, 8000P, 8000Q, 8000R may comprise respective third piezoelectric layers 8003O, 8003P, 8003Q, 8003R having respective third piezoelectric axis orientations (e.g., respective normal piezoelectric axis orientation). Bulk acoustic wave resonators 8000O, 8000P, 8000Q, 8000R may comprise respective fourth piezoelectric layers 8004O, 8004P, 8004Q, 8004R having respective fourth piezoelectric axis orientations (e.g., having respective reverse piezoelectric axis orientations). Bulk acoustic wave resonators 8000Q, 8000R may comprise respective fifth piezoelectric layers 8005Q, 8005R having respective fifth piezoelectric axis orientations (e.g., having respective normal piezoelectric axis orientations). Bulk acoustic wave resonators 8000Q, 8000R may comprise respective sixth piezoelectric layers 8006Q, 8006R having respective sixth piezoelectric axis orientations (e.g., having respective reverse piezoelectric axis orientations).

Bulk acoustic wave resonators 8000M, 8000N may comprise respective two piezoelectric layer stacks in which the piezoelectric layers may have respective thicknesses of approximately half acoustic wavelength of the main resonant frequencies (e.g., 24 GHz main resonant frequency) of the bulk acoustic wave resonators 8000M, 8000N. Bulk acoustic wave resonators 8000O, 8000P may comprise respective four piezoelectric layer stacks in which the piezoelectric layers may have respective thicknesses of approximately half acoustic wavelength of the main resonant frequencies (e.g., 24 GHz main resonant frequency) of the bulk acoustic wave resonators 8000O, 8000P. Bulk acoustic wave resonators 8000Q, 8000R may comprise respective six piezoelectric layer stacks in which the piezoelectric layers may have respective thicknesses of approximately half acoustic wavelength of the main resonant frequencies (e.g., 24 GHz main resonant frequency) of the bulk acoustic wave resonators 8000Q, 8000R.

As shown, the six bulk acoustic wave resonators 8000M, 8000N, 8000O, 8000P, 8000Q, 8000R comprise respective piezoelectric stacks of piezoelectric layers in alternating piezoelectric axis orientation arrangements, sandwiched between respective top acoustic reflector electrodes 8015M, 8015N, 8015O, 8015P, 8015Q, 8015R and respective bottom acoustic reflector electrodes 8013M, 8013N, 8013O, 8013P, 8013Q, 8013R.

Bulk acoustic wave resonator 8000M shown on the top left hand side of FIG. 8C may comprise first interposer layer 8059M arranged between first piezoelectric layer 8001M and second piezoelectric layer 8002M. In contrast, bulk acoustic wave resonator 8000N shown on the top right hand side of FIG. 8C may comprise first—patterned—interposer layer 8059N arranged between first piezoelectric layer 8001N and second piezoelectric layer 8002N. First—patterned—interposer layer 8059N of bulk acoustic wave resonator 8000N may include first central feature 8062N comprising a first material (e.g., Titanium (Ti)) having a first acoustic impedance. First—patterned—interposer layer 8059N of bulk acoustic wave resonator 8000N may further include peripheral features comprising a second material (e.g., Tungsten (W)) having a second acoustic impedance (e.g., second acoustic impedance that is greater than the first acoustic impedance). First interposer layer 8059M of bulk acoustic wave resonator 8000M may comprise the first material (e.g., Titanium (Ti)) having the first acoustic impedance.

A bottom left section of FIG. 8C shows a Smith chart 8001M showing a simulation of Scattering-parameters (e.g., S-parameters, e.g., S11) over frequencies 875M for BAW resonator 8000M (e.g., over frequencies including twenty-four Gigahertz, e.g., over frequencies including the 24 GHz main resonant frequency of BAW resonator 8000M, e.g., over frequencies including the 24 GHz main series resonant frequency, Fs, of BAW resonator 8000M). Uneven artifacts in the Smith chart depiction of electrical reflection coefficient S-parameters over frequencies 875M may be described in various ways such as epicycles, lobes and/or rattles, which may be indicative of the presence of parasitic lateral resonances in operation of the BAW resonator 8000M

A bottom right section of FIG. 8C shows Smith chart 8001N showing a simulation of electrical reflection coefficient S-parameters over frequencies 875N for BAW resonator 8000N (e.g., over frequencies including twenty-four Gigahertz, e.g., over frequencies including the 24 GHz main resonant frequency of BAW resonator 8000N, e.g., over frequencies including the 24 GHz main series resonant frequency, Fs, of BAW resonator 8001N). In the Smith chart depiction of electrical reflection coefficient S-parameters over frequencies 875N may be described in various ways such as smooth (e.g., relatively smooth, e.g., substantially smooth), even (e.g., relatively even, e.g., substantially even), which may be indicative of an absence of unwanted parasitic lateral resonances in operation of the BAW resonator 8000N.

Bulk acoustic wave resonator 8000O shown on the top left hand side of FIG. 8D may comprise first interposer layer 8059O arranged between second piezoelectric layer 8002O and third piezoelectric layer 8003O. In contrast, bulk acoustic wave resonator 8000P shown on the top right hand side of FIG. 8D may comprise first—patterned—interposer layer 8059P arranged between second piezoelectric layer 8002P and third piezoelectric layer 8003P. First—patterned—interposer layer 8059P of bulk acoustic wave resonator 8000P may include first central feature 8062P comprising a first material (e.g., Titanium (Ti)) having a first acoustic impedance. First—patterned—interposer layer 8059P of bulk acoustic wave resonator 8000P may further include peripheral features comprising a second material (e.g., Tungsten (W)) having a second acoustic impedance (e.g., second acoustic impedance that is greater than the first acoustic impedance). First interposer layer 8059O of bulk acoustic wave resonator 8000O may comprise the first material (e.g., Titanium (Ti)) having the first acoustic impedance.

A bottom left section of FIG. 8D shows a Smith chart 8001O showing a simulation of Scattering-parameters (e.g., S-parameters, e.g., S11) over frequencies 875O for BAW resonator 8000O (e.g., over frequencies including twenty-four Gigahertz, e.g., over frequencies including the 24 GHz main resonant frequency of BAW resonator 8000O, e.g., over frequencies including the 24 GHz main series resonant frequency, Fs, of BAW resonator 8000O). Uneven artifacts in the Smith chart depiction of electrical reflection coefficient S-parameters over frequencies 875O may be described in various ways such as epicycles, lobes and/or rattles, which may be indicative of the presence of parasitic lateral resonances in operation of the BAW resonator 8000O

A bottom right section of FIG. 8D shows Smith chart 8001P showing a simulation of electrical reflection coefficient S-parameters over frequencies 875P for BAW resonator 8000P (e.g., over frequencies including twenty-four Gigahertz, e.g., over frequencies including the 24 GHz main resonant frequency of BAW resonator 8002P, e.g., over frequencies including the 24 GHz main series resonant frequency, Fs, of BAW resonator 8002P). In the Smith chart depiction of electrical reflection coefficient S-parameters over frequencies 875P may be described in various ways such as smooth (e.g., relatively smooth, e.g., substantially smooth), even (e.g., relatively even, e.g., substantially even), which may be indicative of an absence of unwanted parasitic lateral resonances in operation of the BAW resonator 8000P.

Bulk acoustic wave resonator 8000Q shown on the top left hand side of FIG. 8E may comprise first interposer layer 8059Q arranged between second piezoelectric layer 8002Q and third piezoelectric layer 8003Q. In contrast, bulk acoustic wave resonator 8000R shown on the top right hand side of FIG. 8E may comprise first—patterned—interposer layer 8059R arranged between second piezoelectric layer 8002R and third piezoelectric layer 8003R. First—patterned—interposer layer 8059R of bulk acoustic wave resonator 8000R may include first central feature 8062R comprising a first material (e.g., Titanium (Ti)) having a first acoustic impedance. First—patterned—interposer layer 8059R of bulk acoustic wave resonator 8000R may further include peripheral features comprising a second material (e.g., Tungsten (W)) having a second acoustic impedance (e.g., second acoustic impedance that is greater than the first acoustic impedance). First interposer layer 8059Q of bulk acoustic wave resonator 8000Q may comprise the first material (e.g., Titanium (Ti)) having the first acoustic impedance.

A bottom left section of FIG. 8E shows a Smith chart 8001Q showing a simulation of Scattering-parameters (e.g., S-parameters, e.g., S11) over frequencies 875Q for BAW resonator 8000Q (e.g., over frequencies including twenty-four Gigahertz, e.g., over frequencies including the 24 GHz main resonant frequency of BAW resonator 8000Q, e.g., over frequencies including the 24 GHz main series resonant frequency, Fs, of BAW resonator 8000Q). Uneven artifacts in the Smith chart depiction of electrical reflection coefficient S-parameters over frequencies 875Q may be described in various ways such as epicycles, lobes and/or rattles, which may be indicative of the presence of parasitic lateral resonances in operation of the BAW resonator 8000Q.

A bottom right section of FIG. 8E shows Smith chart 8001R showing a simulation of electrical reflection coefficient S-parameters over frequencies 875R for BAW resonator 8000R (e.g., over frequencies including twenty-four Gigahertz, e.g., over frequencies including the 24 GHz main resonant frequency of BAW resonator 8002R, e.g., over frequencies including the 24 GHz main series resonant frequency, Fs, of BAW resonator 8002R). In the Smith chart depiction of electrical reflection coefficient S-parameters over frequencies 875R may be described in various ways such as smooth (e.g., relatively smooth, e.g., substantially smooth), even (e.g., relatively even, e.g., substantially even), which may be indicative of an absence of unwanted parasitic lateral resonances in operation of the BAW resonator 8002R.

Comparing Smith charts 8001M, 8001O and 8001Q may show decreasing intensity of uneven artifacts (e.g., smaller epicycles, lobes and/or rattles) in Smith chart 8001O relative to Smith chart 8001M, and decreasing intensity of uneven artifacts (e.g., smaller epicycles, lobes and/or rattles) in Smith chart 8001Q relative to Smith chart 8001M and Smith Chart O. It is theorized that this may be: due to decreasing presence of parasitic lateral resonances in operation of four piezoelectric layer BAW resonator 8000O, relative to operation of two piezoelectric layer BAW resonator 8000M; and due to decreasing presence of parasitic lateral resonances in operation of six piezoelectric layer BAW resonator 8000Q, relative to operation of four layer piezoelectric layer BAW resonator 8000O, and relative to operation of two piezoelectric layer BAW resonator 8000M. Increasing number of piezoelectric layers in the BAW resonators may, but need not decrease presence of parasitic lateral resonances in operation of the BAW resonators.

Further, comparing Smith charts 8001N, 8001P, 8001R (corresponding to BAW resonators 8000N, 8000P, 8000R having respective—patterned—interposer layers 8059N, 8059P, 8059R) to Smith charts 8001M, 8001O, 8001Q (corresponding to BAW resonators 8000M, 8000O, 8000Q having respective interposer layers 8059N, 8059P, 8059R) may show relatively more evenness, e.g., relatively more smoothness in Smith charts 8001N, 8001P, 8001R (corresponding to BAW resonators 8000N, 8000P, 8000R having respective—patterned—interposer layers 8059N, 8059P, 8059R), relative to Smith charts 8001M, 8001O, 8001Q (corresponding to BAW resonators 8000M, 8000O, 8000Q having respective interposer layers 8059M, 8059O, 8059Q). It is theorized that this may be due to decreasing presence of parasitic lateral resonances in operation of BAW resonators 8000N, 8000P, 8000R having—patterned—interposer layers 8059N, 8059P, 8059R, relative to operation of BAW resonators 8000M, 8000O, 8000Q having respective interposer layers 8059M, 8059O, 8059Q. Accordingly, —patterned—interposer layers 8059N, 8059P, 8059R in BAW resonators 8000N, 8000P, 8000R may, but need not reduce presence of presence of parasitic lateral resonances in operation of the BAW resonators.

FIG. 8F shows an additional pair of bulk acoustic wave resonators 8000S, 8000T, along with charts 8100S, 8100T corresponding to respective members of the pair of bulk acoustic wave resonators showing quality factor averaged over two alternative frequency ranges versus ratio of peripheral feature overlap width Wpf to full active width Wfa, as expected from simulation.

FIG. 8G shows another additional pair of bulk acoustic wave resonators 8000U, 8000V, along with charts 8100U, 8100V corresponding to respective members of the pair of bulk acoustic wave resonators showing quality factor averaged over two alternative frequency ranges versus ratio of peripheral feature overlap width Wpf to full active width Wfa, as expected from simulation.

As shown, the four bulk acoustic wave resonators 8000S, 8000T, 8000U, 8000V comprise respective piezoelectric stacks of piezoelectric layers in alternating piezoelectric axis orientation arrangements, sandwiched between respective top acoustic reflector electrodes 8015S, 8015T, 8015U, 8015V and respective bottom acoustic reflector electrodes 8013S, 8013T, 8013U, 8013V.

Bulk acoustic wave resonators 8000S, 8000T, 8000U, 8000V may comprise respective first piezoelectric layers 801S, 801T, 801U, 801V having respective first piezoelectric axis orientations (e.g., having normal piezoelectric axis orientations). Bulk acoustic wave resonators 8000S, 8000T, 8000U, 8000V may comprise respective second piezoelectric layers 802S, 802T, 802U, 802V having respective second piezoelectric axis orientations (e.g., having reverse piezoelectric axis orientations). Bulk acoustic wave resonators 8000S, 8000T, 8000U, 8000V may comprise respective third piezoelectric layers 803S, 803T, 803U, 803V having respective third piezoelectric axis orientations (e.g., having normal piezoelectric axis orientations). Bulk acoustic wave resonators 8000S, 8000T, 8000U, 8000V may comprise respective fourth piezoelectric layers 804S, 804T, 804U, 804V having respective fourth piezoelectric axis orientations (e.g., having reverse piezoelectric axis orientations). Bulk acoustic wave resonators 8000S, 8000T, 8000U, 8000V may comprise respective four piezoelectric layers in which the piezoelectric layers may have respective thicknesses of approximately half acoustic wavelength of the main resonant frequencies (e.g., 24 GHz) of the bulk acoustic wave resonators 8000S, 8000T, 8000U, 8000V.

As shown, the four bulk acoustic wave resonators 8000S, 8000T, 8000U, 8000V comprise respective piezoelectric stacks of piezoelectric layers in alternating piezoelectric axis orientation arrangements, sandwiched between respective top acoustic reflector electrodes 8015S, 8015T, 8015U, 8015V and respective bottom acoustic reflector electrodes 8013S, 8013T, 8013U, 8013V. Bulk acoustic wave resonators 8000S, 8000T, 8000U, 8000V may comprise respective first piezoelectric layers 801S, 801T, 801U, 801V having normal piezoelectric axis orientation. Bulk acoustic wave resonators 8000S, 8000T, 8000U, 8000V may comprise respective second piezoelectric layers 802S, 802T, 802U, 802V having respective reverse piezoelectric axis orientations. Bulk acoustic wave resonators 8000S, 8000T, 8000U, 8000V may comprise respective third piezoelectric layers 803S, 803T, 803U, 803V having respective normal piezoelectric axis orientation. Bulk acoustic wave resonators 8000S, 8000T, 8000U, 8000V may comprise respective fourth piezoelectric layers 804S, 804T, 804U, 804V having respective reverse piezoelectric axis orientations. Bulk acoustic wave resonators 8000S, 8000T, 8000U, 8000V may comprise respective four piezoelectric layers in which the piezoelectric layers may have respective thicknesses of approximately half acoustic wavelength of the main resonant frequencies (e.g., 24 GHz) of the bulk acoustic wave resonators 8000S, 8000T, 8000U, 8000V.

The respective stacks of four piezoelectric material layers of the four example bulk acoustic wave resonators 8000S, 8000T, 8000U, 8000V may have respective active regions (e.g., respective alternating axis active piezoelectric volumes) where respective lateral extents of respective top acoustic reflector electrodes may overlap respective lateral extents of the bottom acoustic reflector electrode. In the four example bulk acoustic wave resonators 8000S, 8000T, 8000U, 8000V of FIGS. 8A and 8B, respective active regions (e.g., respective alternating axis active piezoelectric volumes) where the lateral extent of respective top acoustic reflector electrode may overlap respective lateral extent of the bottom acoustic reflector electrode are highlighted as extending between notional dotted lines. In other words, respective width Wfa of respective active regions (e.g., respective width Wfa of respective alternating axis active piezoelectric volumes) are highlighted as extending between notional dotted lines, for the four example bulk acoustic wave resonators 8000S, 8000T, 8000U, 8000V. The respective widths Wfa of bulk acoustic wave resonators 8000S, 8000T, 8000U, 8000V may correspond to fifty (50) Ohm characteristic impedances e.g., at series main resonant frequencies Fr of about twenty-four GigaHertz (24 GHz).

For example, in operation of bulk acoustic wave resonators 8000S, 8000T, 8000U, 8000V, respective oscillating electric fields may be applied via respective top acoustic reflector electrodes 8015S, 8015T, 8015U, 8015V and respective bottom acoustic reflector electrodes 8013S, 8013T, 8013U, 8013V, so as to activate responsive piezoelectric acoustic oscillations (e.g., a main resonant mode) in the respective active regions (e.g., respective alternating axis active piezoelectric volumes) of the respective stacks of four piezoelectric material layers, having respective widths Wfa, where the lateral extent of the respective top acoustic reflector electrodes may overlap the lateral extent of the respective bottom acoustic reflector electrodes. In other words, where the respective lateral extents of the respective top acoustic reflector electrodes 8015S, 8015T, 8015U, 8015V overlaps the respective lateral extents of the respective bottom acoustic reflector electrodes 8013S, 8013T, 8013U, 8013V may define respective widths Wfa of the respective alternating axis active piezoelectric volumes (e.g., respective widths Wfa of active regions), as highlighted in FIGS. 8F and 8G as width Wfa extending between notional dotted lines.

Bulk acoustic wave resonators 8000S, 8000T, 8000U, 8000V may comprise respective first patterned interposer layers 859S, 859T, 859U, 859V. Varying materials of patterned interposer layers, varying width dimensions of peripheral features of patterned interposer layers, and varying placement of patterned interposer layers may vary figures of merit (e.g., may vary quality factor) e.g., for acoustic wave resonators 8000S, 8000T, 8000U, 8000V.

For example, in bulk acoustic wave resonators 8000S, 8000T shown in FIG. 8F, respective first patterned interposer layers 8059S, 8059T may be arranged between the respective half acoustic wave thicknesses of respective second piezoelectric layers 8002S, 8002T and the respective half acoustic wave thicknesses of respective third piezoelectric layers 8003S, 8003T. It is theorized that an acoustic energy null may be placed near the respective locations of the respective first patterned interposer layers 8059S, 8059T, between the respective half acoustic wave thicknesses of the respective second piezoelectric layers 8002S, 8000T and the respective half acoustic wave thicknesses of respective third piezoelectric layers 8003S, 8003T, during operation of the respective bulk acoustic wave resonators 8000S, 8000T. It is theorized that relatively less acoustic energy may be present at the location of the respective first patterned interposer layers 8059S, 8059T (e.g., at respective acoustic energy nulls) between the respective half acoustic wave thicknesses of the respective second piezoelectric layers 8002S, 8002T and the respective half acoustic wave thicknesses of respective third piezoelectric layers 8003S, 8003T, during operation of the bulk acoustic wave resonators 8000S, 8000T. It is theorized, that the respective first patterned interposer layers 8059S, 8059T may have relatively less interaction with the relatively less acoustic energy e.g., present at the nulls, e.g., present at the respective locations of the respective first patterned interposer layers 8059S, 8059T, between the respective half acoustic wave thicknesses of the respective second piezoelectric layers 8002S, 8000T and the respective half acoustic wave thicknesses of respective third piezoelectric layers 8003S, 8003T.

For example, in bulk acoustic wave resonator 8000S, first patterned interposer layer 8059S may be arranged near the acoustic energy null, e.g., between the half acoustic wave thickness of second piezoelectric layer 8002S and the half acoustic wave thickness of third piezoelectric layer 8003S. Further, first patterned interposer layer 8059S may comprise a central feature 8062S comprising a first material (e.g., Titanium (Ti)) having a first acoustic impedance (e.g., Titanium having a relatively low acoustic impedance). First patterned interposer layer 8059S may comprise a peripheral features comprising a second material (e.g., Tungsten (W)) having a second acoustic impedance (e.g., Tungsten having a relatively high acoustic impedance).

As already discussed in detail previously herein, width Wfa of the active region of BAW resonator 8000S (e.g., width Wfa of the alternating axis active piezoelectric volume) is highlighted as extending between notional dotted lines, for bulk acoustic wave resonator 8000S. Widths Wpf where the peripheral features of patterned interposer layer 8059S may overlap the active region of BAW resonator 8000S (e.g., may overlap the alternating axis active piezoelectric volume) highlighted as extending between notional dotted lines and notional dashed lines. (It may be briefly noted that width of central feature 8062S may be highlighted as extending between the notional dashed lines. The notional dashed lines may define extremities of the central feature 8062S. The notional dashed lines may define central extremities of the peripheral features of first patterned interposer layer 8059S).

Chart 8100S corresponds to bulk acoustic wave resonator 8000S showing quality factor averaged over two alternative frequency ranges versus ratio of peripheral feature overlap width Wpf to full active width Wfa, as expected from simulation. Trace 8101S depicted in solid line shows averages of quality factor values above the series resonant frequency Fs and below the parallel resonant frequency Fp first ranging and increasing from about 1750 to about 3200, as ratio of peripheral feature overlap width Wpf to full active width Wfa ranges and increases from zero percent to about 2.1 percent; with averages of quality factor values above the series resonant frequency Fs and below the parallel resonant frequency Fp then ranging and decreasing from about 3200 to about 1700, as ratio of peripheral feature overlap width Wpf to full active width Wfa ranges and increases from about 3.1 percent to about six percent.

Trace 8103S depicted in dotted line shows averages of quality factor values over twenty five degrees of Smith chart angle below the main series resonant frequency Fs of BAW resonator 8000S first ranging and decreasing from about 2800 to about 1500, as ratio of peripheral feature overlap width Wpf to full active width Wfa ranges and increases from zero percent to about 3.1 percent; with averages of quality factor values over twenty five degrees of Smith chart angle below the main series resonant frequency Fs of BAW resonator 8000S then ranging and increasing from about 1500 to about 2000, as ratio of peripheral feature overlap width Wpf to full active width Wfa ranges and increases from about 3.1 percent to about six percent.

In contrast to bulk acoustic wave resonator 8000S in which first patterned interposer layer 8059S may comprise the central feature 8062S comprising the first material (e.g., Titanium (Ti)) having the first acoustic impedance (e.g., Titanium having the relatively low acoustic impedance), and including peripheral features comprising the second material (e.g., Tungsten (W)) having the second acoustic impedance (e.g., Tungsten having the relatively high acoustic impedance), this arrangement is—reversed—in first patterned interposer layer 8059T of bulk acoustic wave resonator 8000T.

Specifically, in bulk acoustic wave resonator 8000T the first patterned interposer layer 8059T may comprise the central feature 8062T comprising the—second—material (e.g., Tungsten (W)) having the second acoustic impedance (e.g., Tungsten having the relatively high acoustic impedance), and including peripheral features comprising the—first—material (e.g., Titanium (Ti)) having the first acoustic impedance (e.g., Titanium having a relatively low acoustic impedance).

In other words, whereas in first patterned interposer layer 8059S, the central feature 8062S may comprise the first material (e.g., Titanium (Ti) having the relatively low acoustic impedance), and peripheral features may comprise the second material (e.g., Tungsten (W) having the relatively high acoustic impedance), this arrangement is reversed in first patterned interposer layer 8059T. In first patterned interposer layer 8059T, the central feature 8062T may comprise the second material (e.g., Tungsten (W) having the relatively high acoustic impedance), and peripheral features may comprise the first material (e.g., Titanium (Ti) having the relatively low acoustic impedance).

In bulk acoustic wave resonator 8000T, first patterned interposer layer 8059T may be arranged near the acoustic energy null, e.g., between the half acoustic wave thickness of second piezoelectric layer 8002T and the half acoustic wave thickness of third piezoelectric layer 8003T.

As already discussed in detail previously herein, width Wfa of the active region of BAW resonator 8000T (e.g., width Wfa of the alternating axis active piezoelectric volume) is highlighted as extending between notional dotted lines, for bulk acoustic wave resonator 8000T. Widths Wpf where the peripheral features of patterned interposer layer 8059T may overlap the active region of BAW resonator 8000T (e.g., may overlap the alternating axis active piezoelectric volume) highlighted as extending between notional dotted lines and notional dashed lines. (It may be briefly noted that width of central feature 8062T may be highlighted as extending between the notional dashed lines. The notional dashed lines may define extremities of the central feature 8062T. The notional dashed lines may define central extremities of the peripheral features of first patterned interposer layer 8059T).

Chart 8100T corresponds to bulk acoustic wave resonator 8000T showing quality factor averaged over two alternative frequency ranges versus ratio of peripheral feature overlap width Wpf to full active width Wfa, as expected from simulation. Trace 8101T depicted in solid line shows averages of quality factor values above the series resonant frequency Fs and below the parallel resonant frequency Fp ranging from about 1600 to about 2000, as ratio of peripheral feature overlap width Wpf to full active width Wfa ranges and increases from zero percent to about six percent.

Trace 8103T depicted in dotted line shows averages of quality factor values over twenty five degrees of Smith chart angle below the main series resonant frequency Fs of BAW resonator 8000T first ranging from about 2900 to about 3250, as ratio of peripheral feature overlap width Wpf to full active width Wfa ranges and increases from zero percent to about six percent.

For example, in bulk acoustic wave resonators 8000U, 8000V shown in FIG. 8G, respective first patterned interposer layers 8059U, 8059V may be arranged at respective central portions of respective second piezoelectric layers 8002U, 8002V of bulk acoustic wave resonators 8000U, 8000V. For example, in bulk acoustic wave resonators 8000U, 8000V, respective first patterned interposer layers 8059S, 8059T, may split the respective middles of respective second piezoelectric layers 8002U, 8002V of bulk acoustic wave resonators 8000U, 8000V. For example, respective first patterned interposer layers 8059U, 8059V may split the respective half acoustic wavelength thicknesses of respective second piezoelectric layers 8002U, 8002V into two quarter acoustic wavelength thick sub-layers. In other words, respective first patterned interposer layers 8059U, 8059V may be arranged along a central portion of respective second piezoelectric layers 8002U, 8002V.

It is theorized that respective acoustic energy peaks may be placed at the respective locations of the first patterned interposer layers 8059S, 8059T, at the respective central portions of the respective second piezoelectric layers 8002U, 8002V, during operation of the bulk acoustic wave resonators 8000U, 8000V. It is theorized that relatively more acoustic energy may be present at the respective central portions of the respective second half acoustic wavelength thick piezoelectric layers 8002U, 8002V, during operation of the bulk acoustic wave resonators 8000U, 8000V. It is theorized that the first patterned interposer layers 8059S, 8059T may have relatively more interaction with the relatively more acoustic energy present e.g., at the acoustic energy peaks, e.g., at the respective central portions of the respective second half acoustic wavelength thick piezoelectric layers 8002U, 8002V.

For example, in bulk acoustic wave resonator 8000U, first patterned interposer layer 8059U may be arranged near the acoustic energy peak, e.g., at the central portion of the second half acoustic wavelength thick piezoelectric layer 8002U. Further, first patterned interposer layer 8059U may comprise a central feature 8062U comprising the first material (e.g., Titanium (Ti)) having the first acoustic impedance (e.g., Titanium having the relatively low acoustic impedance). First patterned interposer layer 8059S may comprise peripheral features comprising the second material (e.g., Tungsten (W)) having the second acoustic impedance (e.g., Tungsten having the relatively high acoustic impedance).

As already discussed in detail previously herein, width Wfa of the active region of BAW resonator 8000U (e.g., width Wfa of the alternating axis active piezoelectric volume) is highlighted as extending between notional dotted lines, for bulk acoustic wave resonator 8000U. Widths Wpf where the peripheral features of patterned interposer layer 8059U may overlap the active region of BAW resonator 8000U (e.g., may overlap the alternating axis active piezoelectric volume) highlighted as extending between notional dotted lines and notional dashed lines. (It may be briefly noted that width of central feature 8062U may be highlighted as extending between the notional dashed lines. The notional dashed lines may define extremities of the central feature 8062U. The notional dashed lines may define central extremities of the peripheral features of first patterned interposer layer 8059U).

Chart 8100U corresponds to bulk acoustic wave resonator 8000U showing quality factor averaged over two alternative frequency ranges versus ratio of peripheral feature overlap width Wpf to full active width Wfa, as expected from simulation. Trace 8101U depicted in solid line shows averages of quality factor values above the series resonant frequency Fs and below the parallel resonant frequency Fp ranging from about 1850 to about 1500, as ratio of peripheral feature overlap width Wpf to full active width Wfa ranges and increases from zero percent to about six percent.

Trace 8103U depicted in dotted line shows averages of quality factor values over twenty five degrees of Smith chart angle below the main series resonant frequency Fs of BAW resonator 8000U first ranging from about 2900 to about 3100, as ratio of peripheral feature overlap width Wpf to full active width Wfa ranges and increases from zero percent to about six percent.

In contrast to bulk acoustic wave resonator 8000U in which first patterned interposer layer 8059U may comprise the central feature 8062U comprising the first material (e.g., Titanium (Ti)) having the first acoustic impedance (e.g., Titanium having the relatively low acoustic impedance), and including peripheral features comprising the second material (e.g., Tungsten (W)) having the second acoustic impedance (e.g., Tungsten having the relatively high acoustic impedance), this arrangement is—reversed—in first patterned interposer layer 8059V of bulk acoustic wave resonator 8000V.

Specifically, in bulk acoustic wave resonator 8000V the first patterned interposer layer 8059V may comprise the central feature 8062V comprising the—second—material (e.g., Tungsten (W)) having the second acoustic impedance (e.g., Tungsten having the relatively high acoustic impedance), and including peripheral features comprising the—first—material (e.g., Titanium (Ti)) having the first acoustic impedance (e.g., Titanium having a relatively low acoustic impedance).

In other words, whereas in first patterned interposer layer 8059U, the central feature 8062U may comprise the first material (e.g., Titanium (Ti) having the relatively low acoustic impedance), and peripheral features may comprise the second material (e.g., Tungsten (W) having the relatively high acoustic impedance), this arrangement is reversed in first patterned interposer layer 8059V. In first patterned interposer layer 8059V, the central feature 8062V may comprise the second material (e.g., Tungsten (W) having the relatively high acoustic impedance), and peripheral features may comprise the first material (e.g., Titanium (Ti) having the relatively low acoustic impedance).

In bulk acoustic wave resonator 8000V, first patterned interposer layer 8059T may be arranged near the acoustic energy peak, e.g., at the central portion of the second half acoustic wavelength thick piezoelectric layer 8002V.

As already discussed in detail previously herein, width Wfa of the active region of BAW resonator 8000V (e.g., width Wfa of the alternating axis active piezoelectric volume) is highlighted as extending between notional dotted lines, for bulk acoustic wave resonator 8000V. Widths Wpf where the peripheral features of patterned interposer layer 8059T may overlap the active region of BAW resonator 8000V (e.g., may overlap the alternating axis active piezoelectric volume) highlighted as extending between notional dotted lines and notional dashed lines. (It may be briefly noted that width of central feature 8062V may be highlighted as extending between the notional dashed lines. The notional dashed lines may define extremities of the central feature 8062V. The notional dashed lines may define central extremities of the peripheral features of first patterned interposer layer 8059V).

Chart 8100V corresponds to bulk acoustic wave resonator 8000V showing quality factor averaged over two alternative frequency ranges versus ratio of peripheral feature overlap width Wpf to full active width Wfa, as expected from simulation. Trace 8101V depicted in solid line shows averages of quality factor values above the series resonant frequency Fs and below the parallel resonant frequency Fp first ranging and increasing from about 1700 to about 2750, as ratio of peripheral feature overlap width Wpf to full active width Wfa ranges and increases from zero percent to about 2.4 percent; with averages of quality factor values above the series resonant frequency Fs and below the parallel resonant frequency Fp then ranging and decreasing from about 2750 to about 1800, as ratio of peripheral feature overlap width Wpf to full active width Wfa ranges and increases from about 2.4 percent to about six percent.

Trace 8103V depicted in dotted line shows averages of quality factor values over twenty five degrees of Smith chart angle below the main series resonant frequency Fs of BAW resonator 8000V first ranging and decreasing from about 2750 to about 1750, as ratio of peripheral feature overlap width Wpf to full active width Wfa ranges and increases from zero percent to about 4 percent; with averages of quality factor values over twenty five degrees of Smith chart angle below the main series resonant frequency Fs of BAW resonator 8000V then ranging and increasing from about 1750 to about 1850, as ratio of peripheral feature overlap width Wpf to full active width Wfa ranges and increases from about 4 percent to about six percent.

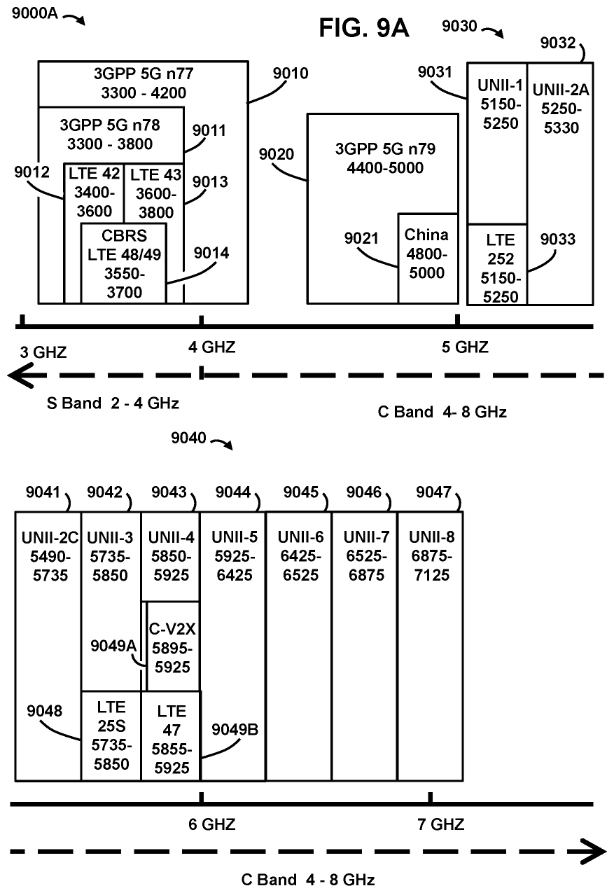

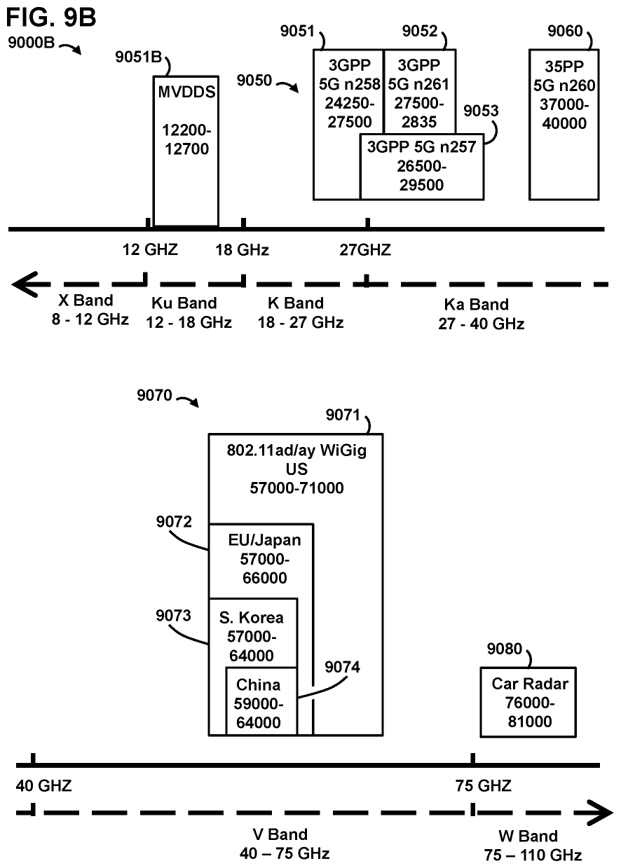

FIGS. 9A and 9B are simplified diagrams of a frequency spectrum illustrating application frequencies and application frequency bands of the example bulk acoustic wave resonators shown in FIG. 1A and FIGS. 4A through 4G, and the example filters shown in FIGS. 5 and 6A and 7A, and the example oscillator shown in FIG. 7B.

A widely used standard to designate frequency bands in the microwave range by letters is established by the United States Institute of Electrical and Electronic Engineers (IEEE). In accordance with standards published by the IEEE, as defined herein, and as shown in FIGS. 9A and 9B are application bands as follows: S Band (2 GHz-4 GHz), C Band (4 GHz-8 GHz), X Band (8 GHz-12 GHz), Ku Band (12 GHz-18 GHz), K Band (18 GHz-27 GHz), Ka Band (27 GHz-40 GHz), V Band (40 GHz-75 GHz), and W Band (75 GHz-110 GHz). FIG. 9A shows a first frequency spectrum portion 9000A in a range from three Gigahertz (3 GHz) to eight Gigahertz (8 GHz), including application bands of S Band (2 GHz-4 GHz) and C Band (4 GHz-8 GHz). As described subsequently herein, the 3rd Generation Partnership Project standards organization (e.g., 3GPP) has standardized various 5G frequency bands. For example, included is a first application band 9010 (e.g., 3GPP 5G n77 band) (3.3 GHz-4.2 GHz) configured for fifth generation broadband cellular network (5G) applications. As described subsequently herein, the first application band 9010 (e.g., 5G n77 band) includes a 5G sub-band 9011 (3.3 GHz-3.8 GHz). The 3GPP 5G sub-band 9011 includes Long Term Evolution broadband cellular network (LTE) application sub-bands 9012 (3.4 GHz-3.6 GHz), 9013 (3.6 GHz-3.8 GHz), and 9014 (3.55 GHz-3.7 GHz). A second application band 9020 (4.4 GHz-5.0 GHz) includes a sub-band 9021 for China specific applications. Discussed next are Unlicensed National Information Infrastructure (UNII) bands. A third application band 9030 includes a UNII-1 band 9031 (5.15 GHz-5.25 GHz) and a UNII-2A band 9032 (5.25 GHz 5.33 GHz). An LTE band 9033 (LTE Band 252) overlaps the same frequency range as the UNII-1 band 6031. A fourth application band 9040 includes a UNII-2C band 9041 (5.490 GHz-5.735 GHz), a UNII-3 band 9042 (5.735 GHz-5.85 GHz), a UNII-4 band 9043 (5.85 GHz-5.925 GHz), a UNII-5 band 9044 (5.925 GHz-6.425 GHz), a UNII-6 band 9045 (6.425 GHz-6.525 GHz), a UNII-7 band 9046 (6.525 GHz-6.875 GHz), and a UNII-8 band 9047 (6.875 GHz-7125 GHz). An LTE band 9048 overlaps the same frequency range (5.490 GHz-5.735 GHz) as the UNII-3 band 9042. A sub-band 9049A shares the same frequency range as the UNII-4 band 9043 (e.g., cellular vehicle-to-everything (c-V2X) 9049A in a thirty MegaHertz (30 MHz) band extending from 5.895 GHz to 5.925 GHz). An LTE band 9049B shares a subsection of the same frequency range (5.855 GHz-5.925 GHz).

FIG. 9B shows a second frequency spectrum portion 9000B in a range from eight Gigahertz (8 GHz) to one-hundred and ten Gigahertz (110 GHz), including application bands of X Band (8 GHz-12 GHz), Ku Band (12 GHz-18 GHz), K Band (18 GHz-27 GHz), Ka Band (27 GHz-40 GHz), V Band (40 GHz-75 GHz), and W Band (75 GHz-110 GHz). A fifth application band 9050 includes 3GPP 5G bands configured for fifth generation broadband cellular network (5G) applications, e.g., 3GPP 5G n258 band 9051 (24.25 GHz-27.5 GHz), e.g., 3GPP 5G n261 band 9052 (27.5 GHz-28.35 GHz), e.g., 3GPP 5G n257 band 9053 (26.5 GHz-29.5). FIG. 9B shows a MVDDS (Multi-channel Video Distribution and Data Service) band 9051B (12.2 GHz-12.7 GHz). FIG. 9B shows an EESS (Earth Exploration Satellite Service) band 9051A (23.6 GHz-24 GHz) adjacent to the 3GPP 5G n258 band 9051 (24.25 GHz-27.5 GHz). As will be discussed in greater detail subsequently herein, an example EESS notch filter of the present disclosure may facilitate protecting the EESS (Earth Exploration Satellite Service) band 9051A (23.6 GHz-24 GHz) from energy leakage from the adjacent 3GPP 5G n258 band 9051 (24.25 GHz-27.5 GHz). For example, this may facilitate satisfying (e.g., facilitate compliance with) a specification of a standards setting organization, e.g., International Telecommunications Union (ITU) specifications, e.g., ITU-R SM.329 Category A/B levels of −20 db W/200 MHz, e.g., 3rd Generation Partnership Project (3GPP) 5G specifications, e.g., 3GPP 5G, unwanted (out-of-band & spurious) emission levels, worst case of −20 db W/200 MHz. Alternatively or additionally, this may facilitate satisfying (e.g., facilitate compliance with) a regulatory requirement, e.g., a government regulatory requirement, e.g., a Federal Communications Commission (FCC) decision or requirement, e.g., a European Commission decision or requirement of −42 db W/200 MHz for 200 MHz for Base Stations (BS) and −38 db W/200 MHz for User Equipment (UE), e.g., European Commission Decision (EU) 2019/784 of 14 May 2019 on harmonization of the 24.25-27.5 GHz frequency band for terrestrial systems capable of providing wireless broadband electronic communications services in the Union, published May 16, 2019, which is hereby incorporated by reference in its entirety, e.g., a European Organization for the Exploitation of Meteorological Satellites (EUMETSAT) decision, requirement, recommendation or study, e.g., a ESA/EUMETSAT/EUMETNET study result of −54.2 db W/200 MHz for Base Stations (BS) and 50.4 db W/200 MHz for User Equipment (UE), e.g., the United Nations agency of the World Meteorological Organization (WMO) decision, requirement, recommendation or study, e.g., the WMO decision of −55 db W/200 MHz for Base Stations (BS) and −51 db W/200 MHz for User Equipment (UE). These specifications and/or decisions and/or requirements may be directed to suppression of energy leakage from an adjacent band, e.g., energy leakage from an adjacent 3GPP 5G band, e.g., suppression of transmit energy leakage from the adjacent 3GPP 5G n258 band 9051 (24.250 GHz-27.500 GHz), e.g. limiting of spurious out of n258 band emissions. A sixth application band 9060 includes the 3GPP 5G n260 band 9060 (37 GHz-40 GHz). A seventh application band 9070 includes United States WiGig Band for IEEE 802.11ad and IEEE 802.11ay 9071 (57 GHz-71 GHz), European Union and Japan WiGig Band for IEEE 802.11ad and IEEE 802.11ay 9072 (57 GHz-66 GHz), South Korea WiGig Band for IEEE 802.11ad and IEEE 802.11ay 9073 (57 GHz-64 GHz), and China WiGig Band for IEEE 802.11ad and IEEE 802.11ay 9074 (59 GHz-64 GHz). An eighth application band 9080 includes an automobile radar band 9080 (76 GHz-81 GHz).

Accordingly, it should be understood from the foregoing that the acoustic wave devices (e.g., resonators, e.g., filters, e.g., oscillators) of this disclosure may be implemented in the respective application frequency bands just discussed. For example, the layer thicknesses of the acoustic reflector electrodes and piezoelectric layers in alternating axis arrangement for the example acoustic wave devices (e.g., the example 24 GHz bulk acoustic wave resonators) of this disclosure may be scaled up and down as needed to be implemented in the respective application frequency bands just discussed. This is likewise applicable to the example filters (e.g., bulk acoustic wave resonator based filters) and example oscillators (e.g., bulk acoustic wave resonator based oscillators) of this disclosure to be implemented in the respective application frequency bands just discussed. The following examples pertain to further embodiments for acoustic wave devices, including but not limited to, e.g., bulk acoustic wave resonators, e.g., bulk acoustic wave resonator based filters, e.g., bulk acoustic wave resonator based oscillators, and from which numerous permutations and configurations will be apparent.

A first example is an acoustic wave device (e.g., a bulk acoustic wave resonator) comprising a substrate, an active piezoelectric volume having a main resonant frequency (e.g., series main resonant frequency), the active piezoelectric volume including first and second piezoelectric layers having respective piezoelectric axis that substantially oppose one another; and a first patterned layer disposed within the active piezoelectric volume. The first patterned layer disposed within the active piezoelectric volume may facilitate suppression of spurious modes.

A second example is an acoustic wave device as described in the first example, in which the resonant frequency of the acoustic wave device is in a 3rd Generation Partnership Project (3GPP) band.

A third example is an acoustic wave device as described in the first example in which the resonant frequency of the acoustic wave device is in a 3rd Generation Partnership Project (3GPP) band.

A fourth example is an acoustic wave device as the first example, in which the resonant frequency of the acoustic wave device is in a 3GPP n77 band 9010 as shown in FIG. 9A.

A fifth example is an acoustic wave device as described in the first example, in which the resonant frequency of the acoustic wave device is in a 3GPP n79 band 9020 as shown in FIG. 9A.

A sixth example is an acoustic wave device as described in the first example, in which the resonant frequency of the acoustic wave device is in a 3GPP n258 band 9051 as shown in FIG. 9B.

A seventh example is an acoustic wave device as described in the first example, in which the resonant frequency of the acoustic wave device is in a 3GPP n261 band 9052 as shown in FIG. 9B.

An eighth example is an acoustic wave device as described in the first example, in which the resonant frequency of the acoustic wave device is in a 3GPP n260 band as shown in FIG. 9B.

An ninth example is an acoustic wave device as described in the first example, in which the resonant frequency of the acoustic wave device is in an Institute of Electrical and Electronic Engineers (IEEE) C band as shown in FIG. 9A.

A tenth example is an acoustic wave device as described in the first example, in which the resonant frequency of the acoustic wave device is in an Institute of Electrical and Electronic Engineers (IEEE) X band as shown in FIG. 9B.

An eleventh example is an acoustic wave device as described in the first example, in which the resonant frequency of the acoustic wave device is in an Institute of Electrical and Electronic Engineers (IEEE) Ku band as shown in FIG. 9B.

A twelfth example is an acoustic wave device as described in the first example, in which the resonant frequency of the acoustic wave device is in an Institute of Electrical and Electronic Engineers (IEEE) X band as shown in FIG. 9B.

A thirteenth example is an acoustic wave device as described in the first example, in which the resonant frequency of the acoustic wave device is in an Institute of Electrical and Electronic Engineers (IEEE) K band as shown in FIG. 9B.

A fourteenth example is an acoustic wave device as described in the first example, in which the resonant frequency of the acoustic wave device is in an Institute of Electrical and Electronic Engineers (IEEE) Ka band as shown in FIG. 9B.

A fifteenth example is an acoustic wave device as described in the first example, in which the resonant frequency of the acoustic wave device is in an Institute of Electrical and Electronic Engineers (IEEE) V band as shown in FIG. 9B.

A sixteenth example is an acoustic wave device as described in the first example, in which the resonant frequency of the acoustic wave device is in an Institute of Electrical and Electronic Engineers (IEEE) W band as shown in FIG. 9B.

A seventeenth example is an acoustic wave device as described in the first example, in which the resonant frequency of the acoustic wave device is in UNII-1 band 9031, as shown in FIG. 9A.

An eighteenth example is an acoustic wave device as described in the first example, in which the resonant frequency of the acoustic wave device is in UNII-2A band 9032, as shown in FIG. 9A.

A nineteenth example is an acoustic wave device as described in the first example, in which the resonant frequency of the acoustic wave device is in UNII-2C band 9041, as shown in FIG. 9A.

A twentieth example is an acoustic wave device as described in the first example, in which the resonant frequency of the acoustic wave device is in UNII-3 band 9042, as shown in FIG. 9A.

A twenty first example is an acoustic wave device as described in the first example, in which the resonant frequency of the acoustic wave device is in UNII-4 band 9043, as shown in FIG. 9A.

A twenty second example is an acoustic wave device as described in the first example, in which the resonant frequency of the acoustic wave device is in UNII-5 band 9044, as shown in FIG. 9A.

A twenty third example is an acoustic wave device as described in the first example, in which the resonant frequency of the acoustic wave device is in UNII-6 band 9045, as shown in FIG. 9A.

A twenty fourth example is an acoustic wave device as described in the first example, in which the resonant frequency of the acoustic wave device is in UNII-7 band 9046, as shown in FIG. 9A.

A twenty fifth example is an acoustic wave device as described in the first example, in which the resonant frequency of the acoustic wave device is in UNII-8 band 9047, as shown in FIG. 9A.

A twenty sixth example is an acoustic wave device as described in the first example, in which the resonant frequency of the acoustic wave device is the MVDDS (Multi-channel Video Distribution and Data Service) band 9051B, as shown in FIG. 9B.

A twenty seventh example is an acoustic wave device as described in the first example, in which the resonant frequency of the acoustic wave device is the EESS (Earth Exploration Satellite Service) band 9051A, as shown in FIG. 9B.

A twenty eighth example is an acoustic wave device as described in the first example, in which the first patterned layer comprises a step mass feature.

A twenty ninth example is an acoustic wave device as described in the first example, in which: the active piezoelectric volume has a lateral perimeter; and the step mass feature of the first patterned layer is proximate to the lateral perimeter of the active piezoelectric volume.

A thirtieth example is an acoustic wave device as described in the first example, in which the first and second piezoelectric layers have respective thicknesses to facilitate the main resonant frequency.

A thirty first example is an acoustic wave device as described in the first example, in which an acoustic reflector electrode is electrically and acoustically coupled with the first and second piezoelectric layers to excite a piezoelectrically excitable main resonant mode at the main resonant frequency of the acoustic wave device.

A thirty second example is an acoustic wave device as described in the thirty first example, in which the acoustic reflector electrode comprises a first pair of metal electrode layers including first and second metal electrode layers electrically and acoustically coupled with the first and second piezoelectric layers.

A thirty third example is an acoustic wave device as described in the thirty second example, in which the acoustic reflector electrode includes a second pair of metal electrode layers electrically and acoustically coupled with the first and second piezoelectric layers to excite the piezoelectrically excitable main resonant mode at the main resonant frequency; and members of the first and second pairs of metal electrode layers have respective acoustic impedances in an alternating arrangement, e.g., to provide a plurality of reflective acoustic impedance mismatches.

A thirty fourth example is an electrical oscillator in which an acoustic wave device as described in any one of the first through thirty third examples forms a portion of the electrical oscillator.

A thirty fifth example is an electrical filter in which an acoustic wave device as described in any one of the first through thirty third examples forms a portion of the electrical filter.

A thirty sixth example is an antenna device in which an acoustic wave device as described in any one of the first through thirty third examples forms a portion of the antenna device.

A thirty seventh example is an antenna device as in the thirty sixth example in which the antenna device comprises: a plurality of antenna elements supported over the substrate, an integrated circuit supported on one side of the substrate, a first millimeter wave acoustic filter coupled with the integrated circuit, in which the first millimeter wave acoustic filter comprises the acoustic wave device, and an antenna feed coupled with the plurality of antenna elements.

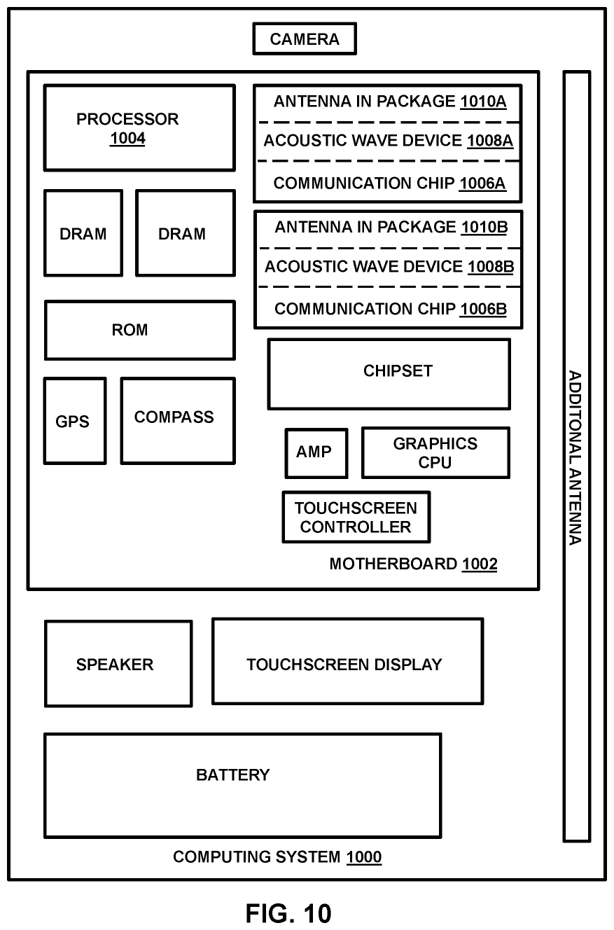

FIG. 10 illustrates a computing system implemented with integrated circuit structures or devices formed using the techniques disclosed herein, in accordance with an embodiment of the present disclosure. As may be seen, the computing system 1000 houses a motherboard 1002. The motherboard 1002 may include a number of components, including, but not limited to, a processor 1004 and at least one communication chip 1006A, 1006B each of which may be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, additional antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions may be integrated into one or more chips (e.g., for instance, note that the communication chips 1006A, 1006B may be part of or otherwise integrated into the processor 1004).

The communication chips 1006A, 1006B enable wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chips 1006A, 1006B may implement any of a number of wireless standards or protocols, including, but not limited to, Wi-Fi (IEEE 802.1 1 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006A, 1006B. For instance, a first communication chip 1006A may be dedicated to shorter range wireless communications such as Wi-Fi and Bluetooth and a second communication chip 1006B may be dedicated to longer range wireless communications such as GPS, EDGE, GPRS, CDMA, WiMAX, LTE, Ev-DO, 5G and others. In some embodiments, communication chips 1006A, 1006B may include one or more acoustic wave devices 1008A, 1008B (e.g., resonators, filters and/or oscillators 1008A, 1008B) as variously described herein (e.g., acoustic wave devices including a stack of alternating axis piezoelectric material). Acoustic wave devices 1008A, 1008B may be included in various ways, e.g., one or more resonators, e.g., one or more filters, e.g., one or more oscillators. For example, acoustic wave devices 1008A, 1008B may be included in one or more filters with communications chips 1006A, 1006B, in combination with respective antenna in package(s) 1010A, 1010B.

Further, such acoustic wave devices 1008A, 1008B, e.g., resonators, e.g., filters, e.g., oscillators may be configured to be Super High Frequency (SHF) acoustic wave devices 1008A, 1008B or Extremely High Frequency (EHF) acoustic wave devices 1008A, 1008B, e.g., resonators, filters, and/or oscillators (e.g., operating at greater than 3, 4, 5, 6, 7, or 8 GHz, e.g., operating at greater than 23, 24, 25, 26, 27, 28, 29, or 30 GHz, e.g., operating at greater than 36, 37, 38, 39, or 40 GHz). Further still, such Super High Frequency (SHF) acoustic wave devices or Extremely High Frequency (EHF) resonators, filters, and/or oscillators may be included in the RF front end of computing system 1000 and they may be used for 5G wireless standards or protocols, for example.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chips 1006A, 1006B also may include an integrated circuit die packaged within the communication chips 1006A, 1006B. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any communication chips 1006A, 1006B is integrated into processor 1004, rather than having separate communication chips). Further note that processor 1004 may be a chip set having such wireless capability. In short, any number of processor 1004 and/or communication chips 1006A, 1006B may be used. Likewise, any one chip or chip set may have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, a streaming media device, an entertainment control unit, a digital camera, a portable music player, a digital video recorder, or any other electronic device that processes data or employs one or more integrated circuit structures or devices formed using the disclosed techniques, as variously described herein.

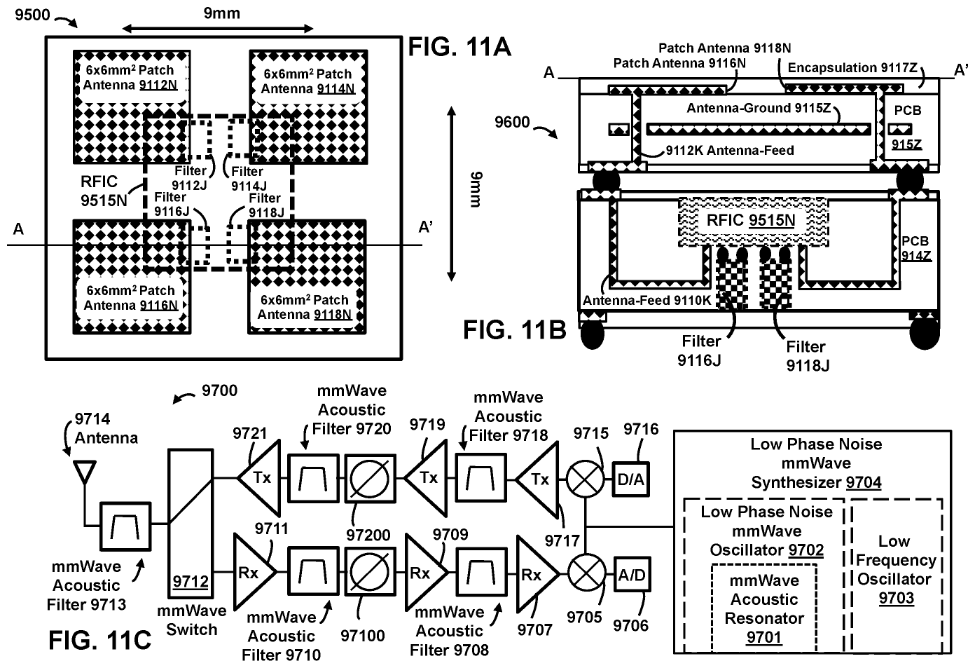

FIG. 11A shows a top view an antenna device 9500 of the present disclosure. The antenna device 9500 may be an antenna in package 9500. The antenna device may comprise an integrated circuit 9515N (e.g., a radio frequency integrated circuit 9515N, e.g., RFIC 9515N). The integrated circuit 9515N may comprise a communication chip 9515N. The integrated circuit 9515N may be operable for 5G wireless communications, for example, in a millimeter wave frequency band, e.g. band including 24 GigaHertz. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Integrated circuit 9515N may be coupled with antenna elements 9112N, 9114N, 9116N, 9118N (e.g., patch antennas 9112N, 9114N, 9116N, 9118N) to facilitate wireless communication. Integrated circuit 9515N may be coupled with bulk acoustic wave resonator based filters 9112J, 9114J, 9116J, 9118J of this disclosure (e.g. bulk acoustic millimeter wave resonator based millimeter wave filters 9112J, 9114J, 9116J, 9118J of this disclosure). The millimeter wave filters 9112J, 9114J, 9116J, 9118J may be band pass millimeter wave filters 9112J, 9114J, 9116J, 9118J to pass a millimeter wave frequency. In some examples, millimeter wave filters 9112J, 9114J, 9116J, 9118J may be two pairs of similar filters, e.g., to address two orthogonal polarizations of patch antennas 9112N, 9114N, 9116N, 9118N.

Patch antennas 9112N, 9114N, 9116N, 9118N may be arranged in a patch antenna array, e.g., having lateral array dimensions (e.g., pitch in a first lateral dimension of, for example, about nine millimeters, e.g., pitch in a second lateral dimension, substantially orthogonal to the first lateral dimension of, for example, about nine millimeters).

The antenna device 9500 may be an antenna in package 9500 may be relatively small in size. This may facilitate: e.g., a relatively small array pitch of patch antennas 9112N, 9114N, 9116N, 9118N (e.g., nine millimeters), e.g., a relatively small respective area of patch antennas 9112N, 9114N, 9116N, 9118N (e.g., six millimeters by six millimeters). The foregoing may be related to frequency, e.g., the millimeter wave frequency band, e.g. band including 24 GigaHertz employed for wireless communication. For example, the array pitch may be approximately one electrical wavelength of the millimeter wave frequency.

For example, as shown in FIG. 11A: a first millimeter wave acoustic filter 9112J may be arranged below the array pitch, e.g., between lateral extremities of the array pitch; a second millimeter wave acoustic filter 9114J may be arranged below the array pitch, e.g., between lateral extremities of the array pitch; a third millimeter wave acoustic filter 9116J may be arranged below the array pitch, e.g., between lateral extremities of the array pitch; and a fourth millimeter wave acoustic filter 9118J may be arranged below the array pitch, e.g., between lateral extremities of the array pitch.

First and second millimeter wave acoustic filters 9112J, 9114J may be arranged below the array pitch between a first pair of the patch antennas 9112N, 9114N. Third and fourth millimeter wave acoustic filters 9116J, 9118J may be arranged below the array pitch between a second pair of the patch antennas 9116N, 9118N. First, second, third and fourth millimeter wave acoustic filters 9112J, 9114J, 9116J, 9118J may be arranged below the array pitch between the quartet of the patch antennas 9112N, 9114N, 9116N, 9118N.

The first millimeter wave acoustic filter 9112J may have an area of about one square millimeter or less, e.g., may have a lateral dimension that is less than the array pitch, e.g., less than nine millimeters. Similarly, the second millimeter wave acoustic filter 9114J may have an area of about one square millimeter or less, e.g., may have a lateral dimension that is less than the array pitch, e.g., less than nine millimeters. The third millimeter wave acoustic filter 9116J may have an area of about one square millimeter or less, e.g., may have a lateral dimension that is less than the array pitch, e.g., less than nine millimeters. The fourth millimeter wave acoustic filter 9118J may have an area of about one square millimeter or less, e.g., may have a lateral dimension that is less than the array pitch, e.g., less than nine millimeters.

The millimeter wave frequency may comprise approximately 24 GigaHertz. The millimeter wave frequency may comprise approximately 28 GigaHertz. The millimeter wave frequency comprises at least one of approximately 39 GigaHertz, approximately 42 GigaHertz, approximately 60 GigaHertz, approximately 77 GigaHertz, and approximately 100 GigaHertz. Respective pass bands of millimeter wave acoustic filters 9112J, 9114J, 9116J, 9118J may be directed to differing frequency pass bands. For example the first millimeter wave acoustic filter 9112J may have a first pass band comprising at least a lower portion of a 3GPP n258 band. For example, the second millimeter wave acoustic filter 9114J may have a second pass band comprising at least an upper portion of a 3GPP n258 band. For example, the third millimeter wave acoustic filter 9116J may have a third pass band comprising at least a lower portion of a 3GPP n261 band. For example, the fourth millimeter wave acoustic filter 9116J may have a pass band comprising at least an upper portion of a 3GPP n261 band.

FIG. 11B shows a cross sectional view 9600 of the antenna device 9500 shown in FIG. 11A comprising millimeter wave acoustic filters 9116J, 9118J coupled (e.g., flip-chip coupled) with integrated circuit 9515N. (In other examples, millimeter wave acoustic filters 9116J, 9118J may alternatively or additionally be millimeter wave acoustic resonators, e.g., of this disclosure, coupled (e.g., electrically coupled, e.g., flip-chip coupled) with oscillator circuitry of integrated circuit 9515N, e.g., to provide one or more millimeter wave oscillators, as discussed in detail elsewhere herein). Integrated circuit 9515N may be coupled with antenna elements 9116N, 9118N (e.g., patch antenna elements 9116N, 9118N) via antenna feeds (e.g., metallic antenna feeds 9110K, 9112K). A first antenna feed 9110K may extend through package substrate 914Z, e.g., printed circuit board 914Z. An antenna substrate 915Z, e.g., printed circuit board 915Z, may comprise an antenna ground plane 9115Z. Antenna elements 9116N, 9118N (e.g., patch antennas 9116N, 9118N may be arranged over substrate 915Z. Antenna elements 9116N, 9118N may be encapsulated with a suitable encapsulation 9117Z.

FIG. 11C shows a schematic of a millimeter wave transceiver 9700 employing millimeter wave filters, and a millimeter wave oscillator respectively employing millimeter wave resonators of this disclosure. The circuitry (e.g., any portions thereof) shown in the FIG. 11C schematic of the millimeter wave transceiver 9700 employing millimeter wave filters, and the millimeter wave oscillator respectively employing millimeter wave resonators may be included in the integrated circuit 9515N shown in FIGS. 11A and 11B, or coupled with the integrated circuit 9515N shown in FIGS. 11A and 11B in the antenna in package 9500 shown in FIG. 11A. The integrated circuit 9515N shown in FIGS. 11A and 11B may be plurality of integrated circuits 9515N.

As shown in FIG. 11C, a millimeter wave acoustic resonator 9701 may be employed in a low phase noise millimeter wave oscillator 9702, for example as discussed in detail previously herein. The low phase noise millimeter wave oscillator 9702 comprising the millimeter wave acoustic resonator 9701 may be employed as a high frequency reference 9702 (e.g., millimeter wave frequency reference 9702) for a low phase noise millimeter wave frequency synthesizer 9704. The low phase noise millimeter wave frequency synthesizer 9704 may comprise a frequency multiplication circuit coupled with the low phase noise millimeter wave oscillator 9702 comprising the millimeter wave acoustic resonator 9701. The low phase noise millimeter wave frequency synthesizer 9704 may comprise a frequency division circuit coupled with the low phase noise millimeter wave oscillator 9702 comprising the millimeter wave acoustic resonator 9701. The low phase noise millimeter wave frequency synthesizer 9704 may comprise direct digital synthesis circuitry coupled with the low phase noise millimeter wave oscillator 9702 comprising the millimeter wave acoustic resonator 9701. The low phase noise millimeter wave frequency synthesizer 9704 may comprise direct digital to time converter coupled with the low phase noise millimeter wave oscillator 9702 comprising the millimeter wave acoustic resonator 9701. The low phase noise millimeter wave frequency synthesizer 9704 may comprise frequency mixing circuitry coupled with the low phase noise millimeter wave oscillator 9702 comprising the millimeter wave acoustic resonator 9701. The low phase noise millimeter wave frequency synthesizer 9704 may comprise phase-locked loop circuitry (e.g., a plurality of phase-locked loops) coupled with the low phase noise millimeter wave oscillator 9702 comprising the millimeter wave acoustic resonator 9701.

The foregoing may further be coupled with a low frequency oscillator 9703, e.g., comprising a crystal oscillator, e.g., comprising a quartz crystal oscillator, e.g., as a low frequency reference. For example, the frequency oscillator 9703 may provide the low frequency reference having a relatively low frequency, e.g., about 100 MHz or lower (e.g, or below 10 MHz, e.g., or below 1 MHz, e.g., or below 100 KHz). The low frequency reference 9703 may have an enhanced long term stability, e.g., an enhanced temperature stability relative to the high frequency reference 9702 (e.g., relative to the low phase noise millimeter wave oscillator 9702 comprising the millimeter wave acoustic resonator 9701). The low phase noise millimeter wave frequency synthesizer 9704 may comprise frequency comparison circuitry coupled with the low frequency reference 9703 and with the high frequency reference 9702 to compare an output of the low frequency reference 9703 and an output of the high frequency reference 9702 to generate a frequency comparison signal. The low phase noise millimeter wave frequency synthesizer 9704 may comprise frequency error detection circuitry coupled with the frequency comparison circuitry to receive the frequency comparison signal and coupled with the low frequency reference 9703 and with the high frequency reference 9702 to generate a frequency error signal based at least in part on the frequency comparison signal. The low phase noise millimeter wave frequency synthesizer 9704 may comprise frequency correction circuitry coupled with frequency error detection circuitry to receive the frequency error signal and coupled with the low frequency reference 9703 and with the high frequency reference 9702 to correct frequency errors (e.g. long term stability errors, e.g., temperature dependent frequency drift errors) which would otherwise be present in an output of the low phase noise millimeter wave frequency synthesizer 9704.

Alternatively or additionally, relative to the high frequency reference 9702, the low frequency reference 9703 may have a relatively smaller close-in phase noise contribution to the output of the low phase noise millimeter wave frequency synthesizer 9704, e.g., close-in phase noise within a 100 KiloHertz bandwidth of the output carrier, e.g., close-in phase noise within a 1 MegaHertz bandwidth of the output carrier, e.g., close-in phase noise within 10 MegaHertz bandwidth of the output carrier. Relative the low frequency reference 9703, the high frequency reference 9702, may have a relatively smaller farther-out phase noise contribution to the output of the low phase noise millimeter wave frequency synthesizer 9704, e.g., phase noise within a 100 MegaHertz bandwidth of the output carrier, e.g., phase noise within a 1 GigaHertz bandwidth of the output carrier, e.g., close-in phase noise within a 10 GigaHertz bandwidth of the output carrier. Accordingly, by employing the frequency comparison circuitry, the frequency error detection circuitry, and the frequency correction circuitry, the output of the low phase noise millimeter wave frequency synthesizer 9704 may provide the relatively smaller close-in phase noise contribution derived from the low frequency reference 9703, and may also provide the relatively smaller farther-out phase noise contribution derived from the high frequency reference 9702 (e.g., derived from the low phase noise millimeter wave oscillator 9702 comprising the millimeter wave acoustic resonator 9701). For example, the low phase noise millimeter wave frequency synthesizer 9704 may employ phase lock circuitry to phase lock a signal derived from the high frequency reference 9702 with a signal derived from low frequency reference 9703.

The low phase noise millimeter wave frequency synthesizer 9704 may be coupled with a frequency down converting mixer 9705 to provide the millimeter wave frequency output of the low phase noise millimeter wave frequency synthesizer 9704 to the frequency down converting mixer 9705. The frequency down converting mixer 9705 may be coupled with an analog to digital converter 9706 to provide a down converted signal to be digitized by the analog to digital converter 9706. A receiver band pass millimeter wave acoustic filter 9708 of this disclosure may be coupled between a pair of receiver amplifiers 9707, 9709 to generate a filtered amplified millimeter wave signal. This may be coupled with the frequency down converting mixer 9705 to down covert the filtered amplified millimeter wave signal. Another receiver band pass millimeter wave acoustic filter 9710 may be coupled between another receiver amplifier 9711 and a receiver phase shifter 97100 to provide an amplified phase shifted millimeter wave signal. This may be coupled with a first member 9709 if the pair of receivers 9709, 9707 for amplification. Yet another band pass millimeter wave acoustic filter 9713 may be coupled between antenna 9714 and millimeter wave switch 9712. Time Division Duplexing (TDD) may be employed using millimeter wave switch 9712 to switch between the receiver chain (just discussed) and a transmitter chain of millimeter wave transceiver 9700, to be discussed next.

The low phase noise millimeter wave frequency synthesizer 9704 may be coupled with a frequency up converting mixer 9715 to provide the millimeter wave frequency output of the low phase noise millimeter wave frequency synthesizer 9704 to the frequency up converting mixer 9715. The frequency up converting mixer 9715 may be coupled with a digital to analog converter 9716 to provide a signal to be up converted to millimeter wave for transmission. A transmitter band pass millimeter wave acoustic filter 9718 may be coupled between a pair of transmitter amplifiers 9717, 9719. This may be coupled with the frequency up converting mixer 9715 to receive the up converted millimeter wave signal to be transmitted and to generate a filtered and amplified transmit signal. Another transmitter band pass millimeter wave acoustic filter 9720 may be coupled between a transmit phase shifter 97200 and another transmit amplifier 9721. This may be coupled with a first member 9719 of the pair of transmit amplifiers 9719, 9718 to receive the filtered and amplified transmit signal and to generate a filtered, amplified and phase shifted signal. This may be coupled with the yet another band pass millimeter wave acoustic filter 9713 and antenna 9714 via millimeter wave switch 9712 for transmission.

### FURTHER EXAMPLE EMBODIMENTS

The following examples pertain to further embodiments, from which numerous permutations and configurations will be apparent. The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. A bulk acoustic wave (BAW) resonator comprising:
a substrate;
an active piezoelectric volume having a main resonant frequency, the active piezoelectric volume including first and second piezoelectric layers having respective piezoelectric axis that substantially oppose one another; and
a first patterned layer disposed within the active piezoelectric volume to facilitate suppression of spurious modes.

2. The BAW resonator as in claim 1 in which the first patterned layer comprises a step mass feature.

3. The BAW resonator as in claim 2 in which:
the active piezoelectric volume has a lateral perimeter; and
the step mass feature of the first patterned layer is proximate to the lateral perimeter of the active piezoelectric volume.

4. The BAW resonator as in claim 2 in which:
a first mesa structure having a lateral perimeter comprises the first and second piezoelectric layers having respective piezoelectric axis that substantially oppose one another; and
the step mass feature of the first patterned layer is proximate to the lateral perimeter of the first mesa structure.

5. The BAW resonator as in claim 1 comprising:
top and bottom acoustic reflector electrodes, in which the active piezoelectric volume is interposed between the top and bottom acoustic reflector electrodes;
a first mesa structure including the first and second piezoelectric layers having respective piezoelectric axis that substantially oppose one another;
a second mesa structure including the bottom acoustic reflector electrode; and
a third mesa structure including the top acoustic reflector electrode.

6. The BAW resonator as in claim 1 in which the first patterned layer comprises:
a first step mass feature having a first acoustic impedance; and
a second step mass feature having a second acoustic impedance, in which the first acoustic impedance is different than the second acoustic impedance.

7. (canceled)

8. The BAW resonator as in claim 1 in which the first patterned layer comprises first and second dielectrics that are different from one another.

9. The BAW resonator as in claim 1 in which the first patterned layer comprises a first metal and a first dielectric.

10. The BAW resonator as in claim 1 in which the first patterned layer comprises first and second metals that are different from one another.

11-25. (canceled)

26. The BAW resonator as in claim 1 comprising:
a third piezoelectric layer; and
a second patterned layer interposed between the second and third piezoelectric layers.

27-44. (canceled)

45. The BAW resonator as in claim 1 comprising a top acoustic reflector electrode in which the acoustic reflector electrode includes at least first and second pairs of top metal electrode layers electrically and acoustically coupled with the first and second piezoelectric layers.

46-66. (canceled)

67. The BAW resonator as in claim 1 in which the main resonant frequency of the BAW resonator is in an Institute of Electrical and Electronic Engineers (IEEE) band in one of a Ku band, a K band, a Ka band, a V band and a W band.

68-78. (canceled)

79. The BAW resonator as in claim 45 in which:
the first pair of top metal electrode layers includes at least a first electrode layer having a first conductivity; and
the acoustic reflector electrode includes at least a current spreading layer having an enhanced conductivity that is greater than the first conductivity of the first electrode layer.

80-91. (canceled)

92. The BAW resonator as in claim 1 comprising:
a top acoustic reflector electrode including a first pair of top metal electrode layers including first and second top metal electrode layers electrically and acoustically coupled with the first and second piezoelectric layers; and
a bottom acoustic reflector electrode including a first pair of bottom metal electrode layers including first and second bottom metal electrode layers electrically and acoustically coupled with the first and second piezoelectric layers.

93. (canceled)

94. The BAW resonator as in claim 45 comprising a millimeter wave integrated inductor electrically coupled with the first and second piezoelectric layers via the top acoustic reflector electrode.

95-104. (canceled)

105. An resonator filter, comprising a plurality of bulk acoustic wave (BAW) resonators on a substrate, a first BAW resonator of the plurality of BAW resonators comprising:
an active piezoelectric volume including a first piezoelectric layer having a piezoelectrically excitable main resonant mode, and having a first thickness to facilitate a main resonant frequency; and
a first patterned layer disposed within the active piezoelectric volume to facilitate suppression of spurious modes.

106. The resonator filter as in claim 105 in which:
the first BAW resonator comprises a second piezoelectric layer;
the second piezoelectric layer is acoustically coupled for the piezoelectrically excitable main resonant mode with the first piezoelectric layer;
the first piezoelectric layer has a first piezoelectric axis orientation; and
the second piezoelectric layer has a piezoelectric axis orientation that substantially opposes the first piezoelectric axis orientation of the first piezoelectric layer.

107. An electrical oscillator, comprising:
electrical oscillator circuitry; and
a bulk acoustic wave (BAW) resonator coupled with the electrical oscillator circuitry to excite electrical oscillation in the BAW resonator, in which the BAW resonator comprises an active piezoelectric volume including at least first and second piezoelectric layers; and
a first patterned layer disposed within the active piezoelectric volume to facilitate suppression of spurious modes.

108-129. (canceled)

130. The electrical oscillator as in claim 107 comprising:
a top acoustic reflector electrode including at least a first pair of top metal electrode layers including first and second top metal electrode layers electrically and acoustically coupled with the first and second piezoelectric layers; and
a bottom acoustic reflector electrode including at least a first pair of bottom metal electrode layers including first and second bottom metal electrode layers electrically and acoustically coupled with the first and second piezoelectric layers.

131. (canceled)

132. The electrical oscillator as in claim 130 comprising an integrated inductor electrically coupled with the first and second piezoelectric layers via the top acoustic reflector electrode.

133-233. (canceled)
